(19) United States
(12) Patent Application Publication
(10) Pub. No.: US 2026/0190729 A1
(43) Pub. Date: Jul. 2, 2026

(54) DEVICES AND METHODS FOR MITIGATING DIFFRACTION EFFECTS FOR ELECTRONIC DEVICE HAVING MULTIPLE OPTO-ELECTRONIC COMPONENTS

(71) Applicant: OTI Lumionics Inc., Mississauga (CA)

(72) Inventors: Michael HELANDER, Mississauga (CA); Zhibin WANG, Mississauga (CA); Longxing CHI, Mississauga (CA)

(73) Assignee: OTI Lumionics Inc., Mississauga (CA)

(21) Appl. No.: 19/548,720

(22) Filed: Feb. 24, 2026

Related U.S. Application Data
(63) Continuation of application No. PCT/IB2024/058250, filed on Aug. 24, 2024.
(60) Provisional application No. 63/578,758, filed on Aug. 25, 2023.

(51) Int. Cl. H10K 59/35; H04N 13/122; H04N 13/327; H10K 59/12; H10K 59/65

(52) U.S. Cl. CPC H10K 59/351; H04N 13/122; H04N 13/327; H10K 59/12; H10K 59/65

(57) ABSTRACT

The present disclosure relates to electronic devices having a display panel and a plurality of opto-electronic components, and in particular, mechanisms for mitigating diffraction effects when exchanging light, by such opto-electronic components, through at least one transmissive region of the display panel. The display panel may be one of: be, and comprise, a layered semiconductor device, which in some non-limiting examples, may be an opto-electronic device, having a plurality of (sub-) pixel emissive regions, each comprising first and second electrodes separated by at least one semiconducting layer.

### RELATED APPLICATIONS

The present application is a continuation application of and claims the benefit of priority under 35 U.S.C. § 120 to International Application No. PCT/IB2024/058250 filed 24 Aug. 2024 which claims priority to, and the benefit of US Provisional Patent Application No. U.S. 63/578,758 filed 25 Aug. 2023, each of which is incorporated by reference in its entirety herein.

### TECHNICAL FIELD

The present disclosure relates to electronic devices having a display panel and a plurality of opto-electronic components, and in particular, mechanisms for mitigating diffraction effects when exchanging light, by such opto-electronic components, through at least one transmissive region of the display panel. The display panel may one of: be, and comprise, a layered semiconductor device, which in some non-limiting examples, may be an opto-electronic device, having a plurality of (sub-) pixel emissive regions, each comprising first and second electrodes separated by at least one semiconducting layer.

### BACKGROUND

In an opto-electronic device such as an organic light emitting diode (OLED), at least one semiconducting layer, comprising an emissive layer, may be disposed between a pair of electrodes, such as an anode and a cathode. The anode and cathode may be electrically coupled with a power source and respectively generate holes and electrons that migrate toward each other through the at least one semiconducting layer. When a pair of holes and electrons combine, light, in the form of a photon, may be emitted by the emissive layer.

OLED display panels, such as an active-matrix OLED (AMOLED) panel, may comprise a plurality of pixels, each pixel further comprising a plurality of (including without limitation, one of: three, and four) sub-pixels. In some non-limiting examples, the various sub-pixels of a pixel may be characterized by one of: three, and four, different colors, including without limitation, R(ed), G(reen), and B(lue). Each (sub-) pixel may have an associated emissive region, comprising a stack of an associated pair of electrodes and at least one semiconducting layer between them. In some non-limiting examples, each sub-pixel of a pixel may emit light, including without limitation, photons, that have an associated wavelength spectrum characterized by a given color, including without limitation, one of, R(ed), G(reen), B(lue), and W(hite). In some non-limiting examples, the (sub-) pixels may be selectively driven by a driving circuit comprising at least one thin-film transistor (TFT) structure electrically coupled with conductive metal lines, in some non-limiting examples, within a substrate upon which the electrodes and the at least one semiconducting layer are deposited. Various coatings (layers) of such panels may, in some non-limiting examples, be formed by vacuum-based deposition processes.

In AMOLED panels, light may be emitted by a (sub-) pixel when a voltage is applied across an anode and a cathode of the (sub-) pixel. By controlling the voltage applied across the anode and the cathode, it may be possible to control the emission of light from each (sub-) pixel of such panel. In cases where a common cathode is provided across multiple (sub-) pixels, the voltage across the anode and the cathode in each (sub-) pixel may be controlled by modulating the voltage of the anode. In some non-limiting examples, the adjacent anodes may be spaced apart in a lateral aspect, and at least one non-emissive region may be provided therebetween.

In some non-limiting examples, such panels may be housed in electronic devices, including without limitation, mobile user devices, such as, smartphones. In some non-limiting examples, such electronic device may comprise an opto-electronic component that at least one of: emits, and receives, light, including without limitation, a camera to capture an image of the light emitted from beyond the electronic device.

In some non-limiting examples, such user devices may incorporate a mechanism for biometric authentication of a user thereof before allowing the user to gain access to the user device. Such a mechanism may involve a facial identification system in which a grid of dots of infrared (IR) light is projected, including without limitation, by an IR emitter, such as, a dot projector, in a grid onto a facial surface of the user. The system captures an image of the projected dots on the surface, including without limitation, by an IR camera, and generates a map therefrom. The generated map may be compared to a reference map and if there is sufficient correspondence between them, the user device may be unlocked, allowing the user to access its hardware and associated software. In some non-limiting examples, the facial identification system may comprise a flood illuminator for shining IR light at the facial surface of the user.

While in some non-limiting examples, at least one opto-electronic component, including without limitation, the camera, and at least one of the components of the facial identification system, including without limitation, at least one of the: dot projector, flood illuminator, and IR camera, may be positioned such that the light that is at least one of: emitted, and captured, by such at least one opto-electronic component, does not pass through the panel, increasingly, there may be an aim to house such opto-electronic component within the user device and under the display panel, such that the light that is at least one of: emitted, and captured, by such at least one opto-electronic component, passes through the panel.

In some non-limiting examples, at least a part of the panel may be made to at least one of: be substantially transparent, and allow light, including without limitation, at least one dot of light, to pass therethrough, while still being capable of emitting light therefrom. In some non-limiting examples, the panel may comprise at least one transmissive region lying within at least one non-emissive region extending between the (sub-) pixel emissive regions.

In some non-limiting examples, there may be at least one constraint on at least one of a: number, location, size, and configuration, of the at least one transmissive region relative to at least one of a: number, location, size, and configuration, of the at least one (sub-) pixel emissive regions.

In some non-limiting examples, increasing an aperture ratio (for (a part of) the panel) of the at least one transmissive region relative to an aperture ratio (for a corresponding (part of the) panel) of the at least one (sub-) pixel emissive regions, may facilitate transmission of light through the panel.

In some non-limiting examples, such an increase may impact an ability to at least one of: secure a minimum area of the panel devoted to light-emitting (sub-) pixels, and maintain a minimum pixel density (including without limitation, as measured in pixels per inch (ppi)) of the panel.

In some non-limiting examples, such an increase may impact an ability to arrange the at least one transmissive region among the at least one (sub-) pixel emissive region(s) such that at least one of: the panel, and a (sub-) pixel layout thereof, may appear to be substantially uniform to a user thereof.

In some applications, where at least one of the opto-electronic component(s), including without limitation, the dot projector, and the (IR) camera, are disposed under the panel, the light, including without limitation, that corresponding to a dot, that is at least one of: projected onto, and reflected off, the facial surface, passes, at least partially, through the at least one transmissive region.

Because the panel comprises, in addition to the at least one transmissive region, at least one of a: substantially non-transmissive region, and region having substantially reduced transmissivity, including without limitation, the at least one emissive region(s) and parts of the non-emissive regions, the light exchanged by the under-display component through the panel may become diffracted as a result of passing through the transmissive regions, which may at least one of: distort the transmitted light, redistribute energy of the light across an enlarged area, and cause interference therewith. In some non-limiting examples, the diffraction may impact the ability to distinguish individual features, causing at least one of: blending, and loss, of information, including without limitation, high-frequency information, and phase information, which in some non-limiting examples, may be challenging to compensate for, and accordingly prevent a certain function of the user device from being properly performed.

In some non-limiting examples, there may be an aim to provide a mechanism for mitigating such diffraction effects.

### BRIEF DESCRIPTION OF THE DRAWINGS

Examples of the present disclosure will now be described by reference to the following figures, in which identical reference numerals in different figures indicate at least one of: identical, and in some non-limiting examples, at least one of: analogous, and corresponding elements, and in which:

FIG. 1 is a schematic diagram illustrating an example cross-sectional view of an example user device, comprising a body, a display panel having a plurality of layers, comprising at least one aperture therewithin, through which at least one electromagnetic signal may be exchanged, and at least one under-display component within the device, according to an example in the present disclosure;

FIG. 2A shows an example fragment of at least one display part of the display panel of FIG. 1, according to an example in the present disclosure;

FIGS. 2B and 2C show various example fragments of a signal-exchanging part comprising at least one transmissive region, according to an example in the present disclosure;

FIGS. 3A-3B, and 3C-3D are respective sets of stacked schematic diagrams illustrating respectively in plan and in cross-section, an example cross-sectional view of a fragment of a signal-exchanging part of a display panel, showing an aperture of a transmissive region whose boundary is defined by an intersection of a boundary of a first layer aperture with a boundary of a second layer aperture according to an example in the present disclosure;

FIGS. 4A and 4B are example schematic diagrams illustrating an optical system, according to an example in the present disclosure;

FIG. 5A schematically shows an experimental set-up, in which a point source is viewed by a receiver through a display panel, according to an example in the present disclosure;

FIG. 5B shows an image recorded by the receiver of FIG. 5A, according to an example in the present disclosure;

FIG. 5C shows a plot of normalized intensity profile of the recorded diffraction pattern of FIG. 5A as a function of a spatial position, along with an intensity profile of a theoretical PSF of a point source without considering a beam distribution, and an intensity profile of a simulated PSF that accounts for a beam distribution, calculated for the experimental set-up of FIG. 5A, according to an example in the present disclosure;

FIG. 5D shows a simulated image that reflects the simulated PSF illustrated in FIG. 5C, according to an example in the present disclosure;

FIG. 6A is a plan view of a user device comprising a display panel, according to an example in the present disclosure;

FIG. 6B shows a cross-sectional view of the display panel of FIG. 6A, according to an example in the present disclosure;

FIGS. 7A-7B are schematic diagrams showing a distribution of a first PSF and an intensity plot thereof, respectively, FIGS. 7C-7D are schematic diagrams showing a distribution of a second PSF and an intensity plot thereof, respectively, and FIGS. 7E-7F are schematic diagrams showing the distribution of the first PSF superimposed over the distribution of the second PSF, and the intensity plot of the first PSF superimposed over the intensity plot of the second PSF, respectively, according to an example in the present disclosure;

FIGS. 8A-8B are schematic diagrams showing a distribution of a first PSF and an intensity plot thereof, respectively, FIGS. 8C-8D are schematic diagrams showing a distribution of a second PSF and an intensity plot thereof, respectively, and FIGS. 8E-8F are schematic diagrams showing the distribution of the first PSF superimposed over the distribution of the second PSF, and the intensity plot of the first PSF superimposed over the intensity plot of the second PSF, respectively, according to an example in the present disclosure;

FIGS. 9A-9B are schematic diagrams showing a distribution of a first PSF and an intensity plot thereof, respectively, FIGS. 9C-9D are schematic diagrams showing a distribution of a second PSF and an intensity plot thereof, respectively, and FIGS. 9E-9F are schematic diagrams showing the distribution of the first PSF superimposed over the distribution of the second PSF, and the intensity plot of the first PSF superimposed over the intensity plot of the second PSF, respectively, according to an example in the present disclosure;

FIGS. 10A-10B are schematic diagrams showing a distribution of a first PSF and an intensity plot thereof, respectively, FIGS. 10C-10D are schematic diagrams showing a distribution of a second PSF and an intensity plot thereof, respectively, and FIGS. 10E-10F are schematic diagrams showing the distribution of the first PSF superimposed over the distribution of the second PSF, and the intensity plot of the first PSF superimposed over the intensity plot of the second PSF, respectively, according to an example in the present disclosure;

FIGS. 11A-11E are schematic diagrams showing, in plan, at least a fragment of various example signal-exchange parts of the display panel of FIGS. 6A-6B, according to an example in the present disclosure;

FIGS. 12A-12B shows, in plan, fragments of various example signal-exchanging parts of the display panel of FIG. 1, according to an example in the present disclosure;

FIG. 13 shows, in plan, fragments of various example signal-exchanging parts of the display panel of FIG. 1, according to an example in the present disclosure;

FIG. 14 shows, in plan, fragments of various example signal-exchanging parts of the display panel of FIG. 1, according to an example in the present disclosure;

FIG. 15 shows, in plan, fragments of various example signal-exchanging parts of the display panel of FIG. 1, according to an example in the present disclosure;

FIGS. 16A-16JJ are schematic diagrams showing, in plan, a series of example coupons, each comprising a different layout of a plurality of transmissive regions, according to an example in the present disclosure;

FIG. 17 shows images recorded by the experimental set-up of FIG. 5A, through each of example coupons A1-F6, according to an example in the present disclosure;

FIG. 18A is a schematic diagram showing, in plan, distributions of PSFs of Sample Coupon A3 and Sample Coupon A5, and the interaction therebetween, reproduced based on the recorded image of FIG. 17, according to an example in the present disclosure;

FIG. 18B is a schematic diagram showing, in plan, distributions of PSFs of Sample Coupon E2 and Sample Coupon E4, and the interaction therebetween, reproduced based on the recorded image of FIG. 17, according to an example in the present disclosure;

FIG. 18C is a schematic diagram showing, in plan, distributions of PSFs of Sample Coupon F3 and Sample Coupon F4, and the interaction therebetween, reproduced based on the recorded image of FIG. 17, according to an example in the present disclosure;

FIG. 18D is a schematic diagram showing, in plan, distributions of PSFs of Sample Coupon D4 and Sample Coupon E6, and the interaction therebetween, reproduced based on the recorded image of FIG. 17, according to an example in the present disclosure;

FIG. 19 is a schematic diagram illustrating an example version of the device of FIG. 1 in a cross-sectional view, according to an example in the present disclosure;

FIG. 20 is a flow chart showing method actions, according to an example in the present disclosure;

FIG. 21 is a simplified block diagram from a longitudinal aspect, of an example device having a plurality of layers in a lateral aspect, formed by selective deposition of a patterning coating in a first portion of the lateral aspect, followed by deposition of a closed coating of deposited material in a second portion thereof, according to an example in the present disclosure;

FIG. 22 is a simplified diagram, from a longitudinal aspect, of an example version of the device of FIG. 21, in which the closed coating of deposited material in the second portion forms a second electrode of an opto-electronic device, according to an example in the present disclosure;

FIG. 23 is a schematic diagram showing an example process for depositing a patterning coating in a pattern on an exposed layer surface of an underlying layer in an example version of the device of FIG. 22, according to an example in the present disclosure;

FIG. 24 is a schematic diagram showing an example process for depositing a deposited material in the second portion on an exposed layer surface that comprises the deposited pattern of the patterning coating of FIG. 23 where the patterning coating is a nucleation-inhibiting coating (NIC) according to an example in the present disclosure;

FIG. 25A is a schematic diagram illustrating an example version of the device of FIG. 22 in a cross-sectional view according to an example in the present disclosure;

FIG. 25B is a schematic diagram illustrating the device of FIG. 25A in a complementary plan view according to an example in the present disclosure;

FIGS. 26A-26B are schematic diagrams that show various potential behaviours of a patterning coating at a deposition interface with a deposited layer in an example version of the device of FIG. 22 according to various examples in the present disclosure;

FIGS. 27A-27H are simplified block diagrams from a cross-sectional aspect, of example versions of the device of FIG. 22, showing various examples of possible interactions between the particle structure patterning coating and the particle structures according to examples in the present disclosure;

FIG. 28 is a schematic diagram illustrating an example cross-sectional view of an example version of the device of FIG. 22 with additional example deposition steps according to an example in the present disclosure;

FIG. 29 is a schematic diagram that may show example stages of an example process for manufacturing an example version of an OLED device having sub-pixel regions having a second electrode of different thickness according to an example in the present disclosure;

FIG. 30 is a schematic diagram illustrating an example cross-sectional view of an example version of an OLED device in which a second electrode is coupled with an auxiliary electrode according to an example in the present disclosure;

FIG. 31 is a schematic diagram illustrating an example cross-sectional view of an example version of an OLED device having a partition and a sheltered region, such as a recess, in a non-emissive region thereof according to an example in the present disclosure;

FIGS. 32A-32B are schematic diagrams that show example cross-sectional views of an example OLED device having a partition and a sheltered region, such as an aperture, in a non-emissive region, according to various examples in the present disclosure;

FIG. 33 is an example energy profile illustrating energy states of an adatom absorbed onto a surface according to an example in the present disclosure;

FIG. 34 is a schematic diagram illustrating the formation of a film nucleus according to an example in the present disclosure; and

FIG. 35 is a block diagram of an example computer device within a computing and communications environment that may be used for implementing devices and methods in accordance with representative examples of the present disclosure.

In the present disclosure, a reference numeral having at least one of: at least one numeric value (including without limitation, in at least one of: superscript, and subscript), and at least one alphabetic character (including without limitation, in lower-case) appended thereto, may be considered to refer to at least one of: a particular instance, and subset thereof, of the feature (element) described by the reference numeral. Reference to the reference numeral without reference to the at least one of: the appended value(s), and the character(s), may, as the context dictates, refer generally to the feature(s) described by at least one of: the reference numeral, and the set of all instances described thereby. Similarly, a reference numeral may have the letter “x’ in the place of a numeric digit. Reference to such reference numeral may, as the context dictates, refer generally to feature(s) described by the reference numeral, where the character “x” is replaced by at least one of: a numeric digit, and the set of all instances described thereby.

In the present disclosure, for purposes of explanation and not limitation, specific details are set forth to provide a thorough understanding of the present disclosure, including without limitation, particular architectures, interfaces and techniques. In some instances, detailed descriptions of well-known systems, technologies, components, devices, circuits, methods, and applications are omitted to not obscure the description of the present disclosure with unnecessary detail.

Further, it will be appreciated that block diagrams reproduced herein can represent conceptual views of illustrative components embodying the principles of the technology.

Accordingly, the system and method components have been represented where appropriate by conventional symbols in the drawings, showing only those specific details that are pertinent to understanding the examples of the present disclosure, to not obscure the disclosure with details that will be readily apparent to those of ordinary skill in the art having the benefit of the description herein.

Any drawings provided herein may not be drawn to scale and may not be considered to limit the present disclosure in any way.

Any feature shown in dashed outline, unless the context indicates otherwise, may in some examples be considered as optional.

### SUMMARY

The present disclosure discloses an electronic device, a display panel thereof, and a method for operating the electronic device. The electronic device comprises a display panel extending in a lateral aspect defined by a lateral axis and comprising at least one signal-exchanging part, and a plurality of opto-electronic components. The signal-exchanging part comprises a plurality of emissive regions, each corresponding to a (sub-) pixel; and a plurality of transmissive regions, each transmissive region being disposed between adjacent emissive regions in the lateral aspect. A first opto-electronic component and a second opto-electronic component are each adapted to at least one of: emit, and receive, light in a wavelength spectrum that lies within at least one of a: visible, infrared (IR), and near-infrared (NIR), spectrum, and each has, associated therewith, a point spread function (PSF) comprising a main lobe and at least one side lobe. The first opto-electronic component is arranged behind a first one of the at least one signal-exchanging part(s) of the display panel, such that light that is the at least one of: emitted, and received, by the first opto-electronic component passes through at least one of the transmissive region(s) of the first signal-exchanging part. A first PSF associated with the first opto-electronic component comprises a component associated with a layout of the at least one transmissive region(s) of the first signal-exchanging part, and differs from a second PSF associated with the second opto-electronic component, in at least one of a(n): distribution, and intensity, of at least one of the: main, and at least one side, lobe.

According to a broad aspect, there is disclosed an electronic device comprising: a display panel extending in a lateral aspect defined by a lateral axis and comprising at least one signal-exchanging part comprising: a plurality of emissive regions, each corresponding to a (sub-) pixel; and a plurality of transmissive regions, each transmissive region being disposed between adjacent emissive regions in the lateral aspect, a first opto-electronic component and a second opto-electronic component, each adapted to at least one of: emit, and receive, light in a wavelength spectrum that lies within at least one of a: visible, infrared (IR), and near-infrared (NIR), spectrum, and each having, associated therewith, a point spread function (PSF) comprising a main lobe and at least one side lobe; wherein: the first opto-electronic component is arranged behind a first one of the at least one signal-exchanging part(s) of the display panel, such that light that is the at least one of: emitted, and received, by the first opto-electronic component passes through at least one of the transmissive region(s) of the first signal-exchanging part; and a first PSF associated with the first opto-electronic component comprises a component associated with a layout of the at least one transmissive region(s) of the first signal-exchanging part, and differs from a second PSF associated with the second opto-electronic component, in at least one of a(n): distribution, and intensity, of at least one of the: main, and at least one side, lobe.

In some non-limiting examples, a side-lobe pattern of the first PSF may be substantially devoid of a side lobe that overlaps with a side-lobe pattern of the second PSF.

In some non-limiting examples, a side-lobe pattern of the first PSF may at least partially overlap with a side-lobe pattern of the second PSF.

In some non-limiting examples, a first subset of the at least one side lobe of the first PSF may at least partially overlap with one of: all, and a subset of, the side lobes of the second PSF.

In some non-limiting examples, a second subset of the at least one side lobe of the first PSF may be substantially devoid of a side lobe that overlaps with any side lobe of the second PSF.

In some non-limiting examples, each side lobe of one of the: first, and second, PSF, may correspond to and at least partially overlap with a side lobe of the other of the: first, and second, PSF.

In some non-limiting examples, the overlap between the side-lobe pattern of the first PSF and the side-lobe pattern of the second PSF may be one of no more than about: 60%, 50%, 40%, 30%, 20%, 25%, 20%, 10%, and 5%.

In some non-limiting examples, an intensity of the at least one side lobe of the first PSF may differ from an intensity of the at least one side lobe of the second PSF, in at least one of: a profile, and an intensity level.

In some non-limiting examples, the main lobe of the first PSF may at least partially overlap with a side lobe of the second PSF.

In some non-limiting examples, a distribution of the main lobe of the first PSF may differ from a distribution of the main lobe of the second PSF.

In some non-limiting examples, the main lobe of the first PSF may differ from the main lobe of the second PSF, in at least one of: a profile, and an intensity level.

In some non-limiting examples, the layout of the at least one transmissive region of the at least one signal-exchanging part may be characterized by at least one of a: size, shape, orientation, and pitch, thereof.

In some non-limiting examples, the second opto-electronic component may be arranged behind a second one of the at least one signal-exchanging part, such that light that is the at least one of: emitted, and received, by the second opto-electronic component may pass through at least one of the transmissive regions of the second signal-exchanging part, and the second PSF may comprise a component associated with a layout of the at least one transmissive region(s) of the second signal-exchanging part that is different from the layout of the at least one transmissive region(s) of the first signal-exchanging part, in at least one of the: size, shape, orientation, and pitch, thereof.

In some non-limiting examples, the first opto-electronic component and the second opto-electronic component may be spaced apart in the lateral aspect of the display panel.

In some non-limiting examples, the first opto-electronic component and the second opto-electronic component may be positioned substantially at at least one of: an extremity of the display panel, a centre thereof, and a centre of one of: a side, and an end, of the display panel.

In some non-limiting examples, the second opto-electronic component may be arranged in a part of the device that is substantially devoid of the (sub-) pixels of the display panel.

In some non-limiting examples, at least one of the: first opto-electronic component, and second opto-electronic component, may comprise at least one of: a transmitter adapted to emit light, and a receiver adapted to receive light.

In some non-limiting examples, the second opto-electronic component may be a non under-display component.

In some non-limiting examples, the second opto-electronic component may be the transmitter.

In some non-limiting examples, the first opto-electronic component may be an under-display camera.

In some non-limiting examples, at least a part of at least one transmissive region of at least one of: the first signal-exchanging part, and the second signal-exchanging part, may have, deposited thereon, a patterning coating adapted to impact a propensity of an evaporated flux of a deposited material to be deposited thereon.

In some non-limiting examples, the at least one transmissive region may comprise a first portion that has a first transmittance, and a second portion that has a second transmittance, the transmittance being at least that of the second transmittance.

In some non-limiting examples, the patterning coating may be deposited at least in the first portion.

In some non-limiting examples, the first opto-electronic component may be adapted to generate a first output that contains diffracted information correlated with the first PSF, the second opto-electronic component may be adapted to generate a second output that contains diffracted information correlated with the second PSF, and the device may comprise a processor adapted to process the first output and the second output to produce a processed output.

In some non-limiting examples, the processor may be adapted to apply a correction to the: first, and second, output, to generate a first corrected output and a second corrected output.

In some non-limiting examples, the correction may comprise diffraction correction.

In some non-limiting examples, the diffraction correction may correct diffraction contained in the output of one of the: first, and second, opto-electronic component using the PSF of the other of the: first, and second, opto-electronic component.

In some non-limiting examples, the processor may be adapted to produce the processed output by combining the first corrected output and the second corrected output.

In some non-limiting examples, the processed output may be displayed by the display panel.

In some non-limiting examples, the processed output may comprise at least one of: an image file, a video file, a 3D image, and a 3D video.

According to a broad aspect, there is disclosed a display panel comprising: a display part comprising a plurality of emissive regions, a first signal-exchanging part and a second signal-exchanging part, each comprising: a plurality of emissive regions, each corresponding to a (sub-) pixel; and a plurality of transmissive regions that allows light in a wavelength spectrum that lies within at least one of a: visible, infrared (IR), and near-infrared (NIR), spectrum to pass therethrough, each transmissive region being disposed between adjacent emissive regions in a lateral aspect of the display panel, wherein: each of the: first, and second, signal-exchanging part, has associated therewith, a point spread function (PSF) comprising: a main, and at least one side, lobe, a layout of the transmissive regions of the first signal-exchanging part is different from a layout of the transmissive regions of the second signal-exchanging part, such that a first PSF associated with the first signal-exchanging part may be different from a second PSF associated with the second signal-exchanging part, in at least one of a(n): distribution, and intensity, of at least one of the: main, and at least one side, lobe.

In some non-limiting examples, a side-lobe pattern of the first PSF may be substantially devoid of a side lobe that overlaps with a side-lobe pattern of the second PSF.

In some non-limiting examples, a side-lobe pattern of the first PSF may at least partially overlap with a side-lobe pattern of the second PSF.

In some non-limiting examples, a first subset of the at least one side lobe of the first PSF may at least partially overlap with one of: all, and a subset, of the side lobes of the second PSF.

In some non-limiting examples, a second subset of the at least one side lobe of the first PSF may be substantially devoid of a side lobe that overlaps with any side lobe of the second PSF.

In some non-limiting examples, each side lobe of one of the: first, and the second, PSF, may correspond to and at least partially overlaps with, a side lobe of the other of the: first, and second, PSF.

In some non-limiting examples, the overlap between the side-lobe pattern of the first PSF and the side-lobe pattern of the second PSF may be one of no more than about: 60%, 50%, 40%, 30%, 20%, 25%, 20%, 10%, and 5%.

In some non-limiting examples, an intensity of the at least one side lobe of the first PSF may differ from an intensity of the at least one side lobe of the second PSF, in at least one of: a profile, and an intensity level.

In some non-limiting examples, the main lobe of the first PSF may at least partially overlap with a side lobe of the second PSF.

In some non-limiting examples, a distribution of the main lobe of the first PSF may differ from a distribution of the main lobe of the second PSF.

In some non-limiting examples, the main lobe of the first PSF may differ from the main lobe of the second PSF, in at least one of: a profile, and an intensity level.

In some non-limiting examples, the layout of the transmissive regions of each signal-exchanging part may be characterized by at least one of a: size, shape, orientation, and pitch, thereof.

In some non-limiting examples, at least a part of at least one transmissive region of at least one of the: first, and second, signal-exchanging part, may have deposited thereon, a patterning coating adapted to impact a propensity of an evaporated flux of a deposited material to be deposited thereon.

In some non-limiting examples, the at least one transmissive region may comprise a first portion that has a first transmittance, and a second portion that has a second transmittance, the first transmittance being at least that of the second transmittance.

In some non-limiting examples, the patterning coating may be deposited at least in the first portion.

According to a broad aspect, there is disclosed a method for operating an electronic device comprising a display panel, and a first opto-electronic component and a second opto-electronic component, each opto-electronic component being adapted to at least one of: emit, and receive, light in a wavelength spectrum that lies within at least one of a: visible, infrared (IR), and near-infrared (NIR), spectrum, and generate an output that contains diffracted information correlated with a point spread function (PSF) thereof, wherein: the first opto-electronic component is arranged behind a first signal-exchanging part comprising a plurality of transmissive regions of the display panel, such that a first PSF associated with the first opto-electronic component comprises a component associated with a layout of the transmissive regions of the first signal-exchanging part, and differs from a second PSF associated with the second opto-electronic component, the method comprising actions of: processing a first output of the opto-electronic component and a second output of the opto-electronic component to produce a processed output.

In some non-limiting examples, the second opto-electronic component may be arranged behind a second signal-exchanging part comprising a plurality of transmissive regions of the display panel, such that a second PSF associated with the second opto-electronic component may comprise a component associated with a layout of the transmissive regions of the second signal-exchanging part.

In some non-limiting examples, the action of processing may comprise processing the output of one of: the first opto-electronic component and the second opto-electronic component using the PSF of the other of: the first opto-electronic component and the second opto-electronic component.

In some non-limiting examples, the action of processing may comprise an action of correcting the first output and the second output to generate a first corrected output and a second correct output.

In some non-limiting examples, the action of correcting may comprise diffraction correction.

In some non-limiting examples, the diffraction correction may correct diffraction contained in the output of one of the first opto-electronic component and the second opto-electronic component using the PSF of the other of the first opto-electronic component and the second opto-electronic component.

In some non-limiting examples, the action of correcting may be performed separately for each of the first output and the second output.

In some non-limiting examples, the action of correcting may be performed by cross-referencing the first output with the second output.

In some non-limiting examples, the action of processing may comprise an action of combining the first corrected output and the second correct output to generate a combined output.

In some non-limiting examples, the action of combining may comprises combining the first corrected output and the second corrected output by at least one of a: fusion, and stitching, process.

In some non-limiting examples, the action of correcting may be preceded by an action of pre-processing the first output and the second output.

In some non-limiting examples, the action of combining may be followed by an action of post-processing the combined output.

In some non-limiting examples, the method may comprise an action of displaying the processed output on the display panel.

In some non-limiting examples, the processed output may comprise at least one of: an image file, a video file, a 3D image, and a 3D video.

In some non-limiting examples, at least one of the first opto-electronic component, and the second opto-electronic component, may comprise at least one of: a transmitter adapted to emit light, and a receiver adapted to receive light.

In some non-limiting examples, the second opto-electronic component may be a non under-display component.

In some non-limiting examples, the second opto-electronic component may be the transmitter.

In some non-limiting examples, the first opto-electronic component may be an under-display camera.

### DESCRIPTION

### Display Panel and User Device

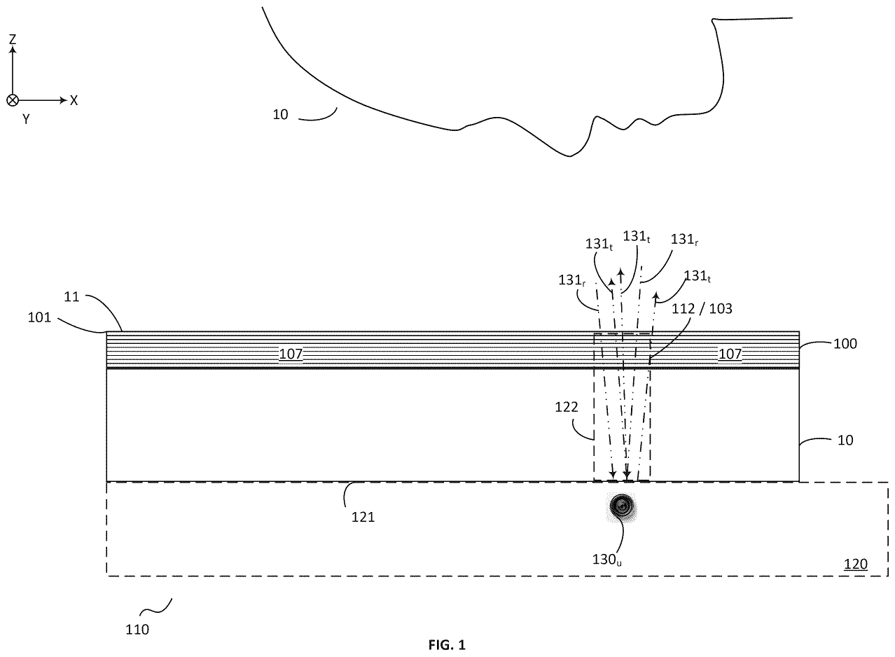

Turning now to FIG. 1, there is shown a cross-sectional view of an example layered opto-electronic device, in the form of a display panel 100. In some non-limiting examples, the display panel 100 may comprise a plurality of layers deposited on a substrate 10, culminating with an outermost layer that forms a face 101 thereof.

A lateral axis, identified as the X-axis, may be shown, together with a longitudinal axis, identified as the Z-axis. A second lateral axis, identified as the Y-axis, may be shown as being substantially transverse to both the X-axis and the Z-axis. At least one of the lateral axes may define a lateral aspect of the device. The longitudinal axis may define a longitudinal aspect of the device.

The face 101 of the display panel 100 may extend across a lateral aspect thereof, substantially along a plane defined by the lateral axes.

In some non-limiting examples, the face 101, and indeed, the entire display panel 100, may act as a face of an electronic device 110 through which at least one EM signal 131 may be exchanged therethrough at a non-zero angle relative to the plane of the face 101. In some non-limiting examples, the electronic device 110 may be a user device 110, including without limitation, a computing device 110, including without limitation, a smartphone, a tablet, a laptop, an e-reader, and some other electronic device 110, such as a monitor, a television set, and a smart device 110, including without limitation, an automotive display, windshield, a household appliance, a wearable device, and a medical, commercial, and industrial device 110.

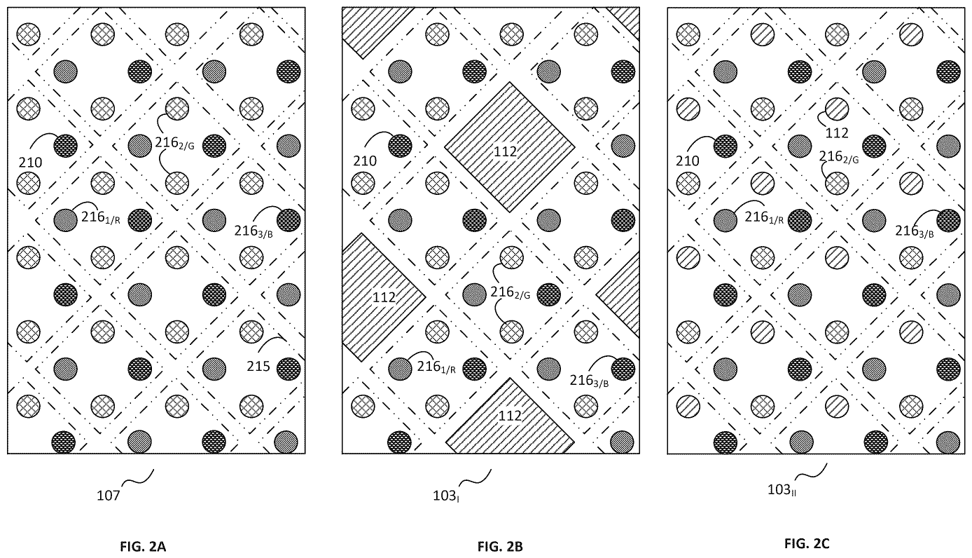

In some non-limiting examples, the electronic device 110 may comprise at least one opto-electronic component 130 that at least one of: emits, and receives, light. In some non-limiting examples, the at least one opto-electronic component 130 may comprise an under-display component (UDC) 130ᵤ disposed under the display panel 100. Although not shown in FIG. 1, in some non-limiting examples, the at least one opto-electronic component 130 may comprise a non under-display component 130ₙ, including without limitation, a punch-hole component 130ₙ, which at least one of: emits, and receives, light that does not pass through the display panel 100. In some non-limiting examples, the non under-display component 130ₙ may be positioned in a non-display part (not shown) of the display panel 100, which in some non-limiting examples, may be substantially devoid of any emissive regions 210 (FIG. 2). In some non-limiting examples, the non-display part may be in a form of, including without limitation, a cut-out, a notch, and a bezel.

In some non-limiting examples, the face 101 may correspond to, and in some non-limiting examples, mate with, at least one of: a body 120, and an opening 121 therewithin, within which the at least one under-display component 130ᵤ may be housed.

In some non-limiting examples, the at least one under-display component 130ᵤ may be formed, including without limitation, at least one of: integrally, and as an assembled module, with the display panel 100 on a surface thereof opposite to the face 101.

In some non-limiting examples, at least one aperture 122 may be formed in the display panel 100 to allow for the exchange of at least one EM signal 131 with the at least one under-display component 130ᵤ through the face 101 of the display panel 100, at a non-zero angle to the plane defined by the lateral axes, including without limitation, concomitantly, the layers of the display panel 100, including without limitation, the face 101 of the display panel 100.

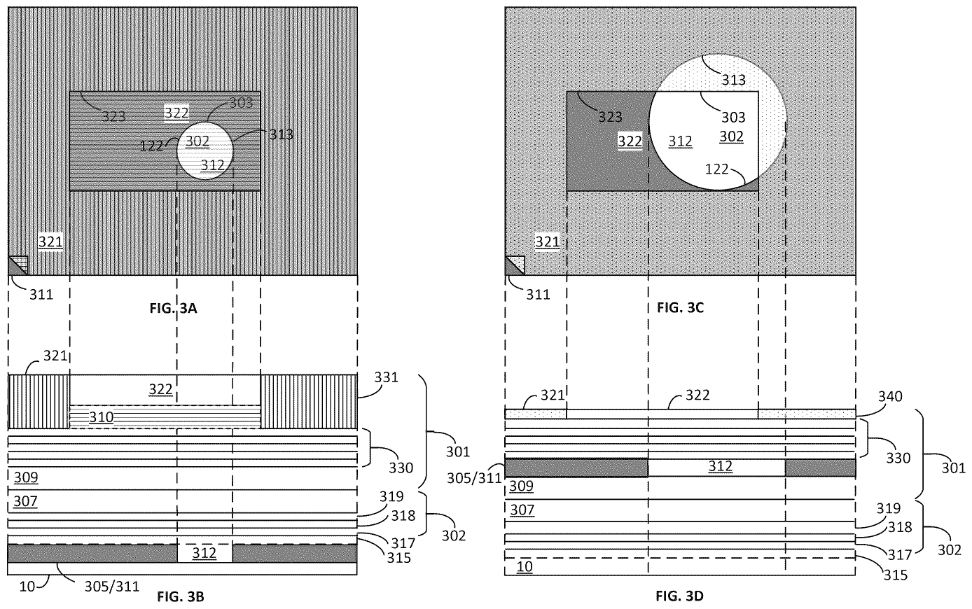

In some non-limiting examples, the at least one aperture 122 may be understood to comprise one of: absence, and reduction, in at least one of: thickness, and coverage, of a substantially opaque region/coating 305 (FIG. 3) and a substantially reduced transmissivity region/coating otherwise disposed across the display panel 100. In some non-limiting examples, the at least one aperture 122 may be embodied as a transmissive region 112 as described herein. In some non-limiting examples, a boundary of the transmissive region 112 may be defined by the aperture 122.

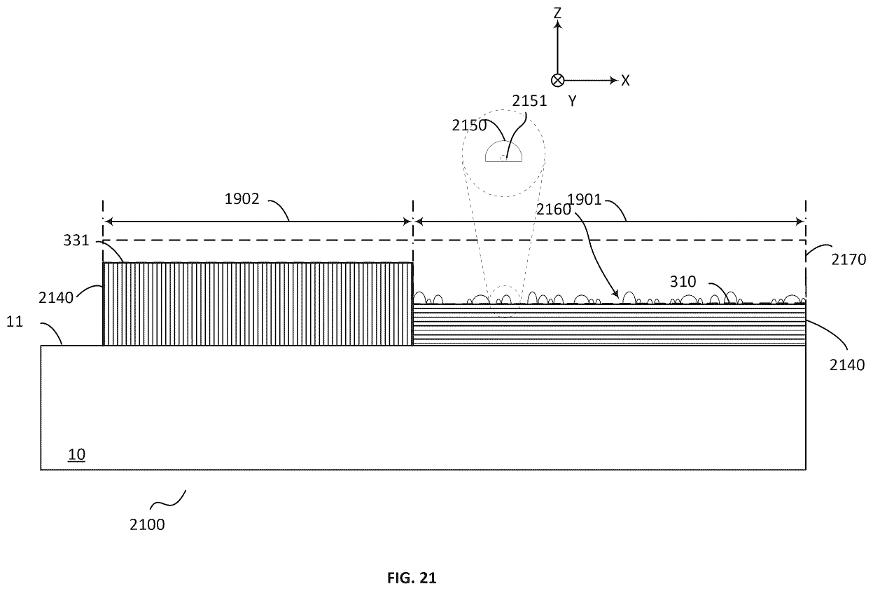

However the at least one aperture 122 is embodied, the at least one EM signal 131 may pass therethrough such that it passes through the face 101. As a result, the at least one EM signal 131 may be considered to exclude any EM radiation that may extend along the plane defined by the lateral axes, including without limitation, any electric current that may be conducted across at least one particle structure 2150 (FIG. 21) laterally across the display panel 100.

Further, those having ordinary skill in the relevant art will appreciate that the at least one EM signal 131 may be differentiated from EM radiation per se, including without limitation, one of: electric current, and an electric field generated thereby, in that the at least one EM signal 131 may convey, either one of: alone, and in conjunction with other EM signals 131, some information content, including without limitation, an identifier by which the at least one EM signal 131 may be distinguished from other EM signals 131. In some non-limiting examples, the information content may be conveyed by at least one of: specifying, altering, and modulating, at least one of: the wavelength, frequency, phase, timing, bandwidth, intensity, time of flight, spatial position, and other characteristic of the at least one EM signal 131.

In some non-limiting examples, the at least one EM signal 131 exchanged with the at least one opto-electronic component 130, including without limitation, (not) passing through the at least one aperture 122 of the display panel 100, may comprise at least one photon and, in some non-limiting examples, may have a wavelength spectrum that lies, without limitation, within at least one of the: visible, IR, and near-infrared (NIR), spectrum. In some non-limiting examples, the at least one EM signal 131 may have a wavelength that lies, without limitation, within at least one of the: IR, and NIR, spectrum.

In some non-limiting examples, the at least one EM signal 131 may comprise ambient light incident thereon.

In some non-limiting examples, the at least one EM signal 131 exchanged through the at least one aperture 122 of the display panel 100 may be at least one of: transmitted, and received, by the at least one under-display component 130ᵤ.

In some non-limiting examples, the at least one under-display component 130ᵤ may have a size that is at least a single transmissive region 112, but may underlie not only a plurality thereof, but also at least one emissive region 210 extending therebetween. In some non-limiting examples, the at least one under-display component 130ᵤ may have a size that is at least a single one of the at least one aperture 122.

In some non-limiting examples, the at least one opto-electronic component 130 may comprise a receiver 130ᵣ, adapted to receive and process at least one received EM signal 131ᵣ. In some non-limiting examples, such receiver 130ᵣ may comprise a camera, including without limitation, an under-display camera, including without limitation, an IR camera, and a detector, including without limitation, IR sensor/detector, an NIR sensor/detector, a LIDAR sensing module, a fingerprint sensing module, an optical sensing module, an IR (proximity) sensing module, an iris recognition sensing module, and a facial identification system, including without limitation, a part thereof.

In some non-limiting examples, the at least one opto-electronic component 130 may comprise a transmitter 130ₜ adapted to emit at least one transmitted EM signal 131ₜ. In some non-limiting examples, such transmitter 130ₜ may comprise a source of light, including without limitation, a built-in flash, a flashlight, an IR emitter, a NIR emitter, a LIDAR sensing module, a fingerprint sensing module, an optical sensing module, an IR proximity sensing module, an iris recognition sensing module, and a facial identification system, including without limitation, a part thereof, including without limitation, at least one of a: dot-matrix projector, and flood illuminator.

In some non-limiting examples, the at least one received EM signal 131ᵣ may include at least a fragment of the at least one transmitted EM signal 131ₜ which is one of: reflected off, and otherwise returned by, a surface, including without limitation, of a user 10, that is external to the user device 110.

In some non-limiting examples, the at least one EM signal 131 passing through the at least one aperture 122 of the display panel 100 beyond the user device 110, including without limitation, those transmitted EM signals 131ₜ emitted by the at least one under-display component 130ᵤ that may comprise a transmitter 130ₜ, may emanate from the display panel 100, and pass back as received EM signals 131ᵣ through the at least one aperture 122 of the display panel 100 to at least one under-display component 130ᵤ that may comprise a receiver 130ᵣ.

In some non-limiting examples, the under-display component 130ᵤ may comprise an IR emitter and an IR sensor. In some non-limiting examples, such under-display component 130ᵤ may comprise, as one of: a part, component, and module, thereof: at least one of: a dot-matrix projector, a time-of-flight (ToF) sensor module, which may operate as one of: a direct ToF, and an indirect ToF, sensor, a vertical cavity surface-emitting laser (VCSEL), flood illuminator, NIR imager, folded optics, and a diffractive grating.

In some non-limiting examples, there may be a plurality of under-display components 130ᵤ within the user device 110, a first one of which may comprise a transmitter 130ᵣ for emitting at least one transmitted EM signal 131ᵣ to pass through the at least one aperture 122, beyond the user device 110, and a second one of which may comprise a receiver 130ᵣ, for receiving at least one received EM signal 131ᵣ. In some non-limiting examples, such transmitter 130ₜ and receiver 130ᵣ may be embodied in a single under-display component 130ᵤ.

### Signal-Exchanging Part and Display Part

In some non-limiting examples, the display panel 100 may comprise at least one signal-exchanging part 103 and at least one display part 107.

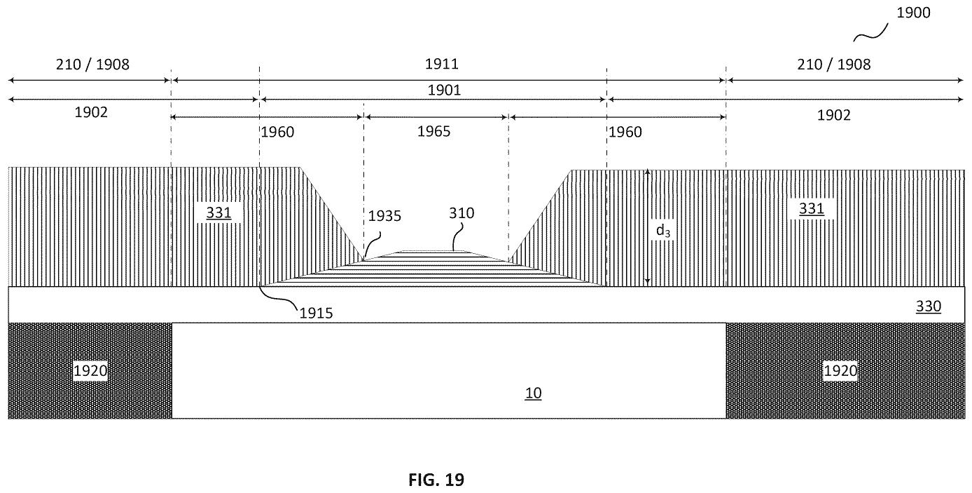

In some non-limiting examples, the at least one display part 107 may comprise a plurality of emissive regions 210, in some non-limiting examples, laid out in a lateral pattern. In some non-limiting examples, the emissive regions 210 in the at least one display part 107 may correspond to (sub-) pixels 215/216 (FIG. 2) of the display panel 100. In some non-limiting examples, at least one non-emissive region 1911 (FIG. 19) may lie adjacent to each emissive region 210, such that each emissive region 210 may be effectively surrounded by non-emissive region(s) 1911.

In some non-limiting examples, the at least one signal-exchanging part 103 may comprise at least one emissive region 210 and at least one transmissive region 112. In some non-limiting examples, the at least one emissive region 210 in the at least one signal-exchanging part 103 may correspond to (sub-) pixel(s) 215/216 of the display panel 100, and in some non-limiting examples, may be substantially laid out in a similar, including without limitation, identical, lateral pattern as in the at least one display part 107.

In the present disclosure, the term “transmissive region” refers to region(s) of the display panel 100, including without limitation, the at least one transmissive region 112 in the at least one signal-exchanging part 103 thereof, that may be configured to permit an increased fraction of EM radiation, incident upon the display panel 100, to be transmitted therethrough, at least in comparison to another region of the display panel 100 that is not a transmissive region 112, including without limitation, in the at least one display part 107.

In some non-limiting examples, the at least one display part 107 may be adjacent to, and in some non-limiting examples, separated by, at least one signal-exchanging part 103.

In some non-limiting examples, the at least one signal-exchanging part 103 may be positioned substantially centrally within the lateral aspect of the display panel 100.

In some non-limiting examples, the at least one display part 107 may substantially surround, including without limitation, in conjunction with at least one other display part 107, the at least one signal-exchanging part 103.

In some non-limiting examples, the at least one signal-exchanging part 103 may be positioned proximate to an extremity of the display panel 100, including without limitation, at least one of: an edge, and a corner, thereof, and configured such that the at least one display part(s) 107 do(es) not completely surround the at least one signal-exchanging part 103.

Those having ordinary skill in the relevant art will appreciate that there may be scenarios calling for the layout, including without limitation, at least one of a: number, size (including without limitation, aperture ratio), shape, orientation, (colour) order, configuration, and pitch, of (sub-) pixels 215/216 in the signal-exchanging part 103 of the display panel 100 to resemble, to some extent, the layout thereof in the at least one display part 107 of the display panel 100, including without limitation, where the pitch thereof in the at least one signal-exchanging part 103 is one of: the same, and an integer multiple thereof, of a pitch thereof in the at least one display part 107.

Having said this, examples in the present disclosure may have applicability in some scenarios in which the layout of (sub-) pixels 215/216 in the at least one signal-exchanging part 103 may be substantially different than the layout thereof in the at least one display part 107 of the display panel 100.

In some non-limiting examples, a pixel density of the at least one signal-exchanging part 103 of the display panel 100 may be no more than a pixel density of the at least one display part 107 of the display panel 100.

In some non-limiting examples, at least one of a: size (including without limitation, aperture ratio), shape, orientation, (colour) order, configuration, and pitch, of the (sub-) pixels 215/216 in the at least one signal-exchanging part 103 of the display panel 100 may be substantially identical to that of the (sub-) pixels 215/216 in the at least one display part 107 of the display panel 100, however a number of such (sub-) pixels 215/216 may be reduced in the signal-exchanging part 103 of the display panel 100. In such scenarios, in some non-limiting examples, a common fine metal mask (FMM) may be used for patterning at least the (sub-) pixels 215/216 in both the at least one signal-exchanging part 103 and the at least one display part 107, with an attendant reduction of manufacturing cost and complexity. In such scenarios, in some non-limiting examples, those apertures in the FMM corresponding to those (sub-) pixel(s) 215/216 that are not present (omitted) in the at least one signal-exchanging part 103 may be covered (blocked) when in use with the at least one signal-exchanging part 103, so as to substantially preclude the formation of such at least one (sub-) pixel(s) 215/216. In some non-limiting examples, at least one transmissive region 112 may be formed in region(s) where the formation of such at least one (sub-) pixel(s) 215/216 has been substantially precluded in the signal-exchanging part 103.

In some non-limiting examples, increasing an aperture ratio (for (a part of) the display panel 100) of the at least one transmissive region 112 relative to an aperture ratio (for a corresponding (part of the) display panel 100) of the at least one emissive regions 210, may impose a constraint on an ability to maintain continuity in at least one of: number, size (including without limitation, aperture ratio), shape, orientation, (colour) order, configuration, and pitch, of (sub-) pixels 215/216 across both the at least one signal-exchanging part 103 and the at least one display part 107, other than for modifications made to at least one of: number, size (including without limitation, aperture ratio), shape, orientation, (colour) order, configuration, and pitch, of (sub-) pixels 215/216 in the at least one signal-exchanging part 103 to accommodate the introduction of at least one transmissive region 112 in their place. Those having ordinary skill in the relevant art will appreciate that such modifications may technically alter the pitch of the (sub-) pixels 215/216 in the at least one signal-exchanging part 103.

Turning to FIG. 2A, there is shown an example fragment of the at least one display part 107 of the display panel 100. For purposes of illustration, some example pixels 215 are shown in dashed outline. In some non-limiting examples, each pixel 215 comprises four sub-pixels 216, including without limitation, a first sub-pixel 216₁, which may, in some non-limiting examples, be a R(ed) sub-pixel 216_{R}, two second sub-pixels 216₂, which may, in some non-limiting examples, be G(reen) sub-pixels 216_{G}, and a third sub-pixel 216₃, which may, in some non-limiting examples, be a B(lue) sub-pixel 216_{B}.

In some non-limiting examples, as shown in FIG. 2B, in an example signal-exchanging part 103₁, the layout of (sub-) pixels 215/216 in the at least one display part 107 shown in FIG. 2A may be replicated, such that the size (including without limitation, aperture ratio), shape, orientation, (colour) order, configuration, and pitch, of the (sub-) pixels 215/216 are the same, except that a subset of the pixels 215 may be omitted and replaced by respective transmissive region(s) 112.

In some non-limiting examples, as shown in FIG. 2C, in an example signal-exchanging part 103₁, the layout of (sub-) pixels 215/216 in the at least one display part 107 shown in FIG. 2A may be replicated, such that the size (including without limitation, aperture ratio), shape, orientation, (colour) order, configuration, and pitch, of the (sub-) pixels 215/216 are the same, except that in at least some of the pixels 215, at least one of the sub-pixels 216 thereof, including without limitation, one of the two second sub-pixels 216₂, may be omitted and replaced by respective transmissive region(s) 112.

While the transmissive regions 112 have been generally illustrated herein as having a clearly defined boundary, which in some non-limiting examples, may be defined by at least one aperture 122 which may be substantially devoid of any at least one of: elements, coatings, and materials that at least one of: are opaque, substantially limit, and prevent, transmission of light incident on an external surface thereof, those having ordinary skill in the relevant art will appreciate that in some non-limiting examples where a region disposed between the emissive regions 210 of the signal-exchanging part 103, including without limitation, the non-emissive region(s) 1911, and a part thereof, is sufficiently transparent, such region may be considered as a transmissive region 112, and accordingly, such transmissive region 112 may not have a clearly defined boundary.

In some non-limiting examples, the display panel 100 may further comprise at least one transition region (not shown) between the at least one signal-exchanging part 103 and the at least one display part 107, wherein the configuration of at least one of: the emissive regions 210, and the transmissive regions 112 therein, may differ from those of at least one of: the at least one signal-exchanging part 103, and the at least one display part 107. In some non-limiting examples, such transition region may be omitted such that the emissive regions 210 may be provided in a substantially continuous repeating pattern across both the at least one signal-exchanging part 103 and the at least one display part 107.

In some non-limiting examples, a pixel density of the at least one emissive region 210 of the at least one signal-exchanging part 103 may be substantially the same as a pixel density of the at least one emissive region 210 of the at least one display part 107 proximate thereto, at least in an area thereof that is substantially proximate to the at least one signal-exchanging part 103. In some non-limiting examples, the pixel density of the display panel 100 may be substantially uniform thereacross. In at least some applications, there may be scenarios calling for the at least one signal-exchanging part 103 and the at least one display part 107 to have substantially the same pixel density, including without limitation, so that a resolution of the display panel 100 may be substantially the same across both the at least one signal-exchanging part 103 and the at least one display part 107 thereof.

In some non-limiting examples, the at least one signal-exchanging part 103 may have a polygonal contour, including without limitation, at least one of a substantially: square, and rectangular, configuration.

In some non-limiting examples, the at least one signal-exchanging part 103 may have a curved contour, including without limitation, at least one of a substantially: circular, oval, and elliptical, configuration.

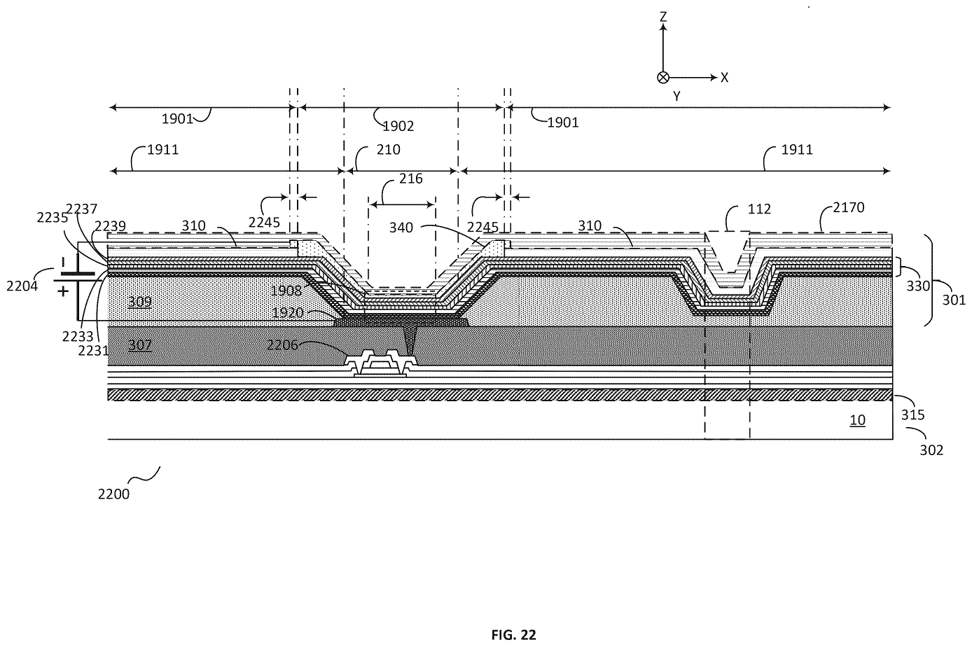

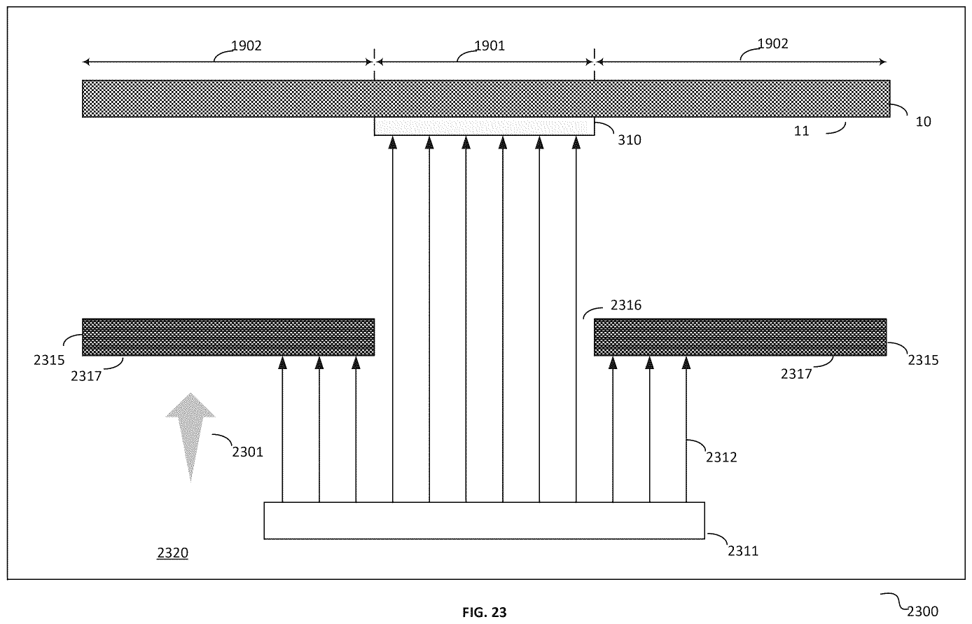

In some non-limiting examples, the at least one signal-exchanging part 103 may have a reduced number of, including without limitation, be substantially devoid of, backplane components, including without limitation, TFT structures 2206 (FIG. 22), including without limitation, metal trace lines, capacitors, and other light-absorbing element, including without limitation, opaque elements, the presence of which may otherwise interfere with the transmission, and concomitantly, at least one of the: capture, and emission, of the EM signals by the at least one under-display component 130ᵤ, including without limitation, the capture of an image by a camera.

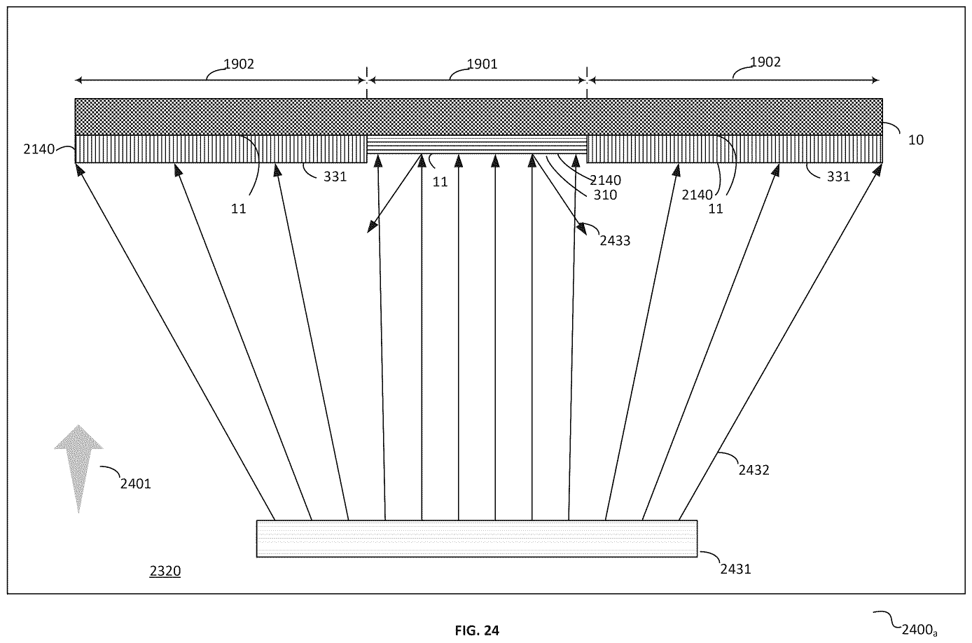

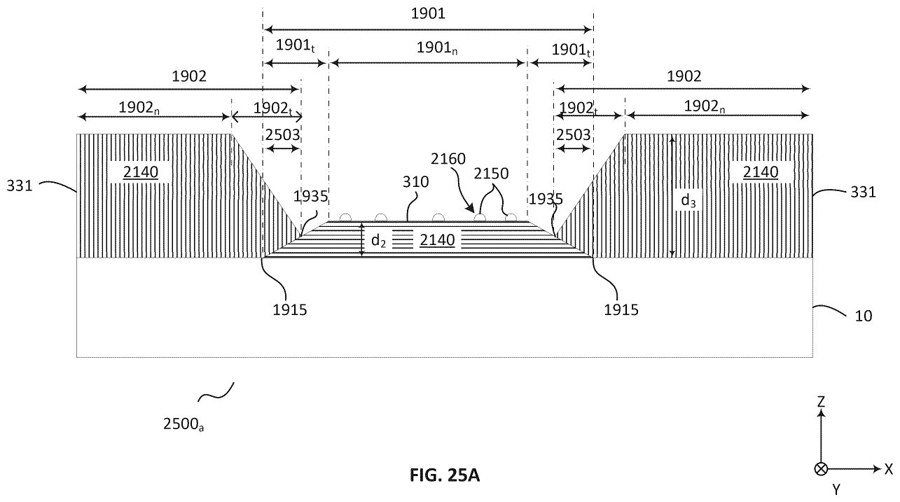

In some non-limiting examples, the at least one transmissive region 112 may be achieved by ensuring the absence of material in at least one defining layer 311, 321 (FIG. 3A), including without limitation, deposited material 2431 (FIG. 24) forming a deposited layer 331 (FIG. 3B), of which the second electrode 340 may be comprised, that substantially reduces transmission of EM radiation therethrough, in at least one wavelength range of the EM spectrum, including without limitation, at least one of (a part of) the: visible, UV, IR, and NIR, spectrum, in regions, in the lateral aspect, corresponding to at least one of the: location, shape, spacing, size, orientation, and position, in the form of at least one boundary 303 (FIG. 3A), of aperture(s) 122 defining it.

In some non-limiting examples, such defining layers 311, 321 may comprise: at least one of: a layer that may be typically encountered in an opto-electronic device 2100, including without limitation, the substrate 10, at least one layer in the backplane 302 (FIG. 3A), including without limitation, at least one TFT structure 2206, a TFT insulating layer 307 (FIG. 3B), a buffer layer 317 (FIG. 3B), a gate insulating layer 318 (FIG. 3B), an interlayer insulating layer 319 (FIG. 3B), at least one conductive metal line coupled with the at least one TFT structure 2206 (including without limitation, data and scan lines which, in some non-limiting examples, may be formed of at least one of: Cu, and a TCO), and the first electrode 1920 (FIG. 19), and at least one layer in a frontplane 301 (FIG. 3B), including without limitation, the first electrode 1920, the second electrode 340 (FIG. 3D), at least one semiconducting layer 330 (FIG. 3B) therebetween, and a PDL 309 (FIG. 3B), to the extent that such layer substantially reduces transmission of light therethrough in at least a wavelength range of the EM spectrum, including without limitation, at least one of (a part of) the: visible, UV, IR, and NIR, spectrum.

Those having ordinary skill in the relevant art will appreciate that in some non-limiting examples, the first electrode 1920 of an opto-electronic device 2200 may be considered to form part of the backplane 302 (FIG. 3B), and in some non-limiting examples, the first electrode 1920 of an opto-electronic device 2200 may be considered to form part of the frontplane 301.

As used herein, the term “substantially reduces transmission of EM radiation therethrough” may generally refer to a reduction, in the transmission of EM radiation therethrough, that is one of about: 99%, 95%, 90%, 80%, 75%, 70%, 60%, 50%, 40%, and 30%.

In some non-limiting examples, the definition of transmissive regions 112, using at least one defining layer 311, 321 that may be typically encountered in an opto-electronic device 2200, that, to at least some extent, may substantially reduce transmission of EM radiation therethrough in at least a wavelength range off the EM spectrum, including without limitation, at least one of: the visible spectrum, the UV spectrum, the IR spectrum, the NIR spectrum, and a part thereof, may introduce a “grey zone” in which the ability to substantially reduce transmission of EM radiation of such at least one defining layer 311, 321, is substantially less than 100% and a substantial fraction of the EM radiation may pass through such defining layer(s) 311, 321 beyond the at least one boundary 313, 323 (FIG. 3A) of aperture(s) 312, 322 defining corresponding transmissive regions 112.

In some non-limiting examples, such defining layers 311, 321 may comprise at least one opaque region/coating 305 that substantially reduces transmission of EM radiation therethrough in at least a wavelength range of the EM spectrum, including without limitation, at least one of (a part of) the: visible, UV, IR, and NIR, spectrum. In some non-limiting examples, such opaque region/coating 305 may not be typically encountered in an opto-electronic device 2200 but has been introduced for purposes of contributing to the definition of at least one boundary 313, 323 of aperture(s) 312, 322 defining corresponding transmissive region(s) 112.

In some non-limiting examples, the use of an opaque region/coating 305 in at least one of the defining layers 311, 312, including without limitation, the first defining layer 311, may reduce a likelihood that at least one boundary 313, 323 of aperture(s) 312, 322 defining corresponding transmissive region(s) 112 may have reduced definition, including without limitation, having a transition region proximate to the at least one boundary 313, 323 of aperture(s) 312, 322 defining corresponding transmissive region(s) 112, in which a reduced amount of EM radiation may be transmitted therethrough.

In some non-limiting examples, the absence of material in aperture(s) 312, 322 in defining layer(s) 311, 321, including without limitation, one of: a layer that may be typically encountered in an opto-electronic device 2200, and an opaque region/coating 305 introduced for purposes of contribution to a definition of at least one boundary 313, 323 of aperture(s) 312, 322 defining corresponding transmissive region(s) 112, may be achieved by removal of such material, including without limitation, by laser ablation.

In some non-limiting examples, the absence of such material may be achieved by ensuring that such material fails to be deposited thereon, including without limitation, by depositing a patterning material 2311 (FIG. 23) in a pattern, including without limitation, corresponding to at least one boundary 313, 323 of aperture(s) 312, 322 defining corresponding transmissive region(s) 112.

In some non-limiting examples, the action of depositing the patterning material 2311 may make use of a shadow mask 2315 (FIG. 23) such as, without limitation, an FMM, during a vapour deposition process, in which the patterning material 2311 is deposited through at least one aperture 2316 (FIG. 23) in the shadow mask 2315 that corresponds to at least one aperture(s) 312, 322 defining corresponding transmissive region(s) 112.

However achieved, in some non-limiting examples, the absence of such material may be restricted to the at least one boundary 313, 323 of aperture(s) 312, 322 defining corresponding transmissive region(s) 112.

In some non-limiting examples, a deposited layer 331 comprising a deposited material 2431 may be deposited in the frontplane 301, in a lateral pattern comprising at least one frontplane aperture 322, characterized by the absence of a closed coating 2140 (FIG. 21) of the deposited material 2431 therewithin, on an exposed layer surface 11 of an underlying layer 2610.

In some non-limiting examples, the lateral pattern of the deposited layer 331 may be specified by depositing a patterning coating 310, comprising a patterning material 2311, including without limitation, a nucleation-inhibiting coating (NIC), in a pattern, including without limitation, by interposing a shadow mask 2315 therebetween during the deposition process, prior to the deposition of the deposited material 2431.

In some non-limiting examples, when the patterning coating 310 comprises an NIC, the pattern of the patterning material 2311 may substantially correspond to at least one boundary 323 of (frontplane) second layer aperture(s) 322, such that, when the deposited material 2431 is thereafter deposited, the deposited material 2431 tends not to be deposited where the patterning coating 310 has been deposited, and tends to accumulate to form the deposited layer 331 in areas that are substantially devoid of the patterning coating 310.

In some non-limiting examples, the lateral pattern of the deposited layer 331 may be specified by depositing the deposited material 1231 through apertures of a shadow mask 2315 in a pattern that is substantially the reverse of the lateral pattern of the at least one (frontplane) second layer aperture(s) 322.

In some non-limiting examples, the lateral pattern of the deposited layer 331 may be specified by depositing the deposited material 2431 and thereafter removing deposited material 2431 corresponding to the at least one (frontplane) second layer aperture(s) 322, including without limitation, by laser ablation.

As shown in the complementary views of FIGS. 3A-3B, and of FIGS. 3C-3D, those having ordinary skill in the relevant art will appreciate that at least one boundary 313, 323 of aperture(s) 312, 322 defining corresponding transmissive region(s) 112, may be defined by a geometric intersection, of at least one first layer aperture boundary 313, of first layer aperture(s) 312, in the lateral aspect, of a first defining layer 311, and of at least one overlapping second layer aperture boundary 323, of second layer aperture(s) 322, in the lateral aspect, of a second defining layer 321, wherein each of: the first defining layer 311, and the second defining layer 312, substantially reduce transmission of EM radiation therethrough.

FIG. 3A is a view of a fragment of the signal-exchanging part 103 shown in plan. FIG. 3B is a complementary cross-sectional view of various layers of the opto-electronic device 2100 across the fragment, including a first defining layer 311 and a second defining layer 321.

In FIG. 3B, at least one layer, including without limitation, at least one layer in the backplane 302, including without limitation: the buffer layer 317, the gate insulating layer 318, the interlayer insulating layer 319, and the TFT insulating layer 307, are shown disposed on a first side of the substrate 10, including without limitation, an exposed layer surface of the base substrate 315. In some non-limiting examples, at least one layer in the frontplane 301, including without limitation: a PDL 309, and at least one semiconducting layer 330, may be disposed on an exposed layer surface 11 of such layer(s) in the backplane 302.

As shown in FIGS. 3A and 3C, the first defining layer 311 may have at least one first layer aperture 312 therein, defined by a corresponding first layer aperture boundary 313 and the second defining layer 321 may have at least one second layer aperture 322 therein, defined by a corresponding second layer aperture boundary 323. The geometric intersection of the first layer aperture boundary 313 overlapping with the second layer aperture boundary 323 may result in an aperture boundary 303 defining an aperture 122, including without limitation, as shown in FIG. 3C.

In some non-limiting examples, a shape of the first layer aperture boundary 313 may be different from a shape of the second layer aperture boundary 323. In some non-limiting examples, as shown, the first layer aperture boundary 313 may exhibit a first shape, including without limitation, a substantially circular shape as shown. In some non-limiting examples, as shown, the second layer aperture boundary 323 may exhibit a second shape, including without limitation, a substantially rectangular shape as shown. In some non-limiting examples, at least one of: the first layer aperture boundary 313, and the second layer aperture boundary 323 may exhibit a substantially irregular shape.

In some non-limiting examples, as shown in FIG. 3A, the first layer aperture boundary 313 may lie entirely within the second layer aperture boundary 323, such that the at least one boundary 303 of aperture(s) 122 may be defined solely by the first layer aperture boundary 313.

In some non-limiting examples, although not shown, the second layer aperture boundary 323 may lie entirely within the first layer aperture boundary 313, such that the at least one boundary 303 of aperture(s) 122 may be defined solely by the second layer aperture boundary 323.

In some non-limiting examples, as shown in FIG. 3B, the first defining layer 311 may comprise a layer in the backplane 302. Where the first defining layer 311 is disposed within the backplane 302, the at least one first layer aperture 312 may be a backplane aperture.

In some non-limiting examples, as shown in FIG. 3D, the first defining layer 311 may comprise a layer in the frontplane 301. Where the first defining layer 311 is disposed within the frontplane 301, the at least one first layer aperture 312 may be a frontplane aperture.

In some non-limiting examples, as shown in FIG. 3B, the first defining layer 311 may comprise an opaque region/coating 305, including without limitation, disposed on the first side of the substrate 10.

Those having ordinary skill in the relevant art will appreciate that, although not shown, in some non-limiting examples, the opaque region/coating 305 may be disposed on the exposed layer surface 11 of other layers, including without limitation, at least one of: the base substrate 315 (corresponding to the first side of the substrate 10), at least one layer in the backplane 302, including without limitation, at least one of: at least one TFT structure 2206, the TFT insulating layer 307, the buffer layer 317, the gate insulating layer 318, the interlayer insulating layer 319, and the first electrode 1920.

In some non-limiting examples, although not shown, the first defining layer 311 may comprise an opaque region/coating 305 disposed on a second side of the substrate 10, which may be opposite to the first side of the substrate 10 corresponding to the base substrate 315.

In some non-limiting examples, as shown in FIG. 3D, the first defining layer 311 may comprise an opaque region/coating 305, including without limitation, disposed on an exposed layer surface 11 of the PDL 309.

Those having ordinary skill in the relevant art will appreciate that, although not shown, in some non-limiting examples, the opaque region/coating 305 may be disposed on the exposed layer surface 11 of other layers of the frontplane 301, including without limitation, at least one of: the first electrode 1920, the second electrode 340, and at least one semiconducting layer 330 therebetween.

In some non-limiting examples, although not shown, the first defining layer 311 may comprise an existing layer of the frontplane 301, including without limitation, at least one of: the first electrode 1920, the second electrode 340, and at least one semiconducting layer 330 therebetween, and the PDL 309.

In some non-limiting examples, although not shown, the at least one first layer aperture boundary 313 of first layer aperture(s) 312 may be formed in existing (backplane) first defining layer(s) 311 of the backplane 302 and without depositing an opaque region/coating 305, including without limitation, by relocating, including without limitation, removing, elements of such (backplane) first defining layer(s) 311 that substantially reduce transmission of EM radiation therethrough in at least a wavelength range of the EM spectrum, including without limitation, at least one of (a part of) the: visible, UV, IR, and NIR, spectrum, including without limitation, elements that are at least one of: opaque, and reflective, including without limitation, at least one TFT structure 2206, and at least one conductive metal line coupled with the at least one TFT structure 2206 (including without limitation, data and scan lines).

In some non-limiting examples, the second defining layer 321 may comprise a layer in the frontplane 301. Where the second defining layer 321 is disposed within the frontplane 301, the second layer aperture 322 may be a frontplane aperture.

In some non-limiting examples, although not shown, the second defining layer 321 may comprise a layer in the backplane 302. Where the second defining layer 321 is disposed within the backplane 302, the second layer aperture 322 may be a backplane aperture.

In some non-limiting examples, as shown in FIG. 3B, the second defining layer 321 may comprise a deposited layer 331, of which the second electrode 340 may be comprised.

In some non-limiting examples, as shown in FIG. 3D, the second defining layer 321 may comprise the second electrode 340.

In some non-limiting examples, where the first defining layer 311 is disposed within the backplane 302, other mechanisms for patterning the at least one (backplane) first aperture boundary 313 of (backplane) first aperture(s) 312 of the (backplane) first defining layer 311, may be employed, including without limitation, photolithography, chemical etching, and laser ablation.

### Point Spread Function

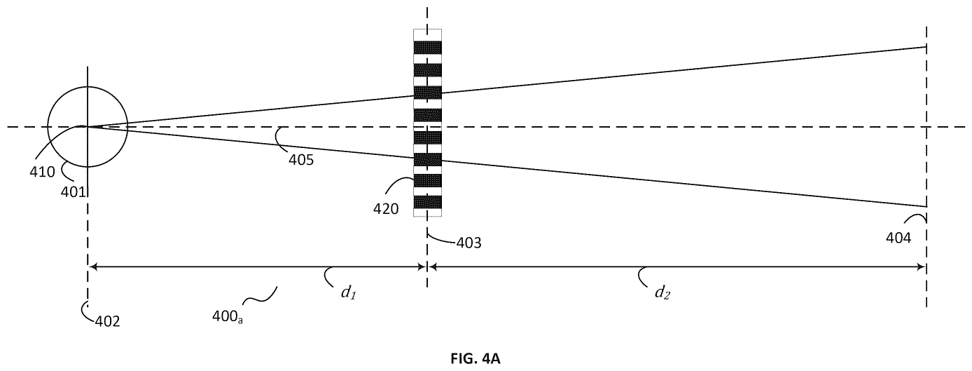

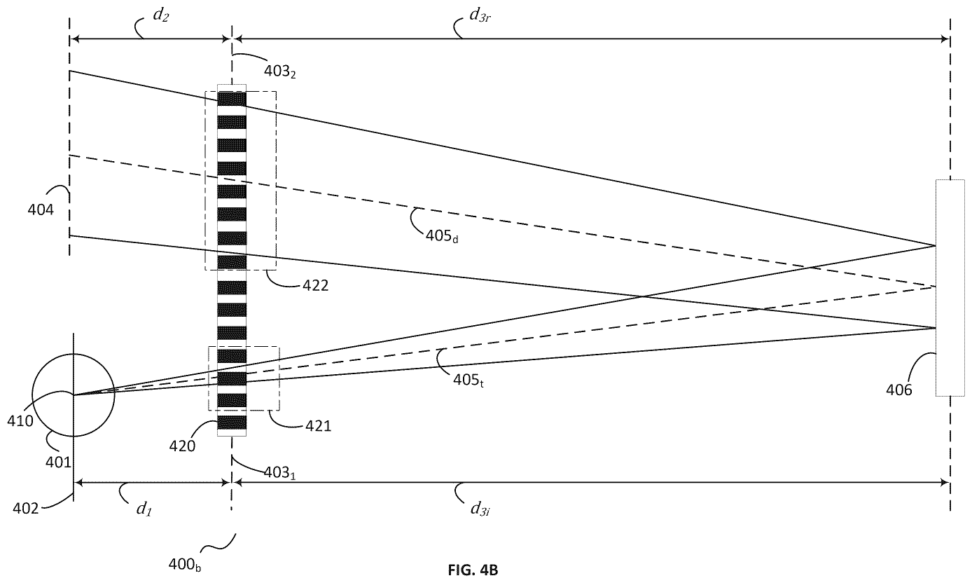

In some non-limiting examples, a point spread function (PSF) of an optical system 420 (FIG. 4A) may be used to study diffraction characteristics of a display panel 100, comprising at least one signal-exchanging part 103 that has at least one opto-electronic component 130, including without limitation, an under-display component 130ᵤ, associated therewith, and comprises at least one transmissive region 112, that allows light that is at least one of: emitted, and received, by the at least one opto-electronic component 130, to pass through.

In some non-limiting examples, a PSF associated with an opto-electronic component 130 may comprise a component associated with optics of the opto-electronic component 130. In some non-limiting examples, the PSF associated with the opto-electronic component 130 may comprise a component associated with the at least one transmissive region(s), including without limitation, a layout thereof, of the signal-exchanging part, behind which the opto-electronic component 130 is arranged.

In some non-limiting examples, the PSF associated with an opto-electronic component 130 may be represented as an integrated PSF, which may be determined based, at least partially, on a PSF exhibited by the opto-electronic component 130, a PSF associated with, including without limitation, exhibited by, (a part of) the display panel 100 through which light passes through, including without limitation, the signal-exchanging part 103, and PSF(s) exhibited by any other optical component(s)/layer(s), including without limitation, part(s) thereof, which are in the optical path.

In some non-limiting examples, a(n) (integrated) PSF associated with an opto-electronic component 130 may be evaluated by a model simulating an optical system 420 formed by the display panel 100.

In some non-limiting examples where the opto-electronic component is a receiver 130ᵣ, including without limitation, at least one of: a camera, and a detector, the (integrated) PSF may be measured by providing, at the input of the optical system 420, one of: a point source 410 (FIG. 4A) of light, and a reference object, which, in some non-limiting examples, may be in a form of a point object that may, in some non-limiting examples, comprise well-defined features, at an object plane 402 (FIG. 4A) and providing, at the output of the optical system 420, the opto-electronic component 130, to capture transmitted light at an image plane 404 (FIG. 4A). In some non-limiting examples where the opto-electronic component 130 is a transmitter 130ₜ, the opto-electronic component 130 may be provided at the input, and a receiver 130ᵣ, including without limitation, a camera, and a photodiode, may be provided at the output to capture the transmitted light.

In some non-limiting examples, the (integrated) PSF may be derived by analyzing the light pattern that is at least one of: recorded on the image plane 404, and received by the receiver 130ᵣ. Those having ordinary skill in the relevant art will appreciate that the PSF may be measured using various techniques known in the art, including without limitation, the direct imaging method, the pinhole method, and the knife-edge method.

In some non-limiting examples, the PSF may be represented in a spatial domain as a three-dimensional distribution describing at least one of: a shape, a pattern, and an intensity, of the PSF. In some non-limiting examples, the spatial domain representation PSFs may exhibit a central, main lobe, which may be surrounded by at least one side lobe. In some non-limiting examples, the main lobe may represent a main peak of the distribution, which in some non-limiting examples, may have a(n) (intensity) level that is a (local) maximum.

In some non-limiting examples, the main lobe may correspond to a 0^{th} order peak corresponding to an image that is substantially not diffracted.

In some non-limiting examples, the at least one side lobe may correspond to an n^{th} order peak, contributing to a diffracted image. In some non-limiting examples, characteristics, including without limitation, a number, shape, size, pattern, and intensity of the side lobes may describe a distribution of the side peak(s) relative to the main peak, and in some non-limiting examples, may indicate a presence of diffraction and other optical artifacts, including without limitation, aberration, and scattering. In some non-limiting examples, including without limitation, where the point source 410 is substantially fully coherent, the at least one side lobe may have at least one of the: shape, and size, that is similar, including without limitation, substantially identical, to that of the main lobe.

In some non-limiting examples, a(n) (intensity) level of the side peaks may reflect an intensity of the side peaks as a fraction of an intensity of the main peaks.

In some non-limiting examples where blurring of the point source 410 may be restricted without being overly dispersed, a well-defined main lobe may be formed with minor, including without limitation, indiscernible, side lobes, and may indicate at least one of: reduced artifacts, a good resolution, and an increased signal-to-noise ratio (SNR).

In some non-limiting examples, the PSF may be represented in a frequency domain as an optical transfer function (OTF). In some non-limiting examples, the OTF may be derived by a Fourier transform of the spatial domain PSFs, which in some non-limiting examples, may be complex-valued. In some non-limiting examples, a magnitude of the OTF may be defined as a modulation transfer function (MTF). In some non-limiting examples, the OTF may provide information on the PSF, including without limitation, frequency response, and phase information. In some non-limiting examples, the OTF may exhibit at least one of a: peak, and valley. In some non-limiting examples, a peak/valley exhibited at a frequency may indicate an ability/limitation, respectively, to resolve at least one of: fine details, and high-frequency information, at such frequency.

In some non-limiting examples, the (integrated) PSF may be estimated by theoretical modelling. In some non-limiting examples, a mathematical model may be built to calculate a simulated PSF, based on optical properties of the optical system 420 formed by the display panel 100. Those having ordinary skill in the relevant will appreciate that the PSF may be estimated using various modelling techniques and algorithms in the art, including without limitation, ray tracing, Gaussian models, and Fourier transform models.

Turning now to FIG. 4A, there is shown an example schematic diagram shown generally at 400ₐ illustrating the transmission, of a wave 401, including without limitation, at least one of: a collimated wave and, a spherical wave, emitted by a source 410 (“emitted EM signal”), including without limitation, a point source, of light at an object plane 402, by an optical system 420, to an image plane 404.

In some non-limiting examples, the source 410 may comprise a(n) (part of) image on a surface external to the user device 110, including without limitation, a facial surface of the user 10, illuminated by an illuminator, including without limitation, a flashlight, and an IR emitter, including without limitation, at least one of: a flood illuminator for illuminating the surface facilitating detection of the surface, and a dot-matrix projector for projecting a plurality of dots, including without limitation, of (IR) light, including without limitation, in a grid, onto the surface, and building a depth map therefrom. In some non-limiting examples, where the IR emitter is a dot-matrix projector, the illumination of the surface by one of the dots may serve as the point source 410.

In some non-limiting examples, the source 410 may comprise a device external to the user device 110, including without limitation, an IR emitter, including without limitation, at least one of: a flood illuminator for illuminating the surface facilitating detection of the surface, and a dot-matrix projector for projecting a plurality of dots, including without limitation, of IR light, including without limitation, in a grid, onto the surface and building a depth map therefrom. In some non-limiting examples, where the IR emitter is a dot-matrix projector, one of the dots may serve as the source 410.

In some non-limiting examples, the image plane 404 may comprise a(n) (part of) image on a surface external to the user device 110, including without limitation, a facial surface of the user 10, captured by a camera, including without limitation, an IR camera.

In some non-limiting examples, the image plane 404 may be (part of) a device external to the user device 110, including without limitation, a camera, including without limitation, an IR camera, for capturing an image on a surface external to the user device 100, including without limitation, a facial surface of the user 10.

In some non-limiting examples, the optical system 420 may comprise at least one signal-exchanging part 103 comprising at least one transmissive region 112 of a display panel 100 of a user device 110 and having an associated PSF. In some non-limiting examples, the associated PSF may comprise components thereof associated with the at least one transmissive region 112, including those related to the layout thereof, including without limitation, at least one of a: size (including without limitation, an aperture ratio), shape, orientation, and pitch, thereof.

In some non-limiting examples, the image plane 404 may be a focal plane of an opto-electronic component 130, including without limitation, an under-display component 130ᵤ, including without limitation, an IR sensor. In some non-limiting examples, an image of the emitted EM signal received at the image plane 404 may be a received version thereof (“received EM signal”).

In some non-limiting examples, a distance between the object plane 402 and a focal plane 403 of the optical system 420 may be represented by d₁, while a distance between the focal plane 403 of the optical system 420 and the image plane 404 may be represented by d₂.

In some non-limiting examples, a two-dimensional impulse function in the spatial domain of the projection of the source 410 through the optical system 420 onto the image plane 404 may be given by Equation (1):

$$h ( x , y ) = f ( x , y ) ⊕ g ( x , y ) \qquad ( 1 )$$

where:
f(x,y) is a two-dimensional impulse function in the spatial domain of the source 410; and
g(x,y) is the spatial PSF of the optical system 420.

Accordingly, if the PSF of the optical system 420 is known, f(x,y) may be recovered (“recreated EM signal”) from the received EM signal recorded by the opto-electronic component 130, by taking the inverse Fourier transform F(u,v) of f(x,y), by a deconvolution operation, including without limitation, a Wiener filter, given by Equation (2):

$$F ( u , v ) = \frac{H ( u , v )}{G ( u , v )} \cdot \frac{{\vert G ( u , v ) \vert}^{2}}{{\vert G ( u , v ) \vert}^{2} + C} \qquad ( 2 )$$

where:
G(u,v) is the Fourier transform of g(x,y);
H(u,v) is the Fourier transform of h(x,y); and
C is a noise-related component, including without limitation, at least one of a function, and a constant.

In some non-limiting examples, the optical system 420 may comprise additional components (not shown) in the optical path, including without limitation, at least one of: optical elements (including without limitation, lenses, and prisms), which may be positioned within the user device 110 between at least one of: the object plane 402 and the optical system 420, and the optical system 420 and the image plane 404 (including without limitation, as part of the under-display component 130ᵤ), and other elements which may introduce distortion, including without limitation, diffraction effects, into the optical system 420, including without limitation, additional components of the display panel 100, including without limitation, electrodes 1920, 340, 2850, TFT structures 2206, particle structures 2150, and overlying layers 2170, thereof.

Those having ordinary skill in the relevant art will appreciate that the presence of such additional components in the optical path may one of: introduce additional focal planes (not shown) to the diagram 400, and alter the effective position of any one of: d₁, and d₂.

Those having ordinary skill in the relevant art will appreciate that the PSF of the optical system 420 on the image plane 404 may reflect aspects contributed by any of such additional components in addition to the aspects contributed by the display panel 100, and the at least one transmissive region 112 therethrough.

In some non-limiting examples, the source of the light incident on the surface may be a component that is not an under-display component 130ᵤ, including without limitation, a non under-display component 130ₙ, which does not pass light through a part of the display panel 100, such that the light incident on the surface may not pass through the optical system 420.

In some non-limiting examples, the source of the light incident on the surface may be an under-display component 130ᵤ, such that the light incident on the surface passes through the optical system 420.

In some non-limiting examples, the image plane 404 may be part of a component, including without limitation, one of: an external camera and a non under-display component 130ₙ, such that the capture of such light may not pass through the optical system 420.

In some non-limiting examples, the image plane 404 may be an under-display component 130ᵤ, such that the capture of the light incident on the surface passes through the optical system 420.

In some non-limiting examples, both the source 410 and the component housing the image plane 404 may be considered to be under-display components 130ᵤ, and as shown in FIG. 4B, the optical system 420 may be considered to be comprised of two optical system components 421, 422, each corresponding to a signal-exchanging part 103 comprising at least one transmissive region 112 of a display panel 100 of a user device 110 and having an associated PSF, including without limitation, a common signal-exchanging part 103. In some non-limiting examples, the source 410 may comprise a first opto-electronic component 130₁, including without limitation, a transmitter 130ₜ. In some non-limiting examples, the component housing the image plane 404 may comprise a second opto-electronic component 130₂, including without limitation, a detector 130_{d}.

As used herein, the term “transmitter-side”, unless the context indicates otherwise, may generally ascribe to a term that it modifies, the sense that the term lies along, including without limitation, intersects, an optical path 405ₜ of an EM signal emanating from, including without limitation, transmitted by, the source 410 of a transmitter that is an under-display component 130ᵤ, and directed toward, including without limitation, impinging upon, a reflector 406, including without limitation, a surface, including without limitation, of the user 10, that is external to the user device 110.

As used herein, the term “detector-side”, unless the context indicates otherwise, may generally ascribe to a term that it modifies, the sense that the term lies along, including without limitation, intersects, an optical path 405ₐ of an EM signal emanating from the reflector 406, including without limitation, a surface, including without limitation, of the user 10, that is external to the user device 110, and directed toward, including without limitation, impinging upon, the image plane 404 of a detector that is an under-display component 130ᵤ.

In some non-limiting examples, as shown, the first optical system component 421 may be positioned such that the optical path 405ₜ passes therethrough, such that the first optical system component 421 may be considered a transmitter-side optical system component 421.

In some non-limiting examples, as shown, the second optical system component 422 may be positioned such that the optical path 405ₐ passes therethrough, such that the second optical system component 422 may be considered a detector-side optical system component 422.

In some non-limiting examples, the first optical system component 421 may be substantially the same as the second optical system component 422, other than the fact that light passes through the at least one transmissive region 112 of a display panel 100 of a user device 110 in the first optical system component 421 in a direction that is opposite to a direction that light passes through the at least one transmissive region 112 of a display panel 100 of a user device 110 in the second optical system component 422.

In some non-limiting examples, at least one of: the PSF associated with the first optical system component 421, and the PSF associated with the second optical system component 422, may comprise components thereof associated with the corresponding at least one transmissive region 112, including those related to the layout thereof, including without limitation, at least one of a: size (including without limitation, an aperture ratio), shape, orientation, and pitch, thereof.

In some non-limiting examples, the PSF associated with the first optical system component 421 may be substantially the same as the PSF associated with the second optical system component 422. In some non-limiting examples, the PSF associated with the first optical system component 421 may be different from the PSF associated with the second optical system component 422.

In some non-limiting examples, a distance between a focal plane 403₁ of the first optical system component 421 and a focal plane 4032 of the second optical system component 422 may be represented by d₃ᵢ+d₃ᵣ, where d₃ᵢ is a distance between the focal plane 403₁ of the first optical system component 421 and a surface external to the user device 110, including without limitation, the user 10, travelled by the light emitted by the source 410 through the at least one transmissive region 112, and incident on the surface, and der is a distance between the surface external to the user device 110, including without limitation, the user 10, and the focal plane 4032 of the second optical system component 422, travelled by the light reflected off the surface and returning through the at least one transmissive region 112, and received at the image plane 404. In some non-limiting examples, d₃ᵢ=d₃ᵣ.

In some non-limiting examples, light transmitted through a signal-exchanging part 103, comprising at least one transmissive region 112, of the display panel 100 having associated therewith at least one opto-electronic component 130, including without limitation, the one disposed behind the panel, may be modulated, including without limitation, interfered with, by each individual optical component in an optical path 405, including without limitation, optics of: the at least one opto-electronic component 130, and the signal-exchanging part 103, including without limitation, at least one of a: size (including without limitation, an aperture ratio), shape, orientation, and pitch, of the at least one transmissive region 112 located therein.

In some non-limiting examples where the PSFs of each optical component, including without limitation, the opto-electronic component 130, and the signal-exchanging part 103, along the optical path are known, the integrated PSF may be calculated by convolving at least one of: all, and a subset of, the PSFs of these optical components, depending on the accuracy to be achieved.

In some non-limiting examples where a signal-exchanging part 103 comprises a plurality of emissive regions 210 between which at least one transmissive region 112 may be disposed, at least one of: a layout, including without limitation, at least one of a: number, size (including without limitation, aperture ratio), shape, orientation, (colour) order), configuration, and pitch, of the emissive regions 210 may impact the diffraction pattern imparted on the light transmitted through the signal-exchanging part 103.

In some non-limiting examples, the PSF may be affected by interaction of the optical components with properties of light, including without limitation, the wavelength spectrum thereof, that is at least one of: emitted, and received, by the opto-electronic component 130 through the display panel 100.

In some non-limiting examples, at least one of the: measurement, estimation, and calculation, of PSF may take factors, including without limitation, at least one of: system noise (including without limitation, component-related noise and background noise), imaging conditions (including without limitation, lightness and contrast), other optical effects (including without limitation, aberrations and scattering), and human vision perception, into account.

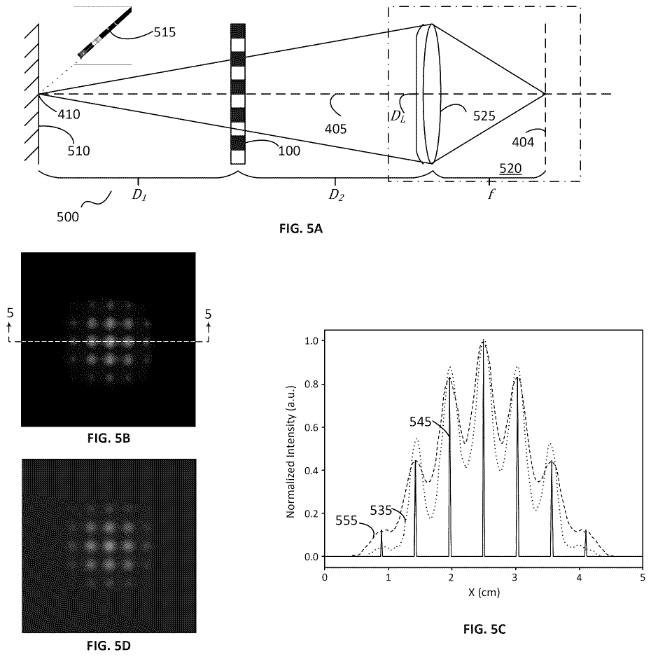

Turning now to FIG. 5A, there is shown an experimental set-up shown generally at 500, in which a point source 410, comprising the illumination of a surface 510 by an illumination source 515, is viewed at a receiver 520 through a display panel 100. In the experiment, the surface 510 was a substantially vertical wall and the illumination source 515 was a laser pointer emitting IR light at a wavelength of substantially about 980 nm. The display panel 100 comprised at least one signal-exchanging part 103 comprising at least one transmissive region 112, and was positioned a distance D₁ substantially about 60 cm away from the wall 510 and oriented such that the laser pointer 515 illuminated the wall 510 without passing therethrough and an optical path 405 between the illuminated wall 510 and the receiver 520 passed through the at least one signal-exchanging part 103. The receiver 520 comprised an IR camera having an objective lens 525 having a diameter D_{L} of substantially about 0.98 cm and a focal length f of substantially about 5.5 cm. The receiver 520 was positioned substantially flush against the display panel 100, such that a distance D₂ therebetween was substantially about 0.1 cm.

FIG. 5B is an image recorded by the receiver 520 that shows a diffraction pattern of the point source 410 on the image plane 404. FIG. 5C shows a plot of normalized intensity profile 535 of the recorded diffraction pattern as a function of a spatial position along line 5-5, along with an intensity profile 545 of a theoretical PSF of a point source without considering a beam distribution, and an intensity profile 555 of a simulated PSF that accounts for a beam distribution, calculated for the experimental set-up of FIG. 5A. FIG. 5D shows a simulated image that reflects the intensity profile 555 of the simulated PSF illustrated in FIG. 5C. In some non-limiting examples, an intensity of the simulated PSF may be derived by convolving an intensity of the theoretical PSF and a beam distribution of the point source, including without limitation, a Gaussian distribution as used in this calculation.

In the images of FIGS. 5B and 5D, there are a plurality of lobes, in a form of dots, laid out in an array about a central, main lobe, surrounded by a plurality of side lobes. The main dot may be understood to be a 0^{th} order dot, which exhibits an intensity and a size that is at least that of the dots surrounding it, which may be understood to be diffracted dots. In some non-limiting examples, a size of the 0^{th} order dot may substantially correspond to a size of the source 410, and may, in some non-limiting examples, be slightly larger, because of divergence.

The central lobe may be seen, by comparison to the intensity profiles in FIG. 5C, to correspond to a central peak of the PSF, which exhibits an intensity that is at least that of the side peaks thereof. In some non-limiting examples, the central peak may encompass the 0^{th} order peak as well as at least one side peak, including without limitation, the 1^{st} order peaks, on either side because of, including without limitation, oversaturation, so that a width of the central peak may be substantially equal to a separation between the encompassed side peaks.

The side lobes may be the result of the light projected by the source 410 passing through the transmissive region(s) 112 of the signal-exchanging part 103 of the panel 100, and interacting with at least one of: at least one boundary defining the transmissive region(s) 112, and a substantially non-transparent element disposed within, including without limitation, across, the transmissive region(s) 112.

In some non-limiting examples, diffracted dots may have an intensity that may be no more than that of the 0^{th} order dot corresponding thereto, such that in some non-limiting examples, an intensity of the side peaks of the PSF corresponding to the diffracted dots may tend to be no more than an intensity of the main peak of the PSF corresponding to the 0^{th} order dot. In some non-limiting examples, an intensity of side peaks of the PSF corresponding to diffracted dots may tend to decrease in intensity as the order N of diffraction increases so that, without limitation, an intensity of the side peaks corresponding to 2^{nd} order diffracted dots may tend to be no more than an intensity of the side peaks corresponding to 1^{st} order diffracted dots.

In some non-limiting examples, the PSF may be evaluated by various geometric metrics, including without limitation, a size, including without limitation, at least one of: a diameter, and an area, of the main lobe, a spacing between the main lobe and the side lobe(s), a spacing between the side lobes, and a distance from the main lobe to a side lobe that has an intensity reaches a threshold value.

In some non-limiting examples, the PSF may be evaluated by various intensity-related metrics, including without limitation, a(n) (intensity) level of a main peak, a(n) (intensity) level of a side peak at a certain order, and a ratio of a(n) (intensity) level of a main peak to a(n) (intensity) level of a side peak at a certain order.

In some non-limiting examples, performing a de-convolution calculation using at least one of the: measured, estimated, and calculated, PSF, may reverse the degradation of at least one of: image, and light pattern represented thereby, to produce a corrected, including without limitation, at least one of: re-constructed, and restored, at least one of: image, and light pattern represented thereby.

In some non-limiting examples, inaccuracy of at least one of the: measured, estimated, and calculated, PSF, may impact an ability to mitigate diffraction effects caused by the display panel 100, and accordingly lead to an amount of at least one of: information distortion, and information loss. In some non-limiting examples, although certain algorithms, including without limitation, algorithms that model different optical effects caused by at least one of the: display panel 100, opto-electronic components 130, and human vision system, may be adopted to compensate for such inaccuracy, there may be challenges in achieving a correction with substantial (visual) fidelity.

### Diffraction Reduction

In the present disclosure, as used herein, the adjective “regular”, unless the context indicates otherwise, may generally ascribe to a term that it modifies, the sense of substantial, including without limitation, exact, similarity, including without limitation, symmetry, in an attribute thereof, including without limitation, in location, shape, spacing, size, orientation, and position, of at least one of: the term itself, and a part of to what the term refers, including without limitation, in respect of a pattern thereof.

In the present disclosure, as used herein, the adjective “irregular”, unless the context indicates otherwise, may generally ascribe to a term that it modifies, the opposite sense of the adjective “regular”, including the sense of one of a: partial, and complete, absence of regularity in the term.

In some non-limiting examples, a display panel 100, comprising at least one signal-exchanging part 103 with at least one transmissive region 112, may interfere with the transmission, and concomitantly, the capture, of at least one of: an image, and a light pattern represented by at least one EM signal 131 passing through an aperture of the at least one transmissive region 112, including without limitation, where the at least one transmissive region 112 is shaped to exhibit a distinctive and non-uniform diffraction pattern.

In some non-limiting examples, such interference may be occasioned by the impact of a diffraction characteristic of the diffraction pattern.

In some non-limiting examples, interference occasioned by the impact of a diffraction characteristic of the diffraction pattern may tend to reduce SNR, and concomitantly, in the context of a facial identification system, increase a likelihood that at least one diffracted dot associated with a first dot may be mistaken for a second dot, with the result that facial identification may be compromised.

In some non-limiting examples, a diffraction characteristic may reduce an ability to facilitate mitigating the interference by such diffraction pattern, that is, an ability to permit an under-display component 130ᵤ to be able to one of: accurately receive and process such pattern, even with the application of post-processing techniques. In some non-limiting examples, this may result in at least one of: the dot array projected from an under-display emitter being distorted, and the image quality being degraded, due to diffraction effects. In some non-limiting examples, this may result in a reduced fidelity of the information captured by the under-display component 130ᵤ, which may interfere with function(s) of the user device 110, which in some non-limiting examples, may rely on the information captured by the under-display component 130ᵤ. In some non-limiting examples where the under-display component 130ᵤ is an under-display camera, degradation, including without limitation, blur, haze, and flare, may be observed in an image captured by such camera.

In some non-limiting examples, an extent of interference with the capture of at least one of: an image, and a light pattern represented thereby, caused by the at least one EM signal 131 passing through at least one transmissive region 112 of at least one signal-exchanging part 103 of a display panel 100 may be characterized by a PSF of such display panel 100.

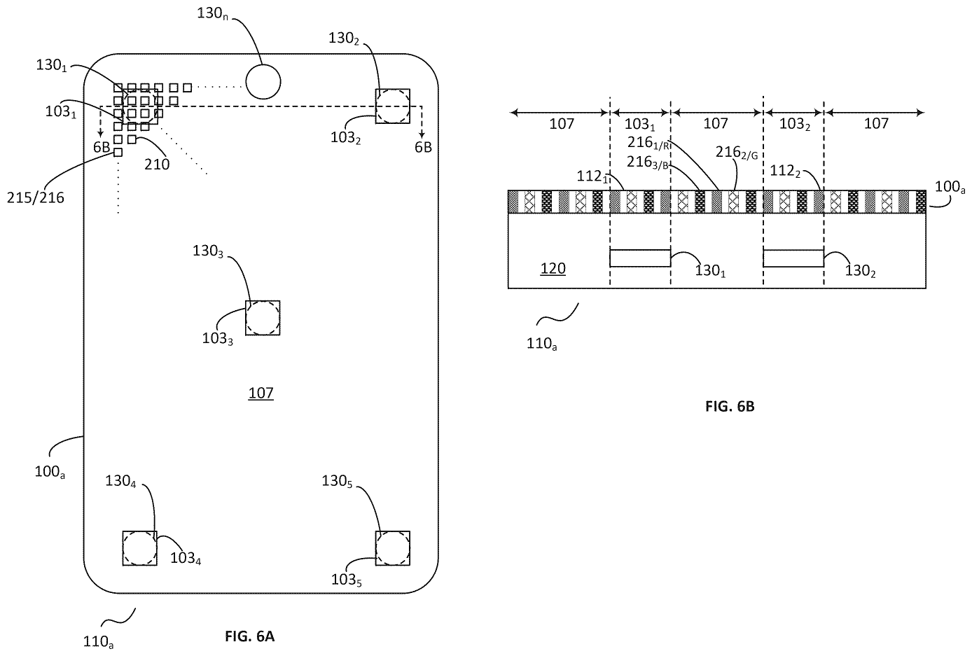

Turning now to FIG. 6A, there may be shown, in plan, an example version 110ₐ of the user device 110 according to a non-limiting example, which comprises a display panel 100ₐ. FIG. 6B shows a cross-sectional view of the display panel 100ₐ taken along the line 6B-6B of FIG. 6A.

In some non-limiting examples, as shown in FIG. 6A, the user device 110ₐ may house a plurality of opto-electronic component 130, at least one of which may be an under-display component 130ᵤ shown in dashed outlines. In some non-limiting examples, all the opto-electronic components 130 may be under-display components 130ᵤ. In some non-limiting examples, as shown, at least one opto-electronic component 130 may be a non under-display component 130ₙ, including without limitation, a punch-hole camera, and a transmitter. In some non-limiting examples, the non under-display component 130ₙ may be positioned in a non-display part (not shown) of the display panel 100ₐ, which in some non-limiting examples, may be substantially devoid of any emissive regions 210. In some non-limiting examples, the non-display part may be in a form of, including without limitation, a cut-out, a notch, and a bezel.

In some non-limiting examples, the display panel 100ₐ may comprise at least one signal-exchanging part 103, each of which may be associated with at least one under-display component 130ᵤ. In some non-limiting examples, each under-display component 130ᵤ may have a corresponding signal-exchanging part 103 disposed in the optical path. Although not shown, in some non-limiting examples, more than one under-display components 130ᵤ may be disposed behind a common signal-exchanging part 103.

In some non-limiting examples, as shown, at least one opto-electronic component 130 may be positioned near, including without limitation, at, an extremity of the lateral aspect of the user device 110ₐ, including without limitation, at least one of: an edge, and a corner, thereof, such that one opto-electronic component 130 may be spaced apart from other opto-electronic components 130 in the lateral aspect of the user device 110ₐ. In some non-limiting examples, such placement of opto-electronic components 130 with a certain lateral distance may have applicability in some scenarios calling for improved depth perception to support 3D imaging. This may be because each component 130 may capture an image at different non-zero angles, with respect to an object, including without limitation, the user 10, and accordingly contain different depth information, resulting in a 3D representation with increased details and accuracy. In some non-limiting examples, at least one of the opto-electronic component(s) 130 positioned near, including without limitation, at, an extremity of the user device 110ₐ may be a non under-display component 130ₙ.

In some non-limiting examples where at least one of the opto-electronic components 130 is a non under-display component 130ₙ, the non under-display component 130ₙ may alter the image quality due to a reduced number of layers along the optical path that the light passes through at least one of: before being received, and after being emitted, by the non under-display component 130ₙ, resulting in reduced degradation, including without limitation, diffraction, aberrations, and scattering. In some non-limiting examples, including without limitation, where there are spatial constraints on providing various opto-electronic components 130 with a lateral distance, having at least one opto-electronic component 130 being a non under-display component 130ₙ may have increased applicability in some scenarios calling for substantial depth imaging.

In some non-limiting examples, at least one opto-electronic component 130, including without limitation, the opto-electronic component 130₃, may be positioned substantially centrally within the lateral aspect of the user device 110ₐ. In some non-limiting examples, such opto-electronic component 130₃ may be an under-display component 130ᵤ.

Those having ordinary skill in the relevant art will appreciate that, the number, type, and location of the opto-electronic components 130 shown in FIG. 6A are solely for illustrative purposes and the examples discussed herein, which should not be considered as limiting, in any fashion, to any of the: number, type, and location, of the opto-electronic components 130, provided that at least one of the opto-electronic components 130 is a under-display component 130ᵤ.

In FIG. 6B, a first opto-electronic components 130₁ and a second opto-electronic component 130₂ may be shown being arranged behind a first signal-exchanging part 103₁ and a second signal-exchanging part 103₂, respectively.

In some non-limiting examples, at least one of: the first opto-electronic components 130₁, and the second opto-electronic component 130₂, may be arranged in an overlapping manner with at least one emissive region 210 each corresponding to a (sub-) pixel 215/216, such that light may be at least one of: emitted, and received, by passing through the transmissive region(s) 112 in the signal-exchanging part 103 without compromising the visual content being displayed in the signal-exchanging part 103 of the display panel 100.

Although not shown, in some non-limiting examples, at least one opto-electronic component 130 may be arranged in a region of the user device 110ₐ that is substantially devoid of the (sub-) pixels 215/216 of the display panel 100ₐ.

Without wishing to be bound by any particular theory, it may be postulated that, in some non-limiting examples, the image quality may be improved due to an increased amount of light that is at least one of: received, and transmitted, by a plurality of opto-electronic components 130 compared to an amount of light that is at least one of: received, and transmitted, when only one opto-electronic component 130 is used.

In some non-limiting examples, there may be scenarios calling for a first opto-electronic component 130₁ to have associated therewith, a first (integrated) PSF₁ that is different from a second (integrated) PSF₂ associated with a second opto-electronic component 130₂.

Without wishing to be bound by any particular theory, it may be postulated that, because the first PSF₁ associated with the first opto-electronic component 130₁ is different from the second PSF₂ associated with the second opto-electronic component 130₂, at least one of the: image, and light pattern, that is one of: emitted, and received, by one of the first opto-electronic component 130₁ and the second opto-electronic component 130₂, may contain different, including without limitation, complementary, diffraction characteristics that may not be present in the other of the first opto-electronic component 130₁ and the second opto-electronic component 130₂. Accordingly, the initial output, including without limitation, at least one of: distortion, and information loss, of one opto-electronic component 130 may be compensated for by the initial output of other opto-electronic component(s) 130.

Without wishing to be bound by any particular theory, it may now be postulated that, because of the difference between the first PSF₁ associated with the first opto-electronic component 130₁ and the second PSF₂ associated with the second opto-electronic component 130₂, a diffraction pattern, including without limitation, diffraction characteristics thereof, imparted to one opto-electronic component 130, may be substantially prevented from being amplified by a diffraction pattern, including without limitation, diffraction characteristics thereof, imparted to another opto-electronic component 130 (even if, in some scenarios it may not be necessarily reduced), such that at least one of the: image, and light pattern, may have reduced likelihood of compromise by a certain diffraction mode.

In some non-limiting examples, an integrated PSF associated with an opto-electronic component 130 may be determined based at least partially on a PSF exhibited by the opto-electronic component 130, a PSF associated with, including without limitation, exhibited by, the corresponding signal-exchanging part 103, and a PSF exhibited by any other component(s)/layer(s), including without limitation, part(s) thereof, in the optical path.

In some non-limiting examples, a first opto-electronic component 130₁ may exhibit a first component PSF_{c1}, and a second opto-electronic component 130₂ may exhibit a second component PSF_{c2}. In some non-limiting examples, the first component PSF_{c1} and the second component PSF_{c2} may be different. In some non-limiting examples, the first component PSF_{c1} and the second component PSF_{c2} may be substantially the same.

In some non-limiting examples, the first signal-exchanging part 103₁ may exhibit a first panel PSFₚ₁, and a signal-exchanging part 103₂ may exhibit a second panel PSFₚ₂. In some non-limiting examples, each of the first signal-exchanging part 103₁ and the second signal-exchanging part 103₂ may be configured such that the first panel PSFₚ₁ and the second panel PSFₚ₂ may be different, and accordingly, they may impart different diffraction characteristics onto the respective opto-electronic components 130 associated therewith. In some non-limiting examples, the signal-exchanging parts 103₁, 103₂ may be configured in a similar, including without limitation, substantially identical, fashion, and, in some non-limiting examples, constitute a single signal-exchanging part 103, such that the first panel PSFₚ₁ and the second panels PSFₚ₂ may be substantially the same.

Accordingly, in some non-limiting examples, at least one of: the first component PSF_{c1} and the first panel PSFₚ₁ may be different from a corresponding at least one of: the second component PSF_{c2}, and the second panel PSFₚ₂, such that a first integrated PSFᵢ₁ associated with the first opto-electronic component 130₁ may be different from a second integrated PSFᵢ₂ associated with the second opto-electronic component 130₂.

In some non-limiting examples, at least one of the: first component PSF_{c1}, first panel PSFₚ₁, and first integrated PSF may exhibit a different distribution, including without limitation, a main-lobe pattern (including without limitation, a size, and a shape, thereof), a main-lobe intensity (including without limitation, an intensity profile and a(n) (intensity) level, thereof), a side-lobe pattern (including without limitation, a number thereof, a size thereof, a shape thereof, a spacing between adjacent side lobes, and a spacing between a side lobe and a main lobe), and side-lobe intensity (including without limitation, an intensity profile and a(n) (intensity) level), from a corresponding at least one of: the second component PSF_{c2}, the second panel PSFₚ₂, and the second integrated PSFᵢ₂, which may concomitantly lead to variations in metrics used to evaluate the PSFs, including without limitation, the geometric metrics, and the intensity-related metrics.

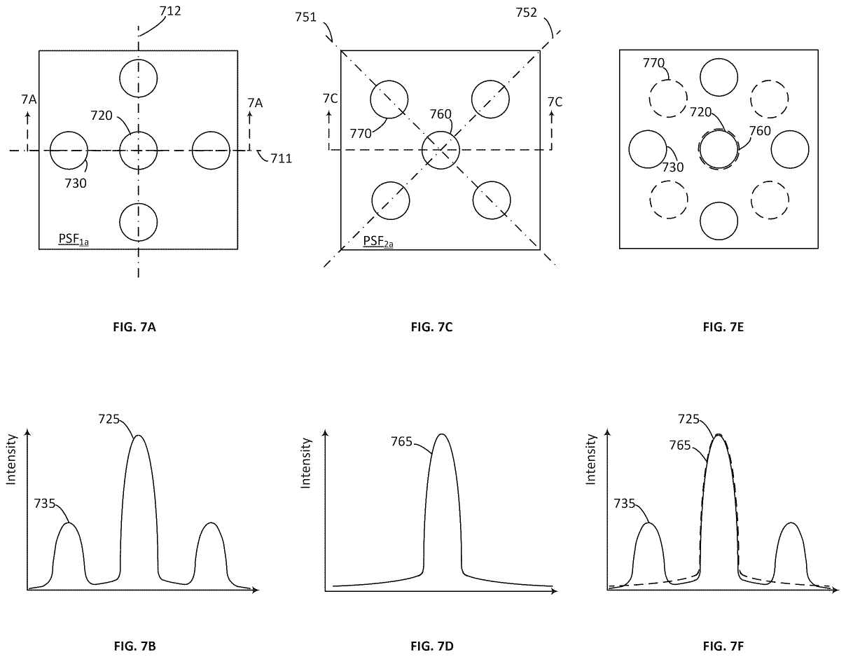

Turning now to FIGS. 7A-7F, 8A-8F, 9A-9F, and 10A-10F, various non-limiting examples of interaction between a first PSF₁ associated with a first opto-electronic component 130₁ and a second PSF₂ associated with a second opto-electronic component 130₂ may be schematically illustrated. The first PSF₁ may represent one of the: first component PSF_{c1}, first panel PSFₚ₁, and first integrated PSFᵢ₁, while the second PSF₂ may represent a corresponding one of the: second component PSF_{c2}, second panel PSFₚ₂, and second integrated PSFᵢ₂.

In some non-limiting examples, a side-lobe pattern of the first PSF₁, including without limitation, at least one of the: first component PSF_{c1}, first panel PSFₚ₁, and first integrated PSFᵢ₁, may not substantially overlap with a side-lobe pattern of the second PSF₂, including without limitation, a corresponding at least one of the: second component PSF_{c2}, second panel PSFₚ₂, and second integrated PSFᵢ₂.

Without wishing to be bound by any particular theory, it may be postulated that, in some non-limiting examples, the information contained in the side lobes may be used to reconstruct more of at least one of the: light, and light pattern, than would be possible with the main lobe alone. Accordingly, a non-overlapping side-lobe pattern of a PSF associated with one opto-electronic component 130 may provide information that may be lost in a PSF associated with other opto-electronic component(s) 130, which may contribute to a recovery with increased accuracy.

FIGS. 7A and 7C schematically illustrate, in plan, a distribution of a first PSF₁ₐ, and a second PSF₂ₐ, respectively, and FIG. 7E shows the distribution of the first PSF₁ₐ, shown in solid outline, superimposed over the distribution of the second PSF₂ₐ, shown in dashed outline. FIGS. 7B and 7D schematically illustrate intensity plots of the first PSF₁ₐ and the second PSF₂ₐ thereof taken along line 7A-7A of FIG. 7A and line 7C-7C of FIG. 7C, respectively, and FIG. 7F shows the intensity plot of the first PSF₁ₐ, shown in solid outline, superimposed over the intensity plot of the second PSF₂ₐ, shown in dashed outline.

In some non-limiting examples, as shown in FIG. 7A, a lobe pattern of the first PSF₁ₐ may be defined by a first configuration axis 711 and a second configuration axis 712. In some non-limiting examples, the first configuration axis 711 and the second configuration axis 712 may both lie in a lateral plane of the display panel 100 and intersect at a point of intersection. In some non-limiting examples, the first configuration axis 711 may be at a non-zero angle to the second configuration axis 712. In some non-limiting examples, the first configuration axis 711 may be substantially orthogonal to the second configuration axis 712.

In some non-limiting examples, as shown, a main lobe 720 in the lobe pattern of the first PSF₁ may be centered, in plan, about the point of intersection of the first configuration axis 711 and the second configuration axis 712. The main lobe 720 may be surrounded by a plurality of, including without limitation, as shown, four, side lobes 730, each of which may be disposed along at least one of the: first configuration axis 711, and second configuration axis 712. In some non-limiting examples, at least two side lobes 730 may be located symmetrically around the main lobe 720, resulting in equal distances from the main lobe 720 along at least one of the: first configuration axis 711, and second configuration axis 712.

In some non-limiting examples, at least one of a: size, and shape, of the main lobe 720 and of the at least one side lobes 730 may be substantially the same. Although not shown, in some non-limiting examples, at least one side lobe 730 may differ from at least one of: the main lobe 720, and other side lobe(s) 730, in at least one of a: size, and shape.

In FIG. 7B, there may be shown a main peak 725, corresponding to an intensity of the main lobe 720, and at least one side peak 735, each corresponding to an intensity of a side lobe 730.

In FIG. 7C, a main lobe 760 in a lobe pattern of a second PSF₂ₐ may be centered, in plan, about a point of intersection of a first configuration axis 751 and a second configuration axis 752. In some non-limiting examples, each of the: first configuration axis 751, and second configuration axis 752, may be rotated by a non-zero angle, including without limitation, as shown, substantially 45°, relative to respective ones of the first configuration axis 711 and the second configuration axis 712 of the first PSF₁ₐ. In some non-limiting examples, the main lobe 760 may be surrounded by a plurality of, including without limitation, as shown, four, side lobes 770, each of which may be disposed along at least one of the: first configuration axis 751, and second configuration axis 752. In some non-limiting examples, at least two side lobes 770 may be located symmetrically around the main lobe 760, resulting in equal distances from the main lobe 760 along at least one of: the first configuration axis 751, and the second configuration axis 752.

In some non-limiting examples, at least one of a: size, and shape, of the main lobe 760 and of the at least one side lobes 770 may be substantially the same. Although not shown, in some non-limiting examples, at least one of a: size, and shape, of at least one side lobe 770 may differ from at least one of: the main lobe 760, and other side lobe(s) 770 in at least one of a: size, and shape.

As shown, in some non-limiting examples, the lobe pattern of the second PSF₂ₐ, may be substantially similar to that of the first PSF₁ₐ, in that, relative to the: intersection, and orientation, of the: first configuration axis 751, and second configuration axis 752, the lobe pattern of the second PSF₂ₐ is substantially identical to that of the first PSFla.

As shown, in some non-limiting examples, the lobe pattern of the second PSF₂ₐ, may differ from that of the first PSF₁ₐ, in that the first configuration axis 751 may be rotated by a non-zero angle, including without limitation, substantially 45°, in one of a: clockwise, and counter-clockwise, direction, with respect to the first configuration axis 711, and the second configuration axis 752 may be rotated by the same non-zero angle with respect to the second configuration axis 712, such that the lobe pattern of the second PSF₂ₐ is concomitantly rotated by such non-zero angle.

In FIG. 7D, there may be shown a main peak 765, corresponding to an intensity of the main lobe 760. However, because of the rotation of the lobe pattern of the second PSF₂ₐ by the non-zero angle, the intensity plot of the second PSF₂ₐ may be substantially devoid of any side peaks corresponding to an intensity of any side lobes 760.

As shown, in some non-limiting examples, the intensity plot of the second PSF₂ₐ, may be substantially similar to the intensity plot of the first PSF₁ₐ, in that at least one of the: intensity profile, and (intensity) level of the main peak 765 may be substantially the same as such at least one of the: intensity profile, and (intensity) level of the main peak 725.

As shown, in some non-limiting examples, the intensity plot of the second PSF₂ₐ, may differ from the intensity plot of the first PSF₁ₐ, in that the intensity plot of the first PSF₁ₐ shows at least one side peak 735, each corresponding to an intensity of a side lobe 730, which is not shown in the intensity plot of the second PSF₂ₐ.

In some non-limiting examples, because at least one of the: lobe pattern, and intensity plot of the first PSF₁ₐ, exhibits a side-lobe profile that is different from a side-lobe profile exhibited by a corresponding at least one of the: lobe pattern, and intensity plot, the side lobes 730 of the first PSF₁ₐ and the side lobes 770 of the second PSF₂ₐ may not substantially overlap, as shown in FIG. 7E, showing, in plan, the lobe pattern of the first PSF₁ₐ superimposed over that of the second PSF₂ₐ, and FIG. 7F, showing, the intensity profile of the first PSF₁ₐ superimposed over that of the second PSF₂ₐ.

Those having ordinary skill in the relevant art will appreciate that the lobe patterns of the first PSF₁ₐ and the second PSF₂ₐ are shown being defined by a same number of configuration axes, and each of the configuration axes 751, 752 of the second PSF₂ₐ is rotated by a substantially same non-zero angle with respect to the corresponding configuration axis 711, 712 of the first PSF₁ₐ, solely for illustrative purposes and the example discussed herein, which should not be considered as limiting. In some non-limiting examples, the lobe patterns of the first PSF₁ₐ and of the second PSF₂ₐ may be defined by a different number of configuration axes. In some non-limiting examples, at least one of the configuration axes 711, 712 of the first PSF₁ₐ may be parallel to at least one of the configuration axes 751, 752 of the second PSF₂ₐ.

While the intensity profile, and (intensity) level of the main peak 725 of the first PSF₁ₐ may be shown as being substantially the same as that of the main peak 765 of the second PSF₂ₐ for purposes of simplicity of illustration, in some non-limiting examples, the main peak 725 of the first PSF₁ₐ may differ from the main peak 765 of the second PSF₂ₐ, in at least one of the: intensity profile, and (intensity) level.

Those having ordinary skill in the relevant art will appreciate that, in some non-limiting examples, the side lobes 730 of the first PSF₁ₐ may differ from the side lobes 770 of the second PSF₂ₐ in other aspects of the distribution, including without limitation, a lobe pattern, including without limitation, at least one of the: size, shape, number, spacing therebetween, spacing from the respective main lobe, and intensity, including without limitation, at least one of: intensity profile, and intensity level, such that the side-lobe pattern of the first PSF₁ₐ is substantially devoid of a side lobe that overlaps with the side-lobe pattern of the second PSF₂ₐ.

In some non-limiting examples, a side-lobe pattern of the first PSF₁, including without limitation, at least one of the: first component PSF_{c1}, first panel PSFₚ₁, and first integrated PSFᵢ₁, may partially overlap with a side-lobe pattern of the second PSF₁, including without limitation, a corresponding at least one of the: second component PSF_{c2}, second panel PSFₚ₂, and second integrated PSFᵢ₂.

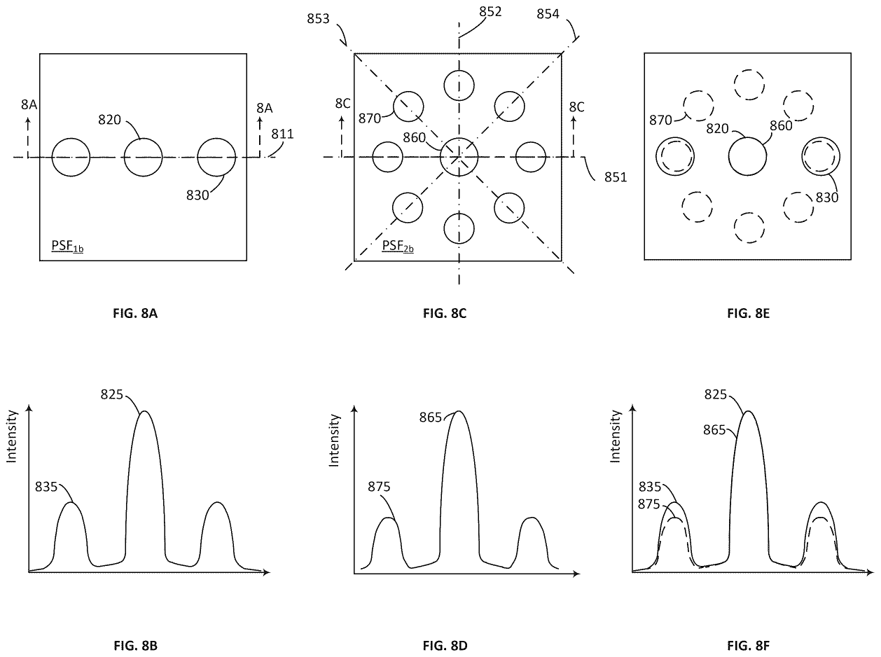

FIGS. 8A and 8C schematically illustrate, in plan, a distribution of a first PSF_{1b}, and a second PSF_{2b}, respectively, and FIG. 8E shows the distribution of the first PSF_{1b}, shown in solid outline, superimposed over the distribution of the second PSF_{2b}, shown in dashed outline. FIGS. 8B and 8D schematically illustrate intensity plots of the first PSF_{1b} and the second PSF_{2b} thereof taken along line 8A-8A of FIG. 8A and line 8C-8C of FIG. 8C, respectively, and FIG. 8F shows the intensity plot of the first PSF_{1b}, shown in solid outline, superimposed over the intensity plot of the second PSF_{2b}, shown in dashed outline.

In some non-limiting examples, as shown in FIG. 8A, a lobe pattern of the first PSF_{1b} may be defined by a configuration axis 811, on which a main lobe 820 may be centered. In some non-limiting examples, the main lobe 820 may be surrounded by a plurality of, including without limitation, as shown, two, side lobes 830, each of which may be disposed along the configuration axis 811. In some non-limiting examples, at least two side lobes 830 may be located symmetrically around the main lobe 820, resulting in equal distances from the main lobe 820 along the configuration axis 811.

In some non-limiting examples, at least one of a: size, and shape, of the main lobe 820 and of the at least one side lobe 830 may be substantially the same. Although not shown, in some non-limiting examples, at least one side lobe 830 may differ from at least one of: the main lobe 820, and other side lobes 830, in at least one of a: size, and shape.

In FIG. 8B, there may be shown a main peak 825, corresponding to an intensity of the main lobe 820, and at least one side peak 835, each corresponding to an intensity of a side lobe 830.

In some non-limiting examples, as shown in FIG. 8C, a lobe pattern of the second PSF_{2b} may be defined by a first configuration axis 851, a second configuration axis 852, a third configuration axis 853, and a fourth configuration axis 854. In some non-limiting examples, the configuration axes 851-854 of the second PSF_{2b} intersect at a point of intersection, about which, a main lobe 860 of the second PSF_{2b} may be centered. In some non-limiting examples, the main lobe 860 may be surrounded by a plurality of, including without limitation, as shown, eight, side lobes 870, each of which may be disposed along at least one of the configuration axes 851-854. The side lobes 870 of the second PSF_{2b} may be substantially equally separated by an angle, including without limitation, substantially 45°. In some non-limiting examples, at least two side lobes 870 may be located symmetrically around the main lobe 860, resulting in equal distances from the main lobe 860 along at least one of the configuration axes 851-854.

In some non-limiting examples, as shown, at least one of a: size, and shape, of the at least one side lobe 870 may be substantially the same, and different from that of the main lobe 860. Although not shown, in some non-limiting examples, at least one of a: size, and shape, of the main lobe 860 and of the at least one side lobe 870 may be substantially the same. In some non-limiting examples, at least one side lobe 870 may differ from other side lobe(s) 870, in at least one of a: size, and shape.

As shown, in some non-limiting examples, the distribution of the second PSF_{2b} may differ from that of the first PSF_{1b} in at least one of the following: there are a different number of side lobes 870 in the lobe pattern of the second PSF_{2b} compared to a number of side lobes 830 in the lobe pattern of the first PSF_{1b}, the side lobes 870 are separated by a different (acute) angle in the lobe pattern of the second PSF_{2b} compared to that of side lobes 830 in the lobe pattern of the first PSF_{1b} (although, every fourth one of the side lobes 870 is substantially coincident with one of the side lobes 830), and a dimension of the side lobes 870 of the second PSF_{2b} is small compared to a dimension of the side lobes 830 of the first PSF_{1b}.

In FIG. 8D, there may be shown a main peak 865, corresponding to an intensity of the main lobe 860, and at least one side peak 875, each corresponding to an intensity of a side lobe 870.

As shown, in some non-limiting examples, the intensity plot of the second PSF_{2b} may be substantially similar to the intensity plot of the first PSF_{1b} in that a number of peaks 865, 875 shown in the intensity plot of the second PSF_{2b} is substantially the same as a number of peaks 825, 835 shown in the intensity plot of the first PSF_{1b}, and the main peak 865 of the second PSF_{2b} is substantially the same as the main peak 825 of the first PSF_{1b}, in at least one of the: intensity profile, and (intensity) level.

As may be seen from shown FIG. 8F, in some non-limiting examples, the intensity plot of the second PSF_{2b} may differ from the intensity plot of the first PSF_{1b}, in that at least one of the: intensity profile, and (intensity) level, of the at least one side peak 875 of the second PSF_{2b} may be different from that of the at least one side peak 835 of the first PSF_{1b}.

Those skill having ordinary skill in the relevant art will appreciate that, in some non-limiting examples, a(n) (intensity) level of at least one of the main lobe 820, and of the side lobes 830, of the first PSF_{1b} may be one of: lower, and higher, than a(n) (intensity) level of a corresponding at least one of: the main lobe 860, and the side lobes 870, of the second PSF_{2b}. In some non-limiting examples, at least one of the main peak 825, and the side peaks 835, of the first PSF_{1b} may be one of: broader, and narrower, than a corresponding at least one of: the main peak 865, and the side peaks 875, of the second PSF_{2b}.

FIGS. 8A-8F differ from FIGS. 7A-7F in that, the first PSF_{1b} and the second PSF_{2b} may exhibit a certain degree of, but short of complete, overlap of side lobes 830, 870, as shown in the plan view of FIG. 8E.

In some non-limiting examples, a first subset of side lobes 870 of the second PSF_{2b} may overlap with one of: all, and a subset of, side lobes 830 of the first PSF_{1b}, while a second subset of side lobes 870 of the second PSF_{2b} does not substantially overlap with any side lobes 830 of the first PSF_{1b}.

Those having ordinary skill in the relevant art will appreciate that, although a subset of the configuration axes 851-854 of the lobe pattern of the second PSF_{2b} are shown substantially coincident with the configuration axis 811 of the lobe pattern of the first PSF_{1b}, and accordingly contribute to the partial but not complete overlap of the side lobes 830 of the first PSF_{1b} and the side lobes 870 of the second PSF_{2b}, such arrangement is solely for illustrative purposes, which should not be considered as limiting.

Those having ordinary skill in the relevant will appreciate that, in some non-limiting examples, the side lobes 830 of the first PSF_{1b} may differ from the side lobes 870 of the second PSF_{2b} in other aspects of the distribution, including without limitation, a lobe pattern, including without limitation, at least one of the: size, shape, number, spacing therebetween, spacing from the respective main lobe, and intensity, including without limitation, intensity profile, and intensity level, such that the side lobes 830 of the first PSF_{1b} and the side lobes 870 of the second PSF_{2b} exhibit a certain degree of, but short of complete, overlap.

However the side-lobe pattern is embodied, the first PSF_{1b} may differ from the second PSF_{2b}, in intensity, including without limitation, at least one of: an intensity profile, and a(n) (intensity) level, of at least one of the: main lobe, and side lobes.

Without wishing to be bound by any particular theory, it may be postulated that, in some non-limiting examples, the variations of at least one of the: main peak, and side peaks, including without limitation, high order side peaks, in at least one of the: intensity profile, and (intensity) level, may provide information that may be used to distinguish individual features, including without limitation, closely spaced features. In some non-limiting examples, the variations in intensities may be reflected in various metrics that may be used to evaluate the PSFs, including without limitation, the geometric metrics, and the intensity-related metrics. In some non-limiting examples, side peaks with different intensities may be weighted differently in evaluation of a PSF, for the purposes of at least one of: enhancing a certain feature, and reducing noise.

In some non-limiting examples, each side lobe of the first PSF₁, including without limitation, at least one of the: first component PSF_{c1}, first panel PSFₚ₁, and first integrated PSFᵢ₁, may correspond to, and in some non-limiting examples, one of: completely, and partially, overlap with, a side lobe of the second PSF₂, including without limitation, a corresponding at least one of the: second component PSF_{c2}, second panel PSFₚ₂, and second integrated PSFᵢ₂. Despite the correspondence of the side lobes of the first PSF₁ and the second PSF₂, the first PSF₁ may differ from the side lobes of the second PSF₂, in at least one of the: profile and level, of intensity thereof.

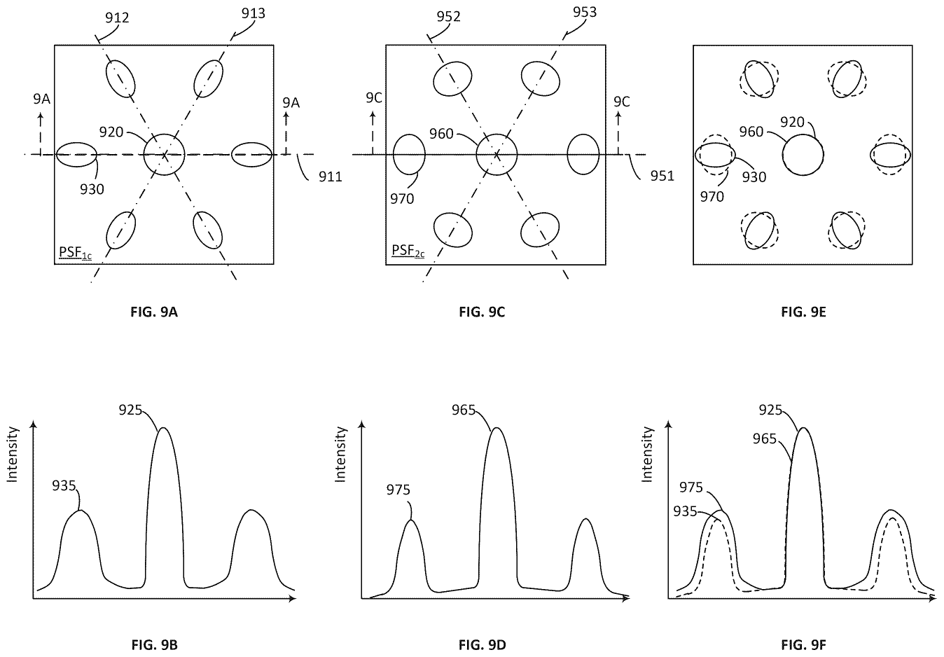

FIGS. 9A and 9C schematically illustrate, in plan, a distribution of a first PSF_{1c}, and a second PSF_{2c}, respectively, and FIG. 9E shows the distribution of the first PSF_{1c}, shown in solid outline, superimposed over the distribution of the second PSF_{2c}, shown in dashed outline. FIGS. 9B and 9D schematically illustrate intensity plots of the first PSF_{1c} and the second PSF_{2c} thereof taken along line 9A-9A of FIG. 9A and line 9C-9C of FIG. 9C, respectively, and FIG. 9F shows the intensity plot of the first PSF_{1c}, shown in solid outline, superimposed over the intensity plot of the second PSF_{2c}, shown in dashed outline.

In some non-limiting examples, as shown in FIG. 9A, a lobe pattern of the first PSF_{1c} may be defined by a first configuration axis 911, a second configuration axis 912, and a third configuration axis 913, which in some non-limiting examples, may lie in a lateral plane of the display panel 100 and intersect at a point of intersection. While the first configuration axis 911, the second configuration axis 912, and the third configuration axis 913 are shown being separated by a substantially identical angle, in some non-limiting examples, each pair of adjacent configuration axes 911-913 may form an angle different from other pair(s) of adjacent configuration axes 911-913.

In some non-limiting examples, as shown, a main lobe 920 in the lobe pattern of the first PSF_{1c} may be centered, in plan, about the point of intersection of the first configuration axis 911, the second configuration axis 912, and the third configuration axis 913. In some non-limiting examples, the main lobe 920 may be surrounded by a plurality of, including without limitation, as shown, six, side lobes 930, each of which may be disposed along at least one of the configuration axes 911-913. In some non-limiting examples, at least two side lobes 930 may be located symmetrically around the main lobe 920, resulting in equal distances from the main lobe 920 along at least one of the configuration axes 911-913.

In some non-limiting examples, as shown, the main lobe 920 may differ from at least one side lobe 930, in at least one of a: size, and shape. Although the side lobes 930 may be shown substantially the same in at least one of a: size, and shape, in some non-limiting examples, at least one side lobe 930 may differ from other side lobe(s) 930, in at least one of a: size, and shape.

In FIG. 9B, there may be shown a main peak 925, corresponding to an intensity of the main lobe 920, and at least one side peak 935, each corresponding to an intensity of a side lobe 930.

In FIG. 9C, a lobe pattern of the second PSF_{2c} may be defined by a first configuration axis 951, a second configuration axis 952, and a third configuration axis 953. In some non-limiting examples, the configuration axes 951-953 may be substantially coincident with those of the first PSF_{1c}. In some non-limiting examples, a main lobe 960 in the lobe pattern of a second PSF_{2c} may be centered, in plan, about the point of intersection of the configuration axes 951-953. In some non-limiting examples, the main lobe 650_{c} may be surrounded by a plurality of, including without limitation, as shown, six, side lobes 970, each of which may be disposed along at least one of the configuration axes 951-953. In some non-limiting examples, at least two side lobes 970 may be located symmetrically around the main lobe 960, resulting in equal distances from the main lobe 960 along at least one of the configuration axes 951-953.

In some non-limiting examples, as shown, the main lobe 960 may differ from at least one side lobe 970, in at least one of a: size, and shape. Although the side lobes 970 may be shown substantially the same in at least one of a: size, and shape, in some non-limiting examples, at least one side lobe 970 may differ from other side lobe(s) 970, in at least one of a: size, and shape.

As shown, in some non-limiting examples, the distribution of the second PSF_{2c} may be substantially similar to the distribution of the first PSF_{1c}, in that: the configuration axes 951-953 of the second PSF_{2c} are substantially coincident with the configuration axes 911-913 of the first PSF_{1c}, the main lobe 960 is substantially the same in size, and shape as the main lobe 920, and the side lobes 970 are substantially the same in pattern, and number as the side lobes 930.

As shown, in some non-limiting examples, the distribution of the second PSF_{2c} may differ from the distribution of the first PSF_{1c}, in that the side lobes 970 of the second PSF_{2c} are oriented such that a minor axis of each side lobe 970 aligns with the configuration axis on which the side lobe 970 is located, and the side lobes 930 of the second PSF_{1c} are oriented such that a major axis of each side lobe 930 aligns with the configuration axis on which the side lobe 930 is located, and the size, including without limitation, a minimum dimension (corresponding to a minor axis thereof), of the side lobes 970 of the second PSF_{2c} is large compared to the size, including without limitation, a minimum dimension, of the side lobes 930 of the first PSF_{1c}.

In FIG. 9D, there may be shown a main peak 965, corresponding to an intensity of the main lobe 960, and at least one side peak 975, each corresponding to an intensity of a side lobe 970.

As shown, in some non-limiting examples, the intensity plot of the second PSF_{2c}, may be substantially similar to the intensity plot of the first PSF_{1c}, in that: a main peak 965 and at least one side peak 975 are shown in the intensity plot of the second PSF_{2c}, and a main peak 925 and at least one side peak 935 are shown in the intensity plot of the first PSF_{1c}, and the main lobe 925 and the main lobe 965 are substantially the same in at least one of: intensity profile, and (intensity) level.

As may be seen from FIG. 9F, in some non-limiting examples, the intensity plot of the second PSF_{2c} may differ from the intensity plot of the first PSF_{1c}, in that the intensity profile, and the intensity level of the side peaks 975 of the second PSF_{2c} may be different from those of the side peaks 935 of the first PSF_{1c}.

In some non-limiting examples, a(n) (intensity) level of the side peak 935 of the first PSF_{1c} may be one of: lower, and higher, than a(n) (intensity) level of the side peak 975 of the second PSF_{2c}. In some non-limiting examples, the side peaks 935 of the first PSF_{1c} may be one of: broader, and narrower, than the side peaks 975 of the second PSF_{2c}.

FIGS. 9A-9F differ from FIGS. 7A-7F and FIGS. 8A-8F in that, each side lobe 970 of the second PSF_{2c} may correspond to, and in some non-limiting examples, partially overlap with, a side lobe 930 of the first PSF_{1c}, as shown in a plan view of FIG. 9E.

Those having ordinary skill in the relevant art will appreciate that, although the configuration axes 951-953 of the lobe pattern of the second PSF_{2c} are shown substantially coincident with the configuration axes 911-913 of the lobe pattern of the first PSF_{1c}, and accordingly, contribute to the correspondence between the side lobes 930 of the first PSF_{1c} and the side lobes 970 of the second PSF_{2c}, such arrangement is solely for illustrative purposes, which should not be considered as limiting. In some non-limiting examples, the configuration axes 951-953 of the lobe pattern of the second PSF₂ₑ may be rotated by a non-zero angle with respect to the configuration axes 911-913 of the lobe pattern of the first PSF_{1c}, but still maintain this correspondence.

Those having ordinary skill in the relevant art will appreciate that, while in some non-limiting examples, the side lobes 930 of the first PSF_{1c} may differ from the side lobes 970 of the second PSF_{2c} in other aspects of the distribution, including without limitation, a lobe pattern, including without limitation, the size, shape, number, spacing therebetween, spacing from the respective main lobe, and intensity, including without limitation, intensity profile, and intensity level, the side lobes 970 of the second PSF_{2c} and the side lobes 930 of the first PSF_{1c} may still exhibit the correspondence.

In some non-limiting examples, a main lobe of the first PSF₁, including without limitation, at least one of the: first component PSF_{c1}, first panel PSFₚ₁, and first integrated PSFᵢ₁, may differ from a main lobe of the second PSF₂, including without limitation, a corresponding at least one of the: second component PSF_{c2}, second panel PSFₚ₂, and second integrated PSFᵢ₂, in at least one of the: profile and level, of intensity thereof.

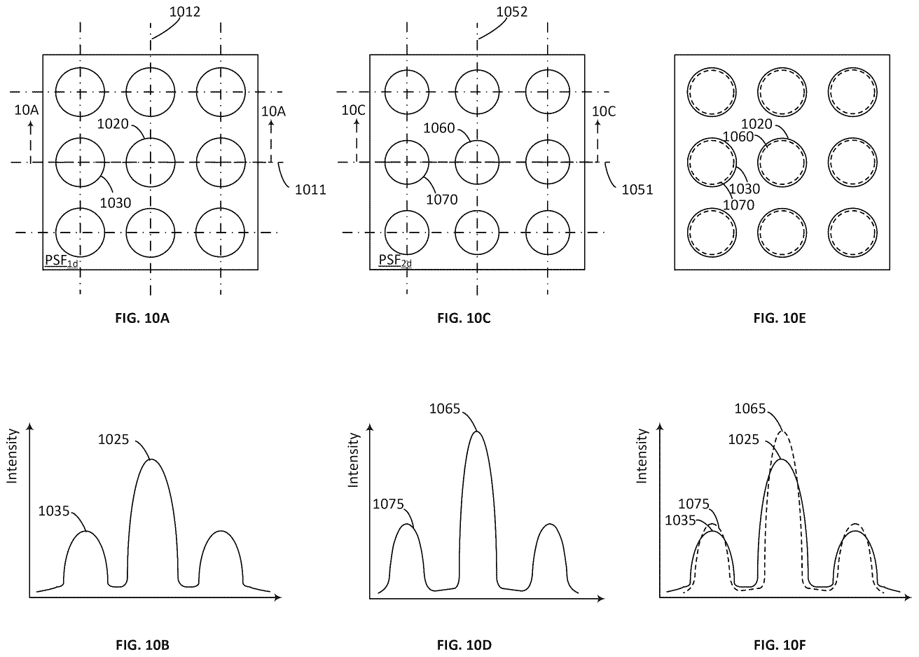

FIGS. 10A and 10C schematically illustrate, in plan, a distribution of a first PSF_{1d}, and a second PSF_{2d}, respectively, and FIG. 10E shows the distribution of the first PSF_{1d}, shown in solid outline, superimposed over the distribution of the second PSF₂ₐ, shown in dashed outline. FIGS. 10B and 10D schematically illustrate intensity plots of the first PSF_{1d} and the second PSF_{2d} thereof taken along line 10A-10A of FIG. 10A and line 10C-10C of FIG. 10C, respectively, and FIG. 10F shows the intensity plot of the first PSF_{1d}, shown in solid outline, superimposed over the intensity plot of the second PSF₂ₐ, shown in dashed outline.

In FIG. 10A, a lobe pattern of the first PSF_{1d} may be defined by a plurality of first configuration axes 1011 and a plurality of second configuration axes 1012. In some non-limiting examples, the plurality of the first configuration axes 1011 and the plurality of the second configuration axes 1012 may both lie in a lateral plane of the display panel 100 and form a grid pattern. In some non-limiting examples, the first configuration axis 1011 may be substantially orthogonal to the second configuration axis 1012.

In some non-limiting examples, as shown, a main lobe 1020, and a plurality of, including without limitation, as shown, eight, side lobes 1030 may be positioned on the grid formed by the first configuration axes 1011 and the second configuration axes 1012. In some non-limiting examples, at least two side lobes 1030 may be located symmetrically around the main lobe 1020, resulting in equal distances from the main lobe 1020.

In some non-limiting examples, at least one of a: size, and shape, of the main lobe 1020 and of the at least one side lobes 1030 may be substantially the same. Although not shown, in some non-limiting examples, at least one side lobe 1030 may differ from at least one of: the main lobe 1020, and other side lobe(s) 1030, in at least one of a: size, and shape.

In FIG. 10B, there may be shown a main peak 1025, corresponding to an intensity of the main lobe 1020, and at least one side peak 1035, each corresponding to an intensity of a side lobe 1030.

In FIG. 10C, a lobe pattern of the second PSF₂ₐ may be defined by a plurality of first configuration axes 1051, and a plurality of second configuration axes 1052. In some non-limiting examples, the plurality of the first configuration axes 1051 and the plurality of the second configuration axes 1052 of the second PSF₂ₐ may be substantially similar to, including without limitation, coincident with, those of the first PSF_{1d}, and form a grid pattern. In some non-limiting examples, a main lobe 1060, and a plurality of, including without limitation, as shown, eight, side lobes 1070, may be positioned on the grid formed by the first configuration axes 1051 and the second configuration axes 1052. In some non-limiting examples, at least two side lobes 1070 may be located symmetrically around the main lobe 1060, resulting in equal distances from the main lobe 1060.

In some non-limiting examples, at least one of a: size, and shape, of the main lobe 1060 and of the at least one side lobes 1070 may be substantially the same. Although not shown, in some non-limiting examples, at least one side lobe 1070 may differ from at least one of: the main lobe 1060, and other side lobe(s) 1070, in at least one of a: size, and shape.

As shown, in some non-limiting examples, the distribution of the second PSF_{2d} may be substantially similar to the distribution of the first PSF_{1d}, in that: the configuration axes 1051, 1052 of the second PSF₂ₐ are substantially coincident with the configuration axes 1011, 1012 of the first PSF_{1d}, and the lobes 1060, 1070 are substantially the same in number, shape, and pattern as the lobes 1020, 1030.

As shown, in some non-limiting examples, the distribution of the second PSF₂ₐ may differ from the distribution of the first PSF_{1d}, in that, the size of the lobes 1060, 1070 of the second PSF_{2d} is small compared to the size of the lobes 1020, 1030 of the first PSF_{1c}.

In FIG. 10D, there may be shown a main peak 1065, corresponding to an intensity of the main lobe 1060, and at least one side peak 1075, each corresponding to an intensity of a side lobe 1070.

As shown, in some non-limiting examples, the intensity plot of the second PSF₂ₐ may be substantially similar to the intensity plot of the first PSF_{1d}, in that a main peak 1065 and at least one side peak 1075 are shown in the intensity plot of the second PSF_{2d}, and a main peak 1025 and at least one side peak 1035 are shown in the intensity plot of the first PSF_{1d}.

As may be seen from FIG. 10F, in some non-limiting examples, the intensity plot of the second PSF_{2d} may differ from the intensity plot of the first PSF_{1d} in that an intensity profile, and an intensity level of at least one of the: main peaks 1065, and side peaks 1075, of the second PSF_{2d} may be different from those of corresponding at least one of the: main peak 1025, and side peaks 1035 of the first PSF_{1d}.

In some non-limiting examples, a(n) (intensity) level of at least one of: the main peak 1025, and at least one side peak 1035, of the first PSF_{1d} may be one of: lower, and higher, than a(n) (intensity) level of corresponding at least one of: the main peak 1065, and at least one side peak 1075, of the second PSF_{2d}. In some non-limiting examples, at least one of: the main peak 1025, and at least one side peak 1035, of the first PSF_{1d} may be one of: broader, and narrower, than corresponding at least one of: the main peak 1065, and at least one side peak 1075, of the second PSF_{2d}.

FIG. 10A-10F differs from FIG. 7A-7F, FIG. 8A-8F, and FIG. 9A-9F, in that: the main lobe 1020 in the distribution of the first PSF₁ₐ is different from the main lobe 1060 in the distribution of the second PSF_{2d}, as shown in FIG. 10E, and the main peak 1025 of the first PSF₁ₐ is different from the main peak 1065 of the second PSF₂ₐ, as shown in a intensity plot of FIG. 10F.

Although the side lobes 1030 in the distribution of the first PSF₁ₐ may be shown as corresponding to and substantially overlapping with the side lobes 1070 in the distribution of the second PSF_{2d}, in some non-limiting examples, the side lobes 1030 of the first PSF_{1d} may have one of: substantially no, and partial overlap with the side lobes 1070 of the second PSF_{2d}. Those having ordinary skill in the relevant art will appreciate that various lobe features described in relation to FIGS. 7A-7F, 8A-8F, 9A-9F, and FIG. 10A-10F may be applicable to one another.

In some non-limiting examples, an overlap in the side-lobe pattern of the first PSF₁, and the side-lobe pattern of the second PSF₂, may be one of no more than about: 60%, 50%, 40%, 30%, 20%, 25%, 20%, 10%, and 5%.

Although not shown, in some non-limiting examples, a main lobe of at least one of: the first PSF₁ and the second PSF₂, may overlap with at least one side lobe of the at least one of: the first PSF₁ and the second PSF₂.

Although not shown, in some non-limiting examples, a main lobe of one of: the first PSF₁ and the second PSF₂, may overlap with at least one side lobe of the other one of: the first PSF₁ and the second PSF₂.

In some non-limiting examples, the PSF associated with (a signal-exchanging part 103 of) the display panel 100 may comprise components related to the transmissive regions 112, including without limitation, a layout of the apertures defining the transmissive regions 112 in plan, including without limitation, at least one of a: number, size (including without limitation, an aperture ratio), shape, orientation, and pitch, thereof.

In some non-limiting examples, the first signal-exchanging part 103₁ may comprise a plurality of first transmissive regions 112₁ configured differently from a plurality of second transmissive regions 112₂ of the second signal-exchanging part 103₂, such that the first panel PSFₚ₁ of the first signal-exchanging part 103₁ may be different from the second panel PSFₚ₂ of the second signal-exchanging part 103₂, and accordingly, the first signal-exchanging part 103₁ and the second signal-exchanging part 103₂ may impart different diffraction characteristics onto at least one of: the image, and light pattern, that is one of: emitted, and received, by the opto-electronic components 130₁ and 130₂, respectively.

In some non-limiting examples, a configuration of the plurality of first transmissive regions 112₁ in the first signal-exchanging part 103₁ may be different from a configuration of the plurality of second transmissive regions 112₂ in the second signal-exchanging part 103₂.

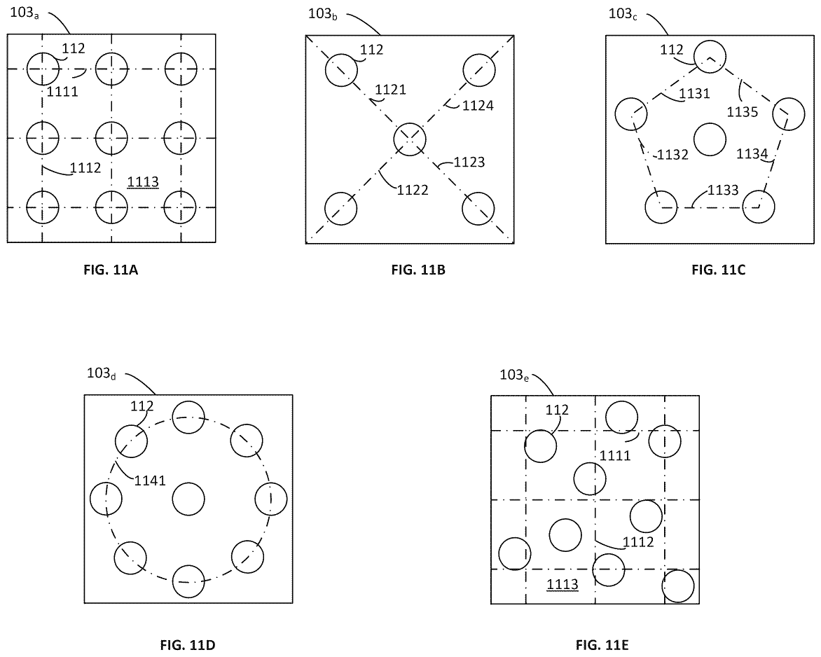

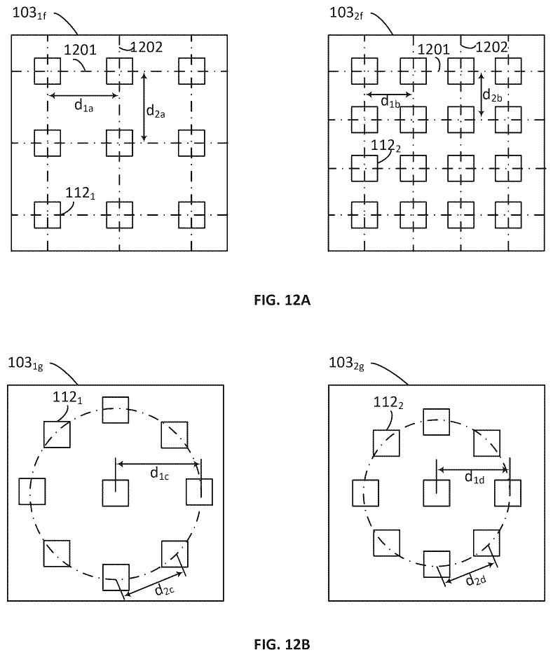

Turning now to FIGS. 11A-11E, there may be shown at least a fragment 103ₐ-103ₑ of various example signal-exchanging parts of a display panel 100.

In FIG. 11A, a signal-exchanging part 103ₐ may comprise a plurality of transmissive regions 112 that may be aligned in at least one of: a row 1111, and column 1112. In some non-limiting examples, the transmissive regions 112 may be aligned in parallel at least one of: rows 1111, and columns 1112. In some non-limiting examples, the transmissive region 112 may be positioned on a grid 1113 formed by the rows 1111 and columns 1112.

In FIG. 11B, a signal-exchanging part 103_{b} may comprise a plurality of transmissive regions 112 that may be arranged along a plurality of, including without limitation, four, configuration axes 1121, 1122, 1123 and 1124, that intersect at a point of intersection. In some non-limiting examples, at least one transmissive region 112 may be disposed at the point of intersection.

In FIG. 11C, a signal-exchanging part 103_{c} may comprise a plurality of transmissive regions 112, which may be arranged in a polygonal, including without limitation, pentagonal, configuration. In some non-limiting examples, at least one of the transmissive regions 112 may be aligned along a plurality of sides 1131-1135 of a polygon defined by the configuration. In some non-limiting examples, each vertex of the polygon may correspond to a transmissive region 112. In some non-limiting examples, at least one transmissive region 112 may be located within the polygon, including without limitation, at a center thereof. While a regular pentagonal configuration is shown, those having ordinary skill in the relevant art will appreciate that other polygonal configurations, whether regular or irregular, including without limitation, triangular, square, rectangular, parallelogram and hexagonal, may be applicable.

In FIG. 11D, a signal-exchanging part 103ₐ may comprise a plurality of transmissive regions 112, which may be arranged in an elliptical, including without limitation, circular configuration. In some non-limiting examples, the transmissive regions 112 may be equally spaced on a perimeter 1141 of the ellipse defined by the configuration. In some non-limiting examples, at least one transmissive region 112 may be located within the ellipse, and in some non-limiting examples, substantially at a center thereof. In some non-limiting examples, the transmissive regions 112 may be arranged along respective perimeters of a plurality of concentric circles.

In some non-limiting examples, as shown in FIGS. 11A-11D, the transmissive regions 112 may be arranged in a configuration exhibiting a substantial degree of periodicity. Although not shown, in some non-limiting examples, the transmissive regions 112 may be arranged in a substantially non-periodic, including without limitation, random, and pseudo-random, configuration.

In FIG. 11E, a signal-exchanging part 103ₑ may comprise a plurality of transmissive regions 112, which may be arranged in a substantially non-periodic configuration. In some non-limiting examples, the transmissive regions 112 may be spaced apart a varying distance. In some non-limiting examples, the transmissive regions 112 may be positioned on a grid 1113 with one of: a random, and pseudo-random, placement.

In some non-limiting examples, a pitch of a plurality of transmissive regions 112₁ in the first signal-exchanging part 103₁ may be different from a pitch of a plurality of transmissive regions 112₂ in the second signal-exchanging part 103₂. In some non-limiting examples, a pitch of transmissive regions 112 may be measured by a spacing between adjacent transmissive regions 112.

Turning now to FIG. 12A, there is shown, in plan, at least a fragment 103_{1f} of the first signal-exchanging part 103₁, and a fragment 103_{2f} of the second signal-exchanging part 103₂ of the display panel 100. As shown, in some non-limiting examples, the first transmissive regions 112₁ of the first signal-exchanging part 103_{1f} and the second transmissive regions 112₂ of the second signal-exchanging part 103_{2f} may be arranged in an array configuration in a similar fashion to FIG. 11A, except the transmissive regions 112 in FIG. 12A have a substantially square shape.

As shown, in some non-limiting examples, the first transmissive regions 112₁ may have a first pitch d₁ₐ along a first direction 1201, and a second pitch d₂ₐ along a second direction 1202, which in some non-limiting examples, may intersect with the first direction 1201 at a non-zero angle, including without limitation, substantially 90°. In some non-limiting examples, the first pitch d₁ₐ and the second pitch d₂ₐ of the first transmissive regions 112₁ may be substantially the same. In some non-limiting examples, the first pitch d₁ₐ and the second pitch d₂ₐ of the first transmissive regions 112₁ may be different.

In some non-limiting examples, the configuration of the plurality of the second transmissive regions 112₂ may be similar to that of the plurality of the first transmissive region 112₁, and have a first pitch d_{1b} along the first direction 1201, and a second pitch d_{2b} along the second direction 1202. In some non-limiting examples, the first pitch d_{1b} and the second pitch d_{2b} of the second transmissive regions 112₂ may be substantially the same. In some non-limiting examples, the first pitch d_{1b} and the second pitch d_{2b} of the second transmissive regions 112₂ may be different.

In some non-limiting examples, a pitch along one direction, including without limitation, the first pitch d₁ₐ, of the first transmissive region 112₁ may be different from a pitch along such direction, including without limitation, the first pitch dib, of the second transmissive region 112₂. In some non-limiting examples, a pitch along one direction, including without limitation, the first pitch d₁ₐ, of the first transmissive region 112₁ may be one of: an integer, and non-integer, multiple of a pitch along such direction, including without limitation, the first pitch dib, of the second transmissive region 112₂. In some non-limiting examples, while the first transmissive region 112₁ and the second transmissive region 112₂ may have a different pitch along one direction, they may have one of the: same, and different, pitch along another direction.

Turning now to FIG. 12B, there is shown, in plan, at least a fragment 103_{1g} of the first signal-exchanging part 103₁, and a fragment 103_{2g} of the second signal-exchanging part 103₂ of the display panel 100.

The signal-exchanging part 103 of FIG. 12B may differ from that of FIG. 12A in that the transmissive regions 112₁, 112₂ may be arranged in an elliptical, including without limitation, circular, configuration in a similar fashion to FIG. 11D (except the transmissive regions 112 in FIG. 12B have a substantially square shape), such that the transmissive regions 112 have a first pitch d_{1c}, did along a first, including without limitation, radial, direction, and a second pitch d_{2c}, d_{2d} along a second, including without limitation, circumferential, direction.

In some non-limiting examples, a pitch along one direction, including without limitation, the first pitch d_{1c}, of the first transmissive region 112₁ may be different from a pitch along such direction, including without limitation, the first pitch d_{1d}, of the second transmissive region 112₂. In some non-limiting examples, a pitch along one direction, including without limitation, the first pitch d_{1c}, of the first transmissive region 112₁ may be one of: an integer, and non-integer, multiple of a pitch along such direction, including without limitation, the first pitch d_{1d}, of the second transmissive region 112₂. In some non-limiting examples, while the first transmissive region 112₁ and the second transmissive regions 112₂ may have a different pitch along one direction, they may have one of the: same, and different, pitch, along another direction.

Although not shown, in some non-limiting examples, the transmissive regions 112 of at least one of: the first signal-exchanging part 103₁ and the second signal-exchanging part 103₂ may have a pitch that is varied along one direction.

The transmissive regions 112 of the first signal-exchanging part 103₁ and the second signal-exchanging part 103₂ are shown, in each fragment 103_{1f}, 303_{2f}, having a substantially square shape arranged in an array configuration in FIG. 12A, and in each fragment 103_{1g}, 103_{2g}, having a substantially square shape arranged in a circular configuration in FIG. 12B, and having a substantially uniform size solely for illustrative purposes and the examples discussed herein, which should not be considered as limiting, in any fashion, any of the size, shape, configuration, and orientation of the transmissive regions 112 in either the first signal-exchanging part 103₁ or the second signal-exchanging part 103₂.

In some non-limiting examples, a size, including without limitation, at least one of: a length, width, diameter, perimeter, area, and an aperture ratio, of at least one of the first transmissive regions 112₁ in the first signal-exchanging part 103₁ may be different from that of at least one of second transmissive regions 112₂ in the second signal-exchanging part 3032.

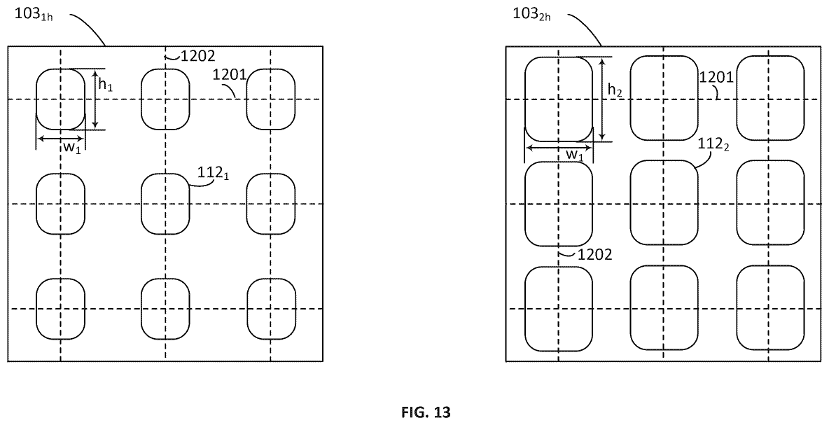

Turning now to FIG. 13, there is shown, in plan, at least a fragment 103₁ h of the first signal-exchanging part 103₁, and a fragment 103₂ h of the second signal-exchanging part 103₂ of the display panel 100. As shown, in some non-limiting examples, the first transmissive regions 112₁ of the first signal-exchanging part 103₁ₕ and the second transmissive regions 112₂ of the second signal-exchanging part 103₂ₕ may be arranged in an array configuration in a similar fashion to FIG. 12A, except the transmissive regions 112 in FIG. 13 have a rounded rectangular shape.

As shown, in some non-limiting examples, the first transmissive regions 112₁ may have a width w₁ along the first direction 1201, and a height h₁ along the second direction 1202, and the second transmissive regions 112₂ may have a width w₂ along the first direction 1201 that is different from width w₁, and a height h₂ along the second direction 1202 that is different from the height h₁.

Although not shown, in some non-limiting examples, a dimension along one direction of the first transmissive regions 112₁ may be different from a dimension along such direction of the second transmissive region 112₂, while a dimension along other direction of the first transmissive regions 112₁ may be the same as a dimension along such other direction of the second transmissive region 112₂.

The transmissive regions 112 of the first signal-exchanging part 103₁ and the second signal-exchanging part 103₂ are shown, in each fragment 103₁ₕ, 103₂ₕ, having an array configuration in FIG. 13, and a substantially uniform shape solely for illustrative purposes and the examples discussed herein, which should not be considered as limiting, in any fashion, any of the shape, pitch, configuration, and orientation of the transmissive regions in either the first signal-exchanging part 103₁ or the second signal-exchanging part 103₂.

In some non-limiting examples, a size, including without limitation, an aperture ratio, of the transmissive regions 112 in the at least one signal-exchanging part 103, may be varied, including without limitation, one of: such that all of the transmissive regions 112 have a common size, and such that at least one of the transmissive regions 112 has a size that is different than that of another one of the transmissive regions 112.

In some non-limiting examples, an orientation of at least one of the first transmissive regions 112₁ in the first signal-exchanging part 103₁ may be different from an orientation of at least one of second transmissive regions 112₂ in the second signal-exchanging part 103₂.

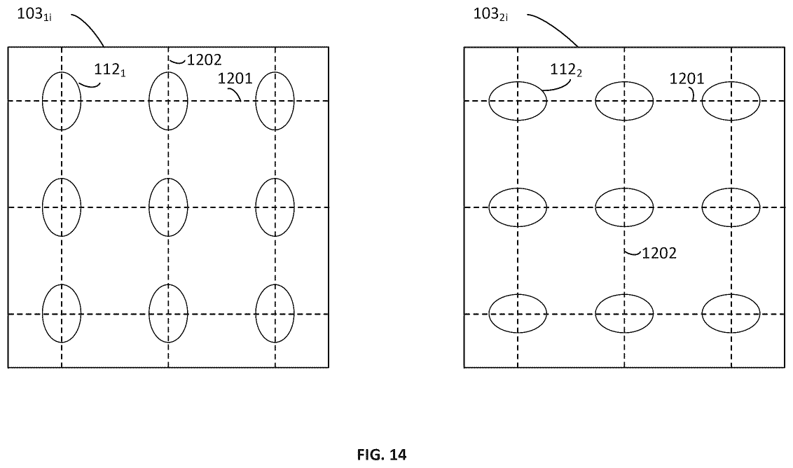

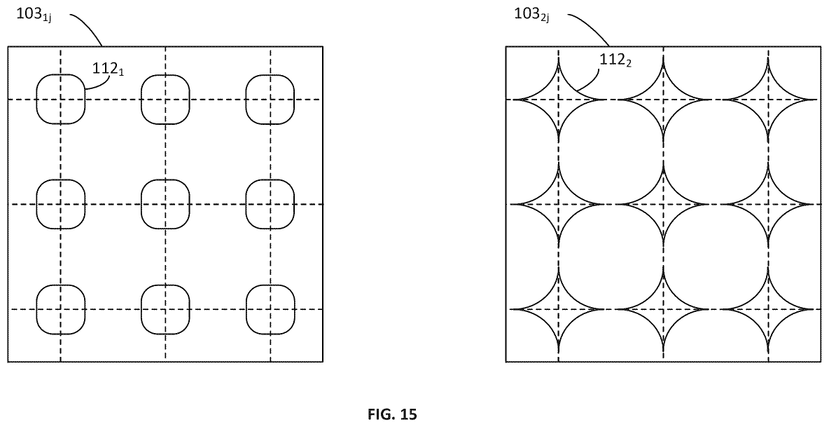

Turning now to FIG. 14, there is shown, in plan, at least a fragment 103₁ᵢ of the first signal-exchanging part 103₁, and a fragment 103₂ᵢ of the second signal-exchanging part 103₂ of the display panel 100. As shown, in some non-limiting examples, the first transmissive regions 112₁ of the first signal-exchanging part 103₁ᵢ and the second transmissive regions 112₂ of the second signal-exchanging part 103₂ᵢ may be arranged in an array configuration in a similar fashion to FIG. 12A, except the transmissive regions 112 in FIG. 14 have an elliptical shape.

As shown, each first transmissive region 112₁ in the first signal-exchanging part 103₁ᵢ may be oriented such that a major axis thereof may be aligned along the second direction 1202, while each second transmissive region 112₂ in the second signal-exchanging part 103₂ᵢ may be oriented such that a major axis thereof may be aligned along the first direction 1201.

In some non-limiting examples, a major axis of each first transmissive region 112₁ may intersect with at least one of the first direction 1201, and the second direction 1202, at an angle that is different from an angle at which the major axis of each second transmissive region 112₂ intersects with such at least one of the first direction 1201, and the second direction 1202.

The transmissive regions 112 of the first signal-exchanging part 103₁ and the second signal-exchanging part 103₂ are shown, in each fragment 103₁ᵢ, 103₂ᵢ, having an array configuration in FIG. 14, and a substantially uniform size solely for illustrative purposes and the examples discussed herein, which should not be considered as limiting, in any fashion, any of the shape, size, pitch, and configuration of the transmissive regions in either the first signal-exchanging part 103₁ or the second signal-exchanging part 103₂.

In some non-limiting examples, an orientation of the transmissive regions 112 relative to an axis of the at least one signal-exchanging part 103 may be varied, including without limitation, one of: such that all of the transmissive regions 112 are oriented in a common direction, and such that at least one of the transmissive regions 112 is oriented in a direction that is different than that of another one of the transmissive regions 112.

In some non-limiting examples, a shape of at least one of the first transmissive regions 112₁ in the first signal-exchanging part 103₁ may be different from a shape of at least one of second transmissive regions 112₂ in the second signal-exchanging part 103₂.

Turning now to FIG. 15, there is shown, in plan, at least a fragment 103₁ⱼ of the first signal-exchanging part 103₁, and a fragment 103₂ⱼ of the second signal-exchanging part 103₂ of the display panel 100. As shown, in some non-limiting examples, the first transmissive regions 112₁ of the first signal-exchanging part 103₁ⱼ and the second transmissive regions 112₂ of the second signal-exchanging part 103₂ⱼ may be arranged in an array configuration in a similar fashion to FIG. 12A.

In some non-limiting examples, the first transmissive regions 112₁ may be shown as having a first shape, including without limitation, a rounded square shape, that is different from a second shape of the second transmissive regions 112₂, including without limitation, a star shape. In some non-limiting examples, the first shape may have a different area from the second shape. In some non-limiting examples, the first shape may have a substantially same area as the second shape.

The transmissive regions 112 of the first signal-exchanging part 103₁ and the second signal-exchanging part 103₂ are shown, in each fragment 103₁ⱼ, 103₂ⱼ, having an array configuration in FIG. 15, and a substantially uniform pitch solely for illustrative purposes and the examples discussed herein, which should not be considered as limiting, in any fashion, any of the size, pitch, orientation, and configuration of the transmissive regions in either the first signal-exchanging part 103₁ or the second signal-exchanging part 103₂.

In some non-limiting examples, a shape of the transmissive regions 112 in the at least one signal-exchanging part 103, including without limitation, a substantially regular shape, including without limitation, one of: substantially polygonal (including without limitation, one of: substantially quadrilateral (including without limitation, substantially rectangular (including without limitation, substantially square)), and substantially triangular), and substantially elliptical (including without limitation, substantially circular), may be varied, including without limitation, one of: such that all of the transmissive regions 112 have a common shape, and such that at least one of the transmissive regions 112 has a shape that is different than that of another one of the transmissive regions 112.

In the present disclosure, the term “polygonal” may refer generally to at least one of: shapes, figures, closed boundaries, and perimeters, formed by a finite number of linear segments and the term “non-polygonal” may refer generally to at least one of: shapes, figures, closed boundaries, and perimeters, that are not polygonal. In some non-limiting examples, a closed boundary formed by a finite number of linear segments and at least one non-linear (curved) segment may be considered non-polygonal.

Without wishing to be bound by any specific theory, it may be postulated that display panels 100 having closed boundaries of transmissive regions 112 defined by a corresponding transmissive region 112, that are substantially regular in shape, may exhibit a distinctive and non-uniform diffraction pattern that may adversely impact an ability to facilitate mitigation of interference caused by the diffraction pattern, relative to a display panel 100 having closed boundaries of transmissive regions 112 defined by a corresponding transmissive region 112 that is non-polygonal.

Without wishing to be bound by a particular theory, it may be postulated that when a closed boundary of a transmissive region 112 defined by a corresponding transmissive region 112 comprises at least one non-linear (curved) segment, EM signals incident thereon and transmitted therethrough may exhibit a less distinctive (more uniform) diffraction pattern that facilitates mitigation of interference caused by the diffraction pattern.

In some non-limiting examples, a display panel 100 having a closed boundary of the transmissive regions 112 defined by a corresponding transmissive region 112 that is substantially elliptical, including without limitation, circular may further facilitate mitigation of interference caused by the diffraction pattern.

In some non-limiting examples, a transmissive region 112 may be defined by a finite plurality of convex rounded segments. In some non-limiting examples, at least some of these segments coincide at a concave notch (peak).

In some non-limiting examples, one of: all, and at least one, of the vertices of at least one of the transmissive regions 112 having a substantially polygonal shape may have substantially rounded corners.

In some non-limiting examples where there may be constraints on at least one of: an aperture ratio of the at least one transmissive region 112, and an aperture ratio of the at least one emissive region 210 within the at least one signal-exchanging part 103, the at least one transmissive region 112 may be provided with a substantially irregular shape, so as to facilitate increasing at least one of: an aperture ratio of the at least one transmissive region 112, and an aperture ratio of the at least one emissive region 210, within the at least one signal-exchanging part 103.

In some non-limiting examples, at least one of: controlling, modulating and tuning, a(n) (integrated) PSF associated with an opto-electronic component 130, including without limitation, a PSF of the optics of the opto-electronic component 130, and a PSF of a signal-exchanging part 103 behind which the opto-electronic component 130 may be arranged, may impact a diffraction pattern of at least one of: an image, and a light pattern represented thereby, and an ability to facilitate mitigating interference by such diffraction pattern, that is, to permit the opto-electronic component 130 to be able to one of: accurately receive and process such pattern, including without limitation, with the application of processing techniques, including without limitation, imaging processing, and optical processing, and to allow a viewer of such pattern through such display panel 100 to discern information contained therein.

In some non-limiting examples, the PSF may be modulated to some extent by judicious selection of at least one of: opto-electronic components 130, and a layout (including without limitation, a size, shape, pitch, orientation, configuration, and pattern) of the transmissive regions 112.

A series of experiments was designed to investigate aspects of the PSF of an optical system 420 comprising the at least one signal-exchanging part 103 that comprises at least one transmissive region 112, and the impact of various layouts (including without limitation, a size (including without limitation, aperture ratio), shape, orientation, and pitch) of the at least one transmissive region 112 in the at least one signal-exchanging part 103 thereon.

Those having ordinary skill in the relevant art will appreciate that the sample coupons are substantially comprised of an opaque film with apertures corresponding to a plurality of transmissive regions 112 therein. The sample coupons are intended to mimic the position of the transmissive regions 112 in at least one signal-exchanging part 103 of a display panel 100, in which the transmissive regions 112 are interspersed among the at least one (sub-) pixels 215/216.

However, the sample coupons used in the experimental set-up are substantially devoid of any emissive regions 210 corresponding to (sub-) pixels 215/216.

The particulars of the layout of the transmissive regions 112 used in the sample coupons herein are set out in Table 1 below:

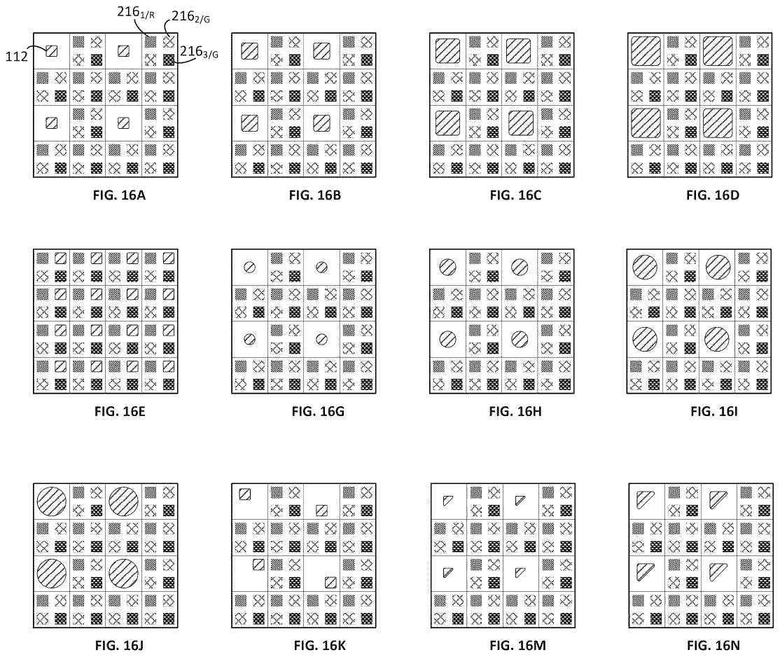

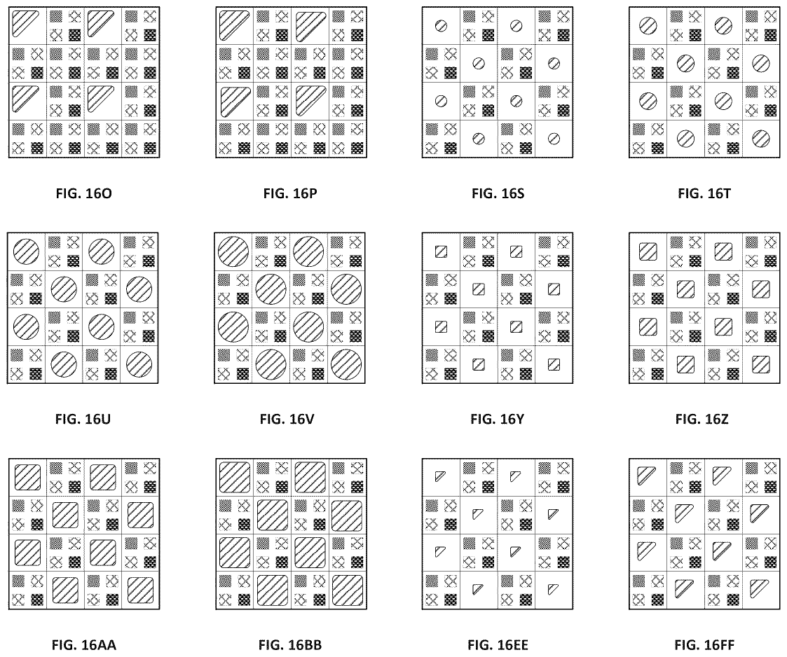

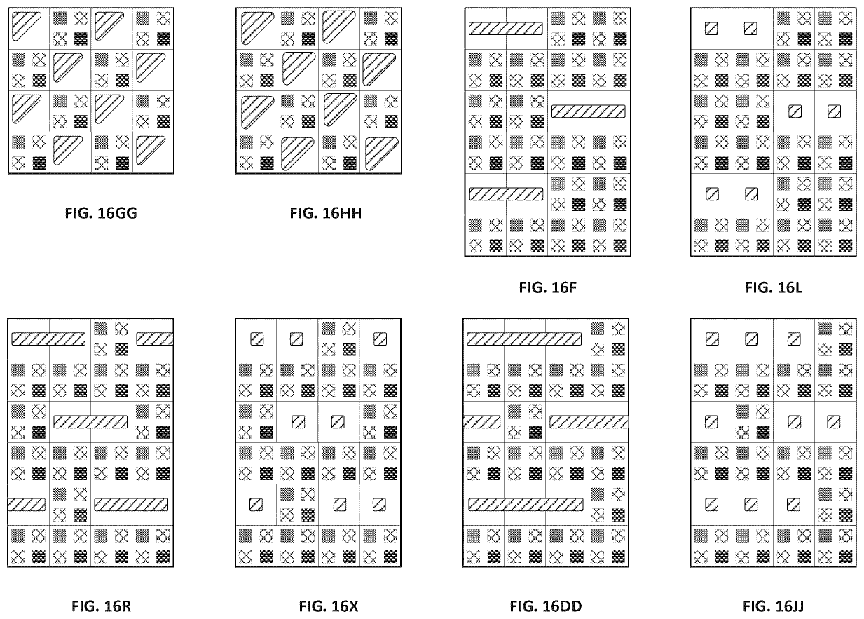

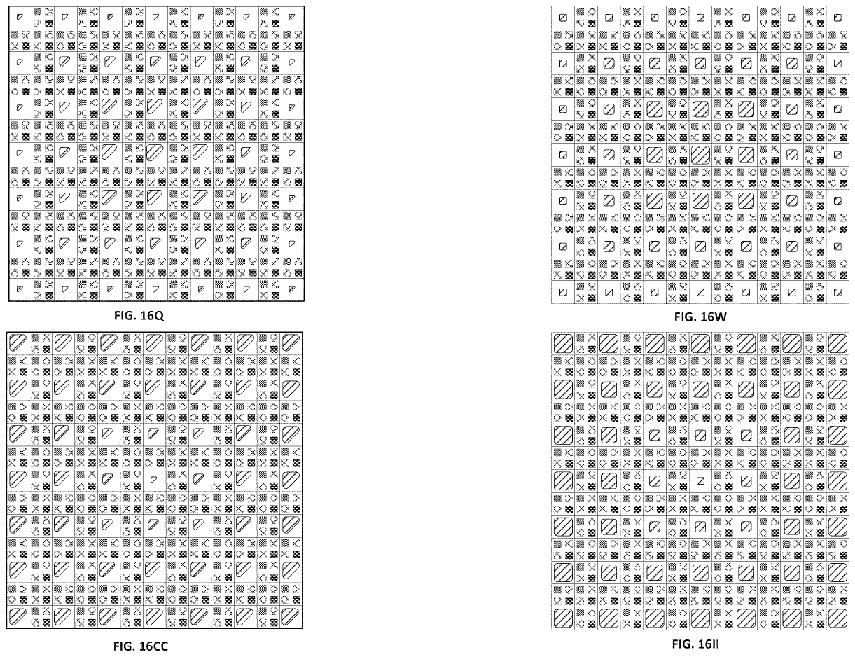

TABLE 1

| Sam- | | | | |
|---|---|---|---|---|
| ple | Size (μm) | Shape | Pitch (μm) | Pattern |
| A1 | 28 (side) | [symbol] | 110 | FIG. 16A |
| A2 | 38 (side) | [symbol] | 110 | FIG. 16B |
| A3 | 48 (side) | [symbol] | 110 | FIG. 16C |
| A4 | 58 (side) | [symbol] | 110 | FIG. 16D |
| A5 | 28 (side) | [symbol] | 55 | FIG. 16E |
| A6 | 28 (vertical side) | [symbol] | | FIG. 16F |
| B1 | 28 (diameter) | [symbol] | 110 | FIG. 16G |
| B2 | 38 (diameter) | [symbol] | 110 | FIG. 16H |
| B3 | 48 (diameter) | [symbol] | 110 | FIG. 16I |
| B4 | 58 (diameter) | [symbol] | 110 | FIG. 16J |
| B5 | 28 (side, random) | [symbol] | 110 | FIG. 16K |
| B6 | 28 (side) | [symbol] | | FIG. 16L |
| C1 | 28 (non-diagonal side) | [symbol] | 110 | FIG. 16M |
| C2 | 38 (non-diagonal side) | [symbol] | 110 | FIG. 16N |
| C3 | 48 (non-diagonal side) | [symbol] | 110 | FIG. 16O |
| C4 | 58 (non-diagonal side) | [symbol] | 110 | FIG. 16P |
| C5 | Varying radially inward | [symbol] | 110 | FIG. 16Q |
| | from 28 (non-diagonal | | | |
| | side) to 58 (non-diagonal | | | |
| | side) at centre | | | |
| C6 | 28 (vertical side) | [symbol] | | FIG. 16R |
| D1 | 28 (side) | [symbol] | 77.6 | FIG. 16S |
| | | | (=\sqrt{55² + 55²}) | |
| D2 | 38 (side) | [symbol] | 77.6 | FIG. 16T |
| D3 | 48 (side) | [symbol] | 77.6 | FIG. 16U |
| D4 | 58 (side) | [symbol] | 77.6 | FIG. 16V |
| D5 | Varying radially inward | [symbol] | 110 | FIG. 16W |
| | from 28 (side) to 58 | | | |
| | (side) at centre | | | |
| D6 | 28 (side) | [symbol] | | FIG. 16X |
| E1 | 28 (non-diagonal side) | [symbol] | 77.6 | FIG. 16Y |
| E2 | 38 (non-diagonal side) | [symbol] | 77.6 | FIG. 16Z |
| E3 | 48 (non-diagonal side) | [symbol] | 77.6 | FIG. 16AA |
| E4 | 58 (non-diagonal side) | [symbol] | 77.6 | FIG. 16BB |
| E5 | Varying radially inward | [symbol] | 110 | FIG. 16CC |
| | from 58 (non-diagonal | | | |
| | side) to 28 (non-diagonal | | | |
| | side) at centre | | | |
| E6 | 28 (vertical side) | [symbol] | | FIG. 16DD |
| F1 | 28 (side) | [symbol] | 77.6 | FIG. 16EE |
| F2 | 38 (side) | [symbol] | 77.6 | FIG. 16FF |
| F3 | 48 (side) | [symbol] | 77.6 | FIG. 16GG |
| F4 | 58 (side) | [symbol] | 77.6 | FIG. 16HH |
| F5 | Varying radially inward | [symbol] | 110 | FIG. 16II |
| | from 58 (side) to 28 | | | |
| | (side) at centre | | | |
| F6 | 28 (side) | [symbol] | | FIG. 16JJ |

For purposes of illustration only, in FIGS. 16A-16JJ, the location of the transmissive regions 112 in the sample coupons, are shown interspersed among a plurality of (sub-) pixels 215/216, so that the position of the at least one transmissive region 112 in the sample coupons may be seen relative to the positions of the (sub-) pixels 215/216.

In the experiments, the diffraction pattern was measured for each sample coupon, using the experimental set-up of FIG. 5A, by projecting a point source 410, in the form of a laser pointer emitting light at substantially about 980 nm through the sample coupon at a distance D₁ of substantially about 60 cm and recording the image with an IR camera.

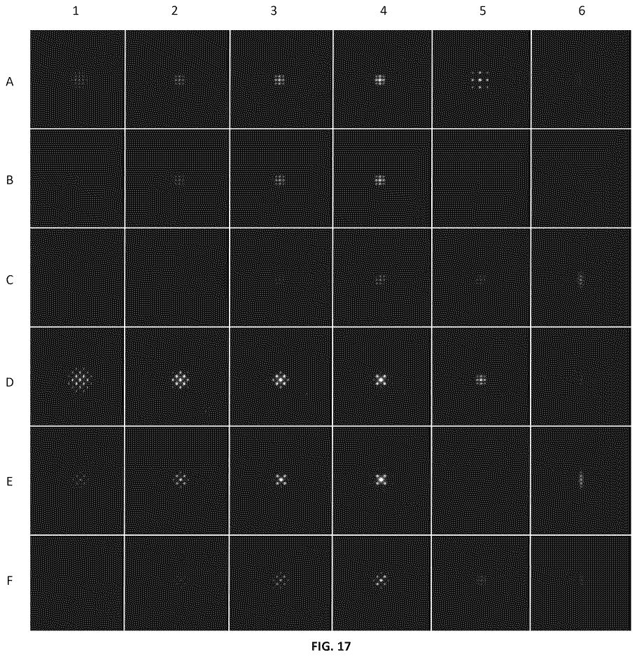

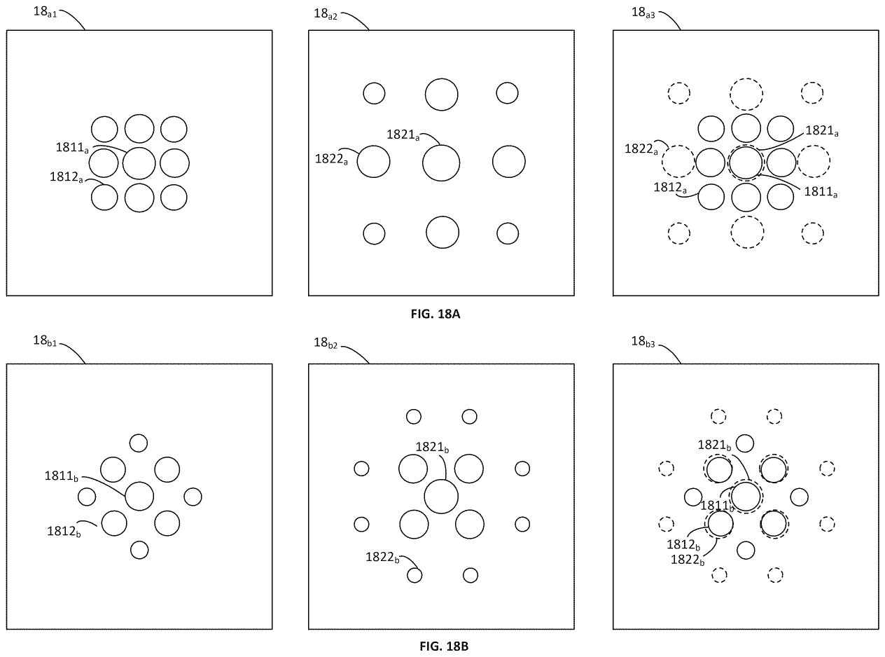

FIG. 17 shows the recorded images for each sample coupon. As may be seen, each sample coupon produced a unique PSF distribution. Those having ordinary skills in the relevant art may appreciate that various combinations of PSFs derived from different layouts of the signal-exchanging parts 103, including without limitation, the layouts of the transmissive region 112, may lead to varying degrees of overlap, including without limitation, at least one of: partial, complete, and substantially no, overlap of at least one of the: main lobe, and side lobe(s), between the first PSF and the second PSF.

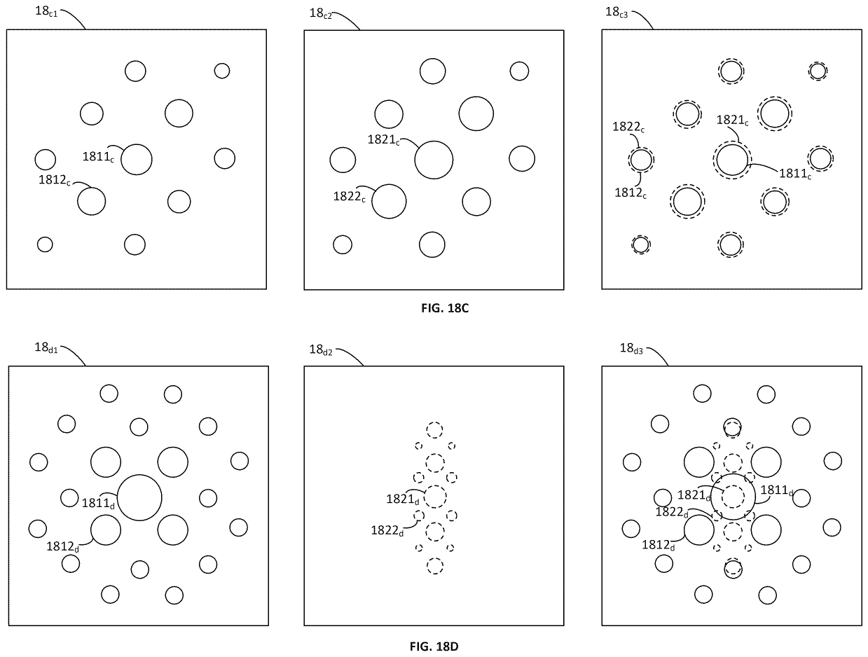

In some non-limiting examples, as shown in FIG. 18A, a distribution of a first PSF exhibited by Sample Coupon A3 and a distribution of a second PSF exhibited by Sample Coupon A5 were reproduced in a simplified representation shown in the plan view 18ₐ₁ and 18ₐ₂, respectively. The side lobes 1812ₐ of the first PSF and the side lobes 1822ₐ of the second PSF may not substantially overlap, as shown in a plan view 18ₐ₃, showing, in plan, the distribution of the first PSF (shown in solid outlines) superimposed over the distribution of the second PSF (shown in dashed outlines). The main lobe 1811ₐ of the first PSF and the main lobe 1821ₐ of the second PSF exhibit a partial, but close-to-complete overlap.

In some non-limiting examples, as shown in FIG. 18B, a distribution of a first PSF exhibited by Sample Coupon E2 and a distribution of a second PSF exhibited by Sample Coupon E4 were reproduced in a simplified representation shown in the plan view 18_{b1} and 18_{b2}, respectively. The side lobes 1812_{b} of the first PSF and the side lobes 1822_{b} of the second PSF may exhibit a certain degree of, but short of complete, overlap, as shown in a plan view 18_{b3}, showing, in plan, a distribution of the first PSF (shown in solid outlines) superimposed over the distribution of the second PSF (shown in dashed outlines). As shown, a first subset of the side lobes 1812_{b} of the first PSF overlaps with a first subset of the side lobes 1822_{b} of the second PSF, while a second subset of the side lobes 1812_{b} of the first PSF does not overlap with a second subset of the side lobes 1822_{b} of the second PSF. The main lobe 1811_{b} of the first PSF and the main lobe 1821_{b} of the second PSF exhibit a partial, but close-to-complete overlap.

In some non-limiting examples, as shown in FIG. 18C, a distribution of a first PSF exhibited by Sample Coupon F3 and a distribution of a second PSF exhibited by Sample Coupon F4 were reproduced in a simplified representation shown in the plan view 18_{c1} and 18_{c2}, respectively. Each side lobe 1812_{c} of the first PSF may correspond to, including without limitation, at least partially overlap with, a side lobe 1822 of the second PSF, as shown in a plan view 18_{c3}, showing, in plan, a distribution of the first PSF (shown in solid outlines) superimposed over the distribution of the second PSF (shown in dashed outlines). The main lobe 1811_{c} of the first PSF and the main lobe 1821_{c} of the second PSF exhibit a partial, but close-to-complete overlap.

In some non-limiting examples, as shown in FIG. 18D, a distribution of a first PSF exhibited by Sample Coupon D4 and a distribution of a second PSF exhibited by Sample Coupon E6 were reproduced in a simplified representation shown in the plan view 18_{d1} and 18_{d2}, respectively. A main lobe 1811_{d} of the first PSF may be substantially different from a main lobe 1821_{d} of the second PSF, as shown in a plan view 18_{d3}, showing, in plan, a distribution of the first PSF (shown in solid outlines) superimposed over the distribution of the second PSF (shown in dashed outlines). A side-lobe pattern of the first PSF also differs from a side-lobe pattern of the second PSF such that a first subset of the side lobes 1812_{d} of the first PSF overlaps with a first subset of the side lobes 1822_{d} of the second PSF, while a second subset of the side lobes 1821_{d} of the first PSF does not overlap a second subset of the side lobes 1822_{d} of the second PSF. The main lobe 1811_{d} of the first PSF and a subset of the side lobes 1822_{d} of the second PSF exhibit a certain degree of the overlap.

Diffracted dots that are indiscernible in the recorded images of FIG. 17 due to a substantially low SNR level are omitted in FIGS. 18A-18D.

In some non-limiting examples, the PSF of the display panel 100 may comprise components related to aspects thereof that may be substantially unrelated to the layout, including without limitation, at least one of a: number, size (including without limitation, aperture ratio), shape, orientation, and pitch, of the at least one transmissive region 112. In some non-limiting examples, such aspects may comprise at least one of: the presence of partially transmissive layers, including without limitation, at least one of: the first electrode 1920, the at least one semiconducting layer 330, the second electrode 340, an auxiliary electrode 2850, an underlying layer 2610, and an overlying layer 2170, including without limitation, a variation in refractive index between such layers, the presence of non-transmissive and partially transmissive elements in the display panel 100 and extending within the lateral aspect of the at least one transmissive region 112, including without limitation, TFT structures 2206, and where the transmissive region 112 is formed by depositing a patterning coating 310 thereon such that an exposed layer 11 thereof is substantially devoid of a closed coating 2140 of a deposited layer 331 of a deposited material 2431, a partially transmissive edge around a boundary of an aperture of the at least one transmissive region 112 formed by a difference, in the lateral aspect, the boundary and a boundary of an FMM for defining where the patterning coating 310 is deposited, and a presence of at least one particle structure 2150 on an exposed layer surface 11 of the patterning coating 310.

FIG. 19 illustrates schematically an example of a part of the display panel 100 comprising a transmissive region 112 formed by depositing a patterning coating 310 thereon, at an interface between the patterning coating 310 in a first portion 1901 and a deposited layer 331 in a second portion 1902.

The patterning coating 310 in the first portion 1901 may be surrounded on all sides by the deposited layer 331 such that the first portion 1901 may have a boundary that is defined by a further edge 1915 of the patterning coating 310 in the lateral aspect along each lateral axis. In some non-limiting examples, the patterning coating edge 1915 in the lateral aspect may be defined by a perimeter of the first portion 1901 in such aspect.

In some non-limiting examples, the deposited layer 331 may have a boundary that is defined by a further edge 1935 of the deposited layer 331 in the lateral aspect along each lateral axis. In some non-limiting examples, the deposited layer edge 1935 in the lateral aspect may be defined by a perimeter thereof in such aspect.

In some non-limiting examples, at least a part of the deposited layer 331 may correspond to a second electrode 340 (not shown) of an emissive region 210. In some non-limiting examples, an active region 1908 of an individual emissive region 210 may be defined to be bounded, in the longitudinal aspect, by a first electrode 1920 (shown schematically) and the second electrode 340, and to be confined, in the lateral aspect, to an emissive region 210, defined by presence of each of the first electrode 1920, the second electrode 340, and at least one semiconducting layer 330 therebetween, which may in some non-limiting examples, overlap laterally.

In some non-limiting examples, in FIG. 19, the boundary defining the transmissive region 112 may thus be seen to correspond substantially to the deposited layer edge 1935, such that a region between the boundary of the active region 1908 and the deposited layer edge 1935 may correspond to a deposition-applied (DA) region 1960 and the part of the first portion 1901 enclosed by the deposited layer edge 1935 may correspond to a deposition-free (DF) region 1965.

While the DF region 1965 may be shown as being surrounded by the DA region 1960, those having ordinary skill in the relevant art will appreciate that, in some non-limiting examples, the DA region 1960 and the DF region 1965 may be positioned such that one of: the DA region 1960 and the DF region 1965 may be adjacent to, including without limitation, interleaved with, and surrounded by, the other of: the DA region 1960 and the DF region 1965.

In some non-limiting examples, a transmissive region 112 comprising a DA region 1960 and a DF region 1965 may be achieved by the aperture 122 defined by the first defining layer 311 and the second defining layer 321. In some non-limiting examples, the second layer aperture boundary 323 may lie entirely within the first layer aperture boundary 313, such that the second layer aperture boundary 323 of the second layer aperture 322 may enclose a DF region 1965 that is substantially devoid of deposited material 2431. Further, in some non-limiting examples, the remaining part within the first layer aperture boundary 313 of the first layer aperture 312 may be considered to be a DA region 1960, in which a deposited layer 331 comprising the deposited material 2431 is disposed, such that the DA region 1960 may substantially surround the DF region 1965.

In some non-limiting examples, the DA region 1960, including without limitation, a part thereof that overlaps with the patterning coating 310, may exhibit a certain degree of transmissivity different from that of the DF region 1965, such that the boundary defining the transmissive region 112 may thus correspond to a patterning coating edge 1915, and the transmissivity may be varied across a transmissive region 112.

In some non-limiting examples, a transmittance through the DF region 1965 may be at least that of a transmittance through the DA region 1960, such that the transmissive region 112, may comprise two non-overlapping regions with different transmittance. In some non-limiting examples, the DA region 1960 may be considered to correspond to the “grey zone”.

In some non-limiting examples, as shown, the absence of the deposited material 2431 in the DF region 1965 may be achieved by ensuring that such material fails to be deposited thereon, including without limitation, by depositing a patterning material 2311, including without limitation, an NIC, in the DF region 1965, to form a patterning coating 310 in a pattern corresponding to the boundary 323 of the aperture 322 defining the DF region 1965, including without limitation, by interposing a shadow mask 2315 therebetween, that corresponds to the boundary 323 of the aperture 322 defining the DF region 1965, during a vapour deposition process, prior to the deposition of the deposited material 2431.

In some non-limiting examples, when the patterning coating 310 comprises an NIC, the pattern of the patterning material 2311 may substantially correspond to the boundary 323 of the (frontplane) second layer aperture(s) 322, such that, when the deposited material 2431 is thereafter deposited, the deposited material 2431 tends not to be deposited where the patterning coating 310 has been deposited, and tends to accumulate to form the deposited layer 330 in areas that are substantially devoid of the patterning coating 310.

In some non-limiting examples, the pattern of the deposited layer 331 may be specified by depositing the deposited material 2431 through apertures of a shadow mask in a pattern that is substantially the reverse of the pattern of the DF region 1965.

In some non-limiting examples, the pattern of the deposited layer 331 may be specified by depositing the deposited material 2431 and thereafter removing deposited material 2431 in a pattern corresponding to the DF region 1965, including without limitation, by photolithography, chemical etching, and laser ablation.

### Biometric Authentication

In some non-limiting examples, the user device 110 may house a transmitter 130ₜ for transmitting at least one transmitted EM signal 131ₜ beyond the face 101. In some non-limiting examples, the user device 110 may house at least one detector/receiver 130, for receiving at least one received EM signal 131ᵣ from beyond the face 101. In some non-limiting examples, the at least one received EM signal 131ᵣ may be the same as the at least one transmitted EM signal 131ₜ, reflected off an external surface, including without limitation, a user 10, including without limitation, for biometric authentication by a facial identification system thereof.

Without wishing to be bound by any particular theory, it may be postulated that diffraction incurred at the side of an under-display transmitter 130ₜ, may have substantial impact on the image compared to diffraction incurred at the side of an under-display detector/receiver 130_{d}, due to a total distance that the light emitted by the under-display transmitter 130ₜ has to travel before returning to the under-display detector/receiver 130ₐ, including without limitation, to and from the object 10, which in some non-limiting examples, may be on the order of between about a fraction of a meter to a few meters. Accordingly, in some non-limiting examples, a display panel 100 comprising a non under-display transmitter 130ₜ and an under-display detector/receiver 130ₐ may have applicability calling for a reduced diffraction incurred at the transmitter side, and concomitantly, an overall enhanced image quality.

Having said this, in some non-limiting examples, there may be scenarios calling for an uninterrupted user experience and a substantial aesthetic appeal of the display panel 100. In some non-limiting examples, each of the transmitter 130ₜ and the detector 130ₐ may be arranged behind the display panel 100, and correspond to a signal-exchanging part 103 comprising at least one transmissive region 112.

In some non-limiting examples, the signal-exchanging part 103 associated with the transmitter 130ₜ may differ from the signal-exchanging part 103 associated with the detector 130_{d}, such that different diffraction characteristics may be imparted to the transmitter 130ₜ and the detector 130_{d}. By doing so, in some non-limiting examples, additional information or data may be obtained compared to the scenarios where both the transmitter 130ₜ and the detector 130ₐ are arranged behind substantially identical signal-exchanging parts 103, including without limitation, a common signal-exchanging part 103. In some non-limiting examples, such additional information or data may be used to at least one of: verify, and supplement, the data obtained by detecting the transmitted light, and accordingly facilitate processing of the data.

In some non-limiting examples, these signal-exchanging parts 103 may differ in at least one of the: layout of the at least one transmissive region 112, including without limitation, at least one of a: size (including without limitation, an aperture ratio), shape, orientation, and pitch, thereof, and the layer structure within the at least one transmissive region 112, including without limitation, presence of a partially transmissive layer, an opaque component, and a particle structure 2150, and their location within the transmissive region 112.

### Method Actions

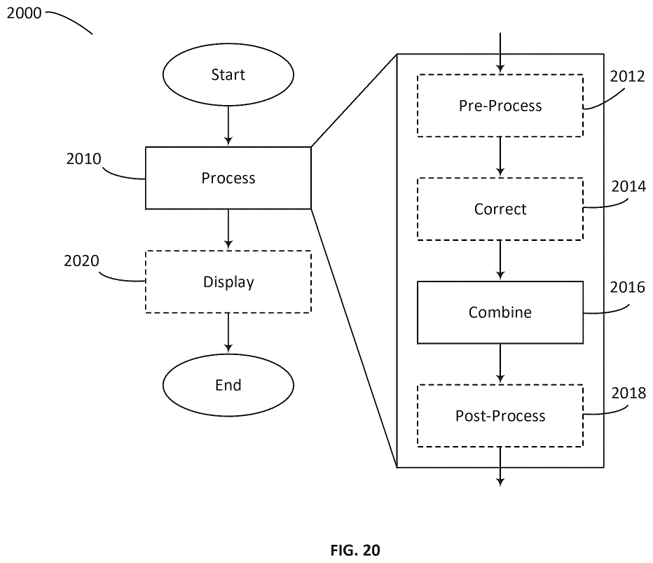

Turning now to FIG. 20, there may be shown a flow chart, shown generally at 2000, showing example actions taken to operate an electronic device 110 comprising a display panel 100 and a plurality of opto-electronic components 130. The opto-electronic components 130 may be configured to at least one of: emit, and receive light in at least a wavelength range of the EM spectrum, including without limitation, at least one of: the visible spectrum, the UV spectrum, the IR spectrum, the NIR spectrum, and a part thereof. The display panel 100 may comprise at least one signal-exchanging part 103 comprising at least one transmissive region 112. In some non-limiting examples, a first one of the opto-electronic components 130 may be arranged behind the at least one signal-exchanging part 130, such that the light that is at least one of: emitted, and received, by the first opto-electronic components 130 may pass through the at least one transmissive region(s) 112.

One example action 2010 is to process initial outputs from the plurality of opto-electronic components 130 to produce a processed output. In some non-limiting examples, each initial output may comprise diffracted information. In some non-limiting examples, the initial output may be a diffracted image, including without limitation, a raw image, a RGB image, a depth image, and an infrared image.

In some non-limiting examples, the diffracted information contained in the initial output of an opto-electronic component 130 may be correlated with a(n) (integrated) PSF that is associated with the opto-electronic component 130. In some non-limiting examples, one opto-electronic component 130 may have, associated therewith, a(n) (integrated) PSF that is different from a(n) (integrated) PSF associated with other opto-electronic component(s) 130. Accordingly, the plurality of opto-electronic components 130 may be imparted with different diffraction characteristics, such that an initial output from one of the opto-electronic components 130 may be different from an initial output from other opto-electronic component(s) 130.

In some non-limiting examples, the PSF associated with the opto-electronic component 130 may comprise a component associated with optics of the opto-electronic component 130. In some non-limiting examples, the PSF associated with the opto-electronic component 130 may comprise a component associated with the at least one transmissive region(s), including without limitation, a layout thereof, of the signal-exchanging part 103, behind which the opto-electronic component 130 may be arranged.

In some non-limiting examples, more than one opto-electronic component 130 may be arranged behind the at least one signal-exchanging part 103, such that each opto-electronic component 130 may be associated with a PSF that may comprise a component associated with the transmissive regions 112 of the corresponding signal-exchanging part 103.

In some non-limiting examples, the processing may include processing the initial output of one of: the first opto-electronic component 130₁ and the second opto-electronic component 130₂ using the PSF of the other of: the first opto-electronic component 130₁ and the second opto-electronic component 130₂. In some non-limiting examples, the processing may be performed using PSFs, which in some non-limiting examples, may be at least one of a(n): measured, estimated, and calculated, PSF, associated with each opto-electronic component 130. In some non-limiting examples, the processing may be achieved by conducting a de-convolution calculation using the PSFs. In some non-limiting examples, the processing may be achieved by applying a filter, which in some non-limiting examples, may be a deconvolution filter, including without limitation, a Wiener filter. In some non-limiting examples, the filter may be selected based at least partially on the PSFs. In some non-limiting examples, the processing may take at least one of: system noise (including without limitation, component-related noise and background noise), imaging conditions, other optical effects (including without limitation, aberrations and scattering), and human vision perception, into account.

In some non-limiting examples, the action 2010 may comprise an action 2014 to correct the initial outputs to generate corrected outputs.

In some non-limiting examples, in action 2014, the correction may include diffraction correction. In some non-limiting examples, the diffraction correction may be performed to correct the diffraction attributed to the presence of the display panel 100 in the optical path of the opto-electronic components 130.

In some non-limiting examples, the correction may be performed separately for initial output of each opto-electronic component 130. In some non-limiting examples, the correction may be performed by cross-referencing the initial outputs of the plurality of opto-electronic components 130 with each other.

In some non-limiting examples, the correction may correct diffraction contained in the initial output of one of the first opto-electronic component 130₁ and the second opto-electronic component 130₂ using the PSF of the other of the first opto-electronic component 130₁ and the second opto-electronic component 130₂. In some non-limiting examples, the correction may be performed using PSFs, which in some non-limiting examples, may be at least one of a(n): measured, estimated, and calculated, PSF, associated with each opto-electronic component 130. In some non-limiting examples, the correction may be achieved by conducting a de-convolution calculation using the PSFs. In some non-limiting examples, the correction may be achieved by applying a filter, which in some non-limiting examples, may be a deconvolution filter, including without limitation, a Wiener filter. In some non-limiting examples, the filter may be selected based at least partially on the PSFs. In some non-limiting examples, the correction may take at least one of: system noise (including without limitation, component-related noise and background noise), imaging conditions, other optical effects (including without limitation, aberrations and scattering), and human vision perception, into account.

In some non-limiting examples, the action 2010 may comprise an action 2016 to combine the corrected outputs to generate a combined output subsequent to action 2014.

In some non-limiting examples, in action 2016, the corrected output from each opto-electronic component 130 may be combined by at least one of a: fusion, and stitching, process, which in some non-limiting examples, may involve aligning and blending.

In some non-limiting examples, the action 2010 may comprise an action 2012 to pre-process the initial outputs from the plurality of opto-electronic components 130. In some non-limiting examples, the initial outputs may be pre-processed by performing at least one of: noise reduction, contrast enhancement, color reconstruction, filtering, and image resizing.

In some non-limiting examples, the action 2010 may comprise an action 2018 to post-process the combined output as a result of the action 2016 of combining. In some non-limiting examples, the combined output may be post-processed by performing at least one: noise reduction, contrast enhancement, color reconstruction, filtering, and image resizing.

In some non-limiting examples, the action 2010 may be followed by an action 2020 to display the processed output on the display panel. In some non-limiting examples, the processed output may be displayed by the display panel 100. In some non-limiting examples, the processed output may be at least one of: an image file, video file, 3D image, and 3D video.

### Layered Device

The present disclosure relates generally to layered semiconductor devices 2100, and more specifically, to opto-electronic devices 2200. An opto-electronic device 2200 may generally encompass any device 2100 that converts electrical signals into light in the form of photons and vice versa. In some non-limiting examples, the opto-electronic device 2200 may be an organic light-emitting diode (OLED).

Those having ordinary skill in the relevant art will appreciate that, while the present disclosure is directed to opto-electronic devices 2200, the principles thereof may, in some non-limiting examples, be applicable to any panel having a plurality of layers, including without limitation, at least one layer of conductive deposited material 2431, including as a thin film, and in some non-limiting examples, through which electromagnetic (EM) signals may pass, including without limitation, one of partially, and entirely, at a non-zero angle relative to a plane of at least one of the layers.

Turning now to FIG. 21, there may be shown a cross-sectional view of an example layered semiconductor device 2100. In some non-limiting examples, as shown in greater detail in FIG. 22, the device 2100 may comprise a plurality of layers deposited upon a substrate 10.

A lateral axis, identified as the X-axis, may be shown, together with a longitudinal axis, identified as the Z-axis. A second lateral axis, identified as the Y-axis, may be shown as being substantially transverse to both the X-axis and the Z-axis. At least one of the lateral axes may define a lateral aspect of the device 2100. The longitudinal axis may define a longitudinal aspect of the device 2100.

The layers of the device 2100 may extend, in the lateral aspect, substantially parallel to a plane defined by the lateral axes. Those having ordinary skill in the relevant art will appreciate that the substantially planar representation shown in FIG. 21 may be, in some non-limiting examples, an abstraction for purposes of illustration. In some non-limiting examples, there may be, across a lateral extent of the device 2100, localized substantially planar strata of different thicknesses and dimension, including, in some non-limiting examples, the substantially complete absence of at least one layer separated by non-planar transition areas (including lateral gaps and even discontinuities).

Thus, while for illustrative purposes, the device 2100 may be shown in its longitudinal aspect as a substantially stratified structure of substantially parallel planar layers, such device 2100 may illustrate locally, a diverse topography to define features, each of which may substantially exhibit the stratified profile discussed in the longitudinal aspect.

In some non-limiting examples, a lateral aspect of an exposed layer surface 11 of the device 2100 may comprise a first portion 1901 and a second portion 1902. In some non-limiting examples, the second portion 1902 may comprise that part of the exposed layer surface 11 of the device 2100 that lies beyond the first portion 1901.

As shown in FIG. 21, the layers of the device 2100 may comprise a substrate 10, and a patterning coating 310 disposed on an exposed layer surface 11 of at least a portion of the lateral aspect thereof. In some non-limiting examples, the patterning coating 310 may be limited in its lateral extent to the first portion 1901 and a deposited layer 331 may be disposed as a closed coating 2140 on an exposed layer surface 11 of the device 2100 in a second portion 1902 of its lateral aspect.

In some non-limiting examples, at least one particle structure 2150 may be disposed as a discontinuous layer 2160 on the exposed layer surface 11 of the patterning coating 310. In some non-limiting examples, although not shown, at least one of: the patterning coating 310, the deposited layer 331, and at least one particle structure 2150, may be deposited on a layer (underlying layer 2610) other than the substrate 10 including without limitation, an intervening layer between the substrate 10 and at least one of: the patterning coating 310, deposited layer 331, and the at least one particle structure 2150. In some non-limiting examples, the underlying layer 2610 may comprise at least one of: an orientation layer, and an organic supporting layer.

In some non-limiting examples, at least one of: the patterning coating 310, the deposited layer 331, and the at least one particle structure 2150, may be covered by at least one overlying layer 2170.

In some non-limiting examples, such overlying layer 2170 may comprise at least one of: an encapsulation layer and an optical coating. In some non-limiting examples, the encapsulation layer may comprise at least one of: a glass cap, a barrier film, a barrier adhesive, a barrier coating, an encapsulation layer, and a thin film encapsulation (TFE) layer, provided to encapsulate the device 2100. In some non-limiting examples, the optical coating may comprise at least one of: an optical, and structural, coating, and at least one component thereof, including without limitation, a polarizer, a color filter, an anti-reflection coating, an anti-glare coating, cover glass, and an optically clear adhesive (OCA).

In some non-limiting examples, at least one of: a substantially thin patterning coating 310 in the first portion 1901, and a deposited layer 331 in the second portion 1902, may provide a substantially planar surface on which the overlying layer 2170 may be deposited. In some non-limiting examples, providing such a substantially planar surface for application of such overlying layer 2170 may increase adhesion thereof to such surface.

In some non-limiting examples, the optical coating may be used to modulate optical properties of light being at least one of: transmitted, emitted, and absorbed, by the device 2100, including without limitation, plasmon modes. In some non-limiting examples, the optical coating may be used as at least one of: an optical filter, index-matching coating, optical outcoupling coating, scattering layer, diffraction grating, and parts thereof.

In some non-limiting examples, the optical coating may be used to modulate at least one optical microcavity effect in the device 2100 by, without limitation, tuning at least one of: the total optical path length, and the refractive index thereof. At least one optical property of the device 2100 may be affected by modulating at least one optical microcavity effect including without limitation, the output light, including without limitation, at least one of: an angular dependence of an intensity thereof, and a wavelength shift thereof. In some non-limiting examples, the optical coating may be a non-electrical component, that is, the optical coating may not be configured to at least one of: conduct, and transmit, electrical current during normal device operations.

In some non-limiting examples, the optical coating may be formed of any deposited material 2431, and in some non-limiting examples, may employ any mechanism of depositing a deposited layer 331 as described herein.

### Opto-Electronic Device

### Substrate

In some non-limiting examples, the substrate 10 may comprise a base substrate 315. In some non-limiting examples, the base substrate 315 may be formed of material suitable for use thereof, including without limitation, at least one of: an inorganic material, including without limitation, at least one of: Si, glass, metal (including without limitation, a metal foil), sapphire, and other inorganic material, and an organic material, including without limitation, a polymer, including without limitation, at least one of: a polyimide, and an Si-based polymer. In some non-limiting examples, the base substrate 315 may be one of: rigid, and flexible. In some non-limiting examples, the substrate 10 may be defined by at least one planar surface. In some non-limiting examples, the substrate 10 may have at least one exposed layer surface 11 that supports the remaining frontplane 301 components of the device 2100, including without limitation, at least one of: the first electrode 1920, the at least one semiconducting layer 330, and the second electrode 340.

In some non-limiting examples, such surface may be at least one of: an organic surface, and an inorganic surface.

In some non-limiting examples, the substrate 10 may comprise, in addition to the base substrate 315, at least one additional at least one of: organic, and inorganic, layer (not shown nor specifically described herein) supported on an exposed layer surface 11 of the base substrate 315.

In some non-limiting examples, such additional layers may comprise, at least one organic layer, which may at least one of: comprise, replace, and supplement, at least one of the semiconducting layers 330.

In some non-limiting examples, such additional layers may comprise at least one inorganic layer, which may comprise, at least one electrode, which in some non-limiting examples, may at least one of: comprise, replace, and supplement, at least one of: the first electrode 1920, and the second electrode 340.

### Backplane and TFT Structure(s) Embodied Therein

In some non-limiting examples, such additional layers may comprise a backplane 302. In some non-limiting examples, the backplane 302 may comprise at least one of: power circuitry, and switching elements for driving the device 2100, including without limitation, at least one of: at least one electronic thin-film transistor (TFT) structure 2206, and at least one component thereof, that may be formed by a photolithography process.

In some non-limiting examples, the backplane 302 of the substrate 10 may comprise at least one electronic, including without limitation, an opto-electronic, component, including without limitation, one of: transistors, resistors, and capacitors, such as which may support the device 2100 acting as one of: an active-matrix, and a passive matrix, device 2100. In some non-limiting examples, such structures may be a TFT structure 2206.

Non-limiting examples of TFT structures 2206 include one of: top-gate, bottom-gate, n-type and p-type TFT structures 2206. In some non-limiting examples, the TFT structure 2206 may incorporate one of: amorphous Si (a-Si), indium gallium zinc oxide (IGZO), and low-temperature polycrystalline Si (LTPS).

### First Electrode

The first electrode 1920 may be deposited over the substrate 10. In some non-limiting examples, the first electrode 1920 may be electrically coupled with at least one of: a terminal of the power source 2204, and ground. In some non-limiting examples, the first electrode 1920 may be so coupled through at least one driving circuit which in some non-limiting examples, may incorporate at least one TFT structure 2206 in the backplane 302 of the substrate 10.

In some non-limiting examples, the first electrode 1920 may comprise one of: an anode, and cathode. In some non-limiting examples, the first electrode 1920 may be an anode.

In some non-limiting examples, the first electrode 1920 may be formed by depositing at least one thin conductive film, over (a part of) the substrate 10. In some non-limiting examples, there may be a plurality of first electrodes 1920, disposed in a spatial arrangement over a lateral aspect of the substrate 10. In some non-limiting examples, at least one of such at least one first electrodes 1920 may be deposited over (a part of) a TFT insulating layer 307 disposed in a lateral aspect in a spatial arrangement. If so, in some non-limiting examples, at least one of such at least one first electrodes 1920 may extend through an opening of the corresponding TFT insulating layer 307 to be electrically coupled with an electrode of the TFT structures 2206 in the backplane 302.

In some non-limiting examples, at least one of: the at least one first electrode 1920, and at least one thin film thereof, may comprise various materials, including without limitation, at least one metallic material, including without limitation, at least one of: magnesium (Mg), aluminum (Al), calcium (Ca), zinc (Zn), silver (Ag), cadmium (Cd), barium (Ba), and ytterbium (Yb), including without limitation, alloys comprising any of such materials, at least one metal oxide, including without limitation, a TCO, including without limitation, ternary compositions such as, without limitation, at least one of: FTO, IZO, and ITO, in varying proportions, including without limitation, combinations of any plurality thereof in at least one layer, any at least one of which may be, without limitation, a thin film.

### Second Electrode

The second electrode 340 may be deposited over the at least one semiconducting layer 330. In some non-limiting examples, the second electrode 340 may be electrically coupled with at least one of: a terminal of the power source 2204, and ground. In some non-limiting examples, the second electrode 340 may be so coupled through at least one driving circuit, which in some non-limiting examples, may incorporate at least one TFT structure 2206 in the backplane 302 of the substrate 10.

In some non-limiting examples, the second electrode 340 may comprise one of: an anode, and a cathode. In some non-limiting examples, the second electrode 340 may be a cathode.

In some non-limiting examples, the second electrode 340 may be formed by depositing a deposited layer 331, in some non-limiting examples, as at least one thin film, over (a part of) the at least one semiconducting layer 330.

In some non-limiting examples, there may be a plurality of second electrodes 340, disposed in a spatial arrangement over a lateral aspect of the at least one semiconducting layer 330.

In some non-limiting examples, the second electrode 340 may extend partially over the patterning coating 310 in a transition region 2245.

In some non-limiting examples, the at least one second electrode 340 may comprise various materials, including without limitation, at least one metallic material, including without limitation, at least one of: Mg, Al, Ca, Zn, Ag, Cd, Ba, and Yb, including without limitation, alloys comprising at least one of: any of such materials, at least one metal oxide, including without limitation, a TCO, including without limitation, ternary compositions such as, without limitation, at least one of: FTO, IZO, and ITO, including without limitation, in varying proportions, zinc oxide (ZnO), and other oxides comprising at least one of: In, and Zn, in at least one layer, and at least one non-metallic material, any of which may be, without limitation, a thin conductive film. In some non-limiting examples, for a Mg:Ag alloy, such alloy composition may range between about 1:9-9:1 by volume.

In some non-limiting examples, the deposition of the second electrode 340 may be performed using one of: an open mask, and a mask-free deposition process.

In some non-limiting examples, the second electrode 340 may comprise a plurality of such coatings. In some non-limiting examples, such coatings may be distinct coatings disposed on top of one another.

In some non-limiting examples, the second electrode 340 may comprise a Yb/Ag bi-layer coating. In some non-limiting examples, such bi-layer coating may be formed by depositing a Yb coating, followed by an Ag coating. In some non-limiting examples, a thickness of such Ag coating may exceed a thickness of the Yb coating.

In some non-limiting examples, the second electrode 340 may be a multi-coating electrode 340 comprising a plurality of one of: a metallic coating, and an oxide coating.

In some non-limiting examples, the second electrode 340 may comprise a fullerene and Mg.

In some non-limiting examples, such coating may be formed by depositing a fullerene coating followed by an Mg coating. In some non-limiting examples, a fullerene may be dispersed within the Mg coating to form a fullerene-containing Mg alloy coating. Non-limiting examples of such coatings are described in at least one of: United States Patent Application Publication No. 2015/0287846 published 8 Oct. 2015, and in PCT International Application No. PCT/IB2017/054970 filed 15 Aug. 2017 and published as WO2018/033860 on 22 Feb. 2018.

### Semiconducting Layer

In some non-limiting examples, the at least one semiconducting layer 330 may comprise a plurality of layers 2231, 2233, 2235, 2237, 2239, any of which may be disposed, in some non-limiting examples, in a thin film, in a stacked configuration, which may include, without limitation, at least one of: a hole injection layer (HIL) 2231, an HTL 2233, an emissive layer (EML) 2235, an ETL 2237, and an electron injection layer (EIL) 2239.

In some non-limiting examples, the at least one semiconducting layer 330 may form a “tandem” structure comprising a plurality of EMLs 2235. In some non-limiting examples, such tandem structure may also comprise at least one charge generation layer (CGL).

Those having ordinary skill in the relevant art will readily appreciate that the structure of the device 2200 may be varied by one of: omitting, and combining, at least one of the semiconducting layers 2231, 2233, 2235, 2237, 2239.

In some non-limiting examples, any of the layers 2231, 2233, 2235, 2237, 2239 of the at least one semiconducting layer 330 may comprise any number of sub-layers. In some non-limiting examples, any of such layers 2231, 2233, 2235, 2237, 2239, including without limitation, sub-layer(s) thereof may comprise various ones of: a mixture, and a composition gradient. In some non-limiting examples, although not shown, the device 2200 may comprise at least one layer comprising one of: an inorganic, and an organometallic, material, and may not be necessarily limited to devices 2200 comprised solely of organic materials. In some non-limiting examples, the device 2200 may comprise at least one quantum dot (QD).

In some non-limiting examples, the HIL 2231 may be formed using a hole injection material, which may, in some non-limiting examples, facilitate injection of holes by the anode.

In some non-limiting examples, the HTL 2233 may be formed using a hole transport material, which may, in some non-limiting examples, exhibit high hole mobility.

In some non-limiting examples, the ETL 2237 may be formed using an electron transport material, which may, in some non-limiting examples, exhibit high electron mobility.

In some non-limiting examples, the EIL 2239 may be formed using an electron injection material, which may, in some non-limiting examples, facilitate injection of electrons by the cathode.

In some non-limiting examples, the at least one EML 2235 may be formed, in some non-limiting examples, by doping a host material with at least one emitter material. In some non-limiting examples, the emitter material may be at least one of: a fluorescent emitter material, a phosphorescent emitter material, and a thermally activated delayed fluorescence (TADF) emitter material.

In some non-limiting examples, the emitter material may be one of a R(ed) emitter material, a G(reen) emitter material, and a B(lue) emitter material, that is, an emitter material that facilitates the emission of respectively, R(ed), G(reen), and B(lue) light.

In some non-limiting examples, the device 2200 may be an OLED in which the at least one semiconducting layer 330 may comprise at least one EML 2235 interposed between conductive thin film electrodes 1920, 340, whereby, when a potential difference is applied across them, holes may be injected into the at least one semiconducting layer 330 through the anode and electrons may be injected into the at least one semiconducting layer 330 through the cathode, to migrate toward the at least one EML 2235 and combine to emit light in the form of photons.

In some non-limiting examples, the device 2200 may be an electro-luminescent QD device in which the at least one semiconducting layer 330 may comprise an active layer comprising at least one QD. When current is provided by the power source 2204 to the first electrode 1920 and second electrode 340, light, including without limitation, in the form of photons, may be emitted from the active layer comprising the at least one semiconducting layer 330 between them.

In some non-limiting examples, including where the device 2200 comprises a lighting panel, an entire lateral aspect of the device 2200 may correspond to a single emissive element. As such, the substantially planar cross-sectional profile shown in FIG. 22 may extend substantially along the entire lateral aspect of the device 2200, such that light is emitted from the device 2200 substantially along the entirety of the lateral extent thereof. In some non-limiting examples, such single emissive element may be driven by a single driving circuit of the device 2200.

In some non-limiting examples, including where the device 2200 comprises a display module, the lateral aspect of the device 2200 may be sub-divided into a plurality of emissive regions 210 of the device 2200, in which the longitudinal aspect of the structure thereof, within each of the emissive region(s) 210, may cause light to be emitted therefrom when energized.

Those having ordinary skill in the relevant art will readily appreciate that the structure of the device 2200 may be varied by the introduction of at least one additional layer (not shown) at appropriate position(s) within the at least one semiconducting layer 330 stack, including without limitation, at least one of: a hole blocking layer (HBL) (not shown), an electron blocking layer (EBL) (not shown), a charge transport layer (CTL) (not shown), and a charge injection layer (CIL) (not shown).

In some non-limiting examples, the patterning coating 310 may be formed concurrently with the at least one semiconducting layer(s) 330. In some non-limiting examples, at least one material used to form the patterning coating 310 may also be used to form the at least one semiconducting layer(s) 330. In some non-limiting examples, the ETL 2237 of the at least one semiconducting layer 330 may be a patterning coating 310 that may be deposited in the first portion 1901 and the second portion 1902 during the deposition of the at least one semiconducting layer 330. The EIL 2239 may then be selectively deposited in the emissive region 210 of the second portion 1902 over the ETL 2237, such that the exposed layer surface 11 of the ETL 2237 in the first portion 1901 may be substantially devoid of the EIL 2239. The exposed layer surface 11 of the EIL 2239 in the emissive region 210 and the exposed layer surface of the ETL 2237, which acts as the patterning coating 310, may then be exposed to a vapor flux 2432 of the deposited material 2431 to form a closed coating 2140 of the deposited layer 331 on the EIL 2239 in the second portion 1902, and a discontinuous layer 2160 of the deposited material 2431 on the ETL 2237 in the first portion 1901. In such non-limiting example, several stages for fabricating the device 2200 may be reduced.

### Emissive Region(s)

A simplified block diagram from a longitudinal aspect, of an emissive region 210, corresponding to a (sub-) pixel 215/216 of an example opto-electronic device 2200, which may be, in some non-limiting examples, an electro-luminescent device 2200, including without limitation, an OLED, according to the present disclosure is shown in FIG. 22, surrounded by at least one non-emissive region 1911.

Within the emissive region 210, the device 2200 may comprise a substrate 10, upon which a frontplane 301, comprising a plurality of layers, respectively, a first electrode 1920, at least one semiconducting layer 330, and a second electrode 340, is disposed. In some non-limiting examples, the frontplane 301 may provide mechanisms for emission of light, including without limitation, photons.

In some non-limiting examples, various coatings of such devices 2200 may be formed by vacuum-based deposition processes.

In some non-limiting examples, the first electrode 1920 and the second electrode 340 of an emissive region 210 of the device 2200 may be electrically coupled with a power source 2204. When so coupled, the emissive region 210 may emit light, including without limitation, photons, as described herein.

In some non-limiting examples, including where the OLED device 2200 may comprise a display module, the lateral aspect of the device 2200 may be sub-divided into a plurality of emissive regions 210 of the device 2200, in which the longitudinal aspect of the device 2200 structure, within each of the emissive region(s) 210, may cause light to be emitted therefrom when energized.

In some non-limiting examples, an individual emissive region 210 may have an associated pair of electrodes 1920, 340, one of which may act as an anode and the other of which may act as a cathode, and at least one semiconducting layer 330 between them. Such an emissive region 210 may emit light at a given wavelength spectrum and may correspond to one of: a pixel 215, and a sub-pixel 216 thereof. In some non-limiting examples, a plurality of sub-pixels 216, each corresponding to and emitting light of a different wavelength (range) may collectively form a pixel 215.

In some non-limiting examples, the wavelength spectrum may correspond to a colour in, without limitation, the visible spectrum. The light at a first wavelength (range) emitted by a first sub-pixel 216 of a pixel 215 may perform differently than the light at a second wavelength (range) emitted by a second sub-pixel 216 thereof because of the different wavelength (range) involved.

In some non-limiting examples, an active region 1908 of an individual emissive region 210 may be defined to be bounded, in the longitudinal aspect, by the first electrode 1920 and the second electrode 340, and to be confined, in the lateral aspect, to an emissive region 210, defined by presence of each of the first electrode 1920, the second electrode 340, and the at least one semiconducting layer 330 therebetween (“emissive region layers”), that is, the first electrode 1920, the second electrode 340, and the at least one semiconducting layer 330 therebetween, overlap laterally.

Those having ordinary skill in the relevant art will appreciate that the lateral aspect of the emissive region 210, and thus the lateral boundaries of the active region 1908, may not correspond to the entire lateral aspect of at least one of: the first electrode 1920, the second electrode 340, and the at least one semiconducting layer 330 therebetween. Rather, as the at least one semiconducting layer 330 may, in some non-limiting examples, extend at least beyond the lateral aspect of at least one of the first electrode 1920, and the second electrode 340, the lateral aspect of the emissive region 210 may be substantially no more than the lateral extent of either of: the first electrode 1920, and the second electrode 340. In some non-limiting examples, at least one of: parts of the first electrode 1920 may be covered by at least one pixel definition layer PDL 309, and parts of the second electrode 340 may not be disposed on the at least one semiconducting layer 330, with the result, in at least one scenario, that the emissive region 210 may be laterally constrained thereby.

In some non-limiting examples, at least one of the various emissive region layers may be deposited by deposition of a corresponding constituent emissive region layer material.

In some non-limiting examples, some of the at least one semiconducting layers 330 may be laid out in a desired pattern by vapor deposition of the corresponding emissive region layer material through a fine metal mask (FMM) having apertures corresponding to the desired locations where the emissive region layer material is to be deposited. In some non-limiting examples, a plurality of the emissive region layers may be laid out in a similar pattern, including without limitation, by depositing the respective emissive region layer material thereof in their respective deposition stages using an FMM.

In some non-limiting examples, as discussed herein, the emissive region layer material corresponding to at least one of the first electrode 1920 and the second electrode 340, including without limitation, the second electrode 340, may be deposited by prior deposition of a patterning coating 310 by vapor deposition of a patterning material through an FMM having apertures corresponding to the desired locations where the patterning coating 310 is to be deposited and thereafter depositing the emissive region layer material using one of: an open mask, and mask-free deposition process.

In some non-limiting examples, the patterning coating 310 may be adapted to impact a propensity of a vapor flux 2432 of a deposited material 2431 of which the emissive region layer material may be comprised, to be deposited thereon, including without limitation, an initial sticking probability against the deposition of the deposited material 2431 that is no more than an initial sticking probability against the deposition of the deposited material 2431 of the exposed layer surface 11 of the at least one semiconducting layer 330.

In some non-limiting examples, the first electrode 1920 may be disposed over an exposed layer surface 11 of the device 2200, in some non-limiting examples, within at least a part of the lateral aspect of the emissive region 210. In some non-limiting examples, at least within the lateral aspect of the emissive region 210 of the (sub-) pixel(s) 215/216, the exposed layer surface 11, may, at the time of deposition of the first electrode 1920, comprise the TFT insulating layer 307 of the various TFT structures 2206 that make up the driving circuit for the emissive region 210 corresponding to a single display (sub-) pixel 215/216.

In some non-limiting examples, the TFT insulating layer 307 may be formed with an opening extending therethrough to permit the first electrode 1920 to be electrically coupled with a TFT electrode including, without limitation, a TFT drain electrode.

Those having ordinary skill in the relevant art will appreciate that the driving circuit may comprise a plurality of TFT structures 2206. In FIG. 22, for purposes of simplicity of illustration, only one TFT structure 2206 may be shown, but it will be appreciated by those having ordinary skill in the relevant art, that such TFT structure 2206 may be representative of at least one of: such plurality thereof, and at least one component thereof, that comprise the driving circuit.

In some non-limiting examples, an extremity of the first electrode 1920 may be covered by at least one PDL 309 such that a part of the at least one PDL 309 may be interposed between the first electrode 1920 and the at least one semiconducting layer 330, such that such extremity of the first electrode 1920 may lie beyond the active region 1908 of the associated emissive region 210.

In some non-limiting examples, part(s) of the second electrode 340 may not be disposed directly on the at least one semiconducting layer 330, such that the emissive region 210 may be laterally constrained thereby.

In some non-limiting examples, the at least one semiconducting layer 330 (including without limitation, at least one of: layers 2231, 2233, 2235, 2237, 2239 thereof) may be deposited over the exposed layer surface 11 of the device 2200, including at least a part of the lateral aspect of such emissive region 210 of the (sub-) pixel(s) 215/216. In some non-limiting examples, at least within the lateral aspect of the emissive region 210 of the (sub-) pixel(s) 215/216, such exposed layer surface 11, may, at the time of deposition of such at least one semiconducting layer 330 comprise the first electrode 1920.

In some non-limiting examples, the at least one semiconducting layer 330 may also extend beyond the lateral aspect of the emissive region 210 of the (sub-) pixel(s) 215/216 and at least partially within the lateral aspects of the surrounding non-emissive region(s) 1911. In some non-limiting examples, such exposed layer surface 11 of such surrounding non-emissive region(s) 1911 may, at the time of deposition of the at least one semiconducting layer 330, comprise the PDL(s) 309.

In some non-limiting examples, the second electrode 340 may be disposed over an exposed layer surface 11 of the device 2200, including at least a part of the lateral aspect of the emissive region 210 of the (sub-) pixel(s) 215/216. In some non-limiting examples, at least within the lateral aspect of the emissive region 210 of the (sub-) pixel(s) 215/216, such exposed layer surface 11, may, at the time of deposition of the second electrode 1920, comprise the at least one semiconducting layer 330.

In some non-limiting examples, the second electrode 340 may also extend beyond the lateral aspect of the emissive region 210 of the (sub-) pixel(s) 215/216 and at least partially within the lateral aspects of the surrounding non-emissive region(s) 1911. In some non-limiting examples, an exposed layer surface 11 of such surrounding non-emissive region(s) 1911 may, at the time of deposition of the second electrode 340, comprise the PDL(s) 309.

In some non-limiting examples, the second electrode 340 may extend throughout a substantial part, including without limitation, substantially all, of the lateral aspects of the surrounding non-emissive region(s) 1911.

In some non-limiting examples, individual emissive regions 210 of the device 2200 may be laid out in a lateral pattern. In some non-limiting examples, the pattern may extend along a first lateral direction. In some non-limiting examples, the pattern may also extend along a second lateral direction, which in some non-limiting examples, may extend at an angle relative to the first lateral direction. In some non-limiting examples, the second lateral direction may be substantially normal to the first lateral direction. In some non-limiting examples, the pattern may have a number of elements in such pattern, each element being characterized by at least one feature thereof, including without limitation, at least one of: a wavelength of light emitted by the emissive region 210 thereof, a shape of such emissive region 210, a dimension (along at least one of: the first, and second, lateral direction(s)), an orientation (relative to at least one of: the first, and second, lateral direction(s)), and a spacing (relative to at least one of: the first, and second, lateral direction(s)) from a previous element in the pattern. In some non-limiting examples, the pattern may repeat in at least one of: the first, and second, lateral direction(s).

In some non-limiting examples, each individual emissive region 210 of the device 2200 may be associated with, and driven by, a corresponding driving circuit within the backplane 302 of the device 2200, for driving an OLED structure for the associated emissive region 210. In some non-limiting examples, including without limitation, where the emissive regions 210 may be laid out in a regular pattern extending in both the first (row) lateral direction and the second (column) lateral direction, there may be a signal line in the backplane 302, corresponding to each row of emissive regions 210 extending in the first lateral direction and a signal line, corresponding to each column of emissive regions 210 extending in the second lateral direction. In such a non-limiting configuration, a signal on a row selection line may energize the respective gates of the switching TFT structure(s) 2206 electrically coupled therewith and a signal on a data line may energize the respective sources of the switching TFT structure(s) 2206 electrically coupled therewith, such that a signal on a row selection line/data line pair may electrically couple and energise, by the positive terminal of the power source 2204, the anode of the OLED structure of the emissive region 210 associated with such pair, causing the emission of a photon therefrom, the cathode thereof being electrically coupled with the negative terminal of the power source 2204.

In some non-limiting examples, a single display pixel 215 may comprise three sub-pixels 216, which in some non-limiting examples, may correspond respectively to a single sub-pixel 216 of each of three colours, including without limitation, at least one of: a R(ed) sub-pixel 216_{R}, a G(reen) sub-pixel 216_{G}, and a B(lue) sub-pixel 216_{B}. In some non-limiting examples, a single display pixel 215 may comprise four sub-pixels 216, each corresponding respectively to a single sub-pixel 216 of each of two colours, including without limitation, a R(ed) sub-pixel 216_{R}, and a B(lue) sub-pixel 216_{B}, and two sub-pixels 216 of a third colour, including without limitation, a G(reen) sub-pixel 216_{G}. In some non-limiting examples, a single display pixel 215 may comprise four sub-pixels 216, which in some non-limiting examples, may correspond respectively to a single sub-pixel 216 of each of three colours, including without limitation, at least one of: a R(ed) sub-pixel 216_{R}, a G(reen) sub-pixel 216_{G}, and a B(lue) sub-pixel 216_{B}, and a fourth W(hite) sub-pixel 216w.

In some non-limiting examples, the emission spectrum of the light emitted by a given (sub-) pixel 215/216 may correspond to the colour by which the (sub-) pixel 215/216 may be denoted. In some non-limiting examples, the wavelength of the light may not correspond to such colour, but further processing may be performed, in a manner apparent to those having ordinary skill in the relevant art, to transform the wavelength to one that does so correspond.

In some non-limiting examples, the emission spectrum of the light emitted by a given (sub-) pixel 215/216, corresponding to the colour by which the (sub-) pixel 215/216 may be denoted, may be related to at least one of: the structure and composition of the at least one semiconducting layer 330 extending between the first electrode 1920 and the second electrode 340 thereof, including without limitation, the at least one EML 2235. In some non-limiting examples, the at least one EML 2235 of the at least one semiconducting layer 330 may be tuned to facilitate the emission of light having an emission spectrum corresponding to the colour by which the (sub-) pixel 215/216 may be denoted. In some non-limiting examples, the EML 2235 of a R(ed) sub-pixel 216_{R} may comprise a R(ed) EML material, including without limitation, a host material doped with a R(ed) emitter material. In some non-limiting examples, the EML 2235 of a G(reen) sub-pixel 216_{G} may comprise a G(reen) EML material, including without limitation, a host material doped with a G(reen) emitter material. In some non-limiting examples, the EML 2235 of a B(lue) sub-pixel 216_{B} may comprise B(lue) EML material, including without limitation, a host material doped with a B(lue) emitter material.

In some non-limiting examples, at least one characteristic of at least one of the at least one semiconducting layer 330, including without limitation, the HIL 2231, the HTL 2233, the EML 2235, the ETL 2237, and the EIL 2239, including without limitation, a presence thereof, an absence thereof, a thickness thereof, a composition thereof, and an order thereof, in the longitudinal aspect, may be selected to facilitate emission therefrom of light having a wavelength spectrum corresponding to the colour by which a given sub-pixel 216 may be denoted, including without limitation, at least one of: R(ed), G(reen), and B(lue).

In some non-limiting examples, emission of light having a wavelength spectrum corresponding to a plurality of colours selected from: R(ed), G(reen), and B(lue) may facilitate emission of light having a wavelength spectrum corresponding to a different colour, including without limitation W(hite) (R+G+B), Y(ellow) (R+G), C(yan) (G+B), and M(agenta) (B+R), according to the additive colour model.

In some non-limiting examples, the exposed layer surface 11 of the device 2100 may be exposed to a vapor flux 2432 of a deposited material 2431, including without limitation, in one of: an open mask, and mask-free, deposition process.

In some non-limiting examples, in at least a part of the emissive region 210, the at least one semiconducting layer 330 may be deposited over the exposed layer surface 11 of the device 2200, which in some non-limiting examples, comprise the first electrode 1920.

In some non-limiting examples, the exposed layer surface 11 of the device 2200, which may, in some non-limiting examples, comprise the at least one semiconducting layer 330, may be exposed to a vapor flux 2312 of the patterning material 2311, including without limitation, using a shadow mask 2315, to form a patterning coating 310 in the first portion 1901. Whether a shadow mask 2315 is employed, the patterning coating 310 may be restricted, in its lateral aspect, substantially to a transmissive region 112.

In some non-limiting examples, a lateral aspect of at least one emissive region 210 may extend across and include at least one TFT structure 2206 associated therewith for driving the emissive region 210 along data and scan lines (not shown), which, in some non-limiting examples, may be formed of at least one of: Cu, and a TCO.

In some non-limiting examples, the (sub-) pixels 215/216 may be disposed in a side-by-side arrangement. In some non-limiting examples, a (colour) order of the sub-pixels 216 of a first pixel 215 may be the same as a (colour) order of the sub-pixels 216 of a second pixel 215. In some non-limiting examples, a (colour) order of the sub-pixels 216 of a first pixel 215 may be different from a (colour) order of the sub-pixels 216 of a second pixel 215.

In some non-limiting examples, the sub-pixels 216 of adjacent pixels 215 may be aligned in at least one of: a row, column, and array, arrangement.

In some non-limiting examples, a first at least one of: a row, and a column, of aligned sub-pixels 216 of adjacent pixels 215 may comprise sub-pixels 216 of one of: a same, and a different, colour.

In some non-limiting examples, a first at least one of: a row, and a column, of aligned sub-pixels 216 of adjacent pixels 215 may be aligned with at least one of: a second, and a third, at least one of: a row, and a column, of aligned sub-pixels 216 of adjacent pixels 215.

In some non-limiting examples, a first at least one of: a row, and a column, of aligned sub-pixels 216 of adjacent pixels 215 may be one of: offset from, and mis-aligned with, at least one of: a second, and a third, at least one of: a row, and a column, of aligned sub-pixels 216 of adjacent pixels 215.

In some non-limiting examples, the sub-pixels 216 of adjacent pixels 215 of such at least one of: first, second, and third, at least one of: a row, and a column, may be arranged such that corresponding sub-pixels 216 of each of the at least one of: first, second, and third, at least one of: a row, and a column, may be of a same colour.

In some non-limiting examples, the sub-pixels 216 of adjacent pixels 215 of such at least one of: first, second, and third, at least one of: a row, and a column, may be arranged such that corresponding sub-pixels 216 of each of the at least one of: first, second and third, at least one of: a row, and a column, may be of different colours.

In some non-limiting examples, in the at least one signal-exchanging part 103 of a display panel 100, the at least one transmissive region 112 may be disposed between a plurality of emissive regions 210. In some non-limiting examples, the at least one transmissive region 112 may be disposed between adjacent (sub-) pixels 215/216. In some non-limiting examples, the adjacent sub-pixels 216 surrounding the at least one transmissive region 112 may form part of a same pixel 215. In some non-limiting examples, the adjacent sub-pixels 216 surrounding the at least one transmissive region 112 may be associated with different pixels 215.

In some non-limiting examples, a region that may be substantially devoid of a closed coating 2140 of a second electrode material (“cathode-free region”), including without limitation, the at least one transmissive region 112, in some non-limiting examples, may exhibit different opto-electronic characteristics from other regions, including without limitation, the at least one emissive region 210. In some non-limiting examples, such cathode-free regions may nevertheless comprise some second electrode material, including without limitation, in the form of a discontinuous layer 2160 of one of: at least one particle structure 2150, and at least one instance of such particle structures 2150.

In some non-limiting examples, this may be achieved by laser ablation of the second electrode material. However, in some non-limiting examples, laser ablation may create a debris cloud, which may impact the vapour deposition process.

In some non-limiting examples, this may be achieved by disposing a patterning coating 310, which may, in some non-limiting examples, be a nucleation inhibiting coating (NIC), using an FMM, in a pattern on an exposed layer surface 11 of the at least one semiconducting layer 330 prior to depositing a deposited material 2431 for forming the second electrode 340 thereon.

In some non-limiting examples, the patterning coating 310 may be adapted to impact a propensity of a vapor flux 2432 of the deposited material 2431 to be deposited thereon, including without limitation, an initial sticking probability against the deposition of the deposited material 2431 that is no more than an initial sticking probability against the deposition of the deposited material 2431 of the exposed layer surface 11 of the at least one semiconducting layer 330.

In some non-limiting examples, the patterning coating 310 may be deposited in a pattern that may correspond to the first portion 1901 of a lateral aspect, including without limitation, of at least some of the transmissive regions 112.

In some non-limiting examples, the patterning coating 310 may be deposited in a plurality of stages, each using a different FMM defining a different pattern within the first portion 1901, that respectively correspond to a different subset of the transmissive regions 112.

In some non-limiting examples, the display panel 100 may, subsequent to (all of the stages of) the deposition of the patterning coating 310, be subjected to a vapor flux 2432 of the deposited material 2431, in one of: an open mask, and mask-free, deposition process, to form the second electrode 340 for each of the emissive regions 210 corresponding to a (sub-) pixel 215/216 in at least the second portion 1902 of the lateral aspect, but not in the first portion 1901 of the lateral aspect.

In some non-limiting examples, although not shown, the overlying layer 2170 may be arranged above at least one of: the second electrode 340, and the patterning coating 310. In some non-limiting examples, although not shown, the overlying layer 2170 may be deposited at least partially across the lateral extent of the opto-electronic device 2200, in some non-limiting examples, covering the second electrode 340 in the second portion 1902, and, in some non-limiting examples, at least partially covering the at least one particle structure 2150 and forming an interface with the patterning coating 310 at the exposed layer surface 11 thereof in the first portion 1901.

### Non-Emissive Regions

In some non-limiting examples, the various emissive regions 210 of the device 2200 may be substantially surrounded and separated by, in at least one lateral direction, at least one non-emissive region 1911, in which at least one of: the structure, and configuration, along the longitudinal aspect, of the device 2200 shown, without limitation, may be varied, to substantially inhibit light to be emitted therefrom.

In some non-limiting examples, the non-emissive regions 1911 may comprise those regions in the lateral aspect, that are substantially devoid of an emissive region 210.

In some non-limiting examples, the longitudinal topology of the various layers of the at least one semiconducting layer 330 may be varied to define at least one emissive region 210, surrounded (at least in one lateral direction) by at least one non-emissive region 1911.

In some non-limiting examples, the emissive region 210 corresponding to a single display (sub-) pixel 215/216 may be understood to have a lateral aspect, surrounded in at least one lateral direction by at least one non-emissive region 1911.

A non-limiting example of an implementation of the longitudinal aspect of the device 2200 as applied to an emissive region 210 corresponding to a single display (sub-) pixel 215/216 of the display 3600 will now be described. While features of such implementation are shown to be specific to the emissive region 210, those having ordinary skill in the relevant art will appreciate that in some non-limiting examples, more than one emissive region 210 may encompass features in common.

In some non-limiting examples, the lateral aspects of the surrounding non-emissive region(s) 1911 may be characterized by the presence of a corresponding PDL 309.

In some non-limiting examples, a thickness of the PDL 309 may increase from a minimum, where it covers the extremity of the first electrode 1920, to a maximum beyond the lateral extent of the first electrode 1920. In some non-limiting examples, the change in thickness of the at least one PDL 309 may define a valley shape centered about the emissive region 210. In some non-limiting examples, the valley shape may constrain the field of view (FOV) of the light emitted by the emissive region 210.

While the PDL(s) 309 have been generally illustrated herein as having a linearly-sloped surface to form a valley-shaped configuration that define the emissive region(s) 210 surrounded thereby, those having ordinary skill in the relevant art will appreciate that in some non-limiting examples, at least one of: the shape, aspect ratio, thickness, width, and configuration of such PDL(s) 309 may be varied. In some non-limiting examples, a PDL 309 may be formed with one of: a substantially steep part and a more gradually sloped part. In some non-limiting examples, such PDL(s) 309 may be configured to extend substantially normally away from a surface on which it is deposited, that may cover at least one edge of the first electrode 1920. In some non-limiting examples, such PDL(s) 309 may be configured to have deposited thereon at least one semiconducting layer 330 by a solution-processing technology, including without limitation, by printing, including without limitation, ink-jet printing.

In some non-limiting examples, the PDLs 309 may be deposited substantially over the TFT insulating layer 307, although, as shown, in some non-limiting examples, the PDLs 309 may also extend over at least a part of the deposited first electrode 1920, including without limitation, its outer edges.

In some non-limiting examples, the lateral extent of at least one of the non-emissive regions 1911 may be at least, and in some non-limiting examples, exceed, including without limitation, be a multiple of, the lateral extent of the emissive region 210 interposed therebetween.

In some non-limiting examples, a thickness of at least one PDL 309 in at least one transmissive region 112, in some non-limiting examples, of at least one non-emissive region 1911, interposed between adjacent emissive regions 210, in some non-limiting examples, at least in a region laterally spaced apart therefrom, and in some non-limiting examples; although not shown, of the TFT insulating layer 307, may be reduced in order to enhance at least one of: a transmittivity, and a transmittivity angle, relative to and through the layers of a display panel 100, to facilitate transmission of light therethrough.

### Patterning

In some non-limiting examples, with reference to FIG. 21, in some non-limiting examples, a patterning coating 310, comprising a patterning material 2311, which in some non-limiting examples, may be an NIC material, may be disposed, in some non-limiting examples, as a closed coating 2140, on an exposed layer surface 11 of an underlying layer 2610, including without limitation, a substrate 10, of the device 2100, in some non-limiting examples, restricted in lateral extent by selective deposition, including without limitation, using a shadow mask 2315 such as, without limitation, a fine metal mask (FMM), including without limitation, to the first portion 1901.

Thus, in some non-limiting examples, in the second portion 1902 of the device 2100, the exposed layer surface 11 of the underlying layer 2610 of the device 2100, may be substantially devoid of a closed coating 2140 of the patterning coating 310.

In some non-limiting examples, the deposited layer 331 may be deposited in a second portion 1902, by exposing the exposed layer surface 11 of the device 2200, which may, in some non-limiting examples, comprise the at least one semiconducting layer 330, to a vapor flux 2312 of a patterning material 2311, including without limitation, using a shadow mask 2315, to form a patterning coating 310 in the first portion 1901. Whether a shadow mask 2315 is employed, in some non-limiting examples, as shown in FIG. 23, the patterning material 2311 may be restricted, in its lateral aspect, substantially to an emissive region 210 to a non-emissive region 1911, including without limitation, at least one transmissive region 112 located therein.

In some non-limiting examples, with reference to FIG. 21, in some non-limiting examples, a patterning coating 310, comprising a patterning material 2311, which in some non-limiting examples, may be an NIC material, may be disposed, in some non-limiting examples, as a closed coating 2140, on an exposed layer surface 11 of an underlying layer 2610, including without limitation, a substrate 10, of the device 2100, in some non-limiting examples, restricted in lateral extent by selective deposition, including without limitation, using a shadow mask 2315 such as, without limitation, an FMM, including without limitation, to the first portion 1901.

Thus, in some non-limiting examples, in the second portion 1902 of the device 2100, the exposed layer surface 11 of the underlying layer 2610 of the device 2100, may be substantially devoid of a closed coating 2140 of the patterning coating 310.

### Patterning Coating

The patterning coating 310 may comprise a patterning material 2311. In some non-limiting examples, the patterning material 2311 may comprise an NIC material. In some non-limiting examples, the patterning coating 310 may comprise a closed coating 2140 of the patterning material 2311.

The patterning coating 310 may provide an exposed layer surface 11 with a substantially low propensity (including without limitation, a substantially low initial sticking probability) (in some non-limiting examples, under the conditions identified in the dual QCM technique described by Walker et al.) against the deposition of a deposited material 2431 to be deposited thereon upon exposing such surface to a vapor flux 2432 of the deposited material 2431, which, in some non-limiting examples, may be substantially less than the propensity against the deposition of the deposited material 2431 to be deposited on the exposed layer surface 11 of the underlying layer 2610 of the device 2100, upon which the patterning coating 310 has been deposited.

Because of the attributes, including without limitation, a low initial sticking probability, of at least one of: at least one of: the patterning coating 310, and the patterning material 2311, in some non-limiting examples, when deposited as at least one of: a film, and a coating, in a form, and under similar circumstances to the deposition of the patterning coating 310 within the device 2100, against the deposition of the deposited material 2431, the exposed layer surface 11 of the first portion 1901 comprising the patterning coating 310 may be substantially devoid of a closed coating 2140 of the deposited material 2431.

In some non-limiting examples, exposure of the device 2100 to a vapor flux 2432 of the deposited material 2431 may, in some non-limiting examples, result in the formation of a closed coating 2140 of a deposited layer 331 of the deposited material 2431 in the second portion 1902, where the exposed layer surface 11 of the underlying layer 2610 may be substantially devoid of a closed coating 2140 of the patterning coating 310.

In some non-limiting examples, the patterning coating 310 may be an NIC that provides high deposition (patterning) contrast against subsequent deposition of the deposited material 2431, such that the deposited material 2431 tends not to be deposited, in some non-limiting examples, as a closed coating 2140, where the patterning coating 310 has been deposited.

In some non-limiting examples, there may be scenarios calling for providing a patterning coating 310 for causing formation of a discontinuous layer 2160 of at least one particle structure 2150, upon the patterning coating 310 in the first portion 1901 being subjected to a vapor flux 2432 of a deposited material 2431. In at least some applications, the attributes of the patterning coating 310 may be such that a closed coating 2140 of the deposited material 2431 may be formed in the second portion 1902, which may be substantially devoid of the patterning coating 310, while only a discontinuous layer 2160 of at least one particle structure 2150 having at least one characteristic may be formed in the first portion 1901 on the patterning coating 310.

For purposes of simplicity of discussion, in the present disclosure, to the extent that a patterning coating 310 is deposited to act as a base for the deposition of at least one particle structure 2150 thereon, such patterning coating 310 may be designated as a particle structure patterning coating 310p. By contrast, to the extent that a patterning coating 310 is deposited in a first portion 1901 to substantially preclude formation in such first portion 1901 of a closed coating 2140 of the deposited layer 331, thus restricting the deposition of a closed coating 2140 of the deposited layer 331 to a second portion 1902, such patterning coating 310 may be designated as a non-particle structure patterning coating 310ₙ. Those having ordinary skill in the relevant art will appreciate that in some non-limiting examples, a patterning coating 310 may act as both a particle structure patterning coating 310p and a non-particle structure patterning coating 310ₙ.

In some non-limiting examples, there may be scenarios calling for formation of a discontinuous layer 2160 of at least one particle structure 2150 of a deposited material 2431, which may be, in some non-limiting examples, of one of: a metal, and a metal alloy (metal/alloy), including without limitation, at least one of: Yb, Ag, Mg, and Ag-containing materials, including without limitation, MgAg, in the second portion 1902, while depositing a closed coating 2140 of the deposited material 2431 having a thickness of, without limitation, one of no more than about: 100 nm, 50 nm, 25 nm, and 15 nm. In some non-limiting examples, an amount of the deposited material 2431 deposited as a discontinuous layer 2160 of at least one particle structure 2150 in the first portion 1901 may correspond to one of between about: 1-50%, 2-25%, 5-20%, and 7-10%, of the amount of the deposited material 2431 deposited as a closed coating 2140 in the second portion 1902, which, in some non-limiting examples may correspond to a thickness of one of no more than about: 100 nm, 75 nm, 50 nm, 25 nm, and 15 nm.

In some non-limiting examples, the patterning coating 310 may be disposed in a pattern that may be defined by at least one region therein that may be substantially devoid of a closed coating 2140 of the patterning coating 310.

In some non-limiting examples, the at least one region may separate the patterning coating 310 into a plurality of discrete fragments thereof. In some non-limiting examples, the plurality of discrete fragments of the patterning coating 310 may be physically spaced apart from one another in the lateral aspect thereof. In some non-limiting examples, the plurality of the discrete fragments of the patterning coating 310 may be arranged in a regular structure, including without limitation, an array (matrix), such that in some non-limiting examples, the discrete fragments of the patterning coating 310 may be configured in a repeating pattern.

In some non-limiting examples, at least one of the plurality of the discrete fragments of the patterning coating 310 may each correspond to an emissive region 210. In some non-limiting examples, an aperture ratio of the emissive regions 210 may be one of no more than about: 50%, 40%, 30%, and 20%.

In some non-limiting examples, the patterning coating 310 may be formed as a single monolithic coating.

### Attributes of Patterning Coating/Material

### Composition

In some non-limiting examples, at least one of: the patterning coating 310, and the patterning material 2311, may comprise at least one of: a fluorine (F) atom, and a silicon (Si) atom. In some non-limiting examples, the patterning material 2311 for forming the patterning coating 310 may be a compound that comprises at least one of: F and Si.

In some non-limiting examples, the patterning material 2311 may comprise a compound that comprises F. In some non-limiting examples, the patterning material 2311 may comprise a compound that comprises F and a carbon atom. In some non-limiting examples, the patterning material 2311 may comprise a compound that comprises F and C in an atomic ratio corresponding to a quotient of F/C of one of at least about: 0.5, 0.7, 1, 1.5, 2, and 2.5.

In some non-limiting examples, an atomic ratio of F to C may be determined by counting the F atoms present in the compound structure, and for C atoms, only counting the sp³ hybridized C atoms present in the compound structure. In some non-limiting examples, the patterning material 2311 may comprise a compound that comprises, as part of its molecular sub-structure, a moiety comprising F and C in an atomic ratio corresponding to a quotient of F/C of one of at least about: 1, 1.5, and 2.

In some non-limiting examples, the patterning material 2311 may comprise an organic-inorganic hybrid material.

In some non-limiting examples, the patterning material 2311 may comprise an oligomer.

In some non-limiting examples, the patterning material 2311 may comprise a compound having a molecular structure comprising a backbone and at least one functional group bonded to the backbone. In some non-limiting examples, the backbone may be an inorganic moiety, and the at least one functional group may be an organic moiety.

In some non-limiting examples, such compound may have a molecular structure comprising a siloxane group. In some non-limiting examples, the siloxane group may be one of: a linear siloxane group, a branched siloxane group, and a cyclic siloxane group. In some non-limiting examples, the backbone may comprise a siloxane group. In some non-limiting examples, the backbone may comprise a siloxane group and at least one functional group comprising F. In some non-limiting examples, the at least one functional group comprising F may be a fluoroalkyl group. In some non-limiting examples, such compound may comprise fluoro-siloxanes, including without limitation, Example Material 6 and Example Material 9 (discussed below).

In some non-limiting examples, the compound may have a molecular structure comprising a silsesquioxane group. In some non-limiting examples, the silsesquioxane group may be a POSS. In some non-limiting examples, the backbone may comprise a silsesquioxane group. In some non-limiting examples, the backbone may comprise a silsesquioxane group and at least one functional group comprising F. In some non-limiting examples, the at least one functional group comprising F may be a fluoroalkyl group. In some non-limiting examples, such compound may comprise fluoro-silsesquioxane and fluoro-POSS, including without limitation, Example Material 8 (discussed below).

In some non-limiting examples, the compound may have a molecular structure comprising at least one of: a substituted aryl group, an unsubstituted aryl group, a substituted heteroaryl group, and an unsubstituted heteroaryl group. In some non-limiting examples, the aryl group may be at least one of: phenyl, and naphthyl. In some non-limiting examples, at least one C atom of an aryl group may be substituted by a heteroatom, which in some non-limiting examples may be at least one of: O, N, and S, to derive a heteroaryl group. In some non-limiting examples, the backbone may comprise at least one of: a substituted aryl group, an unsubstituted aryl group, a substituted heteroaryl group, and an unsubstituted heteroaryl group. In some non-limiting examples, the backbone may comprise at least one of: a substituted aryl group, an unsubstituted aryl group, a substituted heteroaryl group, and an unsubstituted heteroaryl group and at least one functional group comprising F. In some non-limiting examples, the at least one functional group comprising F may be a fluoroalkyl group.

In some non-limiting examples, the compound may have a molecular structure comprising at least one of: a substituted hydrocarbon group, an unsubstituted hydrocarbon group, a linear hydrocarbon group, a branched hydrocarbon group, and a cyclic hydrocarbon group. In some non-limiting examples, at least one C atom of the hydrocarbon group may be substituted by a heteroatom, including without limitation, at least one of: O, N, and S.

In some non-limiting examples, the compound may have a molecular structure comprising a phosphazene group. In some non-limiting examples, the phosphazene group may be at least one of: a linear phosphazene group, a branched phosphazene group, and a cyclic phosphazene group. In some non-limiting examples, the backbone may comprise a phosphazene group. In some non-limiting examples, the backbone may comprise a phosphazene group and at least one functional group comprising F. In some non-limiting examples, the at least one functional group comprising F may be a fluoroalkyl group. Non-limiting examples of such compound include fluoro-phosphazenes. A non-limiting example of such compound is Example Material 4 (discussed below).

In some non-limiting examples, the compound may be a fluoropolymer. In some non-limiting examples, the compound may be a block copolymer comprising F. In some non-limiting examples, the compound may be an oligomer. In some non-limiting examples, the oligomer may be a fluorooligomer. In some non-limiting examples, the compound may be a block oligomer comprising F. Non-limiting examples, of at least one of: fluoropolymers, and fluorooligomers, are those having the molecular structure of at least one of: Example Material 3, Example Material 5, and Example Material 7 (discussed herein).

In some non-limiting examples, the compound may be a metal complex. In some non-limiting examples, the metal complex may be an organo-metal complex. In some non-limiting examples, the organo-metal complex may comprise F. In some non-limiting examples, the organo-metal complex may comprise at least one ligand comprising F. In some non-limiting examples, the at least one ligand comprising F may comprise a fluoroalkyl group.

In some non-limiting examples, the patterning material 2311 may comprise a plurality of different materials.

### Initial Sticking Probability

In some non-limiting examples, the initial sticking probability of the patterning material 2311 may be determined by depositing such material as at least one of: a film, and coating, in a form, and under similar circumstances to the deposition of the patterning coating 310 within the device 2100, having sufficient thickness so as to mitigate/reduce any effects on the degree of inter-molecular interaction with the underlying layer 2610 upon deposition on a surface thereof. In some non-limiting examples, the initial sticking probability may be measured on a film/coating having a thickness of one of at least about: 20 nm, 25 nm, 30 nm, 50 nm, 60 nm, and 100 nm.

In some non-limiting examples, at least one of: the patterning coating 310, and the patterning material 2311, in some non-limiting examples, when deposited as at least one of: a film, and a coating, in a form, and under similar circumstances to the deposition of the patterning coating 310 within the device 2100, may have an initial sticking probability against the deposition of the deposited material 2431, that is one of no more than about: 0.3, 0.2, 0.15, 0.1, 0.08, 0.05, 0.03, 0.02, 0.01, 0.008, 0.005, 0.003, 0.001, 0.0008, 0.0005, 0.0003, and 0.0001.

In some non-limiting examples, at least one of: the patterning coating 310, and the patterning material 2311, in some non-limiting examples, when deposited as at least one of: a film, and a coating, in a form, and under similar circumstances to the deposition of the patterning coating 310 within the device 2100, may have an initial sticking probability against the deposition of at least one of: Ag, and Mg that is one of no more than about: 0.3, 0.2, 0.15, 0.1, 0.08, 0.05, 0.03, 0.02, 0.01, 0.008, 0.005, 0.003, 0.001, 0.0008, 0.0005, 0.0003, and 0.0001.

In some non-limiting examples, at least one of: the patterning coating 310, and the patterning material 2311, in some non-limiting examples, when deposited as at least one of: a film, and a coating, in a form, and under similar circumstances to the deposition of the patterning coating 310 within the device 2100, may have an initial sticking probability against the deposition of a deposited material 2431 of one of between about: 0.15-0.0001, 0.1-0.0003, 0.08-0.0005, 0.08-0.0008, 0.05-0.001, 0.03-0.0001, 0.03-0.0003, 0.03-0.0005, 0.03-0.0008, 0.03-0.001, 0.03-0.005, 0.03-0.008, 0.03-0.01, 0.02-0.0001, 0.02-0.0003, 0.02-0.0005, 0.02-0.0008, 0.02-0.001, 0.02-0.005, 0.02-0.008, 0.02-0.01, 0.01-0.0001, 0.01-0.0003, 0.01-0.0005, 0.01-0.0008, 0.01-0.001, 0.01-0.005, 0.01-0.008, 0.008-0.0001, 0.008-0.0003, 0.008-0.0005, 0.008-0.0008, 0.008-0.001, 0.008-0.005, 0.005-0.0001, 0.005-0.0003, 0.005-0.0005, 0.005-0.0008, and 0.005-0.001.

In some non-limiting examples, at least one of: the patterning coating 310, and the patterning material 2311, in some non-limiting examples, when deposited as at least one of: a film, and a coating, in a form, and under similar circumstances to the deposition of the patterning coating 310 within the device 2100, may have an initial sticking probability against the deposition of a plurality of deposited materials 2431 that is no more than a threshold value. In some non-limiting examples, such threshold value may be one of about: 0.3, 0.2, 0.18, 0.15, 0.13, 0.1, 0.08, 0.05, 0.03, 0.02, 0.01, 0.008, 0.005, 0.003, and 0.001.

In some non-limiting examples, at least one of: the patterning coating 310, and the patterning material 2311, in some non-limiting examples, when deposited as at least one of: a film, and a coating, in a form, and under similar circumstances to the deposition of the patterning coating 310 within the device 2100, may have an initial sticking probability that is no more than such threshold value against the deposition of a plurality of deposited materials 2431 selected from at least one of: Ag, Mg, Yb, Cd, and Zn. In some non-limiting examples, the patterning coating 310 may exhibit an initial sticking probability of no more than such threshold value against the deposition of a plurality of deposited materials 2431 selected from at least one of: Ag, Mg, and Yb.

In some non-limiting examples, at least one of: the patterning coating 310, and the patterning material 2311, in some non-limiting examples, when deposited as at least one of: a film, and a coating, in a form, and under similar circumstances to the deposition of the patterning coating 310 within the device 2100, may exhibit an initial sticking probability against the deposition of a first deposited material 2431 of, including without limitation, below, a first threshold value, and an initial sticking probability against the deposition of a second deposited material 2431 of, including without limitation, below, a second threshold value. In some non-limiting examples, the first deposited material 2431 may be Ag, and the second deposited material 2431 may be Mg. In some non-limiting examples, the first deposited material 2431 may be Ag, and the second deposited material may be Yb. In some non-limiting examples, the first deposited material 2431 may be Yb, and the second deposited material 2431 may be Mg. In some non-limiting examples, the first threshold value may exceed the second threshold value.

In some non-limiting examples, there may be scenarios calling for providing a patterning coating 310 for causing formation of a discontinuous layer 2160 of at least one particle structure 2150, upon the patterning coating 310 being subjected to a vapor flux 2432 of a deposited material 2431. In some non-limiting examples, the patterning coating 310 may exhibit a substantially low initial sticking probability such that a closed coating 2140 of the deposited material 2431 may be formed in the second portion 1902, which may be substantially devoid of the patterning coating 310, while the discontinuous layer 2160 of at least one particle structure 2150 having at least one characteristic may be formed in the first portion 1901 on the patterning coating 310. In some non-limiting examples, there may be scenarios calling for formation of a discontinuous layer 2160 of at least one particle structure 2150 of a deposited material 2431, which may be, in some non-limiting examples, of one of: a metal, and a metal alloy, in the second portion 1902, while depositing a closed coating 2140 of the deposited material 2431 having a thickness of, for example, one of no more than about: 100 nm, 50 nm, 25 nm, and 15 nm. In some non-limiting examples, an amount of the deposited material 2431 deposited as a discontinuous layer 2160 of at least one particle structure 2150 in the first portion 1901 may correspond to one of between about: 1-50%, 2-25%, 5-20%, and 7-10% of the amount of the deposited material 2431 deposited as a closed coating 2140 in the second portion 1902, which in some non-limiting examples may correspond to a thickness of one of no more than about: 100 nm, 75 nm, 50 nm, 25 nm, and 15 nm.

In some non-limiting examples, there may be a positive correlation between the initial sticking probability of at least one of: the patterning coating 310, and the patterning material 2311, in some non-limiting examples, when deposited as at least one of: a film, and a coating, in a form, and under circumstances similar to the deposition of the patterning coating 310 within the device 2100, against the deposition of the deposited material 2431, and an average layer thickness of the deposited material 2431 thereon.

### Transmittance

In some non-limiting examples, at least one of: the patterning coating 310, and the patterning material 2311, in some non-limiting examples, when deposited as at least one of: a film, and a coating, in a form, and under circumstances similar to the deposition of the patterning coating 310 within the device 2100, may have a transmittance for light of at least a threshold transmittance value, after being subjected to a vapor flux 2432 of the deposited material 2431, including without limitation, Ag.

In some non-limiting examples, such transmittance may be measured after exposing the exposed layer surface 11 of at least one of: the patterning coating 310 and the patterning material 2311, formed as a thin film, to a vapor flux 2432 of the deposited material 2431, including without limitation, at least one of: a metal, and an alloy, including without limitation, at least one of: Yb, Ag, Mg, and Ag-containing materials, including without limitation, MgAg, under typical conditions that may be used for depositing an electrode of an opto-electronic device 2200, which in some non-limiting examples, may be a cathode of an organic light-emitting diode (OLED) device 2200.

In some non-limiting examples, the conditions for subjecting the exposed layer surface 11 to the vapor flux 2432 of the deposited material 2431, including without limitation, at least one of: a metal, and an alloy, including without limitation, at least one of: Yb, Ag, Mg, and Ag-containing materials, including without limitation, MgAg, may comprise: maintaining a vacuum pressure at a reference pressure, including without limitation, of one of about: 10⁻⁴ Torr and 10⁻⁵ Torr; the vapor flux 2432 of the deposited material 2431, including without limitation, at least one of: a metal, and an alloy, including without limitation, at least one of: Yb, Ag, Mg, and Ag-containing materials, including without limitation, MgAg, being substantially consistent with a reference deposition rate, including without limitation, of about 1 angstrom (Å)/sec, which in some non-limiting examples, may be monitored using a QCM; the vapor flux 2432 of the deposited material 2431 being directed toward the exposed layer surface 11 at an angle that is substantially close to normal to a plane of the exposed layer surface 11; the exposed layer surface 11 being subjected to the vapor flux 2432 of the deposited material 2431, including without limitation, at least one of: a metal, and an alloy, including without limitation, at least one of: Yb, Ag, Mg, and Ag-containing materials, including without limitation, MgAg, until a reference average layer thickness, including without limitation, of about 15 nm, is reached, and upon such reference average layer thickness being attained, the exposed layer surface 11 not being further subjected to the vapor flux of the deposited material 2431, including without limitation, at least one of: a metal, and an alloy, including without limitation, at least one of: Yb, Ag, Mg, and Ag-containing materials, including without limitation, MgAg.

In some non-limiting examples, the exposed layer surface 11 being subjected to the vapor flux 2432 of the deposited material 2431, including without limitation, at least one of: Yb, Ag, Mg, and Ag-containing materials, including without limitation, MgAg, may be substantially at room temperature (e.g. about 25° C.). In some non-limiting examples, the exposed layer surface 11 being subjected to the vapor flux 2432 of the deposited material 2431, including without limitation, at least one of: a metal, and an alloy, including without limitation, at least one of: Yb, Ag, Mg, and Ag-containing materials, including without limitation, MgAg, may be positioned about 65 cm away from an evaporation source by which the deposited material 2431, including without limitation, at least one of: a metal, and an alloy, including without limitation, at least one of: Yb, Ag, Mg, and Ag-containing materials, including without limitation, MgAg, is evaporated.

In some non-limiting examples, the threshold transmittance value may be measured at a wavelength in the visible spectrum, which may be one of at least about: 460 nm, 500 nm, 550 nm, and 600 nm. In some non-limiting examples, the threshold transmittance value may be measured at a wavelength in at least one of: the IR, and NIR, spectrum. In some non-limiting examples, the threshold transmittance value may be measured at a wavelength of one of about: 700 nm, 900 nm, and 1,000 nm. In some non-limiting examples, the threshold transmittance value may be expressed as a percentage of incident EM power that may be transmitted through a sample. In some non-limiting examples, the threshold transmittance value may be one of at least about: 60%, 65%, 70%, 75%, 80%, 85%, and 90%.

It would be appreciated by a person having ordinary skill in the relevant art that high transmittance may generally indicate an absence of a closed coating 2140 of the deposited material 2431, including without limitation, at least one of: Yb, Ag, Mg, and Ag-containing materials, including without limitation, MgAg. On the other hand, low transmittance may generally indicate presence of a closed coating 2140 of the deposited material 2431, including without limitation, at least one of: Yb, Ag, Mg, and Ag-containing materials, including without limitation, MgAg, since metallic thin films, particularly when formed as a closed coating 2140, may exhibit a high degree of absorption of light.

A series of samples was fabricated to measure the transmittance of an example material, as well as to visually observe whether a closed coating 2140 of Ag was formed on the exposed layer surface 11 of such example material. Each sample was prepared by depositing, on a glass substrate 10, an approximately 50 nm thick coating of an example material, then subjecting the exposed layer surface 11 of the coating to a vapor flux 2432 of Ag at a rate of about 1 Å/sec until a reference layer thickness of about 15 nm was reached. Each sample was then visually analyzed and the transmittance through each sample was measured.

The molecular structures of the example materials used in the samples herein are set out in Table 2 below:

TABLE 2

| Material | Molecular Structure/Name |
|---|---|
| HT211 | 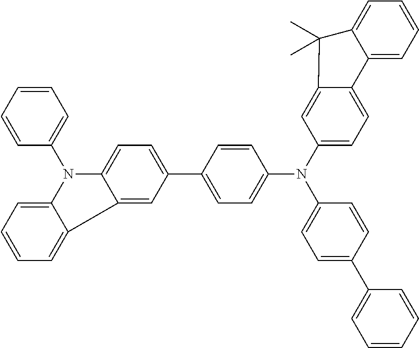 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21] |
| HT01 | 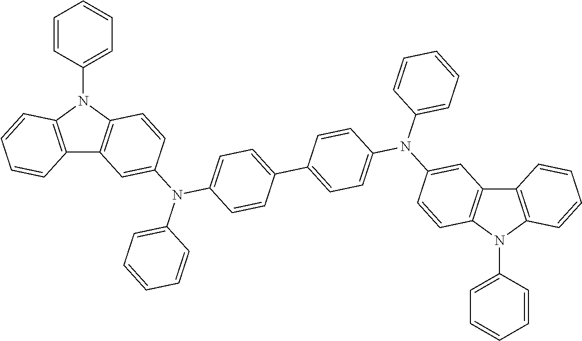 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1] |
| TAZ | 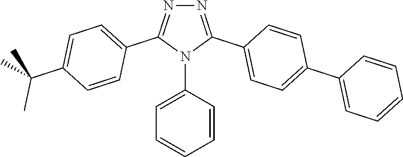 |
| Balq | 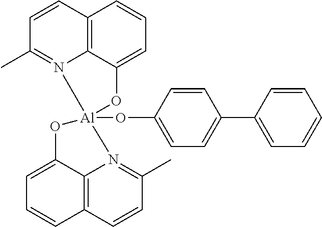 |
| Liq | 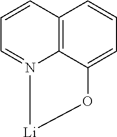 |
| Example Material 1 | 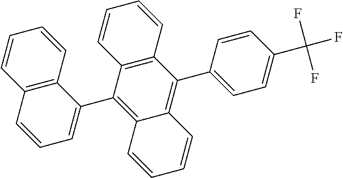 [SMILES: FC(F)(F)c1ccc(-c2c3ccccc3c(-c3cccc4ccccc34)c3ccccc23)cc1] |
| Example Material 2 | 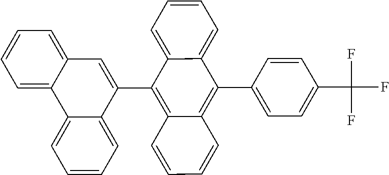 [SMILES: FC(F)(F)c1ccc(-c2c3ccccc3c(-c3cc4ccccc4c4ccccc34)c3ccccc23)cc1] |
| Example Material 3 | 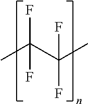 |
| Example Material 4 | 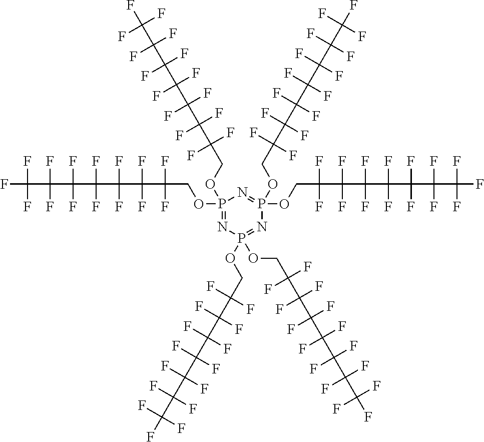 [SMILES: FC(F)(F)C(F)(F)C(F)(F)C(F)(F)C(F)(F)C(F)(F)C(F)(F)COP1(OCC(F)(F)C(F)(F)C(F)(F)C(F)(F)C(F)(F)C(F)(F)C(F)(F)F)=NP(OCC(F)(F)C(F)(F)C(F)(F)C(F)(F)C(F)(F)C(F)(F)C(F)(F)F)(OCC(F)(F)C(F)(F)C(F)(F)C(F)(F)C(F)(F)C(F)(F)C(F)(F)F)=NP(OCC(F)(F)C(F)(F)C(F)(F)C(F)(F)C(F)(F)C(F)(F)C(F)(F)F)(OCC(F)(F)C(F)(F)C(F)(F)C(F)(F)C(F)(F)C(F)(F)C(F)(F)F)=N1] |
| Example Material 5 | 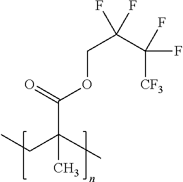 |
| Example Material 6 | 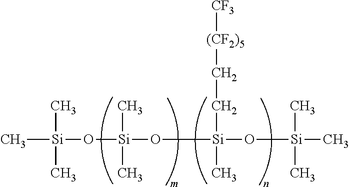 |
| Example Material 7 | 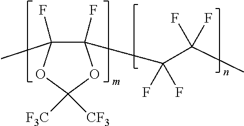 |
| Example Material 8 | 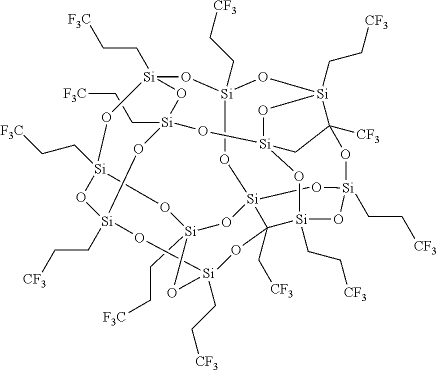 [SMILES: FC(F)(F)CC[Si]12OC3(CC(F)(F)F)[Si]4(CCC(F)(F)F)O[Si]56CC7(C(F)(F)F)O[Si](CCC(F)(F)F)(O4)O[Si]34O[Si](CCC(F)(F)F)(O1)O[Si]1(CCC(F)(F)F)O[Si](CCC(F)(F)F)(O2)O[Si](CCC(F)(F)F)(O[Si](CCC(F)(F)F)(O1)O[Si](CCC(F)(F)F)(O[Si]7(CCC(F)(F)F)O5)O4)O6] |
| Example Material 9 | 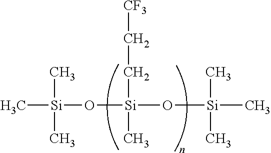 |

Those having ordinary skill in the relevant art will appreciate that samples having little to no deposited material 2431, including without limitation, at least one of: a metal, and an alloy, including without limitation, at least one of: Yb, Ag, Mg, and Ag-containing materials, including without limitation, MgAg, present thereon may be substantially transparent, while samples with substantial amounts of at least one of: a metal, and an alloy, deposited thereon, including without limitation, as a closed coating 2140, may in some non-limiting examples, exhibit a substantially reduced transmittance. Accordingly, the performance of various example coatings as a patterning coating 310 may be assessed by measuring transmission through the samples, which may be inversely correlated to at least one of: an amount, and an average layer thickness, of the deposited material 2431, including without limitation, at least one of: a metal, and an alloy, including without limitation, in the form of at least one of Yb, Ag, Mg, and Ag-containing materials, including without limitation, MgAg, being deposited thereon, since metallic thin films, including without limitation, when formed as a closed coating 2140, may exhibit a high degree of absorption of light.

The samples in which a substantially closed coating 2140 of a deposited material 2431, in the form of Ag, had formed were visually identified, and the presence of such closed coating 2140 in these samples was further confirmed by measurement of transmittance therethrough, which showed transmittance of no more than about 50% at a wavelength of about 460 nm.

In addition, for samples in which the absence of formation of a closed coating 2140 of a deposited material 2431, in the form of Ag, was identified, the absence of such closed coating 2140 in these samples was further confirmed by measurement of EM transmittance therethrough, which showed transmittance (of light at a wavelength of about 460 nm) of at least about 70%.

The results are summarized in Table 3 below:

TABLE 3

| Material | Closed Coating of Ag? |
|---|---|
| HT211 | Present |
| HT01 | Present |
| TAZ | Present |
| Balq | Present |
| Liq | Present |
| Example Material 1 | Present |
| Example Material 2 | Present |
| Example Material 3 | Not Present |
| Example Material 4 | Not Present |
| Example Material 5 | Not Present |
| Example Material 6 | Not Present |
| Example Material 7 | Not Present |
| Example Material 8 | Not Present |
| Example Material 9 | Present |

Based on the foregoing, it was found that the materials used in the first 7 samples (HT211 to Example Material 2) and Example Material 9 in Tables 2 and 3 may have reduced applicability in some scenarios for inhibiting the deposition of the deposited material 2431 thereon, including without limitation, at least one of: a metal, and an alloy, including without limitation, at least one of: Yb, Ag, Mg, and Ag-containing materials, including without limitation, MgAg.

On the other hand, it was found that Example Material 3 to Example Material 8 may have applicability in some scenarios, to act as a patterning coating 310 for inhibiting the deposition of the deposited material 2431 including without limitation, at least one of: a metal, and an alloy, including without limitation, at least one of: Yb, Ag, Mg, and Ag-containing materials, including without limitation, MgAg, thereon.

### Deposition Contrast

In some non-limiting examples, a material, including without limitation, a patterning material 2311, that may function as an NIC for a given at least one of: a metal, and an alloy, including without limitation, at least one of: Mg, Ag, and MgAg, may have a substantially high deposition contrast when deposited on a substrate 10.

In some non-limiting examples, if a substrate 10 tends to act as a nucleation-promoting coating (NPC) 2620, and a portion thereof is coated with a material, including without limitation, a patterning material 2311, that may tend to function as an NIC against deposition of a deposited material 2431, including without limitation, at least one of: a metal, and an alloy, including without limitation, at least one of: Yb, Ag, Mg, and Ag-containing materials, including without limitation, MgAg, a coated portion (first portion 1901) and an uncoated portion (second portion 1902) may tend to have different at least one of: initial sticking probabilities, and nucleation rates, such that the deposited material 2431 deposited thereon may tend to have different average film thicknesses.

As used herein, a quotient of an average film thickness of the deposited material 2431 deposited in the second portion 1902 divided by the average film thickness of the deposited material in the first portion 1901 in such scenario may be generally referred to as a deposition contrast. Thus, if the deposition contrast is substantially high, the average film thickness of the deposited material 2431 in the second portion 1902 may be substantially greater than the average film thickness of the deposited material 2431 in the first portion 1901.

In some non-limiting examples, a material, including without limitation, a patterning material 2311, that may function as an NIC for a given deposited material 2431, may have a substantially high deposition contrast when deposited on a substrate 10.

In some non-limiting examples, there may be a negative correlation between the initial sticking probability of at least one of: the patterning coating 310, and the patterning material 2311, in some non-limiting examples, when deposited as at least one of: a film, and a coating, in a form, and under circumstances similar to the deposition of the patterning coating 310 within the device 2100, against the deposition of the deposited material 2431 and a deposition contrast thereof, that is, a low initial sticking probability may be highly correlated with a high deposition contrast.

In some non-limiting examples, if the deposition contrast is substantially high, there may be little to no deposited material 2431 deposited in the first portion 1901, when there is sufficient deposition of the deposited material 2431 to form a closed coating 2140 thereof in the second portion 1902.

In some non-limiting examples, if the deposition contrast is substantially low, there may be a discontinuous layer 2160 of at least one particle structure 2150 of the deposited material 2431 deposited in the first portion 1901, when there is sufficient deposition of the deposited material 2431 to form a closed coating 2140 in the second portion 1902.

In some non-limiting examples, there may be scenarios calling for the formation of a discontinuous layer 2160 of at least one particle structure 2150 of the deposited material 2431, in the first portion 1901, when an average layer thickness of a closed coating 2140 of the deposited material 2431 in the second portion 1902 is substantially small, including without limitation, one of no more than about: 100 nm, 50 nm, 25 nm, and 15 nm, including without limitation, the formation of nanoparticles (NPs) in the first portion 1901, where absorption of light by such NPs is called for, including without limitation, to protect an underlying layer 2610 from light having a wavelength of no more than about 460 nm.

In some non-limiting examples, in such scenarios, there may be applicability for a deposition contrast of one of between about: 2-100, 4-50, 5-20, and 10-15.

In some non-limiting examples, a material, including without limitation, a patterning material 2311, having a substantially low deposition contrast against deposition of a deposited material 2431, may have reduced applicability in some scenarios calling for substantially high deposition contrast, including without limitation, where the average layer thickness of the deposited material 2431 in the first portion 1901 is large, including without limitation, one of at least about: 95 nm, 45 nm, 20 nm, 10 nm, and 8 nm.

In some non-limiting examples, a material, including without limitation, a patterning material 2311, having a substantially low deposition contrast against deposition of a deposited material 2431, may have reduced applicability in some scenarios calling for substantially high deposition contrast, including without limitation, scenarios calling for at least one of: the substantial absence of a closed coating 2140, and a high density of, particle structures 2150 in the first portion 1901, including without limitation, when an average layer thickness of the deposited material 2431 in the second portion 1902 is large, including without limitation, one of at least about: 95 nm, 45 nm, 20 nm, 10 nm, and 8 nm, including without limitation, in some scenarios calling for the substantial absence of absorption of light in at least one of the visible spectrum and the NIR spectrum, including without limitation, scenarios calling for an increased transparency to light having a wavelength that is at least about 460 nm.

In some non-limiting examples, a material, including without limitation, a patterning material 2311, having a substantially low deposition contrast against the deposition of a deposited material 2431, may have applicability in some scenarios calling for at least one of: a discontinuous layer 2160 of, and a low density of, particle structures 2150 of the deposited material 2431 in the first portion 1901, when an average layer thickness of a closed coating 2140 of the deposited material 2431 in the second portion 1902 is substantially high, including without limitation, one of at least about: 95 nm, 45 nm, 20 nm, 10 nm, and 8 nm. In some non-limiting examples, a deposition contrast of one of between about: 2-100, 4-50, 5-20, and 10-15 may have applicability in some scenarios when an average layer thickness of the deposited material 2431 in the second portion 1902 is substantially high, including without limitation, one of at least about: 95 nm, 45 nm, 20 nm, 10 nm, and 8 nm.

In some non-limiting examples, a material, including without limitation, a patterning material 2311, may tend to have a substantially low deposition contrast if the initial sticking probability of such material against deposition of at least one of: a metal, and an alloy, including without limitation, at least one of: Mg, Ag, and MgAg, is substantially high.

### Surface Energy

A characteristic surface energy, as used herein, in some non-limiting examples, with respect to a material, may generally refer to a surface energy determined from such material.

In some non-limiting examples, a characteristic surface energy may be measured from a surface formed by the material deposited (coated) in a thin film form.

Various methods and theories for determining the surface energy of a solid are known.

In some non-limiting examples, a surface energy may be calculated (derived) based on a series of contact angle measurements, in which various liquids may be brought into contact with a surface of a solid to measure the contact angle between the liquid-vapor interface and the surface. In some non-limiting examples, a surface energy of a solid surface may be equal to the surface tension of a liquid with the highest surface tension that completely wets the surface.

In some non-limiting examples, the critical surface tension of a surface may be determined according to the Zisman method, as further detailed in W. A. Zisman, Advances in Chemistry 43 (1964), pp. 1-51.

In some non-limiting examples, a characteristic surface energy of a material, including without limitation, a patterning material 2311, in a coating, including without limitation, a patterning coating 310, may be determined by depositing the material as a substantially pure coating (e.g. a coating formed by a substantially pure material) on a substrate 10 and measuring a contact angle thereof with an applicable series of probe liquids.

In some non-limiting examples, a Zisman plot may be used to determine a maximum value of surface tension that would result in complete wetting (i.e. a contact angle θ_{c} of) 0° of the surface.

A material which has applicability for use in providing the patterning coating 310 may generally have a low surface energy when deposited as a thin film (coating) on a surface. In some non-limiting examples, a material with a low surface energy may exhibit low intermolecular forces.

Without wishing to be bound by any particular theory, it is now postulated that a material with a substantially high surface energy may have applicability at least in some applications that call for a high temperature reliability.

Without wishing to be bound by any particular theory, it has now been found that a patterning coating 310 comprising a material which, when deposited as a thin film, exhibits a substantially high surface energy, may, in some non-limiting examples, form a discontinuous layer 2160 of at least one particle structure 2150 of a deposited material 2431 in the first portion 1901, and a closed coating 2140 of the deposited material 2431 in the second portion 1902, including without limitation, in cases where the thickness of the closed coating is, in some non-limiting examples, one of no more than about: 100 nm, 75 nm, 50 nm, 25 nm, and 15 nm.

In some non-limiting examples, a series of samples was fabricated to measure the critical surface tension of the surfaces formed by the various materials. The results of the measurement are summarized in Table 4:

TABLE 4

| Material | Critical Surface Tension (dynes/cm) |
|---|---|
| HT211 | 25.6 |
| HT01 | >24 |
| TAZ | 22.4 |
| Balq | 25.9 |
| Liq | 24 |
| Example Material 1 | 26.3 |
| Example Material 2 | 24.8 |
| Example Material 3 | 20 |
| Example Material 4 | 12.4 |
| Example Material 5 | 15.9 |
| Example Material 6 | 21.1 |
| Example Material 7 | 13.1 |
| Example Material 8 | 21 |
| Example Material 9 | 18.9 |

Based on the foregoing measurement of the critical surface tension in Table 4 and the previous observation regarding one of: the presence, and absence, of a substantially closed coating 2140 of a deposited material 2431, in the form of Ag, it was found that materials that form substantially low surface energy surfaces when deposited as a coating, including without limitation, a patterning coating 310, which in some non-limiting examples, may be those having a critical surface tension of one of between about: 13-20 dynes/cm, and 13-19 dynes/cm, may have applicability for forming the patterning coating 310 to inhibit deposition of a deposited material 2431 thereon, including without limitation, at least one of Yb, Ag, Mg, and Ag-containing materials, including without limitation, MgAg.

Without wishing to be bound by any particular theory, it may be postulated that materials that form a surface having a surface energy lower than, in some non-limiting examples, about 13 dynes/cm, may have reduced applicability as a patterning material 2311 in some scenarios, as such materials may exhibit at least one of: substantially poor adhesion to layer(s) surrounding such materials, a low melting point, and a low sublimation temperature.

In some non-limiting examples, a material, including without limitation, a patterning material 2311 that may tend to function as an NIC for a deposited material 2431, including without limitation, at least one of: a metal, and an alloy, including without limitation, at least one of: Mg, Ag, and Ag-containing materials, including without limitation, MgAg, may tend to exhibit a substantially low surface energy when deposited as a thin film (coating) on an exposed layer surface 11.

In some non-limiting examples, a material, including without limitation, a patterning material 2311, may tend to exhibit a substantially low surface energy when deposited as a thin film (coating) on an exposed layer surface 11.

In some non-limiting examples, a material, including without limitation, a patterning material 2311, with a substantially low surface energy may tend to exhibit substantially low inter-molecular forces.

In some non-limiting examples, there may be scenarios calling for a patterning material 2311 that has a substantially low surface energy that is not unduly low.

In some non-limiting examples, a material, including without limitation, a patterning material 2311, with a substantially high surface energy may have applicability for some scenarios to detect a film of such material using optical techniques.

Without wishing to be bound by any particular theory, it may be postulated that, in some non-limiting examples, a material, including without limitation, a patterning material 2311, having a substantially high surface energy may have applicability for some scenarios that call for substantially high temperature reliability.

In some non-limiting examples, a material, including without limitation, a patterning material 2311, that may function as an NIC for at least one of: a metal, and an alloy, including without limitation, at least one of Mg, Ag, and Ag-containing materials, including without limitation, MgAg, having a substantially high surface energy may have applicability in some scenarios calling for a discontinuous layer 2160 of particle structures 2150 of at least one of: the metal, and the alloy, in the first portion 1901, when an average layer thickness of a continuous coating 2140 of at least one of: the metal, and the alloy, in the second portion 1902 is substantially low, including without limitation, one of no more than about: 100 nm, 50 nm, 25 nm, and 15 nm.

In some non-limiting examples, a material, including without limitation, a patterning material 2311, that may function as an NIC for a deposited material 2431, including without limitation, at least one of: a metal, and an alloy, including without limitation, at least one of: Yb, Ag, Mg, and Ag-containing materials, including without limitation, MgAg, having a substantially low surface energy may have applicability in some scenarios calling for one of: a discontinuous layer 2160 of, and a low density of, particle structures 2150 of the deposited material 2431 in the first portion 1901, when an average layer thickness of a closed coating 2140 of the deposited material 2431 in the second portion 1902 is substantially high, including without limitation, one of at least about: 95 nm, 45 nm, 20 nm, 10 nm, and 8 nm.

In some non-limiting examples, the surface of at least one of: the patterning coating 310, and the patterning material 2311, in some non-limiting examples, when deposited as at least one of: a film, and a coating, in a form, and under circumstances similar to the deposition of the patterning coating 310 within the device 2100, comprising the compounds described herein, may exhibit a surface energy of one of no more than about: 24 dynes/cm, 22 dynes/cm, 20 dynes/cm, 18 dynes/cm, 16 dynes/cm, 15 dynes/cm, 13 dynes/cm, 12 dynes/cm, and 11 dynes/cm.

In some non-limiting examples, the surface values in various non-limiting examples herein may correspond to such values measured at around normal temperature and pressure (NTP), which may correspond to a temperature of 20° C., and an absolute pressure of 1 atm.

In some non-limiting examples, the surface energy may be one of at least about: 6 dynes/cm, 7 dynes/cm, and 8 dynes/cm.

In some non-limiting examples, the surface energy may be one of between about: 10-20 dynes/cm, and 13-19 dynes/cm.

### Temperature

### Glass Transition Temperature

In some non-limiting examples, at least one of: the patterning coating 310, and the patterning material 2311, in some non-limiting examples, when deposited as at least one of: a film, and coating, in a form, and under circumstances similar to the deposition of the patterning coating 310 within the device 2100, may have a glass transition temperature that is one of: one of at least about: 300° C., 150° C., and 130° C., and one of no more than about: 30° C., 0° C., −30° C., and −50° C.

### Sublimation Temperature

In some non-limiting examples, a material, including without limitation, a patterning material 2311, having substantially low inter-molecular forces may tend to exhibit a substantially low sublimation temperature.

In some non-limiting examples, a material, including without limitation, a patterning material 2311, having a substantially low sublimation temperature, may have reduced applicability for manufacturing processes that may call for substantially precise control of an average layer thickness in a deposited film of the material.

In some non-limiting examples, a material, including without limitation, a patterning material 2311, having a sublimation temperature that is one of no more than about: 140° C., 120° C., 110° C., 100° C. and 90° C., may tend to encounter constraints on at least one of: the deposition rate and the average layer thickness, of a film comprising such material that may be deposited using known deposition methods, including without limitation, vacuum thermal evaporation.

In some non-limiting examples, a material, including without limitation, a patterning material 2311, having a substantially high sublimation temperature may have applicability in some scenarios calling for substantially high precision in the control of the average layer thickness of a film comprising such material.

In some non-limiting examples, the patterning material may have a sublimation temperature of one of between about: 100-320° C., 120-300° C., 140-280° C., and 150-250° C. In some non-limiting examples, such sublimation temperature may allow the patterning material 2311 to be substantially readily deposited as a coating using PVD.

In some non-limiting examples, a material with substantially low intermolecular forces may exhibit a substantially low sublimation temperature.

In some non-limiting examples, a material, including without limitation, a patterning material 2311, having a substantially low sublimation temperature, may have reduced applicability for manufacturing processes that may call for substantially precise control of an average layer thickness of a closed coating 2140 of the deposited material 2431.

In some non-limiting examples, a material, including without limitation, a patterning material 2311, having a sublimation temperature that is one of no more than about: 140° C., 120° C., 110° C., 100° C. and 90° C., may tend to encounter constraints on at least one of: the deposition rate and the average layer thickness, of a film comprising such material that may be deposited using known deposition methods, including without limitation, vacuum thermal evaporation.

In some non-limiting examples, a material, including without limitation, a patterning material 2311, having a substantially high sublimation temperature may have applicability in some scenarios calling for substantially high precision in the control of the average layer thickness of a film comprising such material.

The sublimation temperature of a material, including without limitation, a patterning material 2311, may be determined using various methods apparent to those having ordinary skill in the relevant art, including without limitation, by heating the material in an evaporation source under a substantially high vacuum environment, in some non-limiting examples, about 10⁻⁴ Torr, and including without limitation, in a crucible and by determining a temperature that may be attained, to at least one of:
observe commencement of the deposition of the material onto an exposed layer surface 11 on a QCM mounted a fixed distance from the crucible;
observe a specific deposition rate, in some non-limiting examples, 0.1 Å/sec, onto an exposed layer surface 11 on a QCM mounted a fixed distance from the crucible; and
reach a threshold vapor pressure of the material, in some non-limiting examples, one of about” 10⁻⁴ and 10⁻⁵ Torr.

In some non-limiting examples, the QCM may be mounted about 65 cm away from the crucible for the purpose of determining the sublimation temperature.

In some non-limiting examples, the patterning material 2311 may have a sublimation temperature of one of between about: 100-320° C., 100-300° C., 120-300° C., 100-250° C., 140-280° C., 120-230° C., 130-220° C., 140-210° C., 140-200° C., 150-250° C., and 140-190° C.

### Melting Point

In some non-limiting examples, a material, including without limitation, a patterning material 2311, with substantially low inter-molecular forces may tend to exhibit a substantially low melting point.

In some non-limiting examples, a material, including without limitation, a patterning material 2311, having a substantially low melting point may have reduced applicability in some scenarios calling for substantial temperature reliability for temperatures of one of no more than about: 60° C., 80° C., and 100° C., in some non-limiting examples, because of changes in physical properties of such material at operating temperatures that approach the melting point.

In some non-limiting examples, a material with a melting point of about 120° C. may have reduced applicability in some scenarios calling for substantially high temperature reliability, including without limitation, of at least about: 100° C.

In some non-limiting examples, a material, including without limitation, a patterning material 2311, having a substantially high melting point may have applicability in some scenarios calling for substantially high temperature reliability.

In some non-limiting examples, at least one of: the patterning coating 310 and the compound thereof may have a melting temperature that is one of at least about: 90° C., 100° C., 110° C., 120° C., 140° C., 150° C., and 180° C.

### Cohesion Energy

According to Young's equation (Equation 15) the cohesion energy (fracture toughness/cohesion strength) of a material may tend to be proportional to its surface energy (cf. Young, Thomas (1805) “An essay on the cohesion of fluids”, Philosophical Transactions of the Royal Society of London, 95:65-87).

According to Lindemann's criterion, the cohesion energy of a material may tend to be proportional to its melting temperature (cf. Nanda, K. K., Sahu, S. N, and Behera, S. N (2002), “Liquid-drop model for the size-dependent melting of low-dimensional systems” Phys. Rev. A. 66 (1): 013208).

In some non-limiting examples, a material, including without limitation, a patterning material 2311, having substantially low inter-molecular forces may tend to exhibit a substantially low cohesion energy.

In some non-limiting examples, a material, including without limitation, a patterning material 2311, having a substantially low cohesion energy may have reduced applicability in some scenarios that call for substantial fracture toughness, including without limitation, in a device 2100 that may tend to undergo at least one of: sheer, and bending, stress during at least one of: manufacture, and use, as such material may tend to crack (fracture) in such scenarios. In some non-limiting examples, a material, including without limitation, a patterning material 2311, having a cohesion energy of no more than about 30 dynes/cm may have reduced applicability in some scenarios in a device 2100 manufactured on a flexible substrate 10.

In some non-limiting examples, a material, including without limitation, a patterning material 2311, that has a substantially high cohesion energy, may have applicability in some scenarios calling for substantially high reliability under at least one of: sheer, and bending, stress, including without limitation, a device 2100 manufactured on a flexible substrate 10.

In some non-limiting examples, a material, including without limitation, a patterning material 2311, having a surface energy that is substantially low but is not unduly low may have applicability in some scenarios that call for substantial reliability under at least one of: sheer, and bending, stress, including without limitation, a device 2100 manufactured on a flexible substrate 10.

### Optical/Band Gap

In the present disclosure, a semiconductor material may be described as a material that generally exhibits a band gap. In some non-limiting examples, the band gap may be formed between a highest occupied molecular orbital (HOMO) and a lowest unoccupied molecular orbital (LUMO) of the semiconductor material. Semiconductor materials may thus tend to exhibit electrical conductivity that is substantially no more than that of a conductive material (including without limitation, at least one of: a metal, and an alloy), but that is substantially at least as great as an insulating material (including without limitation, glass). In some non-limiting examples, the semiconductor material may comprise an organic semiconductor material. In some non-limiting examples, the semiconductor material may comprise an inorganic semiconductor material.

In some non-limiting examples, an optical gap of a material, including without limitation, a patterning material 2311, may tend to correspond to the HOMO-LUMO gap of the material.

In some non-limiting examples, a material, including without limitation, a patterning material 2311, having a substantially large/wide optical (HOMO-LUMO gap) may tend to exhibit substantially weak, including without limitation, substantially no, photoluminescence in at least one of: the deep B(lue) region of the visible spectrum, the near UV spectrum, the visible spectrum, and the NIR spectrum.

In some non-limiting examples, a material having a substantially small HOMO-LUMO gap may have applicability in some scenarios to detect a film of the material using optical techniques.

In some non-limiting examples, an optical gap of the patterning material 2311 may be wider than a photon energy of the light emitted by the source, such that the patterning material 2311 does not undergo photoexcitation when subjected to such light.

### Refractive Index and Extinction Coefficient

In some non-limiting examples, at least one of: the patterning coating 310, and the patterning material 2311, in some non-limiting examples, when deposited as at least one of: a film, and a coating, in a form, and under circumstances similar to the deposition of the patterning coating 310 within the device 2100, may have a low refractive index.

In some non-limiting examples, at least one of: the patterning coating 310, and the patterning material 2311, in some non-limiting examples, when deposited as at least one of: a film, and a coating, in a form, and under circumstances similar to the deposition of the patterning coating 310 within the device 2100, may have a refractive index for light at a wavelength of 550 nm that may be one of no more than about: 1.55, 1.5, 1.45, 1.43, 1.4, 1.39, 1.37, 1.35, 1.32, and 1.3.

In some non-limiting examples, the refractive index, of the patterning coating 310 may be no more than about 1.7. In some non-limiting examples, the refractive index of the patterning coating 310 may be one of no more than about: 1.6, 1.5, 1.4, and 1.3. In some non-limiting examples, the refractive index of the patterning coating 310 may be one of between about: 1.2-1.6, 1.2-1.5, and 1.25-1.45. As further described in various non-limiting examples above, the patterning coating 310 exhibiting a substantially low refractive index may have application in some scenarios, to enhance at least one of: the optical properties, and performance, of the device 2100, including without limitation, by enhancing outcoupling of light emitted by the opto-electronic device 2200.

Without wishing to be bound by any particular theory, it has been observed that providing the patterning coating 310 having a substantially low refractive index may, at least in some devices 2100, enhance transmission of external light through the second portion 1902 thereof. In some non-limiting examples, devices 100 including an air gap therein, which may be arranged near to the patterning coating 310, may exhibit a substantially high transmittance when the patterning coating 310 has a substantially low refractive index relative to a similarly configured device 2100 in which such low-index patterning coating 310 was not provided.

In some non-limiting examples, a series of samples was fabricated to measure the refractive index at a wavelength of 550 nm for the coatings formed by some of the various example materials. The results of the measurement are summarized in Table 5 below:

TABLE 5

| Material | Refractive Index |
|---|---|
| HT211 | 1.76 |
| HT01 | 1.80 |
| TAZ | 1.69 |
| Balq | 1.69 |
| Liq | 1.64 |
| Example Material 2 | 1.72 |
| Example Material 3 | 1.37 |
| Example Material 5 | 1.38 |
| Example Material 7 | 1.3 |
| Example Material 8 | 1.37 |

Based on the foregoing measurement of refractive index in Table 5, and the previous observation regarding one of: the presence, and absence, of a substantially closed coating 2140 of Ag in Table 5, it was found that materials that form a low refractive index coating, which in some non-limiting examples, may be those having a refractive index of one of no more than about: 1.4 and 1.38, may have applicability in some scenarios for forming the patterning coating 310 to substantially inhibit deposition of a deposited material 2431 thereon, including without limitation, at least one of: a metal, and an alloy, including without limitation, at least one of: Yb, Ag, Mg, and an Ag-containing material, including without limitation, MgAg.

In some non-limiting examples, at least one of: the patterning coating 310, and the patterning material 2311, in some non-limiting examples, when deposited as at least one of: a film, and a coating, in a form, and under circumstances similar to the deposition of the patterning coating 310 within the device 2100, may have a low refractive index.

In some non-limiting examples, at least one of: the patterning coating 310, and the patterning material 2311, in some non-limiting examples, when deposited as at least one of: a film, and a coating, in a form, and under circumstances similar to the deposition of the patterning coating 310 within the device 2100, may have a refractive index for light at a wavelength of 550 nm that may be one of no more than about: 1.55, 1.5, 1.45, 1.43, 1.4, 1.39, 1.37, 1.35, 1.32, and 1.3.

In some non-limiting examples, the patterning coating 310 may be at least one of: substantially transparent, and light-transmissive.

In some non-limiting examples, at least one of: the patterning coating 310, and the patterning material 2311, in some non-limiting examples, when deposited as at least one of: a film, and a coating, in a form, and under similar circumstances to the deposition of the patterning coating 310 within the device 2100, may have an extinction coefficient that may be no more than about 0.01 for photons at a wavelength that is one of at least about: 600 nm, 500 nm, 460 nm, 420 nm, and 410 nm.

In some non-limiting examples, at least one of: the patterning coating 310, and the patterning material 2311, in some non-limiting examples, when deposited as at least one of: a film, and a coating, in a form, and under circumstances similar to the deposition of the patterning coating 310 within the device 2100, may have an extinction coefficient that may be one of at least about: 0.05, 0.1, 0.2, and 0.5 for light at a wavelength that is one of no more than about: 400 nm, 390 nm, 380 nm, and 370 nm.

In this way, at least one of: the patterning coating 310, and the patterning material 2311, when deposited as at least one of: a film, and a coating, in a form, and under circumstances similar to the deposition of the patterning coating 310 within the device 2100, may absorb light in the UVA spectrum incident upon the device 2100, thereby reducing a likelihood that light in the UVA spectrum may impart constraints in terms of at least one of: device performance, device stability, device reliability, and device lifetime.

In some non-limiting examples, the patterning coating 310 may exhibit an extinction coefficient of one of no more than about: 0.1, 0.08, 0.05, 0.03, and 0.01 in the visible light spectrum.

### Photoluminescence, Absorption and Other Optical Effects

In some non-limiting examples, photoluminescence of at least one of: a coating, and a material may be observed through a photoexcitation process. In a photoexcitation process, at least one of: the coating, and the material, may be subjected to light emitted by a source, including without limitation, a UV lamp.

When the emitted light is absorbed by at least one of: the coating, and the material, the electrons thereof may be temporarily excited. Following excitation, at least one relaxation process may occur, including without limitation, at least one of: fluorescence and phosphorescence, in which light may be emitted from at least one of: the coating, and the material.

The light emitted from at least one of: the coating, and the material, during such process may be detected, for example, by a photodetector, to characterize the photoluminescence properties of at least one of: the coating, and the material.

As used herein, a wavelength of photoluminescence, in relation to at least one of: the coating, and the material, may generally refer to a wavelength of light emitted by such at least one of: the coating, and the material, as a result of relaxation of electrons from an excited state. As would be appreciated by a person having ordinary skill in the relevant art, a wavelength of light emitted by at least one of: the coating, and the material, as a result of the photoexcitation process may, in some non-limiting examples, be longer than a wavelength of radiation used to initiate photoexcitation. Photoluminescence may be detected using various techniques known in the art, including, without limitation, fluorescence microscopy.

In some non-limiting examples, the optical gap of the various coatings/materials may correspond to an energy gap of the coating/material from which light is one of: absorbed, and emitted, during the photoexcitation process.

In some non-limiting examples, photoluminescence may be detected by subjecting the coating/material to light having a wavelength corresponding to the UV spectrum, such as in some non-limiting examples, one of: UVA, and UVB. In some non-limiting examples, light for causing photoexcitation may have a wavelength of about 365 nm.

In some non-limiting examples, the patterning material 2311 may not substantially exhibit photoluminescence at any wavelength corresponding to the visible spectrum.

In some non-limiting examples, the patterning material 2311 may not exhibit photoluminescence upon being subjected to light having a wavelength of one of at least about: 300 nm, 320 nm, 350 nm, and 365 nm.

As used herein, at least one of: the coating, and the material, that is photoluminescent, may be one that exhibits photoluminescence at a wavelength when irradiated with an excitation radiation at a certain wavelength. In some non-limiting examples, at least one of: the coating, and the material, that is photoluminescent, may exhibit photoluminescence at a wavelength that exceeds about 365 nm, which is a wavelength of the radiation source frequently used in fluorescence microscopy, upon being irradiated with an excitation radiation having a wavelength of 365 nm.

At least one of: the coating, and the material, that is photoluminescent, may be detected on a substrate 10 using standard optical techniques including without limitation, fluorescence microscopy, which may establish the presence of such at least one of: the coating, and the material.

In some non-limiting examples, a coating, including without limitation, a patterning coating 310, may exhibit photoluminescence, including without limitation, by comprising a material that exhibits photoluminescence.

In some non-limiting examples, the presence of such patterning coating 310 may be detected (observed) using routine characterization techniques such as fluorescence microscopy upon deposition of the patterning coating 310.

In some non-limiting examples, a coating, including without limitation, a patterning coating 310, may exhibit photoluminescence at a wavelength corresponding to at least one of: the UV spectrum, and visible spectrum, including without limitation, by comprising a material that exhibits photoluminescence. In some non-limiting examples, photoluminescence may occur at a wavelength (range) corresponding to the UV spectrum, including, without limitation, one of: the UVA spectrum, and UVB spectrum. In some non-limiting examples, photoluminescence may occur at a wavelength (range) corresponding to the visible spectrum. In some non-limiting examples, photoluminescence may occur at a wavelength (range) corresponding to one of: deep B(lue) and near UV.

In some non-limiting examples, at least one of the materials of the patterning coating 310 that may exhibit photoluminescence may comprise at least one of: a conjugated bond, an aryl moiety, a donor-acceptor group, and a heavy metal complex.

In some non-limiting examples, a coating, including without limitation, a patterning coating 310, comprised of a material, including without limitation, a patterning material 2311, having substantially weak to no photoluminescence (absorption) in a wavelength range of one of at least about: 365 nm, and 460 nm, may tend to not act as one of: a photoluminescent, and an absorbing, coating and may have applicability in some scenarios calling for substantially high transparency in at least one of: the visible spectrum, and the NIR spectrum.

In some non-limiting examples, such material may tend to exhibit substantially low photoluminescence upon being subjected to light having a wavelength of about 365 nm, which is a wavelength of the radiation source frequently used in fluorescence microscopy. The presence of such materials, including without limitation, a patterning material 2311, especially when deposited, in some non-limiting examples, as a thin film, may have reduced applicability in some scenarios calling for typical optical detection techniques, including without limitation, fluorescence microscopy. This may impose constraints in some scenarios in which such material may be selectively deposited, for example through an FMM, over part(s) of a substrate 10, as there may be some scenarios for determining, following the deposition of the material, the part(s) in which such materials are present.

In some non-limiting examples, a material with substantially low to no absorption at a wavelength that is one of at least about: 365 nm, and 460 nm, may have applicability in some scenarios calling for substantially high transparency in at least one of: the visible spectrum, and the NIR spectrum.

In some non-limiting examples, at least one of: the patterning coating 310, and the patterning material 2311, in some non-limiting examples, when deposited as at least one of: a film, and a coating, in a form, and under circumstances similar to the deposition of the patterning coating 310 within the device 2100, may not substantially attenuate light passing therethrough, in at least the visible spectrum.

In some non-limiting examples, at least one of: the patterning coating 310, and the patterning material 2311, when deposited as at least one of: a film, and a coating, in a form, and under circumstances similar to the deposition of the patterning coating 310 within the device 2100, may not substantially attenuate light passing therethrough, in at least one of: the IR spectrum, and the NIR spectrum.

In this way, at least one of: the patterning coating 310, and the patterning material 2311, when deposited as at least one of: a film, and a coating, in a form, and under circumstances similar to the deposition of the patterning coating 310 within the device 2100, may absorb light in the UVA spectrum incident upon the device 2100, thereby reducing a likelihood that light in the UVA spectrum may impart constraints in terms of at least one of: device performance, device stability, device reliability, and device lifetime.

In some non-limiting examples, the patterning coating 310 may act as an optical coating.

In some non-limiting examples, the patterning coating 310 may modify at least one of: at least one property, and at least one characteristic, of light (including without limitation, in the form of photons) emitted by the device 2100. In some non-limiting examples, the patterning coating 310 may exhibit a degree of haze, causing emitted light to be scattered. In some non-limiting examples, the patterning coating 310 may comprise a crystalline material for causing light transmitted therethrough to be scattered. Such scattering of light may facilitate enhancement of the outcoupling of light from the device 2100 in some non-limiting examples. In some non-limiting examples, the patterning coating 310 may initially be deposited as a substantially non-crystalline, including without limitation, substantially amorphous, coating, whereupon, after deposition thereof, the patterning coating 310 may become crystallized and thereafter serve as an optical coupling.

In some non-limiting examples, the patterning material 2311 may exhibit insignificant, including without limitation, no detectable, absorption when subjected to light having a wavelength of one of at least about: 300 nm, 320 nm, 350 nm, and 365 nm.

In some non-limiting examples, the patterning coating 310 may not exhibit any substantial light absorption at any wavelength corresponding to the visible spectrum.

### Average Layer Thickness

In some non-limiting examples, an average layer thickness of the patterning coating 310 may be one of no more than about: 10 nm, 8 nm, 7 nm, 6 nm, and 5 nm.

### Weight

Without wishing to be bound by any particular theory, it may be postulated that, for compounds that are adapted to form surfaces with substantially low surface energy, there may be scenarios calling for, in at least some applications, the molecular weight of such compounds to be one of between about: 800-3,000 g/mol, 900-2,000 g/mol, 900-1,800 g/mol, and 900-1,600 g/mol.

In some non-limiting examples, the molecular weight of the compound of the at least one patterning material 2311 may be no more than about 5,000 g/mol. In some non-limiting examples, the molecular weight of the compound may be one of no more than about: 4,500 g/mol, 4,000 g/mol, 3,800 g/mol, and 3,500 g/mol.

In some non-limiting examples, the molecular weight of the compound of the at least one patterning material 2311 may be at least about 800 g/mol. In some non-limiting examples, the molecular weight of the compound may be one of at least about: 1,500 g/mol, 1,700 g/mol, 2,000 g/mol, 2,200 g/mol, and 2,500 g/mol.

In some non-limiting examples, the molecular weight of the compound may be one of between about: 800-3,000 g/mol, 900-2,000 g/mol, 900-1,800 g/mol, and 900-1,600 g/mol.

In some non-limiting examples, a percentage of the molar weight of such compound that may be attributable to the presence of F atoms, may be one of between about: 40-90%, 45-85%, 50-80%, 55-75%, and 60-75%. In some non-limiting examples, F atoms may constitute a majority of the molar weight of such compound.

### Inter-Relationships Between Patterning Coating Attributes

Without wishing to be bound by any particular theory, it may be postulated that exposed layer surfaces 11 exhibiting low initial sticking probability with respect to the deposited material 2431, including without limitation, at least one of: a metal, and an alloy, including without limitation, Yb, Ag, Mg, and an Ag-containing material, including without limitation, MgAg, may exhibit high transmittance. Without wishing to be bound by any particular theory, it may be postulated that exposed layer surfaces 11 exhibiting high sticking probability with respect to the deposited material 2431, including without limitation, at least one of: a metal, and an alloy, including without limitation, Yb, Ag, Mg, and an Ag-containing material, including without limitation, MgAg, may exhibit low transmittance.

In some non-limiting examples, a material, including without limitation, a patterning material 2311, may tend to have a substantially high initial sticking probability against deposition of a deposited material, including without limitation, at least one of: a metal, and an alloy, including without limitation, at least one of: Yb, Ag, Mg, and an Ag-containing material, including without limitation, MgAg, if the material has a substantially high surface energy.

In some non-limiting examples, a patterning material 2311 that has a substantially low surface tension that is not unduly low, may have applicability in some scenarios calling for a substantially high melting point, including without limitation, between about 15-22 dynes/cm.

In some non-limiting examples, a material, including without limitation, a patterning material 2311, having a surface tension that is substantially low, but not unduly low, may have applicability in some scenarios that call for a substantially high sublimation temperature.

In some non-limiting examples, a coating, including without limitation, a patterning coating 310, comprised of a material, including without limitation, a patterning material 2311, having a substantially low surface energy and a substantially high sublimation temperature may have application in some scenarios calling for substantially high precision in the control of the average layer thickness of a film comprising such material.

Without wishing to be bound by any particular theory, it may be postulated that materials that form an exposed layer surface 11 having a surface energy of no more than, in some non-limiting examples, about 13 dynes/cm, may have reduced applicability as a patterning material 2311 in some scenarios, as such materials may exhibit at least one of: substantially low adhesion to layer(s) surrounding such materials, a substantially low melting point, and a substantially low sublimation temperature.

In some non-limiting examples, a patterning coating 310 having a substantially low surface energy and a substantially high melting point may have applicability in some scenarios calling for high temperature reliability. In some non-limiting examples, there may be challenges in achieving such a combination from a single material given that in some non-limiting examples, a single material having a low surface energy may tend to exhibit a low melting point.

Without wishing to be bound by any particular theory, it may be postulated that such compounds, including without limitation, of at least one patterning material 2311, may exhibit at least one property that may have applicability in some scenarios for forming at least one of: a coating, and layer, having at least one of: a substantially high melting point, in some non-limiting examples, of at least 100° C., a substantially low surface energy, and a substantially amorphous structure, when deposited, in some non-limiting examples, using vacuum-based thermal evaporation processes.

In some non-limiting examples, a coating, including without limitation, a patterning coating 310, having a substantially low surface energy, a substantially high cohesion energy, and a substantially high melting point may have applicability in some scenarios that call for substantially high reliability under various conditions. In some non-limiting examples, there may be challenges in achieving such a combination from a single material, given that, in some non-limiting examples, a unitary material having a substantially low surface energy may tend to exhibit a substantially low cohesion energy and a substantially low melting point.

In some non-limiting examples, a material, including without limitation, a patterning material 2311, having a substantially low surface energy and a substantially high cohesion energy may have applicability in some scenarios that call for substantially high reliability under at least one of: sheer, and bending, stress. In some non-limiting examples, there may be challenges in achieving such a combination from a single material, given that, in some non-limiting examples, a thin film formed substantially of a single material having a substantially low surface energy may tend to exhibit a substantially low cohesion energy.

In some non-limiting examples, a material, including without limitation, a patterning material 2311, having a substantially low surface energy may tend to exhibit at least one of: a substantially large, and substantially wide, optical gap. In some non-limiting examples, the optical gap of a material, including without limitation, a patterning material 2311, may tend to correspond to the HOMO-LUMO gap of the material.

In general, a material with a low surface energy may exhibit at least one of: a large, and wide, optical gap which, in some non-limiting examples, may correspond to the HOMO-LUMO gap of the material.

It has also now been found, that a patterning coating 310 formed by a compound exhibiting a substantially low surface energy may also exhibit a substantially low refractive index.

In some non-limiting examples, at least one of: the patterning coating 310, and the patterning material 2311, may exhibit a surface energy of no more than about 25 dynes/cm and a refractive index of no more than about 1.45. In some non-limiting examples, at least one of: the patterning coating 310, and the patterning material 2311, may comprise a material exhibiting a surface energy of no more than about 20 dynes/cm and a refractive index of no more than about 1.4.

In some non-limiting examples, a material, including without limitation, a patterning material 2311, having a substantially low surface energy may have applicability in some scenarios calling for substantially weak to no, at least one of: photoluminescence, and absorption, in a wavelength range that is one of at least about: 365 nm and 460 nm.

In some non-limiting examples, a material, including without limitation, a patterning material 2311, having at least one of: a substantially large, and substantially wide optical gap (and HOMO-LUMO gap) may tend to exhibit a substantially weak to no photoluminescence in at least one of: the deep B(lue) region of the visible spectrum, the near UV spectrum, the visible spectrum, and the NIR spectrum.

Without wishing to be bound by any particular theory, it may be postulated that, for compounds that are adapted to form surfaces with substantially low surface energy, there may be an aim, in at least some applications, for the molecular weight of such compounds to be one of between about: 1,500-5,000 g/mol, 1,500-4,500 g/mol, 1,700-4,500 g/mol, 2,000-4,000 g/mol, 2,200-4,000 g/mol, and 2,500-3,800 g/mol.

At least some materials with at least one of: one of: a large, and wide, optical gap, and HOMO-LUMO gap, may exhibit substantially weak to no photoluminescence in at least one of: the visible spectrum, the deep B(lue) region thereof, and the near UV spectrum. In some non-limiting examples, a material with a substantially small HOMO-LUMO gap may have applicability in applications to detect a film of the material using optical techniques. In some non-limiting examples, a material with higher surface energy may have applicability for applications to detect of a film of the material using optical techniques.

In some non-limiting examples, a material having a substantially large HOMO-LUMO gap may have applicability in some scenarios calling for weak to no at least one of: photoluminescence, and absorption, in a wavelength range of one of at least about: 365 nm, and 460 nm.

### Doping

In some non-limiting examples, the patterning coating 310 may exhibit, including without limitation, because of at least one of: the patterning material 2311 used, and the deposition environment, at least one nucleation site for the deposited material 2431.

In some non-limiting examples, the patterning coating 310 may be doped, including without limitation, by at least one of: covering, and supplementing, with another material that may act as at least one of: a seed, and heterogeneity, to act as such a nucleation site for the deposited material 2431. In some non-limiting examples, such other material may comprise an NPC 2620 material. In some non-limiting examples, such other material may comprise an organic material, in some non-limiting examples, at least one of: a polycyclic aromatic compound, and a material comprising a non-metallic element, including without limitation, at least one of: O, S, N, and C, whose presence might otherwise be a contaminant in at least one of: the source material, equipment used for deposition, and the vacuum chamber environment. In some non-limiting examples, such other material may be deposited in a layer thickness that is a fraction of a monolayer, to avoid forming a closed coating 2140 thereof. Rather, the monomers of such other material may tend to be spaced apart in the lateral aspect so as form discrete nucleation sites for the deposited material.

### Plurality of Patterning Materials

In some non-limiting examples, forming a patterning coating 310 of a single patterning material 2311 against the deposition of a deposited material 2431, including without limitation, at least one of: a given metal, and a given alloy, including without limitation, at least one of: Yb, Ag, Mg, and Ag-containing materials, including without limitation, MgAg, that satisfied constraints of at least one material property selected from at least one of: initial sticking probability, transmittance, deposition contrast, surface energy, glass transition temperature, melting point, sublimation temperature, evaporation temperature, cohesion energy, optical gap, photoluminescence, refractive index, extinction coefficient, absorption, other optical effect, average layer thickness, molecular weight, and composition, for a given scenario, may impose challenges, given the substantially complex inter-relationships between the various material properties.

In some non-limiting examples, the patterning coating 310 may comprise a plurality of materials. In some non-limiting examples, the patterning coating 310 may comprise a first material and a second material.

In some non-limiting examples, at least one of the plurality of materials of the patterning coating 310 may serve as an NIC when deposited as a thin film.

In some non-limiting examples, at least one of the plurality of materials of the patterning coating 310 may serve as an NIC when deposited as a thin film, and another material thereof may form an NPC 2620 when deposited as a thin film. In some non-limiting examples, the first material may form an NPC 2620 when deposited as a thin film, and the second material may form an NIC when deposited as a thin film. In some non-limiting examples, the presence of the first material in the patterning coating 310 may result in an increased initial sticking probability thereof compared to cases in which the patterning coating 310 is formed of the second material and is substantially devoid of the first material.

In some non-limiting examples, at least one of the materials of the patterning coating 310 may be adapted to form a surface having a low surface energy when deposited as a thin film. In some non-limiting examples, the first material, when deposited as a thin film, may be adapted to form a surface having a lower surface energy than a surface provided by a thin film comprising the second material.

In some non-limiting examples, the patterning coating 310 may exhibit photoluminescence, including without limitation, by comprising a material which exhibits photoluminescence.

In some non-limiting examples, the first material may exhibit photoluminescence at a wavelength corresponding to the visible spectrum, and the second material may not exhibit substantial photoluminescence at any wavelength corresponding to the visible spectrum.

In some non-limiting examples, the second material may not substantially exhibit photoluminescence at any wavelength corresponding to the visible spectrum. In some non-limiting examples, the second material may not exhibit photoluminescence upon being subjected to light having a wavelength of one of at least about: 300 nm, 320 nm, 350 nm, and 365 nm. In some non-limiting examples, the second material may exhibit insignificant to no detectable absorption when subjected to such light.

In some non-limiting examples, the second optical gap of the second material may be wider than the photon energy of the light emitted by the source, such that the second material does not undergo photoexcitation when subjected to such light. However, in some non-limiting examples, the patterning coating 310 comprising such second material may nevertheless exhibit photoluminescence upon being subjected to light due to the first material exhibiting photoluminescence. In some non-limiting examples, the presence of the patterning coating 310 may be detected using routine characterization techniques such as fluorescence microscopy upon deposition of the patterning coating 310.

In some non-limiting examples, the first material may have a first optical gap, and the second material may have a second optical gap. In some non-limiting examples, the second optical gap may exceed the first optical gap. In some non-limiting examples, a difference between the first optical gap and the second optical gap may exceed one of about: 0.3 eV, 0.5 eV, 0.7 eV, 1 eV, 1.3 eV, 1.5 eV, 1.7 eV, 2 eV, 2.5 eV, and 3 eV.

In some non-limiting examples, the first optical gap may be one of no more than about: 4.1 eV, 3.5 eV, and 3.4 eV. In some non-limiting examples, the second optical gap may exceed one of about: 3.4 eV, 3.5 eV, 4.1 eV, 5 eV, and 6.2 eV.

In some non-limiting examples, at least one of: the first optical gap, and the second optical gap, may correspond to the HOMO-LUMO gap.

In some non-limiting examples, an optical gap of at least one of: the various coatings, and materials, including without limitation, at least one of: the first optical gap, and the second optical gap, may correspond to an energy gap of at least one of: the coating, and the material, from which light is at least one of: absorbed, and emitted, during the photoexcitation process.

In some non-limiting examples, a concentration, including without limitation by weight, of the first material in the patterning coating 310 may be no more than that of the second material in the patterning coating 310. In some non-limiting examples, the patterning coating 310 may comprise one of at least about: 0.1 wt. %, 0.2 wt. %, 0.5 wt. %, 0.8 wt. %, 1 wt. %, 3 wt. %, 5 wt. %, 8 wt. %, 10 wt. %, 15 wt. %, and 20 wt. %, of the first material. In some non-limiting examples, the patterning coating 310 may comprise one of no more than about: 50 wt. %, 40 wt. %, 30 wt. %, 25 wt. %, 20 wt. %, 15 wt. %, 10 wt. %, 8 wt. %, 5 wt. %, 3 wt. %, and 1 wt. %, of the first material. In some non-limiting examples, a remainder of the patterning coating 310 may be substantially comprised of the second material. In some non-limiting examples, the patterning coating 310 may comprise additional materials, including without limitation, at least one of: a third material, and a fourth material.

In some non-limiting examples, at least one of the materials of the patterning coating 310, including without limitation, the first material and the second material, may comprise at least one of: F, and Si. In some non-limiting examples, at least one of: the first material, and the second material, may comprise at least one of: F, and Si. In some further non-limiting examples, the first material may comprise at least one of: F, and Si, and the second material may comprise at least one of: F, and Si. In some non-limiting examples, the first material and the second material both may comprise F. In some non-limiting examples, the first material and the second material both may comprise Si. In some non-limiting examples, each of the first material and the second material may comprise at least one: F, and Si.

In some non-limiting examples, at least one material of the first material and the second material may comprise both F and Si. In some non-limiting examples, one of the first material and the second material may not comprise at least one of: F, and Si. In some non-limiting examples, the second material may comprise at least one of: F, and Si, and the first material may not comprise at least one of: F, and Si.

In some non-limiting examples, at least one of the materials of the patterning coating 310, which for example, may be at least one of: the first material, and the second material, may comprise F, and at least one of the other materials of the patterning coating 310 may comprise a sp² carbon. In some non-limiting examples, at least one of the materials of the patterning coating 310, including without limitation, at least one of: the first material, and the second material, may comprise F, and at least one of the other materials of the patterning coating 310 may comprise a sp³ carbon. In some non-limiting examples, at least one of the materials of the patterning coating 310, including without limitation, at least one of: the first material, and the second material, may comprise F and a sp³ carbon, and at least one of the other materials of the patterning coating 310 may comprise a sp² carbon. In some non-limiting examples, at least one of the materials of the patterning coating 310, including without limitation, at least one of: the first material, and the second material, may comprise F and a sp³ carbon wherein all F bonded to a C may be bonded to a sp³ carbon, and at least one of the other materials of the patterning coating 310 may comprise a sp² carbon. In some non-limiting examples, at least one of the materials of the patterning coating 310, including without limitation, at least one of: the first material, and the second material, may comprise F and a sp³ carbon wherein all F bonded to C may be bonded to an sp³ carbon, and at least one of the other materials of the patterning coating 310 may comprise a sp² carbon and may not comprise F. In some non-limiting examples, in any of the foregoing non-limiting examples, “at least one of the materials of the patterning coating 310” may correspond to the second material, and the “at least one of the other materials of the patterning coating 310” may correspond to the first material.

As would be appreciated by those having ordinary skill in the relevant art, the presence of materials in a coating which comprises at least one of: F, sp² carbon, sp³ carbon, an aromatic hydrocarbon moiety, other functional groups, and other moieties, may be detected using various methods known in the art, including in some non-limiting examples, X-ray Photoelectron Spectroscopy (XPS).

In some non-limiting examples, at least one of the materials of the patterning coating 310, which in some non-limiting examples may be at least one of: the first material, and the second material, may comprise F, and at least one of the other materials of the patterning coating 310 may comprise an aromatic hydrocarbon moiety. In some non-limiting examples, at least one of the materials of the patterning coating 310, including without limitation, at least one of: the first material, and the second material, may comprise F, and at least one of the materials of the patterning coating 310 may not comprise an aromatic hydrocarbon moiety. In some non-limiting examples, at least one of the materials of the patterning coating 310, including without limitation, at least one of: the first material, and the second material, may comprise F and may not comprise an aromatic hydrocarbon moiety, and at least one of the other materials of the patterning coating 310 may comprise an aromatic hydrocarbon moiety. In some non-limiting examples, at least one of the materials of the patterning coating 310, including without limitation, at least one of: the first material, and the second material, may comprise F and may not comprise an aromatic hydrocarbon moiety, and at least one of the other materials of the patterning coating 310 may comprise an aromatic hydrocarbon moiety and may not comprise F. Non-limiting examples of the aromatic hydrocarbon moiety include at least one of: a substituted polycyclic aromatic hydrocarbon moiety, an unsubstituted polycyclic aromatic hydrocarbon moiety, a substituted phenyl moiety, and an unsubstituted phenyl moiety.

In some non-limiting examples, at least one of the materials of the patterning coating 310, including without limitation, at least one of: the first material, and the second material, may comprise F, and at least one of the other materials of the patterning coating 310 may comprise a polycyclic aromatic hydrocarbon moiety. In some non-limiting examples, at least one of the materials of the patterning coating 310, including without limitation, at least one of: the first material, and the second material, may comprise F, and at least one of the materials of the patterning coating 310 may not comprise a polycyclic aromatic hydrocarbon moiety. In some non-limiting examples, at least one of the materials of the patterning coating 310, including without limitation, at least one of: the first material, and the second material, may comprise F and may not comprise a polycyclic aromatic hydrocarbon moiety, and at least one of the other materials of the patterning coating 310 may comprise a polycyclic aromatic hydrocarbon moiety. In some non-limiting examples, at least one of the materials of the patterning coating 310, including without limitation, at least one of: the first material, and the second material, may comprise F and may not comprise a polycyclic aromatic hydrocarbon moiety, and at least one of the other materials of the patterning coating 310 may comprise a polycyclic aromatic hydrocarbon moiety and may not comprise F.

In some non-limiting examples, at least one of the materials of the patterning coating 310, including without limitation, at least one of: the first material, and the second material, may comprise at least one of: a fluorocarbon moiety and a siloxane moiety, and at least one of the other materials of the patterning coating 310 may comprise a polycyclic aromatic hydrocarbon moiety. In some non-limiting examples, at least one of the materials of the patterning coating 310, including without limitation, at least one of: the first material, and the second material, may comprise at least one of: a fluorocarbon moiety, and a siloxane moiety, and at least one of the materials of the patterning coating 310 may not comprise a polycyclic aromatic hydrocarbon moiety. In some non-limiting examples, at least one of the materials of the patterning coating 310, including without limitation, at least one of: the first material, and the second material, may comprise at least one of: a fluorocarbon moiety, and a siloxane moiety, and may not comprise a polycyclic aromatic hydrocarbon moiety, and at least one of the other materials of the patterning coating 310 may comprise a polycyclic aromatic hydrocarbon moiety. In some non-limiting examples, at least one of the materials of the patterning coating 310, including without limitation, at least one of: the first material, and the second material, may comprise at least one of: a fluorocarbon moiety, and a siloxane moiety, and may not comprise a polycyclic aromatic hydrocarbon moiety, and at least one of the other materials of the patterning coating 310 may comprise a polycyclic aromatic hydrocarbon moiety and may not comprise at least one of: a fluorocarbon moiety, and a siloxane moiety.

In some non-limiting examples, at least one of the materials of the patterning coating 310, including without limitation, at least one of: the first material, and the second material, may comprise F, and at least one of the other materials of the patterning coating 310 may comprise a phenyl moiety. In some non-limiting examples, at least one of the materials of the patterning coating 310, including without limitation, at least one of: the first material, and the second material, may comprise F, and at least one of the materials of the patterning coating 310 may not comprise a phenyl moiety. In some non-limiting examples, at least one of the materials of the patterning coating 310, including without limitation, at least one of: the first material, and the second material, may comprise F and may not comprise a phenyl moiety, and at least one of the other materials of the patterning coating 310 may comprise a phenyl moiety. In some non-limiting examples, at least one of the materials of the patterning coating 310, including without limitation, at least one of: the first material, and the second material, may comprise F and may not comprise a phenyl moiety, and at least one of the other materials of the patterning coating 310 may comprise a phenyl moiety and may not comprise F.

In some non-limiting examples, at least one of the materials of the patterning coating 310, including without limitation, at least one of: the first material, and the second material, may comprise at least one of: a fluorocarbon moiety and a siloxane moiety, and at least one of the other materials of the patterning coating 310 may comprise a phenyl moiety. In some non-limiting examples, at least one of the materials of the patterning coating 310, including without limitation, at least one of: the first material, and the second material, may comprise at least one of: a fluorocarbon moiety, and a siloxane moiety, and at least one of the materials of the patterning coating 310 may not comprise a phenyl moiety. In some non-limiting examples, at least one of the materials of the patterning coating 310, including without limitation, at least one of: the first material, and the second material, may comprise at least one of: a fluorocarbon moiety, and a siloxane moiety and may not comprise a phenyl moiety, and at least one of the other materials of the patterning coating 310 may comprise a phenyl moiety. In some non-limiting examples, at least one of the materials of the patterning coating 310, including without limitation, at least one of: the first material, and the second material, may comprise at least one of: a fluorocarbon moiety, and a siloxane moiety and may not comprise a phenyl moiety, and at least one of the other materials of the patterning coating 310 may comprise a phenyl moiety and may not comprise either of: a fluorocarbon moiety, and a siloxane moiety.

In general, at least one of: the molecular structures, and molecular compositions, of the materials of the patterning coating 310, including without limitation, at least one of: the first material, and the second material, may be different. In some non-limiting examples, the materials may be selected such that they possess at least one property which is one of: substantially similar to, and substantially different from, one another, including without limitation, at least one of: at least one of: a molecular structure of a monomer, a monomer backbone, and a functional group; a presence of a element in common; a similarity in molecular structure; a characteristic surface energy; a refractive index; a molecular weight; and a thermal property, including without limitation, at least one of: a melting temperature, a sublimation temperature, a glass transition temperature, and a thermal decomposition temperature.

A characteristic surface energy, as used herein, in some non-limiting examples, with respect to a material, may generally refer to a surface energy determined from such material. In some non-limiting examples, a characteristic surface energy may be measured from a surface formed by the material deposited in a thin film form. Various methods and theories for determining the surface energy of a solid are known. In some non-limiting examples, a surface energy may be determined based on a series of contact angle measurements, in which various liquids may be brought into contact with a surface of a solid to measure a contact angle between the liquid-vapor interface and the surface. In some non-limiting examples, a surface energy of a solid surface may be equal to the surface tension of a liquid with the highest surface tension that completely wets the surface. In some non-limiting examples, a Zisman plot may be used to determine a highest surface tension value that would result in complete wetting (i.e. contact angle of) 0° of the surface.

In some non-limiting examples, at least one of: the first material, and the second material, of the patterning coating 310 may be an oligomer.

In some non-limiting examples, the first material may comprise a first oligomer, and the second material may comprise a second oligomer. Each of the first oligomer and the second oligomer may comprise a plurality of monomers.

In some non-limiting examples, at least a fragment of the molecular structure of the at least one of the materials of the patterning coating 310, including without limitation, at least one of: the first material, and the second material, may be represented by Formula (I):

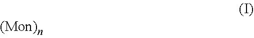

where:
Mon represents a monomer, and
n is an integer of at least 2.

In some non-limiting examples, n may be an integer of one of between about: 2-100, 2-50, 3-20, 3-15, 3-10, and 3-7.

In some non-limiting examples, the molecular structure of the first material and the second material of the patterning coating 310 may each be independently represented by Formula (I). In some non-limiting examples, at least one of: the monomer, and n, of the first material may be different from that of the second material. In some non-limiting examples, n of the first material may be the same as n of the second material. In some non-limiting examples, n of the first material may be different from n of the second material. In some non-limiting examples, the first material and the second material may be oligomers.

In some non-limiting examples, the monomer may comprise at least one of: F, and Si.

In some non-limiting examples, the monomer may comprise a functional group. In some non-limiting examples, at least one functional group of the monomer may have a low surface tension. In some non-limiting examples, at least one functional group of the monomer may comprise at least one of: F, and Si. Non-limiting examples of such functional group include at least one of: a fluorocarbon group, and a siloxane group. In some non-limiting examples, the monomer may comprise a silsesquioxane group.

While some non-limiting examples have been described herein with reference to a first material and a second material, it will be appreciated that the patterning coating may further include at least one additional material, and descriptions regarding at least one of: the molecular structures, and properties, of at least one of: the first material, the second material, the first oligomer, and the second oligomer, may be applicable with respect to additional materials which may be contained in the patterning coating 310.

The surface tension attributable to a fragment of a molecular structure, including without limitation, at least one of: a monomer, a monomer backbone unit, a linker, and a functional group, may be determined using various known methods in the art, including without limitation, the use of a Parachor, such as may be further described, in some non-limiting examples, in “Conception and Significance of the Parachor”, Nature 196:890-891. In some non-limiting examples, at least one functional group of the monomer may have a surface tension of one of no more than about: 25 dynes/cm, 21 dynes/cm, 20 dynes/cm, 19 dynes/cm, 18 dynes/cm, 17 dynes/cm, 16 dynes/cm, 15 dynes/cm, 14 dynes/cm, 13 dynes/cm, 12 dynes/cm, 11 dynes/cm, and 10 dynes/cm.

In some non-limiting examples, the monomer may comprise at least one of: a CF₂, and a CF₂H, moiety. In some non-limiting examples, the monomer may comprise at least one of: a CF₂, and a CF₃, moiety. In some non-limiting examples, the monomer may comprise a CH₂CF₃ moiety. In some non-limiting examples, the monomer may comprise at least one of: C, and O. In some non-limiting examples, the monomer may comprise a fluorocarbon monomer. In some non-limiting examples, the monomer may comprise at least one of: a vinyl fluoride moiety, a vinylidene fluoride moiety, a tetrafluoroethylene moiety, a chlorotrifluoroethylene moiety, a hexafluoropropylene moiety, and a fluorinated 1,3-dioxole moiety.

In some non-limiting examples, the monomer may comprise a monomer backbone and a functional group. In some non-limiting examples, the functional group may be bonded, one of: directly, and via a linker group, to the monomer backbone. In some non-limiting examples, the monomer may comprise the linker group, and the linker group may be bonded to the monomer backbone and to the functional group. In some non-limiting examples, the monomer may comprise a plurality of functional groups, which may be one of: the same, and different, from one another. In such examples, each functional group may be bonded, one of: directly, and via a linker group, to the monomer backbone. In some non-limiting examples, where a plurality of functional groups is present, a plurality of linker groups may also be present.

In some non-limiting examples, the molecular structure of at least one of the materials of the patterning coating 310, which may be at least one of: the first material, and the second material, may comprise a plurality of different monomers. In some non-limiting examples, such molecular structure may comprise monomer species that have different at least one of: molecular composition, and molecular structure. Non-limiting examples of such molecular structure include those represented by Formulae (II) and (III):

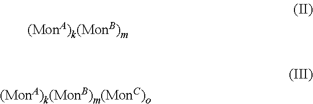

where:
Mon^{A}, Mon^{B}, and Mon^{C} each represent a monomer specie, and
k, m, and o each represent an integer of at least 2.

In some non-limiting examples, k, m, and o each represent an integer of one of between about: 2-100, 2-50, 3-20, 3-15, 3-10, and 3-7. Those having ordinary skill in the relevant art will appreciate that various non-limiting examples and descriptions regarding monomer, Mon, may be applicable with respect to each of Mon^{A}, Mon^{B}, and Mon^{C}.

In some non-limiting examples, the monomer may be represented by Formula (IV):

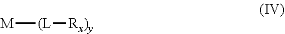

where:
M represents the monomer backbone unit,
L represents the linker group,
R represents the functional group,
x is an integer between 1 and 4, and
y is an integer between 1 and 3.

In some non-limiting examples, the linker group may be represented by at least one of: a single bond, O, N, NH, C, CH, CH₂, and S.

Various non-limiting examples of the functional group which have been described herein may apply with respect to R of Formula (IV). In some non-limiting examples, the functional group R may comprise an oligomer unit, and the oligomer unit may further comprise a plurality of functional group monomer units. In some non-limiting examples, a functional group monomer unit may be at least one of: CH₂, and CF₂. In some non-limiting examples, a functional group may comprise a CH₂CF₃ moiety. For example, such functional group monomer units may be bonded together to form at least one of: an alkyl, and an fluoroalkyl, oligomer unit. In some non-limiting examples, the oligomer unit may further comprise a functional group terminal unit. In some non-limiting examples, the functional group terminal unit may be arranged at a terminal end of the oligomer unit and bonded to a functional group monomer unit. In some non-limiting examples, the terminal end at which the functional group terminal unit may be arranged may correspond to a fragment of the functional group that may be distal to the monomer backbone unit. In some non-limiting examples, the functional group terminal unit may comprise at least one of: CF₂H, and CF₃.

In some non-limiting examples, the monomer backbone unit M may have a high surface tension. In some non-limiting examples, the monomer backbone unit may have a higher surface tension than at least one of the functional group(s) R bonded thereto. In some non-limiting examples, the monomer backbone unit may have a higher surface tension than any functional group R bonded thereto.

In some non-limiting examples, the monomer backbone unit may have a surface tension of one of at least about: 25 dynes/cm, 30 dynes/cm, 40 dynes/cm, 50 dynes/cm, 75 dynes/cm, 100 dynes/cm; 150 dynes/cm, 200 dynes/cm, 250 dynes/cm, 500 dynes/cm, 1,000 dynes/cm, 1,500 dynes/cm, and 2,000 dynes/cm.

In some non-limiting examples, the monomer backbone unit may comprise phosphorus (P) and N, including without limitation, a phosphazene, in which there is a double bond between P and N and may be represented as at least one of: “NP” and “N=P”. In some non-limiting examples, the monomer backbone unit may comprise Si and O, including without limitation, silsesquioxane, which may be represented as SiO_{3/2}.

In some non-limiting examples, at least a part of the molecular structure of the at least one of the materials of the patterning coating 310, including without limitation, at least one of: the first material, and the second material, is represented by Formula (V):

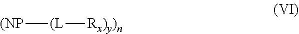

where:
NP represents the phosphazene monomer backbone unit,
L represents the linker group,
R represents the functional group,
x is an integer between 1 and 4,
y is an integer between 1 and 3, and
n is an integer of at least 2.

In some non-limiting examples, the molecular structure of at least one of: the first material, and the second material, may be represented by Formula (V). In some non-limiting examples, at least one of: the first material, and the second material, may be a cyclophosphazene. In some non-limiting examples, the molecular structure of the cyclophosphazene may be represented by Formula (V).

In some non-limiting examples, L may represent oxygen (O), x may be 1, and R may represent a fluoroalkyl group. In some non-limiting examples, at least a fragment of the molecular structure of the at least one material of the patterning coating 310, including without limitation, at least one of: the first material, and the second material, may be represented by Formula (VI):

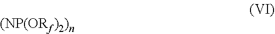

where:
R_{f} represents the fluoroalkyl group, and
n is an integer between 3 and 7.

In some non-limiting examples, the fluoroalkyl group may comprise at least one of: a CF₂ group, a CF₂H group, CH₂CF₃ group, and a CF₃ group. In some non-limiting examples, the fluoroalkyl group may be represented by Formula (VII):

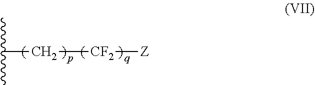

where:
p is an integer of 1 to 5;
q is an integer of 6 to 20; and
Z represents one of: hydrogen, and F.

In some non-limiting examples, p may be 1 and q may be an integer between 6 and 20.

In some non-limiting examples, the fluoroalkyl group R_{f} in Formula (VI) may be represented by Formula (VII).

In some non-limiting examples, at least a fragment of the molecular structure of at least one of the materials of the patterning coating 310, including without limitation, at least one of: the first material, and the second material, may be represented by Formula (VIII):

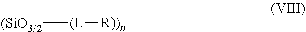

where:
L represents the linker group,
R represents the functional group, and
n is an integer between 6 and 12.

In some non-limiting examples, L may represent the presence of at least one of: a single bond, O, substituted alkyl, and unsubstituted alkyl. In some non-limiting examples, n may be one of: 8, 10, and 12. In some non-limiting examples R may comprise a functional group with low surface tension. In some non-limiting examples, R may comprise at least one of: a F-containing group, and a Si-containing group. In some non-limiting examples, R may comprise at least one of: a fluorocarbon group, and a siloxane-containing group. In some non-limiting examples, R may comprise at least one of: a CF₂ group, and a CF₂H group. In some non-limiting examples, R may comprise at least one of: a CF₂, and a CF₃, group. In some non-limiting examples, R may comprise a CH₂CF₃ group. In some non-limiting examples, the material represented by Formula (VIII) may be a polyoctahedral silsesquioxane.

In some non-limiting examples, at least a fragment of the molecular structure of at least one of the materials of the patterning coating 310, including without limitation, at least one of: the first material, and the second material, may be represented by Formula (IX):

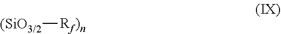

where:
n is an integer of 6-12, and
R_{f} represents a fluoroalkyl group.

In some non-limiting examples n may be one of: 8, 10, and 12. In some non-limiting examples, R_{f} may comprise a functional group with low surface tension. In some non-limiting examples, R_{f} may comprise at least one of: a CF₂ moiety, and a CF₂H moiety. In some non-limiting examples, R_{f} may comprise at least one of: a CF₂, and a CF₃ moiety. In some non-limiting examples, R_{f} may comprise a CH₂CF₃ moiety. In some non-limiting examples, the material represented by Formula (IX) may be a polyoctahedral silsesquioxane.

In some non-limiting examples, the fluoroalkyl group, R_{f}, in Formula (IX) may be represented by Formula (VII).

In some non-limiting examples, at least a fragment of the molecular structure of at least one of the materials of the patterning coating 310, including without limitation, at least one of: the first material, and the second material, may be represented by Formula (X):

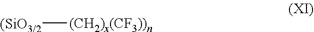

where:
x is an integer between 1 and 5, and
n is an integer between 6 and 12.

In some non-limiting examples, n may be one of: 8, 10, and 12.

In some non-limiting examples, the compound represented by Formula (X) may be a polyoctahedral silsesquioxane.

In some non-limiting examples, at least one of: the functional group R, and the fluoroalkyl group R_{f}, may be selected independently upon each occurrence of such group in any of the foregoing formulae. Those having ordinary skill in the relevant art will appreciate that any of the foregoing formulae may represent a sub-structure of the compound, and at least one of: additional groups, and additional moieties, may be present, which are not explicitly shown in the above formulae. Those having ordinary skill in the relevant art will appreciate that various formulae provided in the present application may represent at least one of: linear, branched, cyclic, cyclo-linear, and cross-linked, structures.

In some non-limiting examples, the patterning coating 310 may comprise at least one material represented by at least one of the following Formulae: (I), (II), (III), (IV), (V), (VI), (VIII), (IX), and (X), and at least one material exhibiting at least one of the following characteristics: includes an aromatic hydrocarbon moiety, includes an sp² carbon, includes a phenyl moiety, has a characteristic surface energy of at least about 20 dynes/cm, and exhibits photoluminescence, including without limitation, exhibiting photoluminescence at a wavelength of at least about 365 nm upon being irradiated by an excitation radiation having a wavelength of about 365 nm.

In some non-limiting examples, the patterning coating may comprise a third material that is different from the first material and the second material. In some non-limiting examples, the third material may comprise a monomer in common with at least one of: the first material, and the second material.

In some non-limiting examples, a difference in the sublimation temperature of the plurality of materials of the patterning coating 310, including, without limitation, a difference between the first material and the second material, may be one of no more than about: 5° C., 10° C., 15° C., 20° C., 30° C., 40° C., and 50° C. In some non-limiting examples, at least one of the materials of the patterning coating 310, including without limitation, at least one of: the first material, and the second material, may comprise at least one of: F, and Si, and the sublimation temperatures of the materials of the patterning coating 310 may differ by no more than one of about: 5° C., 10° C., 15° C., 20° C., 25° C., 40° C., and 50° C. In some non-limiting examples, at least one of the materials of the patterning coating 310, including without limitation, at least one of: the first material, and the second material, may comprise at least one of: a fluorocarbon moiety, and a siloxane moiety, and the sublimation temperatures of the materials of the patterning coating 310 may differ by one of no more than about: 5° C., 10° C., 15° C., 20° C., 25° C., 40° C., and 50° C.

In some non-limiting examples, a difference in a melting temperature of the plurality of materials of the patterning coating 310, including, without limitation, a difference between the first NIC material and the second NIC material, may be one of no more than about: 5° C., 10° C., 15° C., 20° C., 30° C., 40° C., and 50° C. In some non-limiting examples, at least one of the materials of the patterning coating 310, including without limitation, the first material, and the second material, may comprise at least one of: F, and Si, and the melting temperatures of the materials of the patterning coating 310 may differ by one of no more than about: 5° C., 10° C., 15° C., 20° C., 25° C., 40° C., and 50° C. In some non-limiting examples, at least one of the materials of the patterning coating 310, including without limitation, the first material, and the second material, may comprise at least one of: a fluorocarbon moiety, and a siloxane moiety, and the melting temperatures of the materials of the patterning coating 310 may differ by one of no more than about: 5° C., 10° C., 15° C., 20° C., 25° C., 40° C., and 50° C.

In some non-limiting examples, at least one of the materials of the patterning coating 310, including without limitation, at least one of: the first material, and the second material, may have a low characteristic surface energy. In some non-limiting examples, at least one of the materials of the patterning coating 310, including without limitation, the first material, and the second material, may have a low characteristic surface energy, and at least one of the materials of the patterning coating 310 may comprise at least one of: F, and Si. In some non-limiting examples, at least one of the materials of the patterning coating 310, including without limitation, at least one of: the first material, and the second material, may have a low characteristic surface energy, may comprise at least one of: F, and Si, and at least one other material of the patterning coating 310 may have a high characteristic surface energy. In some non-limiting examples, the presence of F and Si may be accounted for by the presence of a fluorocarbon moiety and a siloxane moiety, respectively. In some non-limiting examples, at least one of the materials, including without limitation, the second material, may have a low characteristic surface energy of one of between about: 10-20 dynes/cm, 12-20 dynes/cm, 15-20 dynes/cm, and 17-19 dynes/cm, and another material, including without limitation, the first material, may have a high characteristic surface energy of one of between about: 20-100 dynes/cm, 20-50 dynes/cm, and 25-45 dynes/cm. In some non-limiting examples, at least one of the materials may comprise at least one of: F, and Si. In some non-limiting examples, the second material may comprise at least one of: F, and Si.

In some non-limiting examples, at least one of the materials of the patterning coating 310, including without limitation, the second material, may have a low characteristic surface energy of no more than about 20 dynes/cm and may comprise at least one of: at least one of: F, and Si, and another material, including without limitation, the first material, may have a characteristic surface energy of at least about 20 dynes/cm.

In some non-limiting examples, at least one of the materials of the patterning coating 310, including without limitation, the second material, may have a low characteristic surface energy of no more than about 20 dynes/cm and may comprise at least one of: a fluorocarbon moiety, and a siloxane moiety, and another material of the patterning coating 310, including without limitation, the first material, may have a characteristic surface energy of at least about 20 dynes/cm.

In some non-limiting examples, the surface energy of each of the at least two materials of the patterning coating 310, including, without limitation, those of the first material and the second material, is one of no more about: 25 dynes/cm, 21 dynes/cm, 20 dynes/cm, 19 dynes/cm, 18 dynes/cm, 17 dynes/cm, 16 dynes/cm, 15 dynes/cm, 14 dynes/cm, 13 dynes/cm, 12 dynes/cm, 11 dynes/cm, and 10 dynes/cm.

In some non-limiting examples, a refractive index at a wavelength at least one of: 500 nm, and 460 nm, of at least one of the materials of the patterning coating 310, including without limitation, at least one of: the first material, and the second material, may be one of no more than about: 1.5, 1.45, 1.44, 1.43, 1.42, and 1.41. In some non-limiting examples, the patterning coating 310 may comprise at least one material that exhibits photoluminescence, and the patterning coating 310 may have a refractive index, at a wavelength of at least one of: 500 nm, and 460 nm, of one of no more than about: 1.5, 1.45, 1.44, 1.43, 1.42, and 1.41.

In some non-limiting examples, a molecular weight of at least one of the materials of the patterning coating 310, including without limitation, at least one of: the first material, and the second material, may be one of at least about: 750 g/mol, 1,000 g/mol, 1,500 g/mol, 2,000 g/mol, 2,500 g/mol, and 3,000 g/mol.

In some non-limiting examples, a molecular weight of at least one of the materials of the patterning coating 310, including without limitation, at least one of: the first material, and the second material, may be one of no more than about: 10,000 g/mol, 7,500 g/mol, and 5,000 g/mol.

In some non-limiting examples, the patterning coating 310 may comprise a plurality of materials exhibiting similar thermal properties, wherein at least one of the materials may exhibit photoluminescence. In some non-limiting examples, the patterning coating 310 may comprise a plurality of materials with similar thermal properties, wherein at least one of the materials may photoluminescence, and wherein at least one of the materials, may comprise at least one of: F, and Si. In some non-limiting examples, the patterning coating 310 may comprise a plurality of materials with similar thermal properties, including without limitation, at least one of: a melting temperature, and a sublimation temperature, of the materials, wherein at least one of the materials may exhibit photoluminescence at a wavelength of at least about 365 nm when excited by a radiation having an excitation wavelength of about 365 nm, and wherein at least one of the materials may comprise at least one of: F, and Si.

In some non-limiting examples, the patterning coating 310 may comprise a plurality of having at least one of: at least one element in common, and at least one sub-structure in common, wherein at least one of the materials may exhibit photoluminescence. In some non-limiting examples, at least one of the materials may comprise F and Si. In some non-limiting examples, the patterning coating 310 may comprise a plurality of materials with similar thermal properties, wherein at least one of the materials may exhibit photoluminescence at a wavelength that is at least about 365 nm when excited by a radiation having an excitation wavelength of about 365 nm, and wherein at least one of the materials may comprise at least one of: F, and Si. In some non-limiting examples, the at least one element in common may comprise at least one of: F, and Si. In some non-limiting examples, the at least one sub-structure in common may comprise at least one of: fluorocarbon, fluoroalkyl, and siloxyl.

In some non-limiting examples, a method for manufacturing an opto-electronic device 2100 may comprise actions of: depositing a patterning coating on a first exposed layer surface 11 of the device 2100 in a first portion 1901 of a lateral aspect thereof; and depositing a deposited material 2431 on a second exposed layer surface 11 of the device 2100 in a second portion 1902 of the lateral aspect thereof. An initial sticking probability against deposition of the deposited material 2431 onto an exposed layer surface 11 of the patterning coating 310 in the first portion 1901, may be substantially less than the initial sticking probability against deposition of the deposited material 2431 onto an exposed layer surface 11 in the second portion 1902, such that the exposed layer surface 11 of the patterning coating 310 in the first portion 1901 may be substantially devoid of a closed coating 2140 of the deposited material 2431. The patterning coating 310 deposited on the first exposed layer surface 11 of the device 2100 may comprises a first material and a second material.

In some non-limiting examples, depositing the patterning coating 310 on the first exposed layer surface 11 of the device 2100 may comprise providing a mixture comprising a plurality of materials, and causing the mixture to be deposited onto the first exposed layer surface 11 of the device 2100 to form the patterning coating 310 thereon. In some non-limiting examples, the mixture may comprise the first material and the second material. In some non-limiting examples, the first material and the second material may both be deposited onto the first exposed layer surface 11 to form the patterning coating 310 thereon.

In some non-limiting examples, the mixture comprising the plurality of materials may be deposited onto the first exposed layer surface 11 of the device 2100 by a PVD process, including without limitation, thermal evaporation. In some non-limiting examples, the patterning coating 310 may be formed by evaporating the mixture from a single evaporation source and causing the mixture to be deposited on the first exposed layer surface 11 of the device 2100. In some non-limiting examples, the mixture comprising, in some non-limiting examples, the first material and the second material, may be placed in a single evaporation source (crucible) to be heated under vacuum. Once the evaporation temperature of the materials is reached, a vapor flux generated therefrom may be directed towards the first exposed layer surface 11 of the device 2100 to cause the deposition of the patterning coating 310 thereon.

In some non-limiting examples, the patterning coating 310 may be deposited by co-evaporation of the first material and the second material. In some non-limiting examples, the first material may be evaporated from a first evaporation source, and the second material may be concurrently evaporated from a second evaporation source such that the mixture may be formed in the vapor phase and may be co-deposited onto the first exposed layer surface 11 to provide the patterning coating 310 thereon.

In order to evaluate properties of certain example patterning coatings 310 comprising at least two materials, a series of samples were fabricated by depositing, in vacuo, an approximately 20 nm thick layer of an organic material that may be used as an HTL material, followed by depositing, over the organic material layer, a nucleation modifying coating having varying compositions as summarized in Table 6 below.

TABLE 6

| Sample Identifier | Composition of Nucleation Modifying Coating |
|---|---|
| Sample 1 | Patterning Material (15 nm) |
| Sample 2 | Patterning Material: PL Material 1 (0.5%, 15 nm) |
| Sample 3 | Patterning Material: PL Material 2 (0.5%, 15 nm) |
| Sample 4 | PL Material 1 (10 nm) |
| Sample 5 | PL Material 2 (10 nm) |
| Sample 6 | No nucleation modifying coating provided |

In the present example, the patterning material was selected such that, for example when deposited as a thin film, the patterning material exhibits a low initial sticking probability against deposition of the deposited material(s) 2431, including without limitation, at least one of: Ag, and Yb.

In the present example, PL Material 1 and PL Material 2 were selected such that, in some non-limiting examples, when deposited as a thin film, each of PL Material 1 and PL Material 2 may exhibit photoluminescence detectable by standard optical measurement techniques including without limitation, fluorescence microscopy.

In Table 6, Sample 1 is a comparison sample in which the nucleation modifying coating was provided by depositing the Patterning Material. Sample 2 is an example sample in which the nucleation modifying coating was provided by co-depositing the Patterning Material and PL Material 1 together to form a coating comprising PL Material 1 in a concentration of 0.5 vol. %. Sample 3 is an example sample in which the nucleation modifying coating was provided by co-depositing the Patterning Material and PL Material 2 to form a coating comprising PL Material 2 in a concentration of 0.5 vol. %. Sample 4 is a comparison sample in which the nucleation modifying coating was provided by depositing PL Material 1. Sample 5 is a comparison sample in which the nucleation modifying coating was provided by depositing PL Material 2. Sample 6 is a comparison sample in which no nucleation modifying coating was provided over the organic material layer.

The photoluminescence (PL) response of each of Sample 1, Sample 2, Sample 3, and Sample 6 were measured. It was observed that the PL intensities of Sample 1 and Sample 6 were identical, thus indicating that the Patterning Material does not exhibit photoluminescence in the detected wavelength range. For each of Sample 2 and Sample 3, photoluminescence was detected in wavelengths of around 500 nm to about 600 nm.

Each of Samples 1 to 6 was then subjected to an open mask deposition of Yb, followed by Ag. Specifically, the surfaces of the nucleation modifying coatings formed by the above materials were subjected to an open mask deposition of Yb, followed by Ag. More specifically, each sample was subjected to a Yb vapor flux until a reference thickness of about 1 nm was reached, followed by an Ag vapor flux until a reference thickness of about 12 nm was reached. Once the samples were fabricated, optical transmission measurements were taken to determine the amount of at least one of: Yb, and Ag, deposited on the exposed layer surface 11 of the nucleation modifying coatings. Those having ordinary skill in the relevant art will appreciate that samples having little to no metal present thereon may be substantially transparent, while samples with metal deposited thereon, particularly as a closed coating 2140, may generally exhibit a substantially lower light transmittance. Accordingly, the performance of various example coatings as a patterning coating 310 may be assessed by measuring the light transmission, which may directly correlate to an amount (thickness) of metallic deposited material deposited thereon from deposition of either of both of Yb and Ag.

The reduction in optical transmittance as a function of wavelength of each of Sample 1, Sample 2, Sample 3, Sample 4, Sample 5, and Sample 6 were measured. Additionally, a reduction in optical transmittance at a wavelength of 600 nm after each sample was subjected to an Ag vapor flux was measured and summarized in Table 7 below:

TABLE 7

| Sample Identifier | Transmittance Reduction (%) at λ = 600 nm |
|---|---|
| Sample 1 | <1% |
| Sample 2 | <2% |
| Sample 3 | <1% |
| Sample 4 | 43% |
| Sample 5 | 47% |
| Sample 6 | 45% |

Specifically, the transmittance reduction (%) for each sample in Table 7 was determined by measuring the light transmission through the sample before and after the exposure to the Yb and Ag vapor flux and expressing the reduction in the light transmittance as a percentage.

As may be seen, Sample 1, Sample 2, and Sample 3 exhibited a substantially low transmittance reduction of less than 2%, and in the case of Samples 1 and 3, less than 1%. Accordingly, it may be observed that the nucleation modifying coatings provided for these samples acted as an NIC. By contrast, Sample 4, Sample 5, and Sample 6 each exhibited a transmittance reduction of 43%, 47%, and 45%, respectively. Accordingly, the nucleation modifying coatings provided for these samples did not act as an NIC but may have indeed acted as an NPC 2620.

Moreover, it was found that Sample 1, in which the patterning coating 310 was comprised of substantially only the NIC Material, did not exhibit photoluminescence. However, Sample 2 and Sample 3 in which the patterning coating 310 comprised PL Material 1 and PL Material 2, respectively, in addition to the NIC material, were found to exhibit photoluminescence while also acting as an NIC by providing a surface with low initial sticking probability against the deposition of the deposited material 2431.

### Deposited Layer

In some non-limiting examples, where the patterning coating 310 is restricted in its lateral extent to the first portion 1901, in the second portion 1902 of the lateral aspect of the device 2100, a deposited layer 331 comprising a deposited material 2431 may be disposed as a closed coating 2140 on an exposed layer surface 11 of the underlying layer 2610.

In some non-limiting examples, the deposited layer 331 may comprise a deposited material 2431.

In some non-limiting examples, the deposited material 2431 may comprise an element selected from at least one of: potassium (K), sodium (Na), lithium (Li), Ba, cesium (Cs), Yb, Ag, gold (Au), Cu, Al, Mg, Zn, Cd, tin (Sn), and yttrium (Y). In some non-limiting examples, the element may comprise at least one of: K, Na, Li, Ba, Cs, Yb, Ag, Au, Cu, Al, and Mg. In some non-limiting examples, the element may comprise at least one of: Cu, Ag, and Au. In some non-limiting examples, the element may be Cu. In some non-limiting examples, the element may be Al. In some non-limiting examples, the element may comprise at least one of: Mg, Zn, Cd, and Yb. In some non-limiting examples, the element may comprise at least one of: Mg, Ag, Al, Yb, and Li. In some non-limiting examples, the element may comprise at least one of: Mg, Ag, and Yb. In some non-limiting examples, the element may comprise at least one of: Mg, and Ag. In some non-limiting examples, the element may be Ag.

In some non-limiting examples, the deposited material 2431 may comprise a pure metal. In some non-limiting examples, the deposited material 2431 may be (substantially) pure Ag. In some non-limiting examples, the substantially pure Ag may have a purity of one of at least about: 95%, 99%, 99.9%, 99.99%, 99.999%, and 99.9995%. In some non-limiting examples, the deposited material 2431 may be (substantially) pure Mg. In some non-limiting examples, the substantially pure Mg may have a purity of one of at least about: 95%, 99%, 99.9%, 99.99%, 99.999%, and 99.9995%.

In some non-limiting examples, the deposited material 2431 may comprise an alloy. In some non-limiting examples, the alloy may be one of: an Ag-containing alloy, an Mg-containing alloy, and an AgMg-containing alloy. In some non-limiting examples, the AgMg-containing alloy may have an alloy composition that may range from about 1:10 (Ag:Mg) to about 10:1 by volume.

In some non-limiting examples, the deposited material 2431 may comprise other metals in one of: in place of, and in combination with, Ag. In some non-limiting examples, the deposited material 2431 may comprise an alloy of Ag with at least one other metal. In some non-limiting examples, the deposited material 2431 may comprise an alloy of Ag with at least one of: Mg, and Yb. In some non-limiting examples, such alloy may be a binary alloy having a composition between about 5-95 vol. % Ag, with the remainder being the other metal. In some non-limiting examples, the deposited material 2431 may comprise Ag and Mg. In some non-limiting examples, the deposited material 2431 may comprise an Ag:Mg alloy having a composition between about 1:10-10:1 by volume. In some non-limiting examples, the deposited material 2431 may comprise Ag and Yb. In some non-limiting examples, the deposited material 2431 may comprise a Yb:Ag alloy having a composition between about 1:20-10:1 by volume. In some non-limiting examples, the deposited material 2431 may comprise Mg and Yb. In some non-limiting examples, the deposited material 2431 may comprise an Mg:Yb alloy. In some non-limiting examples, the deposited material 2431 may comprise Ag, Mg, and Yb. In some non-limiting examples, the deposited layer 331 may comprise an Ag:Mg:Yb alloy.

In some non-limiting examples, the deposited layer 331 may comprise at least one additional element. In some non-limiting examples, such additional element may be a non-metallic element. In some non-limiting examples, the non-metallic element may be at least one of: O, S, N, and C. It will be appreciated by those having ordinary skill in the relevant art that, in some non-limiting examples, such additional element(s) may be incorporated into the deposited layer 331 as a contaminant, due to the presence of such additional element(s) in at least one of: the source material, equipment used for deposition, and the vacuum chamber environment. In some non-limiting examples, the concentration of such additional element(s) may be limited to be below a threshold concentration. In some non-limiting examples, such additional element(s) may form a compound together with other element(s) of the deposited layer 331. In some non-limiting examples, a concentration of the non-metallic element in the deposited material 2431 may be one of no more than about: 1%, 0.1%, 0.01%, 0.001%, 0.0001%, 0.00001%, 0.000001%, and 0.0000001%. In some non-limiting examples, the deposited layer 331 may have a composition in which a combined amount of O and C therein may be one of no more than about: 10%, 5%, 1%, 0.1%, 0.01%, 0.001%, 0.0001%, 0.00001%, 0.000001%, and 0.0000001%.

It has now been found, that reducing a concentration of certain non-metallic elements in the deposited layer 331, particularly in cases wherein the deposited layer 331 may be substantially comprised of at least one of: metal(s), and metal alloy(s), may facilitate selective deposition of the deposited layer 331. Without wishing to be bound by any particular theory, it may be postulated that certain non-metallic elements, such as, in some non-limiting examples, at least one of: O, and C, when present in the vapor flux 2432 of at least one of: the deposited layer 331, in the deposition chamber, and the environment, may be deposited onto the surface of the patterning coating 310 to act as nucleation sites for the metallic element(s) of the deposited layer 331. It may be postulated that reducing a concentration of such non-metallic elements that could act as nucleation sites may facilitate reducing an amount of deposited material 2431 deposited on the exposed layer surface 11 of the patterning coating 310.

In some non-limiting examples, the deposited material 2431 may be deposited on a metal-containing underlying layer 2610. In some non-limiting examples, the deposited material 2431 and the underlying layer 2610 thereunder may comprise a metal in common.

In some non-limiting examples, the deposited layer 331 may comprise a plurality of layers of the deposited material 2431. In some non-limiting examples, the deposited material 2431 of a first one of the plurality of layers may be different from the deposited material 2431 of a second one of the plurality of layers. In some non-limiting examples, the deposited layer 331 may comprise a multilayer coating. In some non-limiting examples, such multilayer coating may be one of: Yb/Ag, Yb/Mg, Yb/Mg:Ag, Yb/Yb:Ag, Yb/Ag/Mg, and Yb/Mg/Ag.

In some non-limiting examples, the deposited material 2431 may comprise a metal having a bond dissociation energy, of one of no more than about: 300 kJ/mol, 200 kJ/mol, 165 kJ/mol, 150 kJ/mol, 100 kJ/mol, 50 kJ/mol, and 20 kJ/mol.

In some non-limiting examples, the deposited material 2431 may comprise a metal having an electronegativity that is one of no more than about: 1.4, 1.3, and 1.2.

In some non-limiting examples, a sheet resistance of the deposited layer 331 may generally correspond to a sheet resistance of the deposited layer 331, measured in isolation from other components, layers, and parts of the device 2100. In some non-limiting examples, the deposited layer 331 may be formed as a thin film. Accordingly, in some non-limiting examples, the characteristic sheet resistance for the deposited layer 331 may be determined based on at least one of: the composition, thickness, and morphology, of such thin film. In some non-limiting examples, the sheet resistance may be one of no more than about: 10Ω/□, 5Ω/□, 1Ω/□, 0.5 Ω/□, 0.2 Ω/□, and 0.1 Ω/□.

In some non-limiting examples, the deposited layer 331 may be disposed in a pattern that may be defined by at least one region therein that is substantially devoid of a closed coating 2140 of the deposited layer 331. In some non-limiting examples, the at least one region may separate the deposited layer 331 into a plurality of discrete fragments thereof. In some non-limiting examples, each discrete fragment of the deposited layer 331 may be a distinct second portion 1902.

In some non-limiting examples, the plurality of discrete fragments of the deposited layer 331 may be physically spaced apart from one another in the lateral aspect thereof. In some non-limiting examples, at least two of such plurality of discrete fragments of the deposited layer 331 may be electrically coupled. In some non-limiting examples, at least two of such plurality of discrete fragments of the deposited layer 331 may be each electrically coupled with a common conductive coating, including without limitation, the underlying layer 2610, to allow the flow of electrical current between them. In some non-limiting examples, at least two of such plurality of discrete fragments of the deposited layer 331 may be electrically insulated from one another.

### Selective Deposition Using Patterning Coatings

FIG. 23 is an example schematic diagram illustrating a non-limiting example of an evaporative deposition process, shown generally at 2300, in a chamber 2320, for selectively depositing a patterning coating 310 onto a first portion 1901 of an exposed layer surface 11 of the underlying layer 2610.

In the process 2300, a quantity of a patterning material 2311 may be heated under vacuum, to evaporate (sublime) the patterning material 2311. In some non-limiting examples, the patterning material 2311 may comprise substantially (including without limitation, entirely), a material used to form the patterning coating 310. In some non-limiting examples, such material may comprise an organic material.

An evaporated flux 2312 of the patterning material 2311 may flow through the chamber 2320, including in a direction indicated by arrow 2301, toward the exposed layer surface 11. When the evaporated flux 2312 is incident on the exposed layer surface 11, the patterning coating 310 may be formed thereon.

In some non-limiting examples, as shown in the figure for the process 2300, the patterning coating 310 may be selectively deposited only onto a portion, in the example illustrated, the first portion 1901, of the exposed layer surface 11 of the underlying layer 2610, by the interposition, between the vapor flux 2312 and the exposed layer surface 11 of the underlying layer 2610, of a shadow mask 2315, which in some non-limiting examples, may be an FMM. In some non-limiting examples, such a shadow mask 2315 may, in some non-limiting examples, be used to form substantially small features, with a feature size on the order of (smaller than) tens of microns.

The shadow mask 2315 may have at least one aperture 2316 extending therethrough such that a part of the evaporated flux 2312 passes through the aperture 2316 and may be incident on the exposed layer surface 11 to form the patterning coating 310. Where the evaporated flux 2312 does not pass through the aperture 2316 but is incident on a surface 2317 of the shadow mask 2315, it is precluded from being disposed on the exposed layer surface 11 to form the patterning coating 310. In some non-limiting examples, the shadow mask 2315 may be configured such that the evaporated flux 2312 that passes through the aperture 2316 may be incident on the first portion 1901 but not the second portion 1902. The second portion 1902 of the exposed layer surface 11 may thus be substantially devoid of the patterning coating 310. In some non-limiting examples (not shown), the patterning material 2311 that is incident on the shadow mask 2315 may be deposited on the surface 2317 thereof.

Accordingly, a patterned surface may be produced upon completion of the deposition of the patterning coating 310.

FIG. 24 is an example schematic diagram illustrating a non-limiting example of a result of an evaporative process, shown generally at 2400ₐ, in a chamber 2320, for selectively depositing a closed coating 2140 of a deposited layer 331 onto the second portion 1902 of an exposed layer surface 11 of the underlying layer 2610 that is substantially devoid of the patterning coating 310 that was selectively deposited onto the first portion 1901, including without limitation, by the evaporative process 2300 of FIG. 23.

In some non-limiting examples, the deposited layer 331 may be comprised of a deposited material 2431, in some non-limiting examples, comprising at least one metal. It will be appreciated by those having ordinary skill in the relevant art that, in some non-limiting examples, a vaporization temperature of an organic material is low relative to the vaporization temperature of metals, such as may be employed as a deposited material 2431.

Thus, in some non-limiting examples, there may be fewer constraints in employing a shadow mask 2315 to selectively deposit a patterning coating 310 in a pattern, relative to directly patterning the deposited layer 331 using such shadow mask 2315.

Once the patterning coating 310 has been deposited on the first portion 1901 of the exposed layer surface 11 of the underlying layer 2610, a closed coating 2140 of the deposited material 2431 may be deposited, on the second portion 1902 of the exposed layer surface 11 that is substantially devoid of the patterning coating 310, as the deposited layer 331.

In the process 2400ₐ, a quantity of the deposited material 2431 may be heated under vacuum, to sublime the deposited material 2431. In some non-limiting examples, the deposited material 2431 may be comprised of substantially, including without limitation, entirely, a material used to form the deposited layer 331.

An evaporated flux 2432 of the deposited material 2431 may be directed inside the chamber 2320, including in a direction indicated by arrow 2401, toward the exposed layer surface 11 of the first portion 1901 and of the second portion 1902. When the evaporated flux 2432 is incident on the second portion 1902 of the exposed layer surface 11, a closed coating 2140 of the deposited material 2431 may be formed thereon as the deposited layer 331.

In some non-limiting examples, deposition of the deposited material 2431 may be performed using one of: an open mask, and a mask-free, deposition process.

It will be appreciated by those having ordinary skill in the relevant art that, contrary to that of a shadow mask 2315, the feature size of an open mask may be generally comparable to the size of a device 2100 being manufactured.

It will be appreciated by those having ordinary skill in the relevant art that, in some non-limiting examples, the use of an open mask may be omitted. In some non-limiting examples, an open mask deposition process described herein may alternatively be conducted without the use of an open mask, such that an entire target exposed layer surface 11 may be exposed.

Indeed, as shown in FIG. 24, the evaporated flux 2432 may be incident both on an exposed layer surface 11 of the patterning coating 310 across the first portion 1901 as well as the exposed layer surface 11 of the underlying layer 2610 across the second portion 1902 that is substantially devoid of the patterning coating 310.

Since the exposed layer surface 11 of the patterning coating 310 in the first portion 1901 may exhibit a substantially low initial sticking probability against the deposition of the deposited material 2431 relative to the exposed layer surface 11 of the underlying layer 2610 in the second portion 1902, the deposited layer 331 may be selectively deposited substantially only on the exposed layer surface 11, of the underlying layer 2610 in the second portion 1902, that is substantially devoid of the patterning coating 310. By contrast, the evaporated flux 2432 incident on the exposed layer surface 11 of the patterning coating 310 across the first portion 1901 may tend to not be deposited (as shown 2433), and the exposed layer surface 11 of the patterning coating 310 across the first portion 1901 may be substantially devoid of a closed coating 2140 of the deposited layer 331.

In some non-limiting examples, an initial deposition rate, of the evaporated flux 2432 on the exposed layer surface 11 of the underlying layer 2610 in the second portion 1902, may exceed one of about: 200, 550, 900, 1,000, 1,500, 1,900, and 2,000 times an initial deposition rate of the evaporated flux 2432 on the exposed layer surface 11 of the patterning coating 310 in the first portion 1901.

Thus, the combination of the selective deposition of a patterning coating 310 in FIG. 23 using a shadow mask 2315 and at least one of: the open mask, and a mask-free, deposition of the deposited material 2431 may result in a version 2400ₐ of the device 2100 shown in FIG. 24.

After selective deposition of the patterning coating 310 across the first portion 1901, a closed coating 2140 of the deposited material 2431 may be deposited over the device 2400ₐ as the deposited layer 331, in some non-limiting examples, using one of: an open mask, and a mask-free, deposition process, but may remain substantially only within the second portion 1902, which is substantially devoid of the patterning coating 310.

The patterning coating 310 may provide, within the first portion 1901, an exposed layer surface 11 with a substantially low initial sticking probability, against the deposition of the deposited material 2431, and that is substantially less than the initial sticking probability, against the deposition of the deposited material 2431, of the exposed layer surface 11 of the underlying layer 2610 of the device 2400ₐ within the second portion 1902.

Thus, the first portion 1901 may be substantially devoid of a closed coating 2140 of the deposited material 2431.

While the present disclosure contemplates the patterned deposition of the patterning coating 310 by an evaporative deposition process, involving a shadow mask 2315, those having ordinary skill in the relevant art will appreciate that, in some non-limiting examples, this may be achieved by any applicable deposition process, including without limitation, a micro-contact printing process.

While the present disclosure contemplates the patterning coating 310 being an NIC, those having ordinary skill in the relevant art will appreciate that, in some non-limiting examples, the patterning coating 310 may be an NPC 2620. In such examples, the portion (such as, without limitation, the first portion 1901) in which the NPC 2620 has been deposited may, in some non-limiting examples, have a closed coating 2140 of the deposited material 2431, while the other portion (such as, without limitation, the second portion 1902) may be substantially devoid of a closed coating 2140 of the deposited material 2431.

In some non-limiting examples, an average layer thickness of the patterning coating 310 and of the deposited layer 331 deposited thereafter may be varied according to a variety of parameters, including without limitation, a given application and given performance characteristics. In some non-limiting examples, the average layer thickness of the patterning coating 310 may be comparable to, including without limitation, substantially no more than, an average layer thickness of the deposited layer 331 deposited thereafter. Use of a substantially thin patterning coating 310 to achieve selective patterning of a deposited layer 331 may have applicability to provide flexible devices 100.

In some non-limiting examples, the device 2200 may further comprise an NPC 2620 disposed between the patterning coating 310 and the second electrode 340.

In some non-limiting examples, the patterning coating 310 may be formed concurrently with the at least one semiconducting layer(s) 330. In some non-limiting examples, at least one material used to form the patterning coating 310 may also be used to form the at least one semiconducting layer(s) 330 to reduce a number of stages for fabricating the device 2200.

### Edge Effects

### Patterning Coating Transition Region

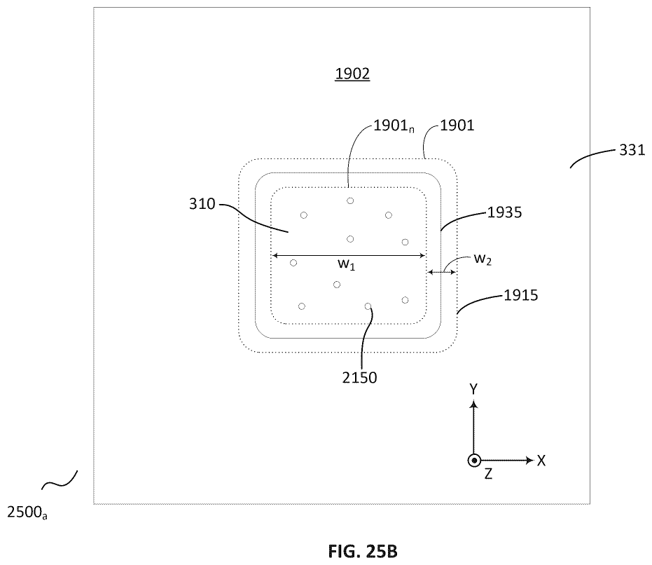

Turning to FIG. 25A, there may be shown a version 2500ₐ of the device 2100 of FIG. 21 that may show in exaggerated form, an interface between the patterning coating 310 in the first portion 1901 and the deposited layer 331 in the second portion 1902. FIG. 25B may show the device 2500ₐ in plan.

As may be better seen in FIG. 25B, in some non-limiting examples, the patterning coating 310 in the first portion 1901 may be surrounded on all sides by the deposited layer 331 in the second portion 1902, such that the first portion 1901 may have a boundary that is defined by the further edge 1915 of the patterning coating 310 in the lateral aspect along each lateral axis. In some non-limiting examples, the patterning coating edge 1915 in the lateral aspect may be defined by a perimeter of the first portion 1901 in such aspect.

In some non-limiting examples, the first portion 1901 may comprise at least one patterning coating transition region 1901ₜ, in the lateral aspect, in which a thickness of the patterning coating 310 may transition from a maximum thickness to a reduced thickness. The extent of the first portion 1901 that does not exhibit such a transition may be identified as a patterning coating non-transition part 1901ₙ of the first portion 1901. In some non-limiting examples, the patterning coating 310 may form a substantially closed coating 2140 in the patterning coating non-transition part 1901ₙ of the first portion 1901.

In some non-limiting examples, the patterning coating transition region 1901ₜ may extend, in the lateral aspect, between the patterning coating non-transition part 1901ₙ of the first portion 1901 and the patterning coating edge 1915.

In some non-limiting examples, in plan, the patterning coating transition region 1901ₜ may extend along a perimeter of the patterning coating non-transition part 1901ₙ of the first portion 1901.

In some non-limiting examples, along at least one lateral axis, the patterning coating non-transition part 1901ₙ may occupy the entirety of the first portion 1901, such that there is no patterning coating transition region 1901ₜ between it and the second portion 1902.

As illustrated in FIG. 25A, in some non-limiting examples, the patterning coating 310 may have an average film thickness d₂ in the patterning coating non-transition part 1901ₙ of the first portion 1901 that may be in a range of one of between about: 1-100 nm, 2-50 nm, 3-30 nm, 4-20 nm, 5-15 nm, 5-10 nm, and 1-10 nm. In some non-limiting examples, the average film thickness d₂ of the patterning coating 310 in the patterning coating non-transition part 1901ₙ of the first portion 1901 may be substantially the same (constant) thereacross. In some non-limiting examples, an average film thickness d₂ of the patterning coating 310 may remain, within the patterning coating non-transition part 1901ₙ, within one of about: 95%, and 90%, of the average film thickness d₂ of the patterning coating 310.

In some non-limiting examples, the average film thickness d₂ may be between about 1-100 nm. In some non-limiting examples, the average film thickness d₂ may be one of no more than about: 80 nm, 60 nm, 50 nm, 40 nm, 30 nm, 20 nm, 15 nm, and 10 nm. In some non-limiting examples, the average film thickness d₂ of the patterning coating 310 may be one of at least about: 3 nm, 5 nm, and 8 nm.

In some non-limiting examples, the average film thickness d₂ of the patterning coating 310 in the patterning coating non-transition part 1901ₙ of the first portion 1901 may be no more than about 10 nm. Without wishing to be bound by any particular theory, it has been found, that a non-zero average film thickness d₂ of the patterning coating 310 that is no more than about 10 nm may, at least in some non-limiting examples, provide certain advantages for achieving, in some non-limiting examples, enhanced patterning contrast of the deposited layer 331, relative to a patterning coating 310 having an average film thickness d₂ in the patterning coating non-transition part 1901ₙ of the first portion 1901 of at least about 10 nm.

In some non-limiting examples, the patterning coating 310 may have a patterning coating thickness that decreases from a maximum to a minimum within the patterning coating transition region 1901ₜ. In some non-limiting examples, the maximum may be proximate to a boundary between the patterning coating transition region 1901ₜ and the patterning coating non-transition part 1901ₙ of the first portion 1901. In some non-limiting examples, the minimum may be proximate to the patterning coating edge 1915. In some non-limiting examples, the maximum may be the average film thickness d₂ in the patterning coating non-transition part 1901ₙ of the first portion 1901. In some non-limiting examples, the maximum may be no more than one of about: 95%, and 90%, of the average film thickness d₂ in the patterning coating non-transition part 1901ₙ of the first portion 1901. In some non-limiting examples, the minimum may be in a range of between about 0-0.1 nm.

In some non-limiting examples, a profile of the patterning coating thickness in the patterning coating transition region 1901ₜ may be sloped. In some non-limiting examples, such profile may be tapered. In some non-limiting examples, the taper may follow one of: a linear, non-linear, parabolic, and exponential decaying, profile.

In some non-limiting examples, the patterning coating 310 may completely cover the underlying layer 2610 in the patterning coating transition region 1901ₜ. In some non-limiting examples, at least a part of the underlying layer 2610 may be left uncovered by the patterning coating 310 in the patterning coating transition region 1901ₜ. In some non-limiting examples, the patterning coating 310 may comprise a substantially closed coating 2140 in at least one of: at least a part of the patterning coating transition region 1901ₜ, and at least a part of the patterning coating non-transition part 1901ₙ.

In some non-limiting examples, the patterning coating 310 may comprise a discontinuous layer 2160 in at least one of: at least a part of the patterning coating transition region 1901ₜ, and at least a part of the patterning coating non-transition part 1901ₙ.

In some non-limiting examples, at least a part of the patterning coating 310 in the first portion 1901 may be substantially devoid of a closed coating 2140 of the deposited layer 331. In some non-limiting examples, at least a part of the exposed layer surface 11 of the first portion 1901 may be substantially devoid of a closed coating 2140 of one of: the deposited layer 331, and the deposited material 2431.

In some non-limiting examples, along at least one lateral axis, including without limitation, the X-axis, the patterning coating non-transition part 1901ₙ may have a width of w₁, and the patterning coating transition region 1901ₜ may have a width of w₂. In some non-limiting examples, the patterning coating non-transition part 1901ₙ may have a cross-sectional area that, in some non-limiting examples, may be approximated by multiplying the average film thickness d₂ by the width w₁. In some non-limiting examples, the patterning coating transition region 1901ₜ may have a cross-sectional area that, in some non-limiting examples, may be approximated by multiplying an average film thickness across the patterning coating transition region 1901ₜ by the width w₁.

In some non-limiting examples, w₁ may exceed w₂. In some non-limiting examples, a quotient of w₁/w₂ may be one of at least about: 5, 10, 20, 50, 100, 500, 1,000, 1,500, 5,000, 10,000, 50,000, and 100,000.

In some non-limiting examples, at least one of w₁ and w₂ may exceed the average film thickness d₁ of the underlying layer 2610.

In some non-limiting examples, at least one of w₁ and w₂ may exceed d₂. In some non-limiting examples, both w₁ and w₂ may exceed d₂. In some non-limiting examples, w₁ and w₂ both may exceed d₁, and d₁ may exceed d₂.

### Deposited Layer Transition Region

As may be better seen in FIG. 25B, in some non-limiting examples, the patterning coating 310 in the first portion 1901 may be surrounded by the deposited layer 331 in the second portion 1902 such that the second portion 1902 has a boundary that is defined by the further edge 1935 of the deposited layer 331 in the lateral aspect along each lateral axis. In some non-limiting examples, the deposited layer edge 1935 in the lateral aspect may be defined by a perimeter of the second portion 1902 in such aspect.

In some non-limiting examples, the second portion 1902 may comprise at least one deposited layer transition region 1902ₜ, in the lateral aspect, in which a thickness of the deposited layer 331 may transition from a maximum thickness to a reduced thickness. The extent of the second portion 1902 that does not exhibit such a transition may be identified as a deposited layer non-transition part 1902ₙ of the second portion 1902. In some non-limiting examples, the deposited layer 331 may form a substantially closed coating 2140 in the deposited layer non-transition part 1902ₙ of the second portion 1902.

In some non-limiting examples, in plan, the deposited layer transition region 1902ₜ may extend, in the lateral aspect, between the deposited layer non-transition part 1902ₙ of the second portion 1902 and the deposited layer edge 1935.

In some non-limiting examples, in plan, the deposited layer transition region 1902ₜ may extend along a perimeter of the deposited layer non-transition part 1902ₙ of the second portion 1902.

In some non-limiting examples, along at least one lateral axis, the deposited layer non-transition part 1902ₙ of the second portion 1902 may occupy the entirety of the second portion 1902, such that there is no deposited layer transition region 1902ₜ between it and the first portion 1901.

As illustrated in FIG. 25A, in some non-limiting examples, the deposited layer 331 may have an average film thickness d₃ in the deposited layer non-transition part 1902ₙ of the second portion 1902 that may be in a range of one of between about: 1-500 nm, 5-200 nm, 5-40 nm, 10-30 nm, and 10-100 nm. In some non-limiting examples, d₃ may exceed one of about: 10 nm, 50 nm, and 100 nm. In some non-limiting examples, the average film thickness d₃ of the deposited layer 331 in the deposited layer non-transition part 1902ₜ of the second portion 1902 may be substantially the same (constant) thereacross.

In some non-limiting examples, d₃ may exceed the average film thickness d₁ of the underlying layer 2610.

In some non-limiting examples, a quotient d₃/d₁ may be one of at least about: 1.5, 2, 5, 10, 20, 50, and 100. In some non-limiting examples, the quotient d₃/d₁ may be in a range of one of between about: 0.1-10, and 0.2-40.

In some non-limiting examples, d₃ may exceed an average film thickness d₂ of the patterning coating 310.

In some non-limiting examples, a quotient d₃/d₂ may be one of at least about: 1.5, 2, 5, 10, 20, 50, and 100. In some non-limiting examples, the quotient d₃/d₂ may be in a range of one of between about: 0.2-10, and 0.5-40.

In some non-limiting examples, d₃ may exceed d₂ and d₂ may exceed d₁. In some non-limiting examples, d₃ may exceed d₁ and d₁ may exceed d₂.

In some non-limiting examples, a quotient d₂/d₁ may be between one of about: 0.2-3, and 0.1-5.

In some non-limiting examples, along at least one lateral axis, including without limitation, the X-axis, the deposited layer non-transition part 1902ₙ of the second portion 1902 may have a width of w₃. In some non-limiting examples, the deposited layer non-transition part 1902ₙ of the second portion 1902 may have a cross-sectional area 3 that, in some non-limiting examples, may be approximated by multiplying the average film thickness d₃ by the width w₃.

In some non-limiting examples, w₃ may exceed the width w₁ of the patterning coating non-transition part 1901ₙ. In some non-limiting examples, w₁ may exceed w₃.

In some non-limiting examples, a quotient w₁/w₃ may be in a range of one of between about: 0.1-10, 0.2-5, 0.3-3, and 0.4-2. In some non-limiting examples, a quotient w₃/w₁ may be one of at least about: 1, 2, 3, and 4.

In some non-limiting examples, w₃ may exceed the average film thickness d₃ of the deposited layer 331.

In some non-limiting examples, a quotient w₃/d₃ may be one of at least about: 10, 50, 100, and 500. In some non-limiting examples, the quotient w₃/d₃ may be no more than about 100,000.

In some non-limiting examples, the deposited layer 331 may have a thickness that decreases from a maximum to a minimum within the deposited layer transition region 1902ₜ. In some non-limiting examples, the maximum may be proximate to the boundary between the deposited layer transition region 1902ₜ and the deposited layer non-transition part 1902ₙ of the second portion 1902. In some non-limiting examples, the minimum may be proximate to the deposited layer edge 1935. In some non-limiting examples, the maximum may be the average film thickness d₃ in the deposited layer non-transition part 1902ₙ of the second portion 1902. In some non-limiting examples, the minimum may be in a range of between about 0-0.1 nm. In some non-limiting examples, the minimum may be the average film thickness d₃ in the deposited layer non-transition part 1902ₙ of the second portion 1902.

In some non-limiting examples, a profile of the thickness in the deposited layer transition region 1902ₜ may be sloped. In some non-limiting examples, such profile may be tapered. In some non-limiting examples, the taper may follow a linear, non-linear, parabolic, and exponential decaying, profile.

In some non-limiting examples, although not shown, the deposited layer 331 may completely cover the underlying layer 2610 in the deposited layer transition region 1902ₜ. In some non-limiting examples, the deposited layer 331 may comprise a substantially closed coating 2140 in at least a part of the deposited layer transition region 1902ₜ. In some non-limiting examples, at least a part of the underlying layer 2610 may be uncovered by the deposited layer 331 in the deposited layer transition region 1902ₜ.

In some non-limiting examples, the deposited layer 331 may comprise a discontinuous layer 2160 in at least a part of the deposited layer transition region 1902ₜ.

Those having ordinary skill in the relevant art will appreciate that, although not shown, the patterning material 2311 may also be present to some extent at an interface between the deposited layer 331 and an underlying layer 2610. Such material may be deposited as a result of a shadowing effect, in which a deposited pattern is not identical to a pattern of a mask and may, in some non-limiting examples, result in some evaporated patterning material 2311 being deposited on a masked part of a target exposed layer surface 11. In some non-limiting examples, such material may form as at least one of: particle structures 2150, and as a thin film having a thickness that may be substantially no more than an average thickness of the patterning coating 310.

### Overlap

In some non-limiting examples, although not shown, the deposited layer edge 1935 may be spaced apart, in the lateral aspect from the patterning coating transition region 1901ₜ of the first portion 1901, such that there is no overlap between the first portion 1901 and the second portion 1902 in the lateral aspect.

In some non-limiting examples, at least a part of the first portion 1901 and at least a part of the second portion 1902 may overlap in the lateral aspect. Such overlap may be identified by an overlap portion 2503, such as may be shown in some non-limiting examples in FIG. 25A, in which at least a part of the second portion 1902 overlaps at least a part of the first portion 1901.

In some non-limiting examples, although not shown, at least a part of the deposited layer transition region 1902ₜ may be disposed over at least a part of the patterning coating transition region 1901ₜ. In some non-limiting examples, at least a part of the patterning coating transition region 1901ₜ may be substantially devoid of at least one of: the deposited layer 331, and the deposited material 2431. In some non-limiting examples, the deposited material 2431 may form a discontinuous layer 2160 on an exposed layer surface 11 of at least a part of the patterning coating transition region 1901ₜ.

In some non-limiting examples, although not shown, at least a part of the deposited layer transition region 1902ₜ may be disposed over at least a part of the patterning coating non-transition part 1901ₙ of the first portion 1901.

Although not shown, those having ordinary skill in the relevant art will appreciate that, in some non-limiting examples, the overlap portion 2503 may reflect a scenario in which at least a part of the first portion 1901 overlaps at least a part of the second portion 1902.

Thus, in some non-limiting examples, at least a part of the patterning coating transition region 1901ₜ may be disposed over at least a part of the deposited layer transition region 1902ₜ. In some non-limiting examples, at least a part of the deposited layer transition region 1902ₜ may be substantially devoid of at least one of: at least one of: the patterning coating 310, and the patterning material 2311. In some non-limiting examples, the patterning material 2311 may form a discontinuous layer 2160 on an exposed layer surface of at least a part of the deposited layer transition region 1902ₜ.

In some non-limiting examples, at least a part of the patterning coating transition region 1901ₜ may be disposed over at least a part of the deposited layer non-transition part 1902ₙ of the second portion 1902.

In some non-limiting examples, the patterning coating edge 1915 may be spaced apart, in the lateral aspect, from the deposited layer non-transition part 1902ₙ of the second portion 1902.

In some non-limiting examples, the deposited layer 331 may be formed as a single monolithic coating across both the deposited layer non-transition part 1902ₙ and the deposited layer transition region 1902ₜ of the second portion 1902.

In some non-limiting examples, at least one deposited layer 331, including without limitation, an initial deposited layer 331, may provide, at least in part, the functionality of an EIL 2239, in the emissive region 210. Non-limiting examples, of the deposited material 2431 for forming such initial deposited layer 331 include Yb, which for example, may be about 1-3 nm in thickness.

### Edge Effects of Patterning Coatings and Deposited Layers

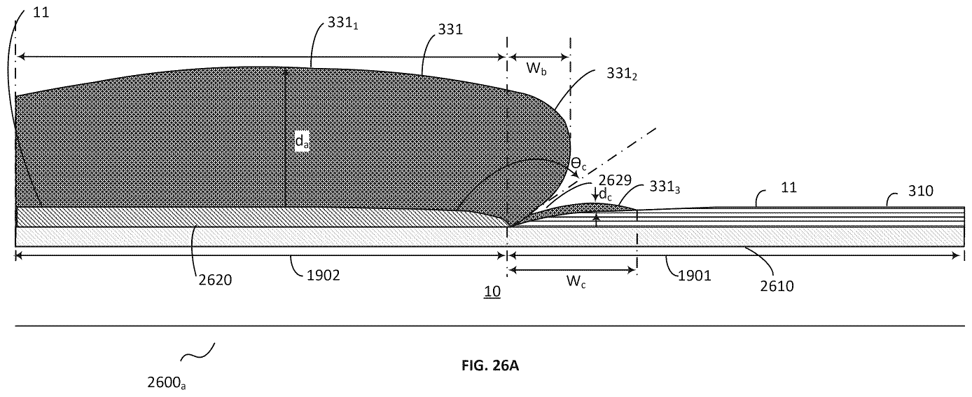

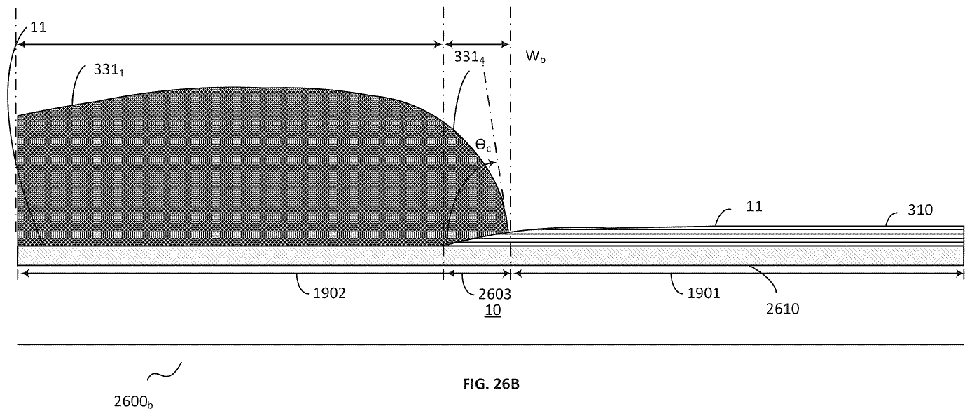

FIGS. 26A-26B describe various potential behaviours of patterning coatings 310 at a deposition interface with deposited layers 331.

Turning to FIG. 26A, there may be shown a first example of a part of an example version 2600ₐ of the device 2100 at a patterning coating deposition boundary. The device 2600ₐ may comprise a substrate 10 having an exposed layer surface 11. A patterning coating 310 may be deposited over a first portion 1901 of the exposed layer surface 11 of the underlying layer 2610. A deposited layer 331 may be deposited over a second portion 1902 of the exposed layer surface 11 of the underlying layer 2610. As shown, in some non-limiting examples, the first portion 1901 and the second portion 1902 may be distinct and non-overlapping parts of the exposed layer surface 11.

The deposited layer 331 may comprise a first part 331₁ and a second part 331₂. As shown, in some non-limiting examples, the first part 331₁ of the deposited layer 331 may substantially cover the second portion 1902 and the second part 331₂ of the deposited layer 331 may partially overlap (project over) a first part of the patterning coating 310.

In some non-limiting examples, since the patterning coating 310 may be formed such that its exposed layer surface 11 exhibits a substantially low initial sticking probability against deposition of the deposited material 2431, there may be a gap 2629 formed between the projecting second part 331₂ of the deposited layer 331 and the exposed layer surface 11 of the patterning coating 310. As a result, the second part 331₂ may not be in physical contact with the patterning coating 310 but may be spaced-apart therefrom by the gap 2629 in a cross-sectional aspect. In some non-limiting examples, the first part 331₁ of the deposited layer 331 may be in physical contact with the patterning coating 310 at an interface (boundary) between the first portion 1901 and the second portion 1902.

In some non-limiting examples, the projecting second part 331₂ of the deposited layer 331 may extend laterally over the patterning coating 310 by a comparable extent as an average layer thickness dₐ of the first part 331₁ of the deposited layer 331. In some non-limiting examples, as shown, a width w_{b} of the second part 331₂ may be comparable to the average layer thickness dₐ of the first part 331₁. In some non-limiting examples, a ratio of a width w_{b} of the second part 331₂ by an average layer thickness dₐ of the first part 331₁ may be in a range of one of between about: 1:1-1:3, 1:1-1:1.5, and 1:1-1:2. While the average layer thickness dₐ may in some non-limiting examples be substantially uniform across the first part 331₁, in some non-limiting examples, the extent to which the second part 331₂ may project over the patterning coating 310 (namely w_{b}) may vary to some extent across different parts of the exposed layer surface 11.

In some non-limiting examples, the deposited layer 331 may be shown to include a third part 331₃ disposed between the second part 331₂ and the patterning coating 310. As shown, the second part 331₂ of the deposited layer 331 may extend laterally over and may be longitudinally spaced apart from the third part 331₃ of the deposited layer 331 and the third part 331₃ may be in physical contact with the exposed layer surface 11 of the patterning coating 310. An average layer thickness dc of the third part 331₃ of the deposited layer 331 may be no more than, and in some non-limiting examples, substantially less than, the average layer thickness dₐ of the first part 331₁ thereof. In some non-limiting examples, a width w_{c} of the third part 331₃ may exceed the width w_{b} of the second part 331₂. In some non-limiting examples, the third part 331₃ may extend laterally to overlap the patterning coating 310 to a greater extent than the second part 331₂. In some non-limiting examples, a ratio of a width w_{c} of the third part 331₃ by an average layer thickness dₐ of the first part 331₁ may be in a range of one of between about: 1:2-3:1, and 1:1.2-2.5:1. While the average layer thickness dₐ may in some non-limiting examples be substantially uniform across the first part 331₁, in some non-limiting examples, the extent to which the third part 331₃ may project (overlap) with the patterning coating 310 (namely w_{c}) may vary to some extent across different parts of the exposed layer surface 11.

In some non-limiting examples, the average layer thickness de of the third part 331₃ may not exceed about 5% of the average layer thickness dₐ of the first part 331₁. In some non-limiting examples, d_{c} may be one of no more than about: 4%, 3%, 2%, 1%, and 0.5% of dₐ. Instead of (including without limitation, in addition to) the third part 331₃ being formed as a thin film, as shown, the deposited material 2431 of the deposited layer 331 may form as particle structures 2150 (not shown) on a part of the patterning coating 310. In some non-limiting examples, such particle structures 2150 may comprise features that are physically separated from one another, such that they do not form a continuous layer.

In some non-limiting examples, as shown, an NPC 2620 may be disposed between the substrate 10 and the deposited layer 331. The NPC 2620 may be disposed between the first part 331₁ of the deposited layer 331 and the second portion 1902 of the exposed layer surface 11 of the underlying layer 2610. The NPC 2620 is illustrated as being disposed on the second portion 1902 and not on the first portion 1901, where the patterning coating 310 has been deposited. The NPC 2620 may be formed such that, at an interface (boundary) between the NPC 2620 and the deposited layer 331, a surface of the NPC 2620 may exhibit a substantially high initial sticking probability against deposition of the deposited material 2431. As such, the presence of the NPC 2620 may promote the formation (growth) of the deposited layer 331 during deposition.

In some non-limiting examples, although not shown, the NPC 2620 may be disposed on both the first portion 1901 and the second portion 1902 of the substrate 10 and the underlying layer 2610 may cover a part of the NPC 2620 disposed on the first portion 1901, and another part of the NPC 2620 may be substantially devoid of the underlying layer 2610 and of the patterning coating 310, and the deposited layer 331 may cover such part of the NPC 2620.

Turning now to FIG. 26B, in some non-limiting examples, the first portion 1901 of the substrate 10 may be coated with the patterning coating 310 and the second portion may be coated with the deposited layer 331. In some non-limiting examples, the deposited layer 331 may partially overlap a part of the patterning coating 310 in a third portion 2603 of the substrate 10. In some non-limiting examples, although not shown, in addition to the first part 331₁ (and, if present, at least one of: the second part 331₂, and the third part 331₃), the deposited layer 331 may further comprise a fourth part 331₄ that may be disposed between the first part 331₁ and the second part 331₂ of the deposited layer 331 and in physical contact with the exposed layer surface 11 of the patterning coating 310. In some non-limiting examples, the fourth part 331₄ of the deposited layer 331 overlapping a subset of the patterning coating in the third portion 2603 may be in physical contact with the exposed layer surface 11 thereof. In some non-limiting examples, the overlap in the third portion 2603 may be formed as a result of lateral growth of the deposited layer 331 during one of: an open mask, and mask-free, deposition process. In some non-limiting examples, while the exposed layer surface 11 of the patterning coating 310 may exhibit a substantially low initial sticking probability against deposition of the deposited material 2431, and thus a probability of the material nucleating on the exposed layer surface 11 may be low, as the deposited layer 331 grows in thickness, the deposited layer 331 may also grow laterally and may cover a subset of the patterning coating 310 as shown.

In some non-limiting examples, it has been observed that conducting one of: an open mask, and mask-free, deposition of the deposited layer 331 may result in the deposited layer 331 exhibiting a tapered cross-sectional profile proximate to an interface between the deposited layer 331 and the patterning coating 310.

In some non-limiting examples, an average layer thickness of the deposited layer 331 proximate to the interface may be less than an average film thickness d₃ of the deposited layer 331. While such tapered profile may be shown as being at least one of: curved, and arched, in some non-limiting examples, the profile may, in some non-limiting examples be substantially one of: linear, and non-linear. In some non-limiting examples, an average film thickness d₃ of the deposited layer 331 may decrease, without limitation, in a substantially at least one of: linear, exponential, and quadratic, fashion in a region proximate to the interface.

It has been observed that a (thin film) contact angle θ_{c} of the deposited layer 331 proximate to the interface between the deposited layer 331 and the patterning coating 310 may vary, depending on properties of the patterning coating 310, such as an initial sticking probability. It may be further postulated that the contact angle θ of the nuclei may, in some non-limiting examples, dictate the thin film contact angle θ_{c} of the deposited layer 331 formed by deposition. Referring to FIG. 26B in some non-limiting examples, the contact angle θ_{c} may be determined by measuring a slope of a tangent of the deposited layer 331 proximate to the interface between the deposited layer 331 and the patterning coating 310. In some non-limiting examples, where the cross-sectional taper profile of the deposited layer 331 is substantially linear, the contact angle θ_{c} may be determined by measuring the slope of the deposited layer 331 proximate to the interface. As will be appreciated by those having ordinary skill in the relevant art, the contact angle θ_{c} may be generally measured relative to a non-zero angle of the underlying layer 2610. In the present disclosure, for purposes of simplicity of illustration, the patterning coating 310 and the deposited layer 331 may be shown deposited on a planar surface. However, those having ordinary skill in the relevant art will appreciate that the patterning coating 310 and the deposited layer 331 may be deposited on non-planar surfaces.

In some non-limiting examples, as shown in FIG. 26A, the contact angle θ_{c} of the deposited layer 331 may exceed about 90° and, in some non-limiting examples, the deposited layer 331 may be shown as including a part 331₂ extending past the interface between the patterning coating 310 and the deposited layer 331 and may be spaced apart from the patterning coating 310 (and, in some non-limiting examples, the third part 331₃ of the deposited layer 331) by the gap 2629. In such non-limiting scenario, the contact angle θ_{c} may, in some non-limiting examples, exceed 90°.

In some non-limiting examples, there may be scenarios calling for a deposited layer 140 exhibiting a substantially high contact angle θ_{c}. In some non-limiting examples, the contact angle θ_{c} may exceed one of about: 10°, 15°, 20°, 25°, 30°, 35°, 40°, 50°, 70°, 75°, and 80°. In some non-limiting examples, a deposited layer 331 having a substantially high contact angle θ_{c} may allow for creation of finely patterned features while maintaining a substantially high aspect ratio. In some non-limiting examples, there may be scenarios calling for a deposited layer 331 exhibiting a contact angle θ_{c} that exceeds about 90°. In some non-limiting examples, the contact angle θ_{c} may exceed one of about: 90°, 95°, 100°, 105°, 110° 120°, 130°, 135°, 140°, 145°, 150°, and 170°.

In some non-limiting examples, the contact angle θ_{c} of the deposited layer 331 may be measured at an edge thereof near the interface between it and the patterning coating 310, as shown. In FIG. 26A, the contact angle θ_{c} may exceed about 90°, which may in some non-limiting examples result in a subset, namely the second part 331₂, of the deposited layer 331 being spaced apart from the patterning coating 310 (and, in some non-limiting examples, the third part 331₃ of the deposited layer 331) by the gap 2629.

### Particle Structure

An NP is a particle of matter whose predominant characteristic size is of nanometer (nm) scale, generally understood to be between about: 1-300 nm. At nm scale, NPs of a given material may possess unique properties (including without limitation, optical, chemical, physical, and electrical) relative to the same material in bulk form, including without limitation, an amount of absorption of light exhibited by such NPs at different wavelengths (ranges).

These properties may be exploited when a plurality of NPs is formed into a layer of a layered semiconductor device 2100, including without limitation, an opto-electronic device 2200, to improve its performance.

Current mechanisms for introducing such a layer of NPs into such a device 2100 have some drawbacks.

First, in some non-limiting examples, such NPs may be formed into at least one of: a close-packed layer, and dispersed into a matrix material, of such device 2100. Consequently, in some non-limiting examples, the thickness of such an NP layer may be much thicker than the characteristic size of the NPs themselves. The thickness of such NP layer may impart undesirable characteristics in terms of at least one of: device performance, device stability, device reliability, and device lifetime that may reduce, including without limitation, obviate, any perceived advantages provided by the unique properties of NPs.

Second, techniques to synthesize NPs, in and for use in such devices may introduce large amounts of at least one of: C, O, and sulfur(S) through various mechanisms.

In some non-limiting examples, wet chemical methods may be used to introduce NPs that have a precisely controlled at least one of: characteristic size, length, width, diameter, height, size distribution, shape, surface coverage, configuration, deposited density, dispersity, and composition into an opto-electronic device 2200. However, such methods may, in some non-limiting examples, employ an organic capping group (such as the synthesis of citrate-capped Ag NPs) to stabilize the NPs, but such organic capping groups introduce at least one of: C, O, and S into the synthesized NPs.

Still further, in some non-limiting examples, an NP layer deposited from solution may comprise at least one of: C, O, and S, because of the solvents used in deposition.

Additionally, these elements may be introduced as contaminants during at least one of: the wet chemical process, and the deposition of the NP layer.

However introduced, the presence of a high amount of at least one of: C, O, and S, in the NP layer of such a device 2100, may erode at least one of: the performance, stability, reliability, and lifetime, of such device 2100.

Third, when depositing an NP layer from solution, as the employed solvents dry, the NP layer(s) may tend to have non-uniform properties at least one of: across the NP layer, and between different patterned regions of such layer. In some non-limiting examples, an edge of a given layer may be considerably at least one of: thicker and thinner, than an internal region of such layer, which disparities may adversely impact at least one of: the device performance, stability, reliability, and lifetime.

Fourth, while there are other methods (and processes) beyond wet chemical synthesis and solution deposition processes, of at least one of: synthesizing and depositing, NPs, including without limitation, a vacuum-based process such as, without limitation, PVD, such methods tend to provide poor control of the at least one of: characteristic size, length, width, diameter, height, size distribution, shape, surface coverage, configuration, deposited density, dispersity, and composition, of the NPs deposited thereby. In some non-limiting examples, in a PVD process, the NPs tend to form a close-packed film as their size increases. As a result, methods such as PVD are generally not well-suited to form a layer of large disperse NPs with low surface coverage. Rather, the poor control of at least one of: the characteristic size, length, width, diameter, height, size distribution, shape, surface coverage, configuration, deposited density, dispersity, and composition, imparted by such methods may result in poor at least one of: device performance, stability, reliability, and lifetime.

In some non-limiting examples, such as may be shown in FIG. 25A, there may be at least one particle, including without limitation, at least one of: a nanoparticle (NP), an island, a plate, a disconnected cluster, and a network (collectively particle structure 2150) disposed on an exposed layer surface 11 of an underlying layer 2610. In some non-limiting examples, the underlying layer 2610 may be the patterning coating 310 in the first portion 1901. In some non-limiting examples, the at least one particle structure 2150 may be disposed on an exposed layer surface 11 of the patterning coating 310. In some non-limiting examples, there may be a plurality of such particle structures 2150.

In some non-limiting examples, the at least one particle structure 2150 may comprise a particle material. In some non-limiting examples, the particle material may be the same as the deposited material 2431 in the deposited layer.

In some non-limiting examples, the particle material in the discontinuous layer 2160 in the first portion 1901, at least one of: the deposited material 2431 in the deposited layer 331, and a material of which the underlying layer 2610 thereunder may be comprised, may comprise a metal in common.

In some non-limiting examples, although not shown, at least one particle structure 2150ₐ of a discontinuous layer 2160 of a particle material may extend partially over the patterning coating 310, which may act as a particle structure patterning coating 310p in the transition region 2245. In some non-limiting examples, such discontinuous layer 2160 may form at least a part of the second electrode 340. In some non-limiting examples, the particle material may be the same as a material of which the deposited layer 331 may be comprised (deposited material 2431).

In some non-limiting examples, the particle material may comprise an element selected from at least one of: K, Na, Li, Ba, Cs, Yb, Ag, Au, Cu, Al, Mg, Zn, Cd, Sn, and Y. In some non-limiting examples, the element may comprise at least one of: K, Na, Li, Ba, Cs, Yb, Ag, Au, Cu, Al, and Mg. In some non-limiting examples, the element may comprise at least one of: Cu, Ag, and Au. In some non-limiting examples, the element may be Cu. In some non-limiting examples, the element may be Al. In some non-limiting examples, the element may comprise at least one of: Mg, Zn, Cd, and Yb. In some non-limiting examples, the element may comprise at least one of: Mg, Ag, Al, Yb, and Li. In some non-limiting examples, the element may comprise at least one of: Mg, Ag, and Yb. In some non-limiting examples, the element may comprise at least one of: Mg, and Ag. In some non-limiting examples, the element may be Ag.

In some non-limiting examples, the particle material may comprise a pure metal. In some non-limiting examples, the at least one particle structure 2150 may be a pure metal. In some non-limiting examples, the at least one particle structure 2150 may be (substantially) pure Ag. In some non-limiting examples, the substantially pure Ag may have a purity of one of about: 95%, 99%, 99.9%, 99.99%, 99.999%, and 99.9995%. In some non-limiting examples, the at least one particle structure 2150 may be (substantially) pure Mg. In some non-limiting examples, the substantially pure Mg may have a purity of one of at least about: 95%, 99%, 99.9%, 99.99%, 99.999%, and 99.9995%.

In some non-limiting examples, the at least one particle structure 2150 may comprise an alloy. In some non-limiting examples, the alloy may be at least one of: an Ag-containing alloy, an Mg-containing alloy, and an AgMg-containing alloy. In some non-limiting examples, the AgMg-containing alloy may have an alloy composition that may range from about 1:10 (Ag:Mg) to about 10:1 by volume.

In some non-limiting examples, the particle material may comprise other metals one of: in place of, and in combination with, Ag. In some non-limiting examples, the particle material may comprise an alloy of Ag with at least one other metal. In some non-limiting examples, the particle material may comprise an alloy of Ag with at least one of: Mg, and Yb. In some non-limiting examples, such alloy may be a binary alloy having a composition of between about: 5-95 vol. % Ag, with the remainder being the other metal. In some non-limiting examples, the particle material may comprise Ag and Mg. In some non-limiting examples, the particle material may comprise an Ag:Mg alloy having a composition of between about 1:10-10:1 by volume. In some non-limiting examples, the particle material may comprise Ag and Yb. In some non-limiting examples, the particle material may comprise a Yb:Ag alloy having a composition of between about 1:20-10:1 by volume. In some non-limiting examples, the particle material may comprise Mg and Yb. In some non-limiting examples, the particle material may comprise an Mg:Yb alloy. In some non-limiting examples, the particle material may comprise an Ag:Mg:Yb alloy.

In some non-limiting examples, the at least one particle structure 2150 may comprise at least one additional element. In some non-limiting examples, such additional element may be a non-metallic element. In some non-limiting examples, the non-metallic material may be at least one of: O, S, N, and C. It will be appreciated by those having ordinary skill in the relevant art that, in some non-limiting examples, such additional element(s) may be incorporated into the at least one particle structure 2150 as a contaminant, due to the presence of such additional element(s) in at least one of: the source material, equipment used for deposition, and the vacuum chamber environment. In some non-limiting examples, such additional element(s) may form a compound together with other element(s) of the at least one particle structure 2150. In some non-limiting examples, a concentration of the non-metallic element in the particle material may be one of no more than about: 1%, 0.1%, 0.01%, 0.001%, 0.0001%, 0.00001%, 0.000001%, and 0.0000001%. In some non-limiting examples, the at least one particle structure 2150 may have a composition in which a combined amount of O and C therein is one of no more than about: 10%, 5%, 1%, 0.1%, 0.01%, 0.001%, 0.0001%, 0.00001%, 0.000001%, and 0.0000001%.

The at least one particle structure 2150 takes advantage of plasmonics, a branch of nanophotonics, which studies the resonant interaction of light with metals. Those having ordinary skill in the relevant art will appreciate that metal NPs may exhibit at least one of: localized surface plasmon (LSP) excitations, and coherent oscillations of free electrons, whose optical response may be tailored by varying at least one of: a characteristic size, size distribution, shape, surface coverage, configuration, deposited density, and composition, of the nanostructures. Such optical response, in respect of particle structures 2150, may include absorption of light incident thereon, thereby reducing at least one of: reflection thereof, and shifting to one of: a lower, and higher, wavelength ((sub-) range) of the EM spectrum, including without limitation, (a sub-range of) the visible spectrum.

It has also been reported that arranging certain metal NPs near a medium having substantially low refractive index, may shift the absorption spectrum of such NPs to a lower wavelength (sub-) range (blue-shifted).

Accordingly, it may be further postulated that disposing particle material, in some non-limiting examples, as a discontinuous layer 2160 of at least one particle structure 2150 on an exposed layer surface 11 of an underlying layer 2610, such that the at least one particle structure 2150 is in physical contact with the underlying layer 2610, may, in some non-limiting examples, favorably shift the absorption spectrum of the particle material, including without limitation, blue-shift, such that it does not substantially overlap with a wavelength range of the EM spectrum of light being at least one of: emitted by, and transmitted at least partially through, the device 2100.

In some non-limiting examples, a peak absorption wavelength of the at least one particle structure 2150 may be less than a peak wavelength of the light being at least one of: emitted by, and transmitted, at least partially through the device 2100. In some non-limiting examples, the particle material may exhibit a peak absorption at a wavelength (range) that is one of no more than about: 470 nm, 460 nm, 455 nm, 450 nm, 445 nm, 440 nm, 430 nm, 420 nm, and 400 nm.

It has now been found, that providing particle material, including without limitation, in the form of at least one particle structure 2150, including without limitation, those comprised of a metal, proximate to, including without limitation, within, a at least one low (er)-index coating, may further impact at least one of: the absorption, and transmittance, of light passing through the device 2100, including without limitation, in the first direction, in at least a wavelength (sub-) range of the EM spectrum, including without limitation, (a sub-range of) the visible spectrum, passing in the first direction from, including without limitation, through, the at least one low (er)-index layer(s) and the at least one particle structure(s) 2150.

In some non-limiting examples, at least one of: absorption may be reduced, and transmittance may be facilitated, in at least a wavelength (sub-) range of the EM spectrum, including without limitation, (a sub-range of) the visible spectrum.

In some non-limiting examples, the absorption may be concentrated in an absorption spectrum that is a wavelength (sub-) range of the EM spectrum, including without limitation, (a sub-range of) the visible spectrum.

In some non-limiting examples, the absorption spectrum may be one of: blue-shifted, and shifted to a higher wavelength (sub-) range (red-shifted), including without limitation, to a wavelength (sub-) range of the EM spectrum, including without limitation, (a sub-range of) the visible spectrum, and to a wavelength (sub-) range of the EM spectrum that lies, at least in part, beyond the visible spectrum.

Those having ordinary skill in the relevant art will appreciate that in some non-limiting examples, a plurality of layers of at least one particle structure 2150 may be disposed on one another, whether separated by additional layers, with varying lateral aspects and having different absorption spectra. In this fashion, the absorption of certain regions of the device 2100 may be tuned according to at least one desired absorption spectra.

In some non-limiting examples, the presence of the at least one particle structure 2150, including without limitation, NPs, including without limitation, in a discontinuous layer 2160, on an exposed layer surface 11 of the patterning coating 310 may affect some optical properties of the device 2100.

In some non-limiting examples, such plurality of particle structures 2150 may form a discontinuous layer 2160.

Without wishing to be limited to any particular theory, it may be postulated that, while the formation of a closed coating 2140 of the particle material may be substantially inhibited by the patterning coating 310, in some non-limiting examples, when the patterning coating 310 is exposed to deposition of the particle material thereon, some vapor monomers of the particle material may ultimately form at least one particle structure 2150 of the particle material thereon.

In some non-limiting examples, at least some of the particle structures 2150 may be disconnected from one another. In other words, in some non-limiting examples, the discontinuous layer 2160 may comprise features, including particle structures 2150, that may be physically separated from one another, such that the particle structures 2150 do not form a closed coating 2140.

Accordingly, such discontinuous layer 2160 may, in some non-limiting examples, thus comprise a thin disperse layer of deposited material 2431 formed as particle structures 2150, inserted at, including without limitation, substantially across, the lateral extent of, an interface between the patterning coating 310 and at least one overlying layer in the device 2100.

In some non-limiting examples, at least one of the particle structures 2150 of particle material may be in physical contact with an exposed layer surface 11 of the patterning coating 310. In some non-limiting examples, substantially all of the particle structures 2150 of particle material may be in physical contact with the exposed layer surface 11 of the patterning coating 310.

Without wishing to be bound by any particular theory, it has been found, that the presence of such a thin, disperse discontinuous layer 2160 of particle material, including without limitation, at least one particle structure 2150, including without limitation, metal particle structures 2150, on an exposed layer surface 11 of the patterning coating 310, may exhibit at least one varied characteristic and concomitantly, varied behaviour, including without limitation, optical effects and properties of the device 2100, as discussed herein. In some non-limiting examples, such effects and properties may be controlled to some extent by judicious selection of at least one of: the characteristic size, size distribution, shape, surface coverage, configuration, deposited density, and dispersity, of the particle structures 2150 on the patterning coating 310.

In some non-limiting examples, the particle structures 2150 may be controllably selected so as to have at least one of: a characteristic size, length, width, diameter, height, size distribution, shape, surface coverage, configuration, deposited density, dispersity, and composition, to achieve an effect related to an optical response exhibited by the particle structures 2150.

Those having ordinary skill in the relevant art will appreciate that, having regard to the mechanism by which materials are deposited, due to possible stacking, including without limitation, clustering, of at least one of: monomers, and atoms, at least one of: an actual size, height, weight, thickness, shape, profile, and spacing, of the at least one particle structure 2150 may be, in some non-limiting examples, substantially non-uniform. Additionally, although the at least one particle structure 2150 are illustrated as having a given profile, this is intended to be illustrative only, and not determinative of at least one of: a size, height, weight, thickness, shape, profile, and spacing, thereof.

In some non-limiting examples, the at least one particle structure 2150 may have a characteristic dimension of no more than about 200 nm. In some non-limiting examples, the at least one particle structure 2150 may have a characteristic diameter that may be one of between about: 1-200 nm, 1-160 nm, 1-100 nm, 1-50 nm, and 1-30 nm.

In some non-limiting examples, the at least one particle structure 2150 may comprise discrete metal plasmonic islands (clusters).

In some non-limiting examples, the at least one particle structure 2150 may comprise a particle material.

In some non-limiting examples, such particle structures 2150 may be formed by depositing a scant amount, in some non-limiting examples, having an average layer thickness that may be on the order of one of: a few, and a fraction of one, angstrom(s), of a particle material on an exposed layer surface 11 of the underlying layer 2610. In some non-limiting examples, the exposed layer surface 11 may be of an NPC 2620.

In some non-limiting examples, the particle material may comprise at least one of: Ag, Yb, and Mg.

In some non-limiting examples, the formation of at least one of: the characteristic size, size distribution, shape, surface coverage, configuration, deposited density, and dispersity, of such discontinuous layer 2160 may be controlled, in some non-limiting examples, by judicious selection of at least one of: at least one characteristic of the patterning material 2311, an average film thickness d₂ of the patterning coating 310, the introduction of heterogeneities in at least one of: the patterning coating 310, and a deposition environment, including without limitation, a temperature, pressure, duration, deposition rate, and deposition process, for the patterning coating 310.

In some non-limiting examples, the formation of at least one of the characteristic size, size distribution, shape, surface coverage, configuration, deposited density, and dispersity, of such discontinuous layer 2160 may be controlled, in some non-limiting examples, by judicious selection of at least one of: at least one characteristic of the particle material (which may be the deposited material 2431), an extent to which the patterning coating 310 may be exposed to deposition of the particle material (which, in some non-limiting examples may be specified in terms of a thickness of the corresponding discontinuous layer 2160), and a deposition environment, including without limitation, at least one of: a temperature, pressure, duration, deposition rate, and method of deposition for the particle material.

In some non-limiting examples, the discontinuous layer 2160 may be deposited in a pattern across the lateral extent of the patterning coating 310.

In some non-limiting examples, the discontinuous layer 2160 may be disposed in a pattern that may be defined by at least one region therein that is substantially devoid of the at least one particle structure 2150.

In some non-limiting examples, the characteristics of such discontinuous layer 2160 may be assessed, in some non-limiting examples, somewhat arbitrarily, according to at least one of several criteria, including without limitation, at least one of: a characteristic size, size distribution, shape, configuration, surface coverage, deposited distribution, dispersity, and a presence, and an extent of aggregation instances, of the particle material, formed on a part of the exposed layer surface 11 of the underlying layer 2610.

In some non-limiting examples, an assessment of the discontinuous layer 2160 according to such at least one criterion, may be performed on, including without limitation, by at least one of: measuring, and calculating, at least one attribute of the discontinuous layer 2160, using a variety of imaging techniques, including without limitation, at least one of: transmission electron microscopy (TEM), atomic force microscopy (AFM), and scanning electron microscopy (SEM).

Those having ordinary skill in the relevant art will appreciate that such an assessment of the discontinuous layer 2160 may depend, to at least one of: a greater, and lesser, extent, by the extent, of the exposed layer surface 11 under consideration, which in some non-limiting examples may comprise an area, including without limitation, a region thereof. In some non-limiting examples, the discontinuous layer 2160 may be assessed across the entire extent, in at least one of: a first lateral aspect, and a second lateral aspect that is substantially transverse thereto, of the exposed layer surface 11. In some non-limiting examples, the discontinuous layer 2160 may be assessed across an extent that comprises at least one observation window applied against (a part of) the discontinuous layer 2160.

In some non-limiting examples, the at least one observation window may be located at at least one of: a perimeter, interior location, and grid coordinate, of the lateral aspect of the exposed layer surface 11. In some non-limiting examples, a plurality of the at least one observation windows may be used in assessing the discontinuous layer 2160.

In some non-limiting examples, the observation window may correspond to a field of view of an imaging technique applied to assess the discontinuous layer 2160, including without limitation, at least one of: TEM, AFM, and SEM. In some non-limiting examples, the observation window may correspond to a given level of magnification, including without limitation, one of: 2.00 μm, 1.00 μm, 500 nm, and 200 nm.

In some non-limiting examples, the assessment of the discontinuous layer 2160, including without limitation, at least one observation window used, of the exposed layer surface 11 thereof, may involve at least one of: calculating, and measuring, by any number of mechanisms, including without limitation, at least one of: manual counting, and known estimation techniques, which may, in some non-limiting examples, may comprise at least one of: curve, polygon, and shape, fitting techniques.

In some non-limiting examples, the assessment of the discontinuous layer 2160, including without limitation, at least one observation window used, of the exposed layer surface 11 thereof, may involve at least one of: calculating, and measuring, at least one of: an average, median, mode, maximum, minimum, and other at least one of: probabilistic, statistical, and data, manipulation, of a value of the at least one of: calculation, and measurement.

In some non-limiting examples, one of the at least one criterion by which such discontinuous layer 2160 may be assessed, may be a surface coverage of the particle material on such (part of the) discontinuous layer 2160. In some non-limiting examples, the surface coverage may be represented by a (non-zero) percentage coverage by such particle material of such (part of the) discontinuous layer 2160. In some non-limiting examples, the percentage coverage may be compared to a maximum threshold percentage coverage.

In some non-limiting examples, a (part of a) discontinuous layer 2160 having a surface coverage that may be substantially no more than the maximum threshold percentage coverage, may result in a manifestation of different optical characteristics that may be imparted by such part of the discontinuous layer 2160, to light passing therethrough, whether at least one of: transmitted entirely through the device 2100, and emitted thereby, relative to light passing through a part of the discontinuous layer 2160 having a surface coverage that substantially exceeds the maximum threshold percentage coverage.

In some non-limiting examples, one measure of a surface coverage of an amount of an electrically conductive material on a surface may be a (EM radiation) transmittance, since in some non-limiting examples, electrically conductive materials, including without limitation, metals, including without limitation: Ag, Mg, and Yb, may at least one of: attenuate, and absorb, light.

Those having ordinary skill in the relevant art will appreciate that in some non-limiting examples, surface coverage may be understood to encompass at least one of: particle size, and deposited density. Thus, in some non-limiting examples, a plurality of these three criteria may be positively correlated. Indeed, in some non-limiting examples, a criterion of low surface coverage may comprise some combination of a criterion of low deposited density with a criterion of low particle size.

In some non-limiting examples, one of the at least one criterion by which such discontinuous layer 2160 may be assessed, may be a characteristic size of the constituent particle structures 2150.

In some non-limiting examples, the at least one particle structure 2150 of the discontinuous layer 2160, may have a characteristic size that is no more than a maximum threshold size. Non-limiting examples of the characteristic size may include at least one of: height, width, length, and diameter.

In some non-limiting examples, substantially all of the particle structures 2150 of the discontinuous layer 2160 may have a characteristic size that lies within a specified range.

In some non-limiting examples, such characteristic size may be characterized by a characteristic length, which in some non-limiting examples, may be considered a maximum value of the characteristic size. In some non-limiting examples, such maximum value may extend along a major axis of the particle structure 2150. In some non-limiting examples, the major axis may be understood to be a first dimension extending in a plane defined by the plurality of lateral axes. In some non-limiting examples, a characteristic width may be identified as a value of the characteristic size of the particle structure 2150 that may extend along a minor axis of the particle structure 2150. In some non-limiting examples, the minor axis may be understood to be a second dimension extending in the same plane but substantially transverse to the major axis.

In some non-limiting examples, the characteristic length of the at least one particle structure 2150, along the first dimension, may be no more than the maximum threshold size.

In some non-limiting examples, the characteristic width of the at least one particle structure 2150, along the second dimension, may be no more than the maximum threshold size.

In some non-limiting examples, a size of the constituent particle structures 2150, in the (part of the) discontinuous layer 2160, may be assessed by at least one of: calculating, and measuring a characteristic size of such at least one particle structure 2150, including without limitation, at least one of: a mass, volume, length of a diameter, perimeter, major, and minor axis, thereof.

In some non-limiting examples, one of the at least one criterion by which such discontinuous layer 2160 may be assessed, may be a deposited density thereof.

In some non-limiting examples, the characteristic size of the particle structure 2150 may be compared to a maximum threshold size.

In some non-limiting examples, the deposited density of the particle structures 2150 may be compared to a maximum threshold deposited density.

In some non-limiting examples, at least one of such criteria may be quantified by a numerical metric. In some non-limiting examples, such a metric may be a calculation of a dispersity D that describes the distribution of particle (area) sizes in a deposited layer 331 of particle structures 2150, in which Equation (3) provides:

$$D = \frac{\overline{{S}_{s}}}{\overline{{S}_{n}}} \qquad ( 3 )$$

where, pursuant to Equation (4):

$$\overline{{S}_{s}} = \frac{{\sum }_{i = 1}^{n} {s}_{i}^{2}}{{\sum }_{i = 1}^{n} {s}_{i}} , \overline{{S}_{n}} = \frac{{\sum }_{i = 1}^{n} {s}_{i}}{n} , \qquad ( 4 )$$

n is the number of particle structures 2150 in a sample area,
Sᵢ is the (area) size of the i^{th} particle structure 2150,
S̅ₙ is the number average of the particle (area) sizes, and
S̅ₛ is the (area) size average of the particle (area) sizes.

Those having ordinary skill in the relevant art will appreciate that the dispersity is roughly analogous to a polydispersity index (PDI) and that these averages are roughly analogous to the concepts of number average molecular weight and weight average molecular weight familiar in organic chemistry, but applied to an (area) size, as opposed to a molecular weight of a sample particle structure 2150.

Those having ordinary skill in the relevant will also appreciate that while the concept of dispersity may, in some non-limiting examples, be considered a three-dimensional volumetric concept, in some non-limiting examples, the dispersity may be considered to be a two-dimensional concept. As such, the concept of dispersity may be used in connection with viewing and analyzing two-dimensional images of the deposited layer 331, such as may be obtained by using a variety of imaging techniques, including without limitation, at least one of: TEM, AFM, and SEM. It is in such a two-dimensional context, that the equations set out above are defined.

In some non-limiting examples, at least one of: the dispersity, and the number average, of the particle (area) size and the (area) size average of the particle (area) size may involve a calculation of at least one of: the number average of the particle diameters and the (area) size average of the particle diameters as provided by Equation (5):

$$\overline{{d}_{n}} = 2 \sqrt{\frac{\overline{{S}_{n}}}{π}} , \overline{{d}_{s}} = 2 \sqrt{\frac{\overline{{S}_{s}}}{π}} \qquad ( 5 )$$

In some non-limiting examples, the particle material, including without limitation as particle structures 2150, of the at least one deposited layer 331, may be deposited by one of: an open mask, and mask-free, deposition process.

In some non-limiting examples, the particle structures 2150 may have a substantially round shape. In some non-limiting examples, the particle structures 2150 may have a substantially spherical shape.

For purposes of simplification, in some non-limiting examples, it may be assumed that a longitudinal extent of each particle structure 2150 may be substantially the same (and, in any event, may not be directly measured from a plan view SEM image) so that the (area) size of the particle structure 2150 may be represented as a two-dimensional area coverage along the pair of lateral axes. In the present disclosure, a reference to an (area) size may be understood to refer to such two-dimensional concept, and to be differentiated from a size (without the prefix “area”) that may be understood to refer to a one-dimensional concept, such as a linear dimension.

Indeed, in some early investigations, it appears that, in some non-limiting examples, the longitudinal extent, along the longitudinal axis, of such particle structures 2150, may tend to be small relative to the lateral extent (along at least one of the lateral axes), such that the volumetric contribution of the longitudinal extent thereof may be much less than that of such lateral extent. In some non-limiting examples, this may be expressed by an aspect ratio (a ratio of a longitudinal extent to a lateral extent) that may be no more than 1. In some non-limiting examples, such aspect ratio may be one of about: 1:10, 1:20, 1:50, 1:75, and 1:300.

In this regard, the assumption set out above (that the longitudinal extent is substantially the same and can be ignored) to represent the particle structure 2150 as a two-dimensional area coverage may be appropriate.

Those having ordinary skill in the relevant art will appreciate, having regard to the non-determinative nature of the deposition process, especially in the presence of at least one of: defects, and anomalies, on the exposed layer surface 11 of the underlying layer 2610, including without limitation, heterogeneities, including without limitation, at least one of: a step edge, a chemical impurity, a bonding site, a kink, and a contaminant, thereon, and consequently the formation of particle structures 2150 thereon, the non-uniform nature of coalescence thereof as the deposition process continues, and in view of the uncertainty in the at least one of: size, and position, of observation windows, as well as the intricacies and variability inherent in at least one of: the calculation, and measurement, of their characteristic size, spacing, deposited density, degree of aggregation, and the like, there may be considerable variability in terms of the features (topology) within observation windows.

In the present disclosure, for purposes of simplicity of illustration, certain details of particle materials, including without limitation, at least one of: thickness profiles, and edge profiles, of layer(s) have been omitted.

Those having ordinary skill in the relevant art will appreciate that certain metal NPs, whether as part of a discontinuous layer 2160 of particle material, including without limitation, at least one particle structure 2150, may exhibit at least one of: surface plasmon (SP) excitations, and coherent oscillations of free electrons, with the result that such NPs may one of: absorb, and scatter, light in a range of the EM spectrum, including without limitation, (a sub-range of) the visible spectrum. The optical response, including without limitation, at least one of: the (sub-) range of the EM spectrum over which absorption may be concentrated (absorption spectrum), refractive index, and extinction coefficient, of such one of: LSP excitations, and coherent oscillations, may be tailored by varying properties of such NPs, including without limitation, at least one of: a characteristic size, size distribution, shape, surface coverage, configuration, deposition density, dispersity, and property, including without limitation, at least one of: material, and degree of aggregation, of at least one of: the nanostructures, and a medium proximate thereto.

Such optical response, in respect of photon-absorbing coatings, may include absorption of photons incident thereon, thereby reducing reflection. In some non-limiting examples, the absorption may be concentrated in a range of the EM spectrum, including without limitation, (a sub-range of) the visible spectrum. While the at least one particle structure 2150 may absorb light incident thereon from beyond the layered semiconductor device 2100, thus reducing reflection, those having ordinary skill in the relevant art will appreciate that, in some non-limiting examples, the at least one particle structure 2150 may absorb light incident thereon that is emitted by the device 2100. In some non-limiting examples, employing a photon-absorbing layer as part of an opto-electronic device 2200 may reduce reliance on a polarizer therein.

It has been reported in Fusella et al., “Plasmonic enhancement of stability and brightness in organic light-emitting devices”, Nature 2020, 585, at 379-382, that the stability of an OLED device may be enhanced by incorporating an NP-based outcoupling layer above the cathode layer to extract energy from the plasmon modes. The NP-based outcoupling layer was fabricated by spin-casting cubic Ag NPs on top of an organic layer on top of a cathode. However, since most commercial OLED devices are fabricated using vacuum-based processing, spin-casting from solution may not constitute an appropriate mechanism for forming such an NP-based outcoupling layer above the cathode.

It has been discovered that such an NP-based outcoupling layer above the cathode may be fabricated in vacuum (and thus, may have applicability for use in a commercial OLED fabrication process), by depositing a metal particle material in a discontinuous layer 2160 onto a patterning coating 310, which in some non-limiting examples, may at least one of: be, and be deposited on, the cathode. Such process may avoid the use of one of: solvents, and other wet chemicals, that may at least one of: cause damage to the OLED device 2200 and may adversely impact device reliability.

In some non-limiting examples, the presence of such a discontinuous layer 2160 of particle material, including without limitation, at least one particle structure 2150, may contribute to enhanced extraction of at least one of: light, performance, stability, reliability, and lifetime of the device 2100.

In some non-limiting examples, the existence, in a layered device 2100, of at least one discontinuous layer 2160, proximate to at least one of: the exposed layer surface 11 of a patterning coating 310, and, in some non-limiting examples, proximate to the interface of such patterning coating 310 with at least one overlying layer 2170, may impart optical effects to EM signals, including without limitation, photons, that are one of: emitted by the device 2100, and transmitted therethrough.

Those having ordinary skill in the relevant art will appreciate that, while a simplified model of the optical effects is presented herein, at least one of: other models, and other explanations, may be applicable.

In some non-limiting examples, the presence of such a discontinuous layer 2160 of the particle material, including without limitation, at least one particle structure 2150, may reduce (mitigate) crystallization of thin film coatings disposed adjacent in the longitudinal aspect, including without limitation, at least one of: the patterning coating 310, and at least one overlying layer 2170, thereby stabilizing the property of the thin film(s) disposed adjacent thereto, and, in some non-limiting examples, reducing scattering. In some non-limiting examples, such thin film may comprise at least one layer of at least one of: an outcoupling, and an encapsulating coating (not shown) of the device 2100, including without limitation, a capping layer (CPL).

In some non-limiting examples, the presence of such a discontinuous layer 2160 of particle material, including without limitation, at least one particle structure 2150, may provide an enhanced absorption in at least a part of the UV spectrum. In some non-limiting examples, controlling the characteristics of such particle structures 2150, including without limitation, at least one of: characteristic size, size distribution, shape, surface coverage, configuration, deposited density, dispersity, particle material, and refractive index, of the particle structures 2150, may facilitate controlling the degree of absorption, wavelength range and peak wavelength of the absorption spectrum, including in the UV spectrum. Enhanced absorption of light in at least a part of the UV spectrum may have applicability in some scenarios, for improving at least one of: device performance, stability, reliability, and lifetime.

In some non-limiting examples, the optical effects may be described in terms of its impact on at least one of: the transmission, and absorption wavelength spectrum, including at least one of: a wavelength range, and peak intensity thereof.

Additionally, while the model presented may suggest certain effects imparted on at least one of: the transmission, and absorption, of photons passing through such discontinuous layer 2160, in some non-limiting examples, such effects may reflect local effects that may not be reflected on a broad, observable basis.

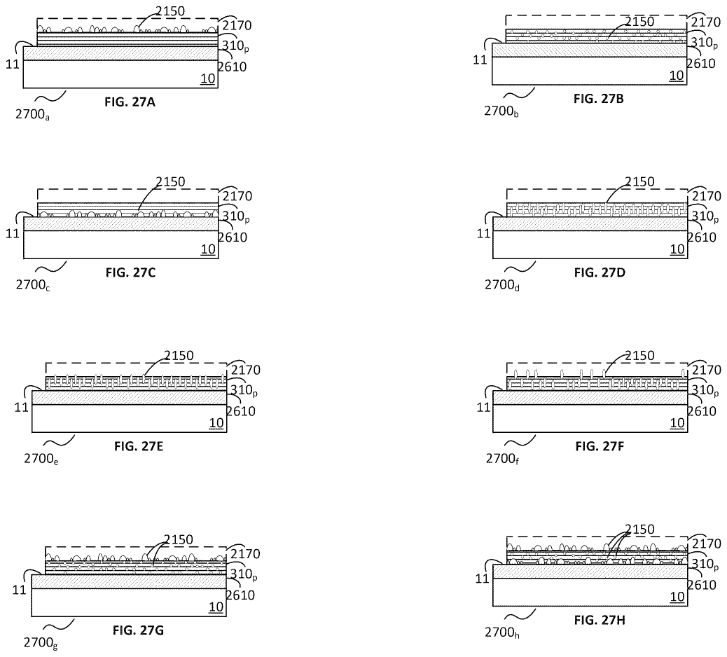

FIGS. 27A-27H illustrate non-limiting examples of possible interactions between the particle structure patterning coating 310p and the at least one particle structure 2150ₜ in contact therewith.

Thus, as shown in FIGS. 27A-27H, the particle material may be in physical contact with the patterning material 2311 including without limitation, as shown in the various figures, being one of: deposited thereon, and being substantially surrounded thereby.

In FIG. 27A, the particle material may be in physical contact with the particle structure patterning coating 310p in that it is deposited thereon.

In FIG. 27B, the particle material may be substantially surrounded by the particle structure patterning coating 310p. In some non-limiting examples, the at least one particle structure 2150 may be distributed throughout at least one of: the lateral, and longitudinal, extent of the particle structure patterning coating 310p.

In some non-limiting examples, the distribution of the at least one particle structure 2150 throughout the particle structure patterning coating 310p may be achieved by causing the particle structure patterning coating 310p to be at least one of: deposited, and to remain, in a substantially viscous state at the time of deposition of the particle material thereon, such that the at least one particle structure 2150ₜ may tend to penetrate (settle) within the particle structure patterning coating 310p.

In some non-limiting examples, the viscous state of the particle structure patterning coating 310p may be achieved in a number of manners, including without limitation, conditions during deposition of the patterning material 2311, including without limitation, at least one of: a time, temperature, and pressure, of the deposition environment thereof, a composition of the patterning material 2311, a characteristic of the patterning material 2311, including without limitation, a melting point, a freezing temperature, a sublimation temperature, a viscosity, and a surface energy, thereof, conditions during deposition of the particle material, including without limitation, at least one of: a time, temperature, and pressure, of the deposition environment thereof, a composition of the particle material, and a characteristic of the particle material, including without limitation, a melting point, a freezing temperature, a sublimation temperature, a viscosity, and a surface energy thereof.

In some non-limiting examples, the distribution of the at least one particle structure 2150 throughout the particle structure patterning coating 310p may be achieved through the presence of small apertures, including without limitation, at least one of: pin-holes, tears, and cracks, therein. Those having ordinary skill in the relevant art will appreciate that such apertures may be formed during the deposition of a thin film of the patterning structure patterning coating 310p, using various techniques and processes, including without limitation, those described herein, due to inherent variability in the deposition process, and in some non-limiting examples, to the existence of impurities in at least one of the particle material and the exposed layer surface 11 of the patterning material 2311.

In FIG. 27C, the particle material of which the at least one particle structure 2150 may be comprised may settle at a bottom of the particle structure patterning coating 310p such that it is effectively disposed on the exposed layer surface 11 of the underlying layer 2610.

In some non-limiting examples, the distribution of the at least one particle structure 2150 at a bottom of the particle structure patterning coating 310p may be achieved by causing the particle structure patterning coating 310p to be at least one of: deposited, and to remain, in a substantially viscous state at the time of deposition of the particle material thereon, such that the at least one particle structure 2150 may tend to settle to the bottom of the particle structure patterning coating 310p. In some non-limiting examples, the viscosity of the patterning material 2311 used in FIG. 27C may be no more than the viscosity of the patterning material 2311 used in FIG. 27B, allowing the at least one particle structure 2150 to settle further within the particle structure patterning coating 310p, eventually descending to the bottom thereof.

In FIGS. 27D-27F, a shape of the at least one particle structure 2150 is shown as being longitudinally elongated relative to a shape of the at least one particle structure 2150 of FIG. 27B.

In some non-limiting examples, the longitudinally elongated shape of the at least one particle structure 2150 may be achieved in a number of manners, including without limitation, conditions during deposition of the patterning material 2311, including without limitation, at least one of: a time, temperature, and pressure, of the deposition environment thereof, a composition of the patterning material 2311, a characteristic of the patterning material 2311, including without limitation, a melting point, a freezing temperature, a sublimation temperature, a viscosity, and a surface energy thereof, conditions during deposition of the particle material, including without limitation, a time, temperature, and pressure, of the deposition environment thereof, a composition of the particle material, and a characteristic of the particle material, including without limitation, a melting point, a freezing temperature, a sublimation temperature, a viscosity, and a surface energy thereof, that may tend to facilitate the deposition of such longitudinally elongated particle structures 2150.

In FIG. 27D, the longitudinally elongated particle structures 2150 are shown to remain substantially entirely within the particle structure patterning coating 310p. By contrast, in FIG. 27E, at least one of the longitudinally elongated particle structures 2150 may be shown to protrude at least partially beyond the exposed layer surface 11 of the particle structure patterning coating 310p. Further, in FIG. 27F, at least one of the longitudinally elongated particle structures 2150 may be shown to protrude substantially beyond the exposed layer surface 11 of the particle structure patterning coating 310p, to the extent that such protruding particle structures 2150 may begin to be considered to be substantially deposited on the exposed layer surface 11 of the particle structure patterning coating 310p.

Thus, as shown in FIG. 27G, there may be a scenario in which at least one particle structure 2150 may be deposited on the exposed layer surface 11 of the particle structure patterning coating 310p and at least one particle structure 2150 may settle within the particle structure patterning coating 310p. Although the at least one particle structure 2150 shown within the particle structure patterning coating 310p is shown as having a shape such as is shown in FIG. 27B, those having ordinary skill in the relevant art will appreciate that, although not shown, such particle structures 2150 may have a longitudinally elongated shape such as is shown in FIGS. 27D-27F.

Further, FIG. 27H shows a scenario in which at least one particle structure 2150 may be deposited on the exposed layer surface 11 of the particle structure patterning coating 310p, at least one particle structure 2150 may penetrate (settle within) the particle structure patterning coating 310p, and at least one particle structure 2150 may settle to the bottom of the particle structure patterning coating 310p.

### Auxiliary Electrode

Those having ordinary skill in the relevant art will appreciate that the process of depositing a deposited layer 331 to form the second electrode 340 may, in some non-limiting examples, be used in similar fashion to form an auxiliary electrode 2850 for the device 2200.

In some non-limiting examples, particularly in a top-emission device 2200, the second electrode 340 may be formed by depositing a substantially thin conductive film layer in order, in some non-limiting examples, to reduce optical interference (including, without limitation, at least one of: attenuation, reflections, and diffusion) related to the presence of the second electrode 340.

In some non-limiting examples, particularly in at least one of: a bottom-emission, and double-sided emission, device 2200, the second electrode 340 may be formed as a substantially thick conductive layer without substantially affecting optical characteristics of such a device 2200. Nevertheless, even in such scenarios, the second electrode 340 may nevertheless be formed as a substantially thin conductive film layer, in some non-limiting examples, so that the device 2200 may be substantially transmissive relative to light incident on an external surface thereof, such that a substantial part of such externally-incident light may be transmitted through the device 2200, in addition to the emission of light generated internally within the device 2200 as disclosed herein.

In some non-limiting examples, a device 2200 having at least one electrode 1920, 340 with a high sheet resistance may create a large current resistance (IR) drop when coupled with the power source 2204, in operation. In some non-limiting examples, such an IR drop may be compensated for, to some extent, by increasing a level of the power source 2204. However, in some non-limiting examples, increasing the level of the power source 2204 to compensate for the IR drop due to high sheet resistance, for at least one (sub-) pixel 215/216 may call for increasing the level of a voltage to be supplied to other components to maintain effective operation of the device 2200.

In some non-limiting examples, as discussed elsewhere, a reduced thickness of the second electrode 340, may generally increase a sheet resistance of the second electrode 340, which may, in some non-limiting examples, reduce at least one of: the performance, and efficiency, of the device 2200. By providing the auxiliary electrode 2850 that may be electrically coupled with the second electrode 340, the sheet resistance and thus, the IR drop associated with the second electrode 340, may, in some non-limiting examples, be decreased.

In some non-limiting examples, to reduce power supply demands for a device 2200 without significantly impacting an ability to make an electrode 1920, 340 substantially thin, an auxiliary electrode 2850 may be formed on the device 2200 to allow current to be carried more effectively to various emissive region(s) 210 of the device 2200, while at the same time, reducing the sheet resistance and its associated IR drop of the transmissive electrode 1920, 340.

In some non-limiting examples, a sheet resistance specification, for a common electrode 1920, 340 of a display device 2200, may vary according to several parameters, including without limitation, at least one of: a (panel) size of the device 2200, and a tolerance for voltage variation across the device 2200. In some non-limiting examples, the sheet resistance specification may increase (that is, a lower sheet resistance is specified) as the panel size increases. In some non-limiting examples, the sheet resistance specification may increase as the tolerance for voltage variation decreases.

In some non-limiting examples, a sheet resistance specification may be used to derive an example thickness of an auxiliary electrode 2850 to comply with such specification for various panel sizes.

In some non-limiting examples, the auxiliary electrode 2850 may be electrically coupled with the second electrode 340 to reduce a sheet resistance thereof. In some non-limiting examples, the auxiliary electrode 2850 may be in physical contact, including without limitation, being deposited over at least a part thereof, with the second electrode 340 to reduce a sheet resistance thereof. In some non-limiting examples, the auxiliary electrode 2850 may not be in physical contact with the second electrode 340 but may be electrically coupled with the second electrode 340 by several well-understood mechanisms. In some non-limiting examples, the presence of a substantially thin film (in some non-limiting examples, of up to about 50 nm) of a patterning coating 310 extending between and separating the auxiliary electrode 2850 and the second electrode 340, may still allow a current to pass therethrough, thus allowing a sheet resistance of the second electrode 340 to be reduced.

The auxiliary electrode 2850 may be electrically conductive. In some non-limiting examples, the auxiliary electrode 2850 may be formed by at least one of: a metal, and a metal oxide. Such metals may include, without limitation, Cu, Al, molybdenum (Mo), and Ag. In some non-limiting examples, the auxiliary electrode 2850 may comprise a multi-layer metallic structure, including without limitation, one formed by Mo/Al/Mo. Such metal oxides may include, without limitation, ITO, ZnO, IZO, and other oxides comprising In, and Zn. In some non-limiting examples, the auxiliary electrode 2850 may comprise a multi-layer structure formed by a combination of at least one metal and at least one metal oxide, including without limitation, Ag/ITO, Mo/ITO, ITO/Ag/ITO, and ITO/Mo/ITO. In some non-limiting examples, the auxiliary electrode 2850 comprises a plurality of such electrically conductive materials.

Because of the nucleation-inhibiting properties of those portions 1901 where the patterning coating 310 was disposed, the deposited material 2431 disposed in the first portion 1901 may tend to not remain, resulting in a pattern of selective deposition of the deposited layer 331, that may correspond substantially to at least one second portion 1902, leaving the first portion 1901 substantially devoid of a closed coating 2140 of the deposited layer 331.

In other words, the deposited layer 331 that may form the auxiliary electrode 2850 may be selectively deposited substantially only on a second portion 1902 comprising those regions of the at least one semiconducting layer 330, that surround but do not occupy the first portion 1901.

In some non-limiting examples, selectively depositing the auxiliary electrode 2850 to cover only certain portions 102 of the lateral aspect of the device 2200, while other portions 1901 thereof remain uncovered, may one of: control, and reduce, optical interference related to the presence of the auxiliary electrode 2850.

In some non-limiting examples, the auxiliary electrode 2850 may be selectively deposited in a pattern that may not be readily detected by the naked eye from a typical viewing distance.

In some non-limiting examples, the auxiliary electrode 2850 may be formed in devices 2100 other than OLED devices 2200, including for decreasing an effective resistance of the electrodes of such devices 2200.

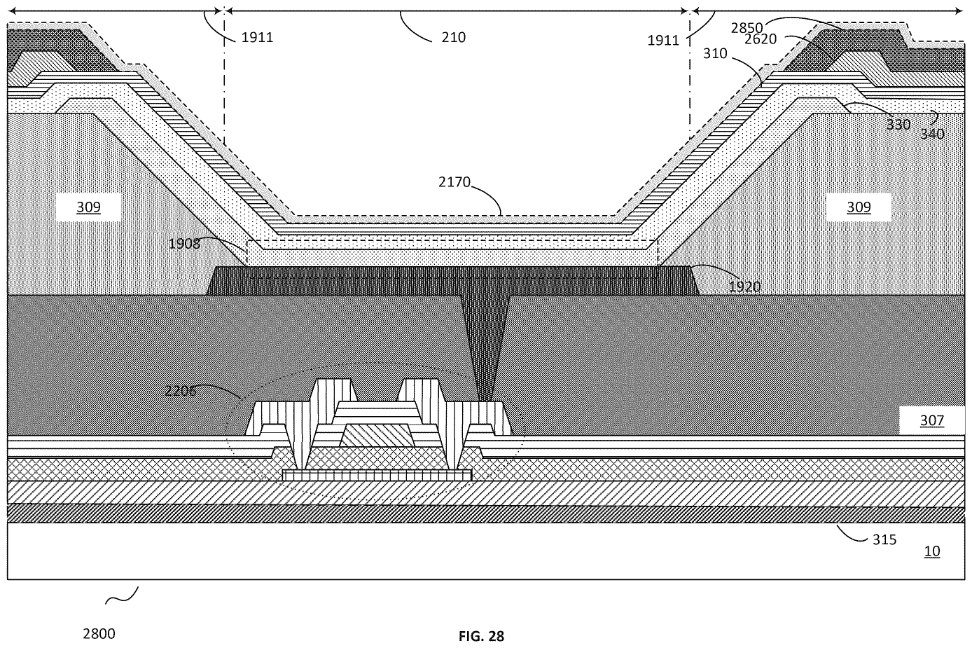

Turning now to FIG. 28, there may be shown an example version 2800 of the device 2200, which may encompass the device 2200 shown in cross-sectional view in FIG. 22, but with additional deposition steps that are described herein.

The device 2100 may show a patterning coating 310 deposited over the exposed layer surface 11 of the underlying layer 2610, in the figure, the second electrode 340.

The patterning coating 310 may provide an exposed layer surface 11 with a substantially low initial sticking probability against deposition of a deposited material 2431 to be thereafter deposited as a deposited layer 331 to form an auxiliary electrode 2850.

In some non-limiting examples, after deposition of the patterning coating 310, an NPC 2620 may be selectively deposited over the exposed layer surface 11 of the underlying layer 2610, in the figure, the patterning coating 310.

In some non-limiting examples, the NPC 2620 may be disposed between the auxiliary electrode 2850 and the second electrode 340.

In some non-limiting examples, the NPC 2620 may be selectively deposited using a shadow mask 2315, in a second portion 1902 of the lateral aspect of the device 2100.

The NPC 2620 may provide an exposed layer surface 11 with a substantially high initial sticking probability against deposition of a deposited material 2431 to be thereafter deposited as a deposited layer 331 to form an auxiliary electrode 2850.

After selective deposition of the NPC 2620, the deposited material 2431 may be deposited over the device 2100 but may remain substantially where the patterning coating 310 has been overlaid with the NPC 2620, to form the auxiliary electrode 2850, that is, substantially only the second portion 1902.

In some non-limiting examples, the deposited layer 331 may be deposited using one of: an open mask, and a mask-free, deposition process.

### Transparent OLED

Because the OLED device 2200 may emit light through at least one of: the first electrode 1920 (in the case of one of: a bottom-emission, and a double-sided emission, device 2200), as well as the substrate 10, and the second electrode 340 (in the case of one of: a top-emission, and double-sided emission, device 2200), there may be an aim to make at least one of: the first electrode 1920, and the second electrode 340, substantially EM radiation-(light-) transmissive (“transmissive”), in some non-limiting examples, at least across a substantial part of the lateral aspect of the emissive region(s) 210 of the device 2200. In the present disclosure, such a transmissive element, including without limitation, an electrode 1920, 340, at least one of: a material from which such element may be formed, and a property thereof, may comprise at least one of: an element, material, and property thereof, that is one of: substantially transmissive (“transparent”), and, in some non-limiting examples, partially transmissive (“semi-transparent”), in some non-limiting examples, in at least one wavelength range.

A variety of mechanisms may be adopted to impart transmissive properties to the device 2200, at least across a substantial part of the lateral aspect of the emissive region(s) 210 thereof.

In some non-limiting examples, including without limitation, where the device 2200 is at least one of: a bottom-emission, and a double-sided emission, device, the TFT structure(s) 2206 of the driving circuit associated with an emissive region 210 of a (sub-) pixel 215/216, which may at least partially reduce the transmissivity of the surrounding substrate 10, may be located within the lateral aspect of the surrounding non-emissive region(s) 1911 to avoid impacting the transmissive properties of the substrate 10 within the lateral aspect of the emissive region 210.

In some non-limiting examples, where the device 2200 is a double-sided emission device 2200, in respect of the lateral aspect of an emissive region 210 of a (sub-) pixel 215/216, a first one of the electrodes 1920, 340 may be made substantially transmissive, including without limitation, by at least one of the mechanisms disclosed herein, in respect of the lateral aspect of neighbouring (sub-) pixel(s) 215/216, a second one of the electrodes 1920, 340 may be made substantially transmissive, including without limitation, by at least one of the mechanisms disclosed herein. Thus, the lateral aspect of a first emissive region 210 of a (sub-) pixel 215/216 may be made substantially top-emitting while the lateral aspect of a second emissive region 210 of a neighbouring (sub-) pixel 215/216 may be made substantially bottom-emitting, such that a subset of the (sub-) pixel(s) 215/216 may be substantially top-emitting and a subset of the (sub-) pixel(s) 215/216 may be substantially bottom-emitting, in an alternating (sub-) pixel 215/216 sequence, while only a single electrode 1920, 340 of each (sub-) pixel 215/216 may be made substantially transmissive.

In some non-limiting examples, a mechanism to make an electrode 1920, 340, in the case of at least one of: a bottom-emission device 2200, and a double-sided emission device 2200, the first electrode 1920, and in the case of at least one of: a top-emission device 2200, and a double-sided emission device 2200, the second electrode 340, transmissive, may be to form such electrode 1920, 340 of a transmissive thin film.

In some non-limiting examples, an electrically conductive deposited layer 331, in a thin film, including without limitation, those formed by depositing a thin conductive film layer of at least one of: a metal, including without limitation, Ag, Al, and a metallic alloy, including without limitation, at least one of: an Mg:Ag alloy, and a Yb:Ag alloy, may exhibit transmissive characteristics. In some non-limiting examples, the alloy may comprise a composition ranging from between about 1:9-9:1 by volume. In some non-limiting examples, the electrode 1920, 340 may be formed of a plurality of thin conductive film layers of any combination of deposited layers 331, any at least one of which may be comprised of at least one of: TCOs, thin metal films, and thin metallic alloy films.

In some non-limiting examples, especially in the case of such thin conductive films, a substantially thin layer thickness may be up to substantially a few tens of nm to contribute to enhanced transmissive qualities but also favorable optical properties (including without limitation, reduced microcavity effects) for use in an OLED device 2200.

Thus, in some non-limiting examples, an average layer thickness of the second electrode 340 may be no more than about 40 nm, including without limitation, one of between about: 5-30 nm, 10-25 nm, and 15-25 nm.

In some non-limiting examples, a reduction in the thickness of an electrode 1920, 340 to promote transmissive qualities may be accompanied by an increase in the sheet resistance of the electrode 1920, 340.

In some non-limiting examples, the auxiliary electrode 2850 may be electrically coupled with the second electrode 340 to reduce a sheet resistance of thin, and concomitantly, (substantially) transmissive, second electrode 340.

In some non-limiting examples, the auxiliary electrode 2850 may not be substantially transmissive but may be electrically coupled with the second electrode 340, including without limitation, by deposition of a conductive deposited layer 331 therebetween, to reduce an effective sheet resistance of the second electrode 340.

In some non-limiting examples, such auxiliary electrode 2850 may be one of: positioned, and shaped, in at least one of: a lateral aspect, and longitudinal aspect, to not interfere with the emission of photons from the lateral aspect of the emissive region 210 of a (sub-) pixel 215/216.

In some non-limiting examples, a mechanism to make at least one of: the first electrode 1920, and the second electrode 340, may be to form such electrode 1920, 340 in a pattern across at least one of: at least a part of the lateral aspect of the emissive region(s) 210 thereof, and in some non-limiting examples, across at least a part of the lateral aspect of the non-emissive region(s) 1911 surrounding them. In some non-limiting examples, such mechanism may be employed to form the auxiliary electrode 2850 in one of: a position, and shape, in at least one of: a lateral aspect, and longitudinal aspect to not interfere with the emission of photons from the lateral aspect of the emissive region 210 of a (sub-) pixel 215/216, as discussed above.

In some non-limiting examples, the device 2200 may be configured such that it may be substantially devoid of a conductive oxide material in an optical path of light emitted by the device 2200. In some non-limiting examples, in the lateral aspect of at least one emissive region 210 corresponding to a (sub-) pixel 215/216, at least one of the coatings deposited after the at least one semiconducting layer 330, including without limitation, at least one of: the second electrode 340, the patterning coating 310, and any other coatings deposited thereon, may be substantially devoid of any conductive oxide material. In some non-limiting examples, being substantially devoid of any conductive oxide material may reduce at least one of: absorption, and reflection, of light emitted by the device 2200. In some non-limiting examples, conductive oxide materials, including without limitation, at least one of: ITO, and IZO, may absorb light in at least the B(lue) region of the visible spectrum, which may, in generally, reduce at least one of: efficiency, and performance, of the device 2200.

In some non-limiting examples, a combination of these mechanisms may be employed.

Additionally, in some non-limiting examples, in addition to rendering at least one of the first electrode 1920, the second electrode 340, and the auxiliary electrode 2850, substantially transmissive across at least across a substantial part of the lateral aspect of the emissive region 210 corresponding to the (sub-) pixel(s) 215/216 of the device 2200, to allow light to be emitted substantially across the lateral aspect thereof, there may be an aim to make at least one of the lateral aspect(s) of the surrounding non-emissive region(s) 1911 of the device 2200 substantially transmissive in both the bottom and top directions, to render the device 2200 substantially transmissive relative to light incident on an external surface thereof, such that a substantial part of such externally-incident light may be transmitted through the device 2200, in addition to the emission (in at least one of: a top-emission, bottom-emission, and double-sided emission) of light generated internally within the device 2200 as disclosed herein.

In some non-limiting examples, the transmissive region 112 of the device 2200 may remain substantially devoid of any materials that may substantially affect the transmission of light therethrough, including without limitation, EM signals, including without limitation, in at least one of: the IR, and the NIR, spectrum. In some non-limiting examples, the TFT structure(s) 2206 and the first electrode 1920 may be positioned, in a longitudinal aspect, below the (sub-) pixel 215/216 corresponding thereto, and together with the auxiliary electrode 2850, may lie beyond the transmissive region 112. As a result, these components may not impede, including without limitation, attenuate light, including without limitation, light, from being transmitted through the transmissive region 112. In some non-limiting examples, such arrangement may allow a viewer viewing the device 2200 from a typical viewing distance to see through the device 2200, in some non-limiting examples, when all the (sub-) pixel(s) 215/216 may not be emitting, thus creating a transparent device 2100.

In some non-limiting examples, a patterning coating 310 may be selectively deposited over first portion(s) 1901 of the device 2200, comprising a transmissive region 112.

In some non-limiting examples, at least one particle structure 2150 may be disposed on an exposed layer surface 11 within the transmissive region 112, to facilitate absorption of light therein in at least a part of the visible spectrum, while allowing EM signals having a wavelength in at least a part of at least one of: the IR, and NIR, spectrum to be exchanged through the device 2200 in the transmissive region 112.

Those having ordinary skill in the relevant art will appreciate that in some non-limiting examples, various other coatings, including without limitation those forming at least one of: the at least one semiconducting layer(s) 330, and the second electrode 340, may cover a part of the transmissive region 112, especially if such coatings are substantially transparent. In some non-limiting examples, the PDL(s) 309 may have a reduced thickness, including without limitation, by forming a well therein, which in some non-limiting examples may be similar to the well defined for emissive region(s) 210, to further facilitate transmission of light through the transmissive region 112.

In some non-limiting examples, the transmissive region 112 of the device 2200 may remain substantially devoid of any materials that may substantially inhibit the transmission of light, including without limitation, EM signals, including without limitation, in at least one of: the IR spectrum, and the NIR spectrum, therethrough. In some non-limiting examples, at least one of: the TFT structure 2206, and the first electrode 1920, may be positioned, in a longitudinal aspect below the (sub-) pixel 215/216 corresponding thereto and beyond the transmissive region 112. As a result, these components may not impede, including without limitation, attenuate, light from being transmitted through the transmissive region 112. In some non-limiting examples, such arrangement may allow a viewer viewing the device 2200 from a typical viewing distance to see through the device 2200, in some non-limiting examples, when the (sub-) pixel(s) 215/216 are not emitting, thus creating a transparent AMOLED device 2200.

In some non-limiting examples, such arrangement may also allow at least one of: an IR emitter 130ₑ, and an IR detector 130ₐ, to be arranged behind the device 2200 such that EM signals, including without limitation, in at least one of: the IR, and NIR, spectrum, to be exchanged through the device 2200 by such under-display components 130ᵤ.

In some non-limiting examples, as discussed herein, the patterning coating 310 may be formed concurrently with the at least one semiconducting layer(s) 330. In some non-limiting examples, at least one material used to form the patterning coating 310 may also be used to form the at least one semiconducting layer(s) 330. In such non-limiting example, several stages for fabricating the device 2200 may be reduced, which may, in some non-limiting examples, facilitate making the transmissive region 112 (substantially) transmissive.

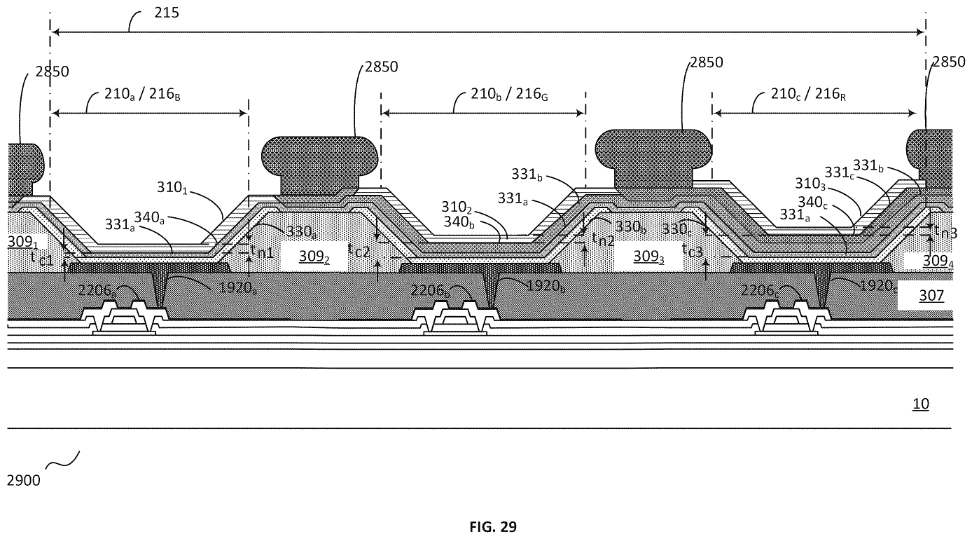

Turning now to FIG. 29, there is shown an example cross-sectional view of a fragment of an example version 2900 of the opto-electronic device 2200 according to the present disclosure. In the fragment shown, emissive regions 210 corresponding to each of three sub-pixels 216, of a single pixel 215, are shown, which in some non-limiting examples, may correspond to a B(lue) sub-pixel 216_{B}, a G(reen) sub-pixel 216_{G}, and a R(ed) sub-pixel 216_{R}. In some non-limiting examples, each sub-pixel 216 may have a first electrode 1920, with which an associated TFT structure 2206 may be electrically coupled, a second electrode 340, and at least one semiconducting layer 330 deposited between the first electrode 1920 and the second electrode 340.

In some non-limiting examples, the at least one semiconducting layer 330 may comprise at least one R(ed) EML material within at least the lateral aspect of the R(ed) sub-pixel 216_{R}. In some non-limiting examples, the at least one semiconducting layer 330 may comprise at least one G(reen) EML material within at least the lateral aspect of the G(reen) sub-pixel 216_{G}. In some non-limiting examples, the at least one semiconducting layer 330 may comprise at least one B(lue) EML material within at least the lateral aspect of the B(lue) sub-pixel 216_{B}.

In some non-limiting examples, at least one characteristic of at least one of the at least one semiconducting layer 330, including without limitation, at least one of: the HIL 2231, HTL 2233, EML 2235, ETL 2237, and EIL 2239, including without limitation, a presence thereof, an absence thereof, a thickness thereof, a composition thereof, and an order thereof, in the longitudinal aspect, may be varied within at least a lateral aspect of one of the (sub-) pixels 216, to facilitate emission therefrom of light having a wavelength spectrum corresponding to the colour by which such sub-pixel 216 may be denoted, including without limitation, at least one of: R(ed), G(reen), and B(lue), such that such at least one characteristic may be varied across substantially its entire lateral extent.

In some non-limiting examples, neighboring sub-pixels 216 may be separated by a non-emissive region 1911 having a corresponding PDL 309, that covers at least a part of an extremity of the corresponding first electrodes 1920. In some non-limiting examples, although not shown, the PDL 309 may be truncated in at least one of: a lateral aspect, and a longitudinal aspect. In some non-limiting examples, truncation of the PDL 309 in the lateral aspect may cause the lateral extent of the neighboring emissive regions 210 to be at least, and in some non-limiting examples, exceed, including without limitation, be a multiple of, the lateral extent of the non-emissive region 1911 interposed therebetween.

In some non-limiting examples, although not shown, at least one PDL 309 between neighboring emissive regions 210 may be truncated to a greater extent than shown, until the emissive regions 210 may be considered to be substantially immediately adjacent to one another, substantially without a non-emissive region 1911 therebetween.

In some non-limiting examples, although not shown, neighboring emissive regions 210 may not have a PDL 309 interposed therebetween, although, in such scenario, alternative measures may be called for to electrically isolate a first electrode 1920 corresponding to a first emissive region 210 from a first electrode 1920 corresponding to a second emissive region 210 immediately adjacent thereto.

In some non-limiting examples, the at least one semiconducting layer 330 may extend across substantially the lateral extent of each of the first electrodes 1920 and across substantially the lateral extent of each of the non-emissive regions 1911 corresponding to the PDLs 309 separating them. In some non-limiting examples, the at least one semiconducting layer 330 may extend across substantially the entire lateral aspect of the device 2200.

### Selective Deposition to Modulate Electrode Thickness Over Emissive Region(s)

In some non-limiting examples, the output, including without limitation, the emission spectrum, of a given (sub-) pixel 215/216 may be impacted, according to at least one of: its associated color, and wavelength range, including without limitation, by at least one of: controlling, modulating, and tuning, optical microcavity effects, including without limitation, at least one of: an emission spectrum, a(n) (luminous) intensity, and an angular distribution of at least one of: a brightness, and a color shift, of emitted light in each emissive region 210 corresponding each (sub-) pixel 215/216.

Some factors that may impact an observed microcavity effect in a device 2200 include, without limitation, a total path length (which in some non-limiting examples may correspond to a total thickness (in the longitudinal aspect) of the device 2200 through which light emitted therefrom will travel before being outcoupled) and the refractive indices of various layers and coatings.

Since the wavelength of (sub-) pixels 215/216 of different colours may be different, the optical characteristics of such (sub-) pixels 215/216 may differ, especially if a common electrode 1920, 340 having a substantially uniform thickness profile may be employed for (sub-) pixels 215/216 of different colours.

In some non-limiting examples, a separation distance between the pair of electrodes 1920, 340 within an emissive region 210 corresponding to a (sub-) pixel 215/216, may be varied to reflect a (half-) integer multiple of a wavelength range associated with an emitted colour of the (sub-) pixel 215/216.

In some non-limiting examples, such tuning may be achieved, at least in part, by varying the thickness of the at least one semiconducting layer 330 extending between the electrodes 1920, 340.

In some non-limiting examples, where (substantially all) the at least one semiconducting layer 330 comprise(s) a common layer extending across all of the (sub-) pixels 215/216, such measures may be incomplete.

In some non-limiting examples, irrespective of whether a thickness of the at least one semiconducting layer 330 may be varied, at least one of: across the device 2200, and as between (sub-) pixels 215/216 thereof, the separation distance between the pair of electrodes 1920, 340 within an emissive region 210 corresponding to a (sub-) pixel 215/216 may be further varied by modulating the thickness of an electrode 1920, 340 in, and across a lateral aspect of emissive region(s) 210 of such (sub-) pixel 215/216.

The second electrode 340 used in such devices 2200 may in some non-limiting examples, be a common electrode 1920, 340 coating a plurality of (sub-) pixels 215/216. In some non-limiting examples, such common electrode 1920, 340 may be a substantially thin conductive film having a substantially uniform thickness across the device 2200. When a common electrode 1920, 340 having a substantially uniform thickness may be provided as the second electrode 340 in a device 2200, the optical performance of the device 2200 may not be readily be fine-tuned according to an emission spectrum associated with each (sub-) pixel 215/216.

In some non-limiting examples, modulating a thickness of an electrode 1920, 340 in and across a lateral aspect of emissive region(s) 210 of a (sub-) pixel 215/216 may impact the microcavity effect observable. In some non-limiting examples, such impact may be attributable to a change in the total optical path length.

In some non-limiting examples, modulating a thickness of an electrode 1920, 340 in and across a lateral aspect of emissive region(s) 210 of a (sub-) pixel 215/216 may impact the microcavity effect observable. In some non-limiting examples, such impact may be attributable to a change in the total optical path length.

In some non-limiting examples, a change in a thickness of the electrode 1920, 340 may also change the refractive index of light passing therethrough, in some non-limiting examples, in addition to a change in the total optical path length. In some non-limiting examples, this may be particularly the case where the electrode 1920, 340 may be formed of at least one deposited layer 331.

Thus, in some non-limiting examples, the presence of optical interfaces created by a plurality of thin-film coatings with different refractive indices, such as may in some non-limiting examples be used to construct opto-electronic devices 2200, may create different optical microcavity effects for (sub-) pixels 215/216 of different colours.

In some non-limiting examples, selective deposition of at least one deposited layer 331 through deposition of at least one patterning coating 310, including without limitation, at least one of: an NIC, and an NPC 2620, in the lateral aspects of emissive region(s) 210 corresponding to different (sub-) pixel(s) 215/216, may allow the thickness of at least one electrode 1920, 340, of each (sub-) pixel 215/216 to be varied, and concomitantly, for the optical microcavity effect in each emissive region 210 corresponding thereto, to be at least one of: controlled, and modulated, to optimize desirable optical microcavity effects on a (sub-) pixel 215/216 basis.

The thickness of the at least one electrode 1920, 340 may be varied by independently modulating at least one of: an average layer thickness, and a number, of the deposited layer(s) 331, disposed in each emissive region 210 of the (sub-) pixel(s) 215/216. In some non-limiting examples, the average layer thickness of a second electrode 340 disposed over, and corresponding to, a B(lue) sub-pixel 216; may be no more than the average layer thickness of a second electrode 340 disposed over, and corresponding to, a G(reen) sub-pixel 216_{G}, and the average layer thickness of a second electrode 340 disposed over, and corresponding to, a G(reen) sub-pixel 216_{G} may be no more than the average layer thickness of a second electrode 340 disposed over, and corresponding to, a R(ed) sub-pixel 216_{R}.

Turning now to FIG. 29, in some non-limiting examples, including without limitation, in versions 2900 of an OLED display device 2200 there may be deposited layer(s) 331 of varying average layer thickness selectively deposited for emissive region(s) 210 corresponding to sub-pixel(s) 216, having different emission spectra. In some non-limiting examples, a first emissive region 210ₐ may correspond to a (sub-) pixel 215/216 configured to emit light of a first at least one of: a wavelength, and an emission spectrum. In some non-limiting examples, a device 2900 may comprise a second emissive region 210_{b} that may correspond to a (sub-) pixel 215/216 configured to emit light of a second at least one of: a wavelength, and an emission spectrum. In some non-limiting examples, a device 2900 may comprise a third emissive region 210_{c} that may correspond to a (sub-) pixel 215/216 configured to emit light of a third at least one of: a wavelength, and an emission spectrum.

In some non-limiting examples, the first wavelength may be one of: no more than, greater than, and equal to, at least one of: the second wavelength, and the third wavelength. In some non-limiting examples, the second wavelength may be one of: no more than, greater than, and equal to, at least one of: the first wavelength, and the third wavelength. In some non-limiting examples, the third wavelength may be at least one of: no more than, greater than, and equal to, at least one of: the first wavelength, and the second wavelength.

As shown in some non-limiting examples in FIG. 29, there may be deposited layer(s) 331 of varying at least one of: number, and average layer thickness, selectively deposited for various emissive region(s) 210 corresponding to various (sub-) pixel(s) 215/216, in some non-limiting examples, in a version 2900 of device 2200, having different emission spectra. In some non-limiting examples, the device 2900 may comprise a first emissive region 210ₐ corresponding to a sub-pixel 216_{B} configured to emit light of at least one of: a first wavelength, and emission spectrum, which in some non-limiting examples, may be associated with a B(lue) emitted colour. In some non-limiting examples, the device 2900 may comprise a second emissive region 210_{b} corresponding to a sub-pixel 216_{G} configured to emit light of at least one of: a second wavelength, and emission spectrum, which in some non-limiting examples, may be associated with a G(reen) emitted colour. In some non-limiting examples, the device 2900 may comprise a third emissive region 210_{c} corresponding to a sub-pixel 216_{R} configured to emit light of at least one of: a third wavelength, and emission spectrum, which in some non-limiting examples, may be associated with a R(ed) emitted colour.

In some non-limiting examples, the first wavelength may be one of: equal to, at least, and no more than, at least one of: the second wavelength, and the third wavelength. In some non-limiting examples, the second wavelength may be one of: equal to, at least, and no more than, at least one of: the first wavelength, and the third wavelength. In some non-limiting examples, the third wavelength may be one of: equal to, at least, and no more than, at least one of: the first wavelength, and the second wavelength.

In some non-limiting examples, although not shown, the device 2900 may comprise at least one additional emissive region 210 that may in some non-limiting examples be configured to emit light having at least one of: a wavelength, and emission spectrum, that may be substantially identical to at least one of: the first emissive region 210ₐ, the second emissive region 210_{b}, and the third emissive region 210_{c}, including without limitation, the second emissive region 210_{b}.

In some non-limiting examples, the device 2900 may also comprise any number of emissive regions 210, and (sub-) pixel(s) 215/216 thereof.

In some non-limiting examples, the plurality of sub-pixels 216 may correspond to a single pixel 215. In some non-limiting examples, the device 2900 may comprise a plurality of pixels 215, wherein each pixel 215 comprises a plurality of sub-pixel(s) 216.

Those having ordinary skill in the relevant art will appreciate that the specific arrangement of (sub-) pixel(s) 215/216 may be varied depending on the device design. In some non-limiting examples, the sub-pixel(s) 216 may be arranged according to known arrangement schemes, including without limitation, RGB side-by-side, diamond, and PenTile®.

In some non-limiting examples, the device 2900 may be shown as comprising a substrate 10, and a plurality of emissive regions 210, each having a corresponding at least one TFT structure 2206, covered by at least one TFT insulating layer 307, and a corresponding first electrode 1920, formed on an exposed layer surface 11 of the TFT insulating layer 307.

In some non-limiting examples, the substrate 10 may comprise the base substrate 315.

In some non-limiting examples, each at least one TFT structure 2206 may be longitudinally aligned below and within the lateral extent of its corresponding emissive region 210, for driving the corresponding (sub-) pixel 215/216 and electrically coupled with its associated first electrode 1920.

In some non-limiting examples, neighboring first electrodes 1920 may be separated by a non-emissive region 1911 having a corresponding PDL 309, formed over the TFT insulating layer 307, that may, in some non-limiting examples, cover at least a part of an extremity of the corresponding first electrodes 1920.

In the present disclosure, each of the various emissive region layers of the device 2200, including without limitation, at least one of: the first electrode 1920, the second electrode 340, and the at least one semiconducting layer 330 therebetween, may be formed by depositing a respective constituent emissive region layer material in a desired pattern in a manufacturing process.

In some non-limiting examples, such deposition may take place in a deposition process, in combination with a shadow mask 2315, which may, in some non-limiting examples, may be one of: an open mask, and a fine metal mask (FMM), having apertures to achieve such desired pattern by at least one of: masking, and precluding deposition of, the emissive region layer material on certain parts of an exposed layer surface of an underlying material exposed thereto.

The device 2900 may be shown as comprising a substrate 10, a TFT insulating layer 307 and a plurality of first electrodes 1920, formed on an exposed layer surface 11 of the TFT insulating layer 307.

In some non-limiting examples, the substrate 10 may comprise the base substrate 315 (not shown for purposes of simplicity of illustration), and in some non-limiting examples, at least one TFT structure 2206 corresponding to, and for driving, a corresponding emissive region 210, each having a corresponding (sub-) pixel 215/216, positioned substantially thereunder and electrically coupled with its associated first electrode 1920. PDL(s) 309 may be formed over the substrate 10, to define emissive region(s) 210. In some non-limiting examples, the PDL(s) 309 may cover edges of their respective first electrode 1920.

In some non-limiting examples, at least one semiconducting layer 330 may be deposited over exposed region(s) of the first electrodes 210 corresponding to the emissive region 210 of each (sub-) pixel 215/216 and, in some non-limiting examples, at least parts of corresponding at least one of: non-emissive regions 1911, and corresponding PDLs 309, interposed therebetween.

In some non-limiting examples, a first deposited layer 331ₐ may be deposited over the exposed layer surface 11 of the at least one semiconducting layer(s) 330. In some non-limiting examples, such deposition may be effected by exposing the entire exposed layer surface 11 of the device 2900 to a vapor flux 2432 of deposited material 2431, using one of: an open mask, and a mask-free, deposition process, to deposit the first deposited layer 331ₐ over the at least one semiconducting layer(s) 330 to form a first layer of a second electrode 340 for a first emissive region 210ₐ so that such second electrode 340 is designated as a second electrode 340ₐ. Such second electrode 340ₐ may have a first thickness t_{c1} in the first emissive region 210ₐ. In some non-limiting examples, the first thickness t_{c1} may correspond to a thickness of the first deposited layer 331ₐ.

In some non-limiting examples, a first patterning coating 310₁ may be selectively deposited over first portions 1901 of the device 2900, comprising the first emissive region 210ₐ.

In some non-limiting examples, the patterning coating 310₁ may be selectively deposited using a shadow mask 2315 that may also have been used to deposit the at least one semiconducting layer 330ₐ of the first emissive region 210ₐ to reduce a number of stages for fabricating the device 2900.

In some non-limiting examples, a second deposited layer 331_{b} may be deposited over an exposed layer surface 11 of the device 2900 that is substantially devoid of the patterning coating 310, namely the exposed layer surface 11 of the first deposited layer 331ₐ in both of the second emissive region 210_{b}, and the third emissive region 210_{c} and, in some non-limiting examples, at least part(s) of the non-emissive region(s) 1911 interposed therebetween, in which the PDLs 309 (if any) may lie. In some non-limiting examples, such deposition may be effected by exposing the entire exposed layer surface 11 of the device 2900 to a vapor flux 2432 of deposited material 2431, using one of: an open mask, and a mask-free deposition process, to deposit the second deposited layer 331_{b} over the first deposited layer 331ₐ to the extent that it is substantially devoid of the first patterning coating 310₁, such that the second deposited layer 331_{b} may be deposited on the second portion(s) 1902 of the first deposited layer 331ₐ that are substantially devoid of the first patterning coating 310₁ to form a second layer of a second electrode 340 for the second emissive region 210_{b}, so that such second electrode 340 may be designated as a second electrode 340_{b}. Such second electrode 340_{b} may have a second thickness t_{c2} in the second emissive region 210_{b}. In some non-limiting examples, the second thickness t_{c2} may correspond to a combined average layer thickness of the first deposited layer 331ₐ and of the second deposited layer 331_{b} and may, in some non-limiting examples, be at least the first thickness t_{c1}.

In some non-limiting examples, a second patterning coating 310₂ may be selectively deposited over further first portions 1901 of the device 2900, comprising the second emissive region 210_{b}.

In some non-limiting examples, a third deposited layer 331_{c} may be deposited over an exposed layer surface 11 of the device 2900, namely the exposed layer surface 11 of the second deposited layer 331_{b} in the third emissive region 210_{c}. In some non-limiting examples, such deposition may be effected by exposing the entire exposed layer surface 11 of the device 2900 to a vapor flux 2432 of deposited material 2431. In some non-limiting examples, the third deposited layer 331_{c} may be deposited using one of: an open mask, and a mask-free, deposition process, to deposit the third deposited layer 331_{c} over the second deposited layer 331_{b} to the extent that it is substantially devoid of any of: the first patterning coating 310₁, and the second patterning coating 310₂ to form a third layer of a second electrode 340 for the third emissive region 210_{c}, so that such second electrode 340 may be designated as a second electrode 340_{c}. Such second electrode 340_{c} may have a third thickness t_{c3} in the third emissive region 210_{c}. In some non-limiting examples, the third thickness t_{c3} may correspond to a combined average layer thickness of the first deposited layer 331ₐ, the second deposited layer 331_{b}, and the third deposited layer 331, and may, in some non-limiting examples, be at least one of: the first thickness t_{c1}, and the second thickness t_{c2}.

In some non-limiting examples, a third patterning coating 310₃ may be selectively deposited over additional first portions 1901 of the device 2900, comprising the third emissive region 210_{c}.

In some non-limiting examples, at least one auxiliary electrode 2850 may be disposed in the non-emissive region(s) 1911 of the device 2900 between neighbouring emissive regions 210 thereof and in some non-limiting examples, over the PDLs 309. In some non-limiting examples, the deposited layer 331 used to deposit the at least one auxiliary electrode 2850 may be deposited using one of: an open mask, and a mask-free, deposition process, to deposit a deposited material 2431 over the first deposited layer 331ₐ, the second deposited layer 331_{b}, and the third deposited layer 331_{c}, to the extent that it is substantially devoid of any of: the first patterning coating 310₁, the second patterning coating 310₂, and the third patterning coating 310₃ to form the at least one auxiliary electrode 2850. In some non-limiting examples, each of the at least one auxiliary electrodes 2850 may be electrically coupled with a respective at least one of the second electrodes 340.

In some non-limiting examples, at least one of: the first deposited layer 331ₐ, the second deposited layer 331_{b}, and the third deposited layer 331_{c} may be at least one of: transmissive, and substantially transparent, in at least a part of the visible spectrum. Thus, in some non-limiting examples, at least one of: the second deposited layer 331_{b}, and the third deposited layer 331_{c} (and any additional deposited layer(s) 331 (not shown) may be disposed on top of the first deposited layer 331ₐ to form a multi-coating electrode 1920, 340 that may also be at least one of: transmissive, and substantially transparent, in at least a part of the visible spectrum. In some non-limiting examples, the transmittance of at least one of: at least one of: the first deposited layer 331ₐ, the second deposited layer 331_{b}, and the third deposited layer 331_{c}, (and any additional deposited layer(s) 331), and the multi-coating electrode 1920, 340 formed thereby, may exceed one of about: 30%, 40% 45%, 50%, 60%, 70%, 75%, and 80% in at least a part of the visible spectrum.

In some non-limiting examples, an average layer thickness of at least one of: the first deposited layer 331ₐ, the second deposited layer 331_{b}, and the third deposited layer 331_{c} may be made substantially thin to maintain a substantially high transmittance. In some non-limiting examples, an average layer thickness of the first deposited layer 331ₐ may be one of between about: 5-30 nm, 8-25 nm, and 10-20 nm. In some non-limiting examples, an average layer thickness of the second deposited layer 331_{b} may be one of between about: 1-25 nm, 1-20 nm, 1-15 nm, 1-10 nm, and 3-6 nm. In some non-limiting examples, an average layer thickness of the third deposited layer 331_{c} may be one of between about: 1-25 nm, 1-20 nm, 1-15 nm, 1-10 nm, and 3-6 nm. In some non-limiting examples, a thickness of a multi-coating electrode formed by a combination of the first deposited layer 331ₐ, the second deposited layer 331_{b}, and the third deposited layer 331_{c}, (and any additional deposited layer(s) 331) may be one of between about: 6-35 nm, 10-30 nm, 10-25 nm, and 12-18 nm.

The thickness of the at least one electrode 1920, 340 may be varied to an even greater extent by independently modulating the average layer thickness, and a number, of at least one of: the patterning coating 310, and an NPC 2620, deposited in part(s) of each emissive region 210 of the (sub-) pixel(s) 216.

In some non-limiting examples, an average layer thickness of at least one of: the first patterning coating 310₁, the second patterning coating 310₂, and the third patterning coating 310₃ disposed in at least one of: the first emissive region 210ₐ, the second emissive region 210_{b}, and the third emissive region 210, respectively, may be varied according to at least one of: a colour, and emission spectrum of light, emitted by each emissive region 210. In some non-limiting examples, the first patterning coating 310₁ may have a first patterning coating thickness tₙ₁. In some non-limiting examples, the second patterning coating 310₂ may have a second patterning coating thickness tₙ₂. In some non-limiting examples, the third patterning coating 310₃ may have a third patterning coating thickness tₙ₃. In some non-limiting examples, at least one of: the first patterning coating thickness tₙ₁, the second patterning coating thickness tₙ₂, and the third patterning coating thickness tₙ₃, may be substantially the same. In some non-limiting examples, at least one of: the first patterning coating thickness tₙ₁, the second patterning coating thickness tₙ₂, and the third patterning coating thickness tₙ₃, may be different from one another.

In some non-limiting examples, an average layer thickness of the first deposited layer 331ₐ may exceed an average layer thickness of at least one of: the second deposited layer 331_{b}, and the third deposited layer 331_{c}. In some non-limiting examples, the average layer thickness of the second deposited layer 331_{b} may exceed the average layer thickness of at least one of: the first deposited layer 331ₐ, and the third deposited layer 331_{c}. In some non-limiting examples, the average layer thickness of the third deposited layer 331_{c} may exceed the average layer thickness of at least one of: the first deposited layer 331ₐ, and the second deposited layer 331_{b}. In some non-limiting examples, the average layer thickness of the first deposited layer 331ₐ, the average layer thickness of the second deposited layer 331_{b}, and the average layer thickness of the third deposited layer 331_{c}, may be substantially the same.

In some non-limiting examples, at least one deposited material 2431 used to form the first deposited layer 331ₐ may be substantially the same as at least one deposited material 2431 used to form at least one of: the second deposited layer 331_{b}, and the third deposited layer 331_{c}. In some non-limiting examples, such at least one deposited material 2431 may be substantially as described herein in respect of at least one of: the first electrode 1920, the second electrode 340, the auxiliary electrode 2850, and a deposited layer 331 thereof.

In some non-limiting examples, at least one of: the first emissive region 210ₐ, the second emissive region 210_{b}, and the third emissive region 210_{c} may be substantially devoid of a closed coating 2140 of the deposited material 2431 used to form the at least one auxiliary electrode 2850.

In some non-limiting examples, at least one of the first deposited layer 331ₐ, the second deposited layer 331_{b}, and the third deposited layer 331_{c}, may be at least one of: transmissive, and substantially transparent, in at least a part of the visible spectrum. Thus, in some non-limiting examples, at least one of: the second deposited layer 331_{b}, and the third deposited layer 331ₐ (and any additional deposited layer(s) 331) may be disposed on top of the first deposited layer 331ₐ to form a multi-coating electrode 1920, 340, 2850 that may also be at least one of: transmissive, and substantially transparent, in at least a part of the visible spectrum. In some non-limiting examples, the transmittance of any of the at least one of: the first deposited layer 331ₐ, the second deposited layer 331_{b}, the third deposited layer 331_{c}, any additional deposited layer(s) 331, and the multi-coating electrode 1920, 340, 2850, may exceed one of about: 30%, 40% 45%, 50%, 60%, 70%, 75%, and 80% in at least a part of the visible spectrum.

In some non-limiting examples, an average layer thickness of at least one of: the first deposited layer 331ₐ, the second deposited layer 331_{b}, and the third deposited layer 331_{c}, may be made substantially thin to maintain a substantially high transmittance. In some non-limiting examples, an average layer thickness of the first deposited layer 331ₐ may be one of between about: 5-30 nm, 8-25 nm, and 10-20 nm. In some non-limiting examples, an average layer thickness of the second deposited layer 331_{b} may be one of between about: 1-25 nm, 1-20 nm, 1-15 nm, 1-10 nm, and 3-6 nm. In some non-limiting examples, an average layer thickness of the third deposited layer 331_{c} may be one of between about: 1-25 nm, 1-20 nm, 1-15 nm, 1-10 nm, and 3-6 nm. In some non-limiting examples, a thickness of a multi-coating electrode formed by a combination of a plurality of: the first deposited layer 331ₐ, the second deposited layer 331_{b}, the third deposited layer 331_{c}, and any additional deposited layer(s) 331, may be one of between about: 6-35 nm, 10-30 nm, 10-25 nm, and 12-18 nm.

In some non-limiting examples, a thickness of the at least one auxiliary electrode 2850 may exceed an average layer thickness of at least one of: the first deposited layer 331ₐ, the second deposited layer 331_{b}, the third deposited layer 331_{c}, and a common electrode. In some non-limiting examples, the thickness of the at least one auxiliary electrode 2850 may be one of about: 50 nm, 80 nm, 100 nm, 150 nm, 200 nm, 300 nm, 400 nm, 500 nm, 700 nm, 800 nm, 1 μm, 1.2 μm, 1.5 μm, 2 μm, 2.5 μm, and 3 μm.

In some non-limiting examples, the at least one auxiliary electrode 2850 may be substantially at least one of: non-transparent, and opaque. However, since the at least one auxiliary electrode 2850 may be, in some non-limiting examples, provided in a non-emissive region 1911 of the device 2900, the at least one auxiliary electrode 2850 may not contribute to significant optical interference. In some non-limiting examples, the transmittance of the at least one auxiliary electrode 2850 may be one of no more than about: 50%, 70%, 80%, 85%, 90%, and 95% in at least a part of the visible spectrum.

In some non-limiting examples, the at least one auxiliary electrode 2850 may absorb light in at least a part of the visible spectrum.

### Conductive Coating for Electrically Coupling an Electrode to an Auxiliary Electrode

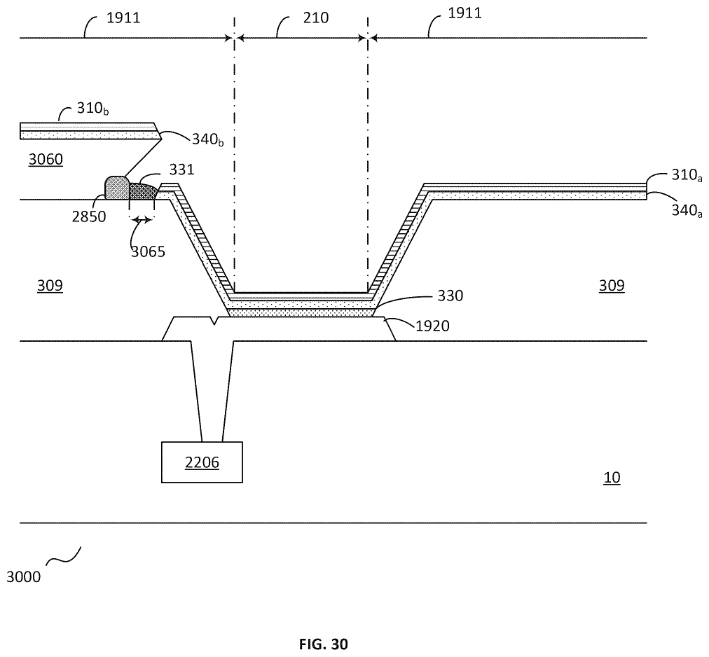

Turning to FIG. 30, there may be shown a cross-sectional view of an example version 3000 of an OLED device 2200. The device 3000 may comprise in a lateral aspect, an emissive region 210 and an adjacent non-emissive region 1911.

In some non-limiting examples, the emissive region 210 may correspond to a (sub-) pixel 215/216 of the device 3000. The emissive region 210 may have a substrate 10, a first electrode 1920, a second electrode 340 and at least one semiconducting layer 330 arranged therebetween.

The first electrode 1920 may be disposed on an exposed layer surface 11 of the substrate 10. The substrate 10 may comprise a TFT structure 2206, that may be electrically coupled with the first electrode 1920. At least one of: the edges, and perimeter, of the first electrode 1920 may generally be covered by at least one PDL 309.

The non-emissive region 1911 may have an auxiliary electrode 2850 and a first part of the non-emissive region 1911 may have a projection 3060 arranged to project over a lateral aspect of the auxiliary electrode 2850. The projection 3060 may extend laterally to provide a shaded region 3065. In some non-limiting examples, the projection 3060 may be recessed proximate to the auxiliary electrode 2850 on at least one side to provide the shaded region 3065. As shown, the shaded region 3065 may in some non-limiting examples, correspond to a region on a surface of the PDL 309 that may overlap with a lateral projection of the projection 3060. The non-emissive region 1911 may further comprise a deposited layer 331 disposed in the shaded region 3065. The deposited layer 331 may electrically couple the auxiliary electrode 2850 with the second electrode 340.

A patterning coating 310ₐ may be disposed in the emissive region 210 over the exposed layer surface 11 of the second electrode 340. In some non-limiting examples, an exposed layer surface 11 of the projection 3060 may be coated with a residual thin conductive film from deposition of a thin conductive film to form a second electrode 340. In some non-limiting examples, an exposed layer surface 11 of the residual thin conductive film may be coated with a residual patterning coating 310_{b} from deposition of the patterning coating 310.

However, because of the lateral projection of the projection 3060 over the shaded region 3065, the shaded region 3065 may be substantially devoid of patterning coating 310. Thus, when a deposited layer 331 may be deposited on the device 3000 after deposition of the patterning coating 310, the deposited layer 331 may at least one of: be deposited on, and migrate to, the shaded region 3065 to couple the auxiliary electrode 2850 with the second electrode 340.

Those having ordinary skill in the relevant art will appreciate that a non-limiting example has been shown in FIG. 30 and that various modifications may be apparent. In some non-limiting examples, the projection 3060 may provide a shaded region 3065 along at least two of its sides. In some non-limiting examples, the projection 3060 may be omitted and the auxiliary electrode 2850 may comprise a recessed portion that may define the shaded region 3065. In some non-limiting examples, the auxiliary electrode 2850 and the deposited layer 331 may be disposed directly on a surface of the substrate 10, instead of the PDL 309.

### Partition and Recess

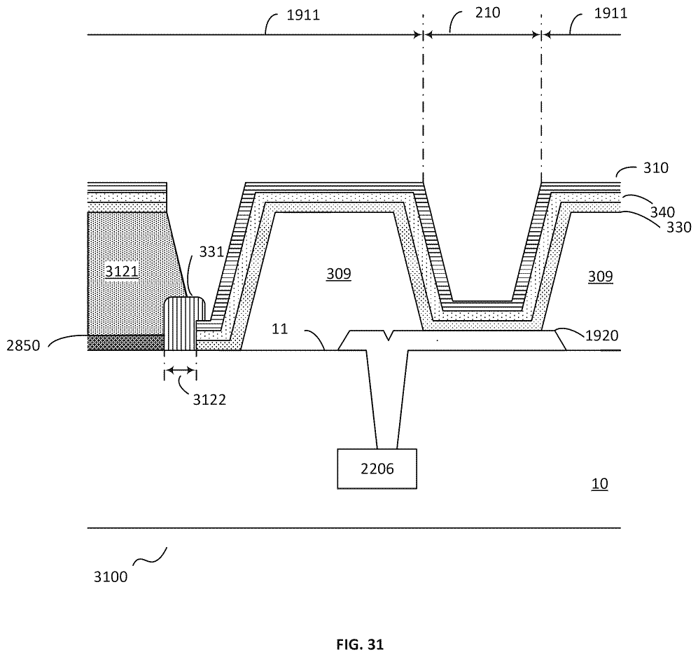

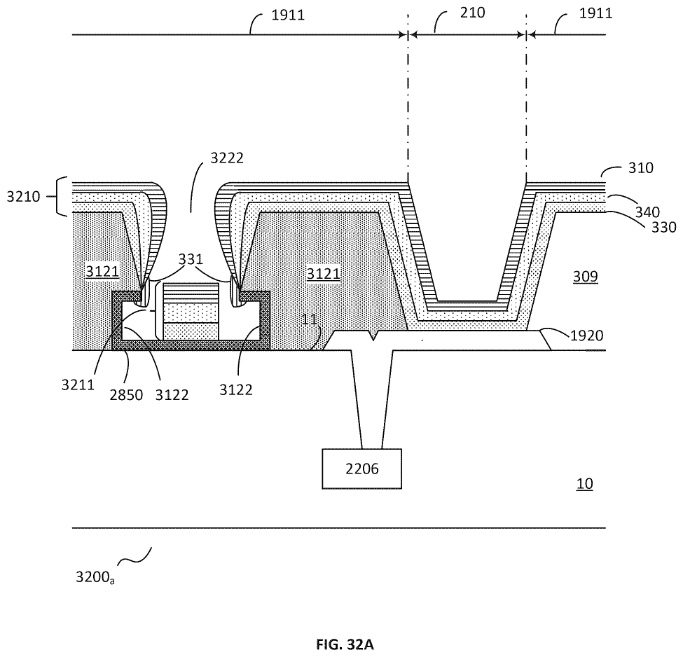

Turning to FIG. 31, there may be shown a cross-sectional view of an example version 3100 of an OLED device 2200. The device 3100 may comprise a substrate 10 having an exposed layer surface 11. The substrate 10 may comprise at least one TFT structure 2206. In some non-limiting examples, the at least one TFT structure 2206 may be formed by depositing and patterning a series of thin films when fabricating the substrate 10, in some non-limiting examples, as described herein.

The device 3100 may comprise, in a lateral aspect, an emissive region 210 having an associated lateral aspect and at least one adjacent non-emissive region 1911, each having an associated lateral aspect. The exposed layer surface 11 of the substrate 10 in the emissive region 210 may be provided with a first electrode 1920, that may be electrically coupled with the at least one TFT structure 2206. A PDL 309 may be provided on the exposed layer surface 11, such that the PDL 309 covers the exposed layer surface 11 as well as at least one of: an edge, and perimeter, of the first electrode 1920. The PDL 309 may, in some non-limiting examples, be provided in the lateral aspect of the non-emissive region 1911. The PDL 309 may define a valley-shaped configuration that may provide an opening that generally may correspond to the lateral aspect of the emissive region 210 through which a layer surface of the first electrode 1920 may be exposed. In some non-limiting examples, the device 3100 may comprise a plurality of such openings defined by the PDLs 309, each of which may correspond to a (sub-) pixel 215/216 region of the device 3100.

As shown, in some non-limiting examples, a partition 3121 may be provided on the exposed layer surface 11 in the lateral aspect of a non-emissive region 1911 and, as described herein, may define a shaded region 3065, such as a recessed region 3122. In some non-limiting examples, the recessed region 3122 may be formed by an edge of a lower section of the partition 3121 being at least one of: recessed, staggered, and offset, with respect to an edge of an upper section of the partition 3121 that may project beyond the recessed region 3122.

In some non-limiting examples, the lateral aspect of the emissive region 210 may comprise at least one semiconducting layer 330 disposed over the first electrode 1920, a second electrode 340, disposed over the at least one semiconducting layer 330, and a patterning coating 310 disposed over the second electrode 340. In some non-limiting examples, the at least one semiconducting layer 330, the second electrode 340 and the patterning coating 310 may extend laterally to cover at least the lateral aspect of a part of at least one adjacent non-emissive region 1911. In some non-limiting examples, as shown, the at least one semiconducting layer 330, the second electrode 340 and the patterning coating 310 may be disposed on at least a part of at least one PDL 309 and at least a part of the partition 3121. Thus, as shown, the lateral aspect of the emissive region 210, the lateral aspect of a part of at least one adjacent non-emissive region 1911, a part of at least one PDL 309, and at least a part of the partition 3121, together may make up a first portion 1901, in which the second electrode 340 may lie between the patterning coating 310 and the at least one semiconducting layer 330.

An auxiliary electrode 2850 may be disposed proximate to, including without limitation, within, the recessed region 3122 and a deposited layer 331 may be arranged to electrically couple the auxiliary electrode 2850 with the second electrode 340. Thus, as shown, in some non-limiting examples, the recessed region 3122 may comprise a second portion 1902, in which the deposited layer 331 is disposed on the exposed layer surface 11.

In some non-limiting examples, in depositing the deposited layer 331, at least a part of the evaporated flux 2432 of the deposited material 2431 may be directed at a non-normal angle relative to a lateral plane of the exposed layer surface 11. In some non-limiting examples, at least a part of the evaporated flux 2432 may be incident on the device 3100 at a non-zero angle of incidence that is, relative to such lateral plane of the exposed layer surface 11, one of no more than about: 90°, 85°, 80°, 75°, 70°, 60°, and 50°. By directing an evaporated flux 2432 of a deposited material 2431, including at least a part thereof incident at a non-normal angle, at least one exposed layer surface 11 of, including without limitation, in, the recessed region 3122 may be exposed to such evaporated flux 2432.

In some non-limiting examples, a likelihood of such evaporated flux 2432 being precluded from being incident onto at least one exposed layer surface 11 of, including without limitation, in, the recessed region 3122 due to the presence of the partition 3121, may be reduced since at least a part of such evaporated flux 2432 may be flowed at a non-normal angle of incidence.

In some non-limiting examples, at least a part of such evaporated flux 2432 may be non-collimated. In some non-limiting examples, at least a part of such evaporated flux 2432 may be generated by an evaporation source that is at least one of: a point, linear, and surface, source.

In some non-limiting examples, the device 3100 may be displaced during deposition of the deposited layer 331. In some non-limiting examples, at least one of: the device 3100, and the substrate 10 thereof, including without limitation, any layer(s) deposited thereon, may be subjected to a displacement that is angular, in an aspect that is at least one of: lateral, and substantially parallel, to the longitudinal aspect.

In some non-limiting examples, the device 3100 may be rotated about an axis that substantially normal to the lateral plane of the exposed layer surface 11 while being subjected to the evaporated flux 2432.

In some non-limiting examples, at least a part of such evaporated flux 2432 may be directed toward the exposed layer surface 11 of the device 3100 in a direction that is substantially normal to the lateral plane of the exposed layer surface 11.

Without wishing to be bound by a particular theory, it may be postulated that the deposited material 2431 may nevertheless be deposited within the recessed region 3122 due to at least one of: lateral migration, and desorption, of adatoms adsorbed onto the exposed layer surface 11 of the patterning coating 310. In some non-limiting examples, it may be postulated that any adatoms adsorbed onto the exposed layer surface 11 of the patterning coating 310 may tend to at least one of: migrate, and desorb, from such exposed layer surface 11 due to thermodynamic properties of the exposed layer surface 11 that may not have applicability for forming a stable nucleus. In some non-limiting examples, it may be postulated that at least some of the adatoms at least one of: migrating, and desorbing, off such exposed layer surface 11 may be re-deposited onto the surfaces in the recessed region 3122 to form the deposited layer 331.

In some non-limiting examples, the deposited layer 331 may be formed such that the deposited layer 331 may be electrically coupled with both the auxiliary electrode 2850 and the second electrode 340. In some non-limiting examples, the deposited layer 331 may be in physical contact with at least one of the auxiliary electrode 2850, and the second electrode 340. In some non-limiting examples, an intermediate layer may be present between the deposited layer 331 and at least one of: the auxiliary electrode 2850, and the second electrode 340. However, in such example, such intermediate layer may not substantially preclude the deposited layer 331 from being electrically coupled with the at least one of: the auxiliary electrode 2850, and the second electrode 340. In some non-limiting examples, such intermediate layer may be substantially thin and be such as to permit electrical coupling therethrough. In some non-limiting examples, a sheet resistance of the deposited layer 331 may be no more than a sheet resistance of the second electrode 340.

As shown in FIG. 31, the recessed region 3122 may be substantially devoid of the second electrode 340. In some non-limiting examples, during the deposition of the second electrode 340, the recessed region 3122 may be masked by the partition 3121, such that the evaporated flux 2432 of the deposited material 2431 for forming the second electrode 340 may be substantially precluded from being incident on at least one exposed layer surface 11 of, including without limitation, in, the recessed region 3122. In some non-limiting examples, at least a part of the evaporated flux 2432 of the deposited material 2431 for forming the second electrode 340 may be incident on at least one exposed layer surface 11 of, including without limitation, in, the recessed region 3122, such that the second electrode 340 may extend to cover at least a part of the recessed region 3122.

In some non-limiting examples, at least one of: the auxiliary electrode 2850, the deposited layer 331, and the partition 3121, may be selectively provided in certain region(s) of an OLED display panel 100. In some non-limiting examples, any of these features may be provided proximate to at least one edge of such display panel 100 for electrically coupling at least one element of the frontplane 301, including without limitation, the second electrode 340, with at least one element of the backplane 302. In some non-limiting examples, providing such features proximate to such edges may facilitate supplying and distributing electrical current to the second electrode 340 from an auxiliary electrode 2850 located proximate to such edges. In some non-limiting examples, such configuration may facilitate reducing a bezel size of the display panel 100.

In some non-limiting examples, at least one of: the auxiliary electrode 2850, the deposited layer 331, and the partition 3121, may be omitted from certain regions(s) of such display panel 100. In some non-limiting examples, such features may be omitted from parts of the display panel 100, including without limitation, where a substantially high pixel density may be provided, other than proximate to at least one edge thereof.

### Aperture in Non-Emissive Region

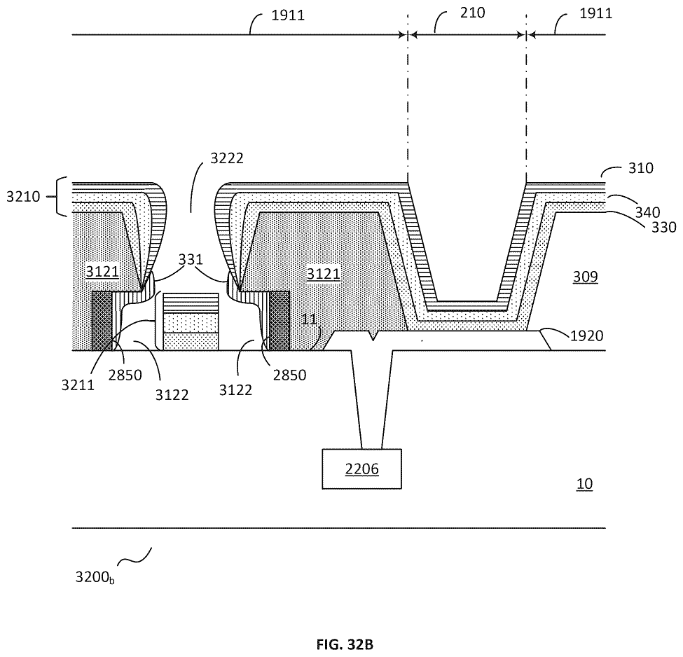

Turning now to FIG. 32A, there may be shown a cross-sectional view of an example version 3200ₐ of an OLED device 2200. The device 3200ₐ may differ from the device 3100 in that a pair of partitions 3121 in the non-emissive region 1911 may be disposed in a facing arrangement to define a shaded region 3065, such as an aperture 3222, therebetween. As shown, in some non-limiting examples, at least one of the partitions 3121 may function as a PDL 309 that covers at least an edge of the first electrode 1920 and that defines at least one emissive region 210. In some non-limiting examples, at least one of the partitions 3121 may be provided separately from a PDL 309.

A shaded region 3065, such as the recessed region 3122, may be defined by at least one of the partitions 3121. In some non-limiting examples, the recessed region 3122 may be provided in a part of the aperture 3222 proximate to the substrate 10. In some non-limiting examples, the aperture 3222, when viewed in plan, may be substantially elliptical. In some non-limiting examples, the recessed region 3122, when viewed in plan, may be substantially annular and surround the aperture 3222.

In some non-limiting examples, the recessed region 3122 may be substantially devoid of materials for forming each of the layers of at least one of: a device stack 3210, and of a residual device stack 3211.

In these figures, a device stack 3210 may be shown comprising the at least one semiconducting layer 330, the second electrode 340 and the patterning coating 310 deposited on an upper section of the partition 3121.

In these figures, a residual device stack 3211 may be shown comprising the at least one semiconducting layer 330, the second electrode 340 and the patterning coating 310 deposited on the substrate 10 beyond the partition 3121 and recessed region 3122. From comparison with FIG. 31, it may be seen that the residual device stack 3211 may, in some non-limiting examples, correspond to the semiconducting layer 330, second electrode 340 and the patterning coating 310 as it approaches the recessed region 3122 proximate to a lip of the partition 3121. In some non-limiting examples, the residual device stack 3211 may be formed when one of: an open mask, and a mask-free, deposition process is used to deposit various materials of the device stack 3210.

In some non-limiting examples, the residual device stack 3211 may be disposed within the aperture 3222. In some non-limiting examples, evaporated materials for forming each of the layers of the device stack 3210 may be deposited within the aperture 3222 to form the residual device stack 3211 therein.

In some non-limiting examples, the auxiliary electrode 2850 may be arranged such that at least a part thereof is disposed within the recessed region 3122. As shown, in some non-limiting examples, the auxiliary electrode 2850 may be arranged within the aperture 3222, such that the residual device stack 3211 is deposited onto a surface of the auxiliary electrode 2850.

A deposited layer 331 may be disposed within the aperture 3222 for electrically coupling the second electrode 340 with the auxiliary electrode 2850. In some non-limiting examples, at least a part of the deposited layer 331 may be disposed within the recessed region 3122.

Turning now to FIG. 32B, there may be shown a cross-sectional view of a further version 3200_{b} of an OLED device 2200. As shown, the auxiliary electrode 2850 may be arranged to form at least a part of a side of the partition 3121. As such, the auxiliary electrode 2850 may be substantially annular, when viewed in plan view, and may surround the aperture 3222. As shown, in some non-limiting examples, the residual device stack 3211 may be deposited onto an exposed layer surface 11 of the substrate 10.

In some non-limiting examples, the partition 3121 may comprise an NPC 2620. In some non-limiting examples, the auxiliary electrode 2850 may act as an NPC 2620.

In some non-limiting examples, the NPC 2620 may be provided by the second electrode 340, including without limitation, at least one of: a portion, layer, and material thereof. In some non-limiting examples, the second electrode 340 may extend laterally to cover the exposed layer surface 11 arranged in the shaded region 3065. In some non-limiting examples, the second electrode 340 may comprise a lower layer thereof and a second layer thereof, wherein the second layer thereof may be deposited on the lower layer thereof. In some non-limiting examples, the lower layer of the second electrode 340 may comprise an oxide such as, without limitation, ITO, IZO, and ZnO. In some non-limiting examples, the upper layer of the second electrode 340 may comprise a metal such as, without limitation, at least one of Ag, Mg, Mg:Ag, Yb/Ag, other alkali metals, and other alkali earth metals.

In some non-limiting examples, the lower layer of the second electrode 340 may extend laterally to cover a surface of the shaded region 3065, such that it forms the NPC 2620. In some non-limiting examples, at least one surface defining the shaded region 3065 may be treated to form the NPC 2620. In some non-limiting examples, such NPC 2620 may be formed by at least one of: chemical, and physical, treatment, including without limitation, subjecting the surface(s) of the shaded region 3065 to at least one of: a plasma, UV, and UV-ozone treatment.

Without wishing to be bound to any particular theory, it may be postulated that such treatment may at least one of: chemically, and physically, alter such surface(s) to modify at least one property thereof. In some non-limiting examples, such treatment of the surface(s) may increase at least one of: a concentration of at least one of: C—O, and C—OH, bonds on such surface(s), a roughness of such surface(s), and a concentration of certain species, including without limitation, functional groups, including without limitation, at least one of: halogens, nitrogen-containing functional groups, and oxygen-containing functional groups, to thereafter act as an NPC 2620.

### Removal of Selective Coating

In some non-limiting examples, the patterning coating 310 may be removed after deposition of the deposited layer 331, such that at least a part of a previously exposed layer surface 11 of an underlying layer 2610 of a device 2200, covered by the patterning coating 310 may become exposed once again. In some non-limiting examples, the patterning coating 310 may be selectively removed by at least one of: etching, dissolving the patterning coating 310, and by employing at least one of: plasma, and solvent, processing techniques that do not substantially affect, including without limitation, erode, the deposited layer 331.

In some non-limiting examples, at an initial deposition stage, a patterning coating 310 may have been selectively deposited on a first portion 1901 of an exposed layer surface 11 of an underlying layer 2610, including without limitation, the substrate 10.

In some non-limiting examples, at a further deposition stage, a deposited layer 331 may be deposited on the exposed layer surface 11 of the underlying layer 2610, that is, on both the exposed layer surface 11 of the patterning coating 310 where the patterning coating 310 may have been deposited during the initial deposition stage, as well as the exposed layer surface 11 of the substrate 10 where that patterning coating 310 may not have been deposited during the initial deposition stage. Because of the nucleation-inhibiting properties of the first portion 1901 where the patterning coating 310 may have been disposed, the deposited layer 331 disposed thereon may tend to not remain, resulting in a pattern of selective deposition of the deposited layer 331, that may correspond to a second portion 1902, leaving the first portion 1901 substantially devoid of the deposited layer 331.

In some non-limiting examples, at a final deposition stage, the patterning coating 310 may have been removed from the first portion 1901 of the exposed layer surface 11 of the substrate 10, such that the deposited layer 331 deposited during the further deposition stage may remain on the substrate 10 and regions of the substrate 10 on which the patterning coating 310 may have been deposited during the initial deposition stage may now be exposed (uncovered).

In some non-limiting examples, the removal of the patterning coating 310 in the final deposition stage may be effected by exposing the device 2200 to at least one of: a solvent, and a plasma that etches away (reacts with) the patterning coating 310 without substantially impacting the deposited layer 331.

### Thin Film Formation

The formation of thin films during vapor deposition on an exposed layer surface 11 of an underlying layer 2610 may involve processes of nucleation and growth.

During initial stages of film formation, a sufficient number of vapor monomers, which in some non-limiting examples may be at least one of: molecules, and atoms of a deposited material 2431 in vapor form) may condense from a vapor phase to form initial nuclei on the exposed layer surface 11 presented of an underlying layer 2610. As vapor monomers may impinge on such surface, at least one of: a characteristic size, and deposited density, of these initial nuclei may increase to form small particle structures 2150. Non-limiting examples of a dimension to which such characteristic size refers may include at least one of: a height, width, length, and diameter, of such particle structure 2150.

After reaching a saturation island density, adjacent particle structures 2150 may start to coalesce, increasing an average characteristic size of such particle structures 2150, while decreasing a deposited density thereof.

With continued vapor deposition of monomers, coalescence of adjacent particle structures 2150 may continue until a substantially closed coating 2140 may eventually be deposited on an exposed layer surface 11 of an underlying layer 2610. The behaviour, including optical effects caused thereby, of such closed coatings 140 may be generally substantially uniform, and consistent.

There may be at least three basic growth modes for the formation of thin films, in some non-limiting examples, culminating in a closed coating 2140: 1) island (Volmer-Weber), 2) layer-by-layer (Frank-van der Merwe), and 3) Stranski-Krastanov.

Island growth may occur when stale clusters of monomers nucleate on an exposed layer surface 11 and grow to form discrete islands. This growth mode may occur when the interaction between the monomers is stronger than that between the monomers and the surface.

The nucleation rate may describe how many nuclei of a given size (where the free energy does not push a cluster of such nuclei to one of: grow, and shrink) (“critical nuclei”) may be formed on a surface per unit time. During initial stages of film formation, it may be unlikely that nuclei will grow from direct impingement of monomers on the surface, since the deposited density of nuclei is low, and thus the nuclei may cover a substantially small fraction of the surface (e.g., there are large gaps/spaces between neighboring nuclei). Therefore, the rate at which critical nuclei may grow may depend on the rate at which adatoms (e.g., adsorbed monomers) on the surface migrate and attach to nearby nuclei.

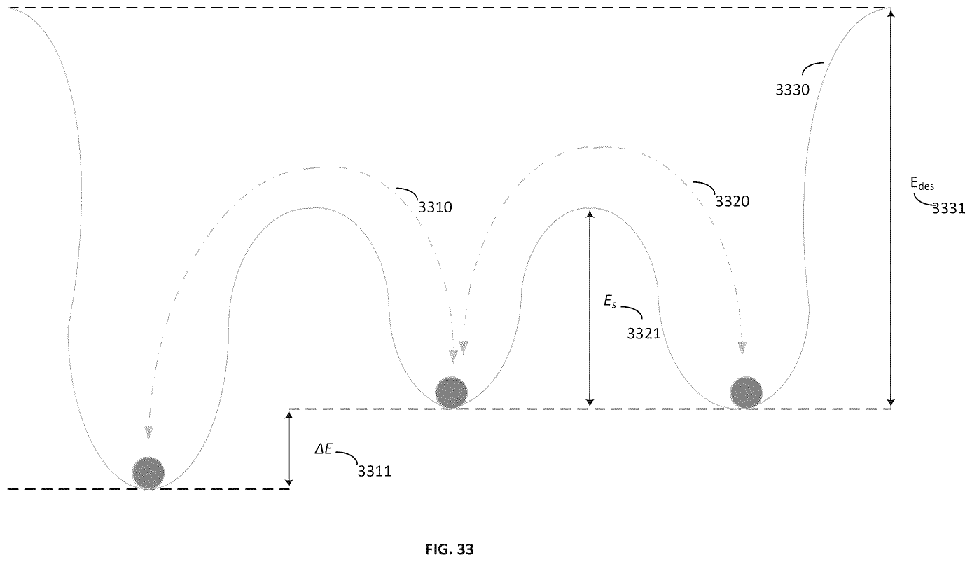

An example of an energy profile of an adatom adsorbed onto an exposed layer surface 11 of an underlying layer 2610 is illustrated in FIG. 33. Specifically, FIG. 33 may illustrate example qualitative energy profiles corresponding to: an adatom escaping from a local low energy site (3310); diffusion of the adatom on the exposed layer surface 11 (3320); and desorption of the adatom (3330).

In 3310, the local low energy site may be any site on the exposed layer surface 11 of an underlying layer 2610, onto which an adatom will be at a lower energy. In some non-limiting examples, the nucleation site may comprise at least one of: a defect, and an anomaly, on the exposed layer surface 11, including without limitation, at least one of: a ledge, a step edge, a chemical impurity, a bonding site, and a kink (“heterogeneity”).

Sites of substrate heterogeneity may increase an energy involved to desorb the adatom from the surface E_{des} 3331, leading to a higher deposited density of nuclei observed at such sites. Also, impurities, including without limitation, contamination, on a surface may also increase E_{des} 3331, leading to a higher deposited density of nuclei. For vapor deposition processes, conducted under high vacuum conditions, the type and deposited density of contaminants on a surface may be affected by a vacuum pressure and a composition of residual gases that make up that pressure.

Once the adatom is trapped at the local low energy site, there may, in some non-limiting examples, be an energy barrier before surface diffusion takes place. Such energy barrier may be represented as ΔE 3311 in FIG. 33. In some non-limiting examples, if the energy barrier ΔE 3311 to escape the local low energy site is substantially large, the site may act as a nucleation site.

In 3320, the adatom may diffuse on the exposed layer surface 11. In some non-limiting examples, in the case of localized absorbates, adatoms may tend to oscillate near a minimum of the surface potential and migrate to various neighboring sites until the adatom is either one of: desorbed, and is incorporated into growing islands 2150 formed by at least one of: a cluster of adatoms, and a growing film. In FIG. 33, the activation energy associated with surface diffusion of adatoms may be represented as Eₛ 3321.

In 3330, the activation energy associated with desorption of the adatom from the surface may be represented as E_{des} 3331. Those having ordinary skill in the relevant art will appreciate that any adatoms that are not desorbed may remain on the exposed layer surface 11. In some non-limiting examples, such adatoms may diffuse on the exposed layer surface 11, become part of a cluster of adatoms that at least one of: form islands 2150 on the exposed layer surface 11, and be incorporated as part of a growing coating.

After adsorption of an adatom on a surface, the adatom may one of: desorb from the surface, and may migrate some distance on the surface before either desorbing, interacting with other adatoms to one of: form a small cluster, attach to a growing nucleus. An average amount of time that an adatom may remain on the surface after initial adsorption may be given by Equation (6):

$${τ}_{s} = \frac{1}{v} exp ( \frac{{E}_{d e s}}{k T} ) \qquad ( 6 )$$

In the above Equation (6):
v is a vibrational frequency of the adatom on the surface,
k is the Boltzmann constant, and
T is temperature.

From Equation (6) it may be noted that the lower the value of E_{des} 3331, the easier it may be for the adatom to desorb from the surface, and hence the shorter the time the adatom may remain on the surface. A mean distance an adatom can diffuse may be given by Equation (7):

$$X = {a}_{0} exp ( \frac{{E}_{des} - {E}_{s}}{2 k T} ) \qquad ( 7 )$$

where:
α₀ is a lattice constant.

For at least one of: low values of E_{des} 3331, and high values of Eₛ 3321, the adatom may diffuse a shorter distance before desorbing, and hence may be less likely to at least one of: attach to growing nuclei, and interact with another one of: adatom, and cluster of adatoms.

During initial stages of formation of a deposited layer of particle structures 2150, adsorbed adatoms may interact to form particle structures 2150, with a critical concentration of particle structures 2150 per unit area being given by Equation (8):

$$\frac{{N}_{i}}{{n}_{0}} = {\vert \frac{{N}_{1}}{{n}_{0}} \vert}^{i} exp ( \frac{{E}_{i}}{k T} ) \qquad ( 8 )$$

where:
Eᵢ is an energy involved to dissociate a critical cluster comprising i adatoms into separate adatoms,
n₀ is a total deposited density of adsorption sites, and
N₁ is a monomer deposited density given by Equation (9):

$${N}_{1} = \dot{R} {τ}_{s} \qquad ( 9 )$$

where:
R is a vapor impingement rate.

In some non-limiting examples, i may depend on a crystal structure of a material being deposited and may determine a critical size of particle structures 2150 to form a stable nucleus.

A critical monomer supply rate for growing particle structures 2150 may be given by the rate of vapor impingement and an average area over which an adatom can diffuse before desorbing according to Equation (10):

$$\dot{R} {X}^{2} = {α}_{0}^{2} exp ( \frac{{E}_{d e s} - {E}_{s}}{k T} ) \qquad ( 10 )$$

The critical nucleation rate may thus be given by the combination of the above equations to form Equation (11):

$${\dot{N}}_{i} = \dot{R} {α}_{0}^{2} {{n}_{0} ( \frac{R}{v {n}_{0}} )}^{i} exp ( \frac{( i + 1 ) {E}_{d e s} - {E}_{s} + {E}_{i}}{k T} ) \qquad ( 11 )$$

From Equation (11), it may be noted that the critical nucleation rate may be suppressed for surfaces that have a low desorption energy for adsorbed adatoms, a high activation energy for diffusion of an adatom, are at least one of: at high temperatures, and are subjected to vapor impingement rates.

Under high vacuum conditions, a flux 2432 of molecules that may impinge on a surface (per cm²-sec) may be given by Equation (12):

$$ϕ = 3.513 \times 1 {0}^{22} \frac{P}{M T} \qquad ( 12 )$$

where:
P is pressure, and
M is molecular weight.

Therefore, a higher partial pressure of a reactive gas, such as H₂O, may lead to a higher deposited density of contamination on a surface during vapor deposition, leading to an increase in E_{des} 3331 and hence a higher deposited density of nuclei.

In the present disclosure, “nucleation-inhibiting” may refer to at least one of: a coating, material, and a layer thereof, that may have a surface that exhibits an initial sticking probability against deposition of a deposited material 2431 thereon, that may be close to 0, including without limitation, less than about 0.3, such that the deposition of the deposited material 2431 on such surface may be inhibited.

In the present disclosure, “nucleation-promoting” may refer to at least one of: a coating, material, and a layer thereof, that has a surface that exhibits an initial sticking probability against deposition of a deposited material 2431 thereon, that may be close to 1, including without limitation, greater than about 0.7, such that the deposition of the deposited material 2431 on such surface may be facilitated.

Without wishing to be bound by a particular theory, it may be postulated that the shapes and sizes of such nuclei and the subsequent growth of such nuclei into islands 2150 and thereafter into a thin film may depend upon various factors, including without limitation, interfacial tensions between at least one of: the vapor, the surface, and the condensed film nuclei.

One measure of at least one of: a nucleation-inhibiting, and nucleation-promoting, property of a surface may be the initial sticking probability of the surface against the deposition of a given deposited material 2431.

In some non-limiting examples, the sticking probability S may be given by Equation (13):

$$S = \frac{{N}_{a d s}}{{N}_{t o t a l}} \qquad ( 13 )$$

where:
N_{ads} is a number of adatoms that remain on an exposed layer surface 11 (that is, are incorporated into a film), and
Nₜₒₜₐₗ is a total number of impinging monomers on the surface.

A sticking probability S equal to 1 may indicate that all monomers that impinge on the surface are adsorbed and subsequently incorporated into a growing film. A sticking probability S equal to 0 may indicate that all monomers that impinge on the surface are desorbed and subsequently no film may be formed on the surface.

A sticking probability S of a deposited material 2431 on various surfaces may be evaluated using various techniques of measuring the sticking probability S, including without limitation, a dual quartz crystal microbalance (QCM) technique as described by Walker et al., J. Phys. Chem. C 2007, 111, 765 (2006).

As the deposited density of a deposited material 2431 may increase (e.g., increasing average film thickness), a sticking probability S may change.

An initial sticking probability So may therefore be specified as a sticking probability S of a surface prior to the formation of any significant number of critical nuclei. One measure of an initial sticking probability So may involve a sticking probability S of a surface against the deposition of a deposited material 2431 during an initial stage of deposition thereof, where an average film thickness of the deposited material 2431 across the surface is at, including without limitation, below, a threshold value. In the description of some non-limiting examples a threshold value for an initial sticking probability may be specified as, in some non-limiting examples, 1 nm. An average sticking probability S may then be given by Equation (14):

$$\overline{S} = {S}_{0} ( 1 - {A}_{n u c} ) + {S}_{n u c} ( {A}_{n u c} ) \qquad ( 14 )$$

where:
S_{nuc} is a sticking probability S of an area covered by particle structures 2150, and
A_{nuc} is a percentage of an area of a substrate surface covered by particle structures 2150.

In some non-limiting examples, a low initial sticking probability may increase with increasing average film thickness. This may be understood based on a difference in sticking probability between an area of an exposed layer surface 11 with no particle structures 2150, in some non-limiting examples, a bare substrate 10, and an area with a high deposited density. In some non-limiting examples, a monomer that may impinge on a surface of a particle structure 2150 may have a sticking probability that may approach 1.

Based on the energy profiles 3310, 3320, 3330 shown in FIG. 33, it may be postulated that materials that exhibit at least one of: substantially low activation energy for desorption (E_{des} 3331), and substantially high activation energy for surface diffusion (Eₛ 3321), may be deposited as a patterning coating 310, and may have applicability for use in various applications.

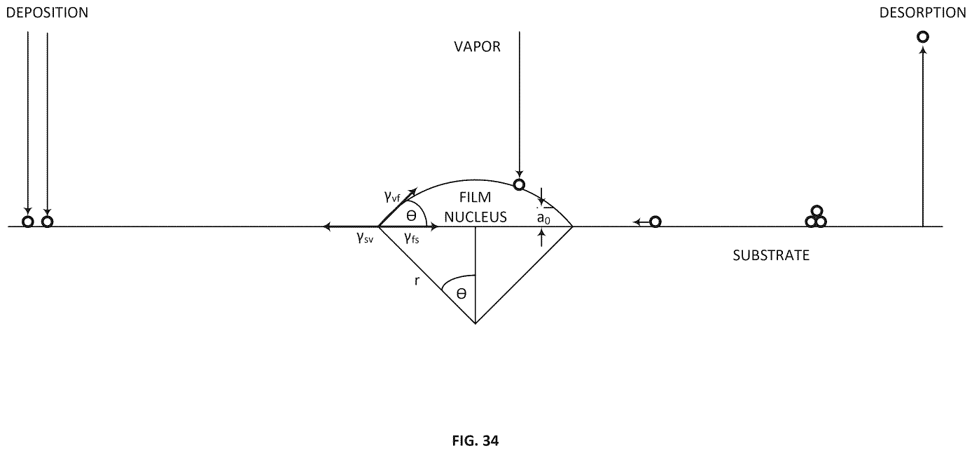

Without wishing to be bound by a particular theory, it may be postulated that, in some non-limiting examples, the relationship between various interfacial tensions present during nucleation and growth may be dictated according to Young's equation in capillarity theory (Equation (15)):

$${γ}_{s v} = {γ}_{fs} + {γ}_{vf} cos θ \qquad ( 15 )$$

where:
γₛᵥ (FIG. 34) corresponds to the interfacial tension between the substrate 10 and vapor,
γ_{fs} (FIG. 34) corresponds to the interfacial tension between the deposited material 2431 and the substrate 10,
γ_{vf} (FIG. 34) corresponds to the interfacial tension between the vapor flux 2432 and the film, and
θ is the film nucleus contact angle.

FIG. 34 may illustrate the relationship between the various parameters represented in this equation.

On the basis of Young's equation (Equation (15)), it may be derived that, for island growth, the film nucleus contact angle may exceed 0 and therefore: γₛᵥ<γ_{fs}+γ_{vf}.

For layer growth, where the deposited material 2431 may “wet” the substrate 10, the nucleus contact angle θ may be equal to 0, and therefore: γₛᵥ=γ_{fs}+γ_{vf}.

For Stranski-Krastanov growth, where the strain energy per unit area of the film overgrowth may be large with respect to the interfacial tension between the vapor flux 2432 and the deposited material 2431: γₛᵥ>γ_{fs}+γ_{vf}.

Without wishing to be bound by any particular theory, it may be postulated that the nucleation and growth mode of a deposited material 2431 at an interface between the patterning coating 310 and the exposed layer surface 11 of the substrate 10, may follow the island growth model, where θ>0.

Particularly in cases where the patterning coating 310 may exhibit a substantially low initial sticking probability (in some non-limiting examples, under the conditions identified in the dual QCM technique described by Walker et al.) against deposition of the deposited material 2431, there may be a substantially high thin film contact angle of the deposited material 2431.

On the contrary, when a deposited material 2431 may be selectively deposited on an exposed layer surface 11 without the use of a patterning coating 310, in some non-limiting examples, by employing a shadow mask 2315, the nucleation and growth mode of such deposited material 2431 may differ. In some non-limiting examples, it has been observed that a coating formed using a shadow mask 2315 patterning process may, at least in some non-limiting examples, exhibit a substantially low thin film contact angle of no more than about 10°.

It has now been found, that in some non-limiting examples, a patterning coating 310 (including without limitation, the patterning material 2311 of which it is comprised) may exhibit a substantially low critical surface tension.

Those having ordinary skill in the relevant art will appreciate that a “surface energy” of at least one of: a coating, layer, and a material constituting such at least one of: a coating, and layer, may generally correspond to a critical surface tension of the at least one of: coating, layer, and material. According to some models of surface energy, the critical surface tension of a surface may correspond substantially to the surface energy of such surface.

Generally, a material with a low surface energy may exhibit low intermolecular forces. Generally, a material with low intermolecular forces may readily one of: crystallize, and undergo other phase transformation, at a lower temperature in comparison to another material with high intermolecular forces. In at least some applications, a material that may readily one of: crystallize, and undergo other phase transformations, at substantially low temperatures may be detrimental to at least one of: the long-term performance, stability, reliability, and lifetime, of the device 2100.

Without wishing to be bound by a particular theory, it may be postulated that certain low energy surfaces may exhibit substantially low initial sticking probabilities and may thus have applicability for forming the patterning coating 310.

Without wishing to be bound by any particular theory, it may be postulated that, especially for low surface energy surfaces, the critical surface tension may be positively correlated with the surface energy. In some non-limiting examples, a surface exhibiting a substantially low critical surface tension may also exhibit a substantially low surface energy, and a surface exhibiting a substantially high critical surface tension may also exhibit a substantially high surface energy.

In reference to Young's equation (Equation (15)), a lower surface energy may result in a greater contact angle, while also lowering the γₛᵥ, thus enhancing the likelihood of such surface having low wettability and low initial sticking probability with respect to the deposited material 2431.

The critical surface tension values, in various non-limiting examples, herein may correspond to such values measured at around normal temperature and pressure (NTP), which in some non-limiting examples, may correspond to a temperature of 20° C., and an absolute pressure of 1 atm. In some non-limiting examples, the critical surface tension of a surface may be determined according to the Zisman method, as further detailed in Zisman, W. A., “Advances in Chemistry” 43 (1964), p. 1-51.

In some non-limiting examples, the exposed layer surface 11 of the patterning coating 310 may exhibit a critical surface tension of one of no more than about: 20 dynes/cm, 19 dynes/cm, 18 dynes/cm, 17 dynes/cm, 16 dynes/cm, 15 dynes/cm, 13 dynes/cm, 12 dynes/cm, and 11 dynes/cm.

In some non-limiting examples, the exposed layer surface 11 of the patterning coating 310 may exhibit a critical surface tension of one of at least about: 6 dynes/cm, 7 dynes/cm, 8 dynes/cm, 9 dynes/cm, and 10 dynes/cm.

Those having ordinary skill in the relevant art will appreciate that various methods and theories for determining the surface energy of a solid may be known. In some non-limiting examples, the surface energy may be calculated (derived) based on a series of measurements of contact angle, in which various liquids are brought into contact with a surface of a solid to measure the contact angle between the liquid-vapor interface and the surface. In some non-limiting examples, the surface energy of a solid surface may be equal to the surface tension of a liquid with the highest surface tension that completely wets the surface. In some non-limiting examples, a Zisman plot may be used to determine the highest surface tension value that would result in a contact angle of 0° with the surface. According to some theories of surface energy, various types of interactions between solid surfaces and liquids may be considered in determining the surface energy of the solid. In some non-limiting examples, according to some theories, including without limitation, at least one of: the Owens/Wendt theory, and Fowkes' theory, the surface energy may comprise a dispersive component and a non-dispersive (“polar”) component.

Without wishing to be bound by a particular theory, it may be postulated that, in some non-limiting examples, the contact angle of a coating of deposited material 2431 may be determined, based at least partially on the properties (including, without limitation, initial sticking probability) of the patterning coating 310 onto which the deposited material 2431 is deposited. Accordingly, patterning materials 2311 that allow selective deposition of deposited materials 2431 exhibiting substantially high contact angles may provide some benefit.

Those having ordinary skill in the relevant art will appreciate that various methods may be used to measure a contact angle θ, including without limitation, at least one of: the static, and dynamic, sessile drop method and the pendant drop method.

In some non-limiting examples, the activation energy for desorption (E_{des} 3331) (in some non-limiting examples, at a temperature T of about 300K) may be one of no more than about: 2, 1.5, 1.3, 1.2, 1.0, 0.8, and 0.5 times, the thermal energy. In some non-limiting examples, the activation energy for surface diffusion (Eₛ 3321) (in some non-limiting examples, at a temperature of about 300K) may exceed one of about: 1.0, 1.5, 1.8, 2, 3, 5, 7, and 10 times the thermal energy.

Without wishing to be bound by a particular theory, it may be postulated that, during thin film nucleation and growth of a deposited material 2431 proximate to an interface between the exposed layer surface 11 of the underlying layer 2610 and the patterning coating 310, a substantially high contact angle between the edge of the deposited material 2431 and the underlying layer 2610 may be observed due to the inhibition of nucleation of the solid surface of the deposited material 2431 by the patterning coating 310. Such nucleation inhibiting property may be driven by minimization of surface energy between the underlying layer 2610, thin film vapor and the patterning coating 310.

One measure of at least one of: a nucleation-inhibiting, and nucleation-promoting, property of a surface may be an initial deposition rate of a given (electrically conductive) deposited material 2431, on the surface, relative to an initial deposition rate of the same deposited material 2431 on a reference surface, where both surfaces are subjected to, (including without limitation, exposed to) an evaporation flux of the deposited material 2431.

### Computer Device for Performing Method Actions

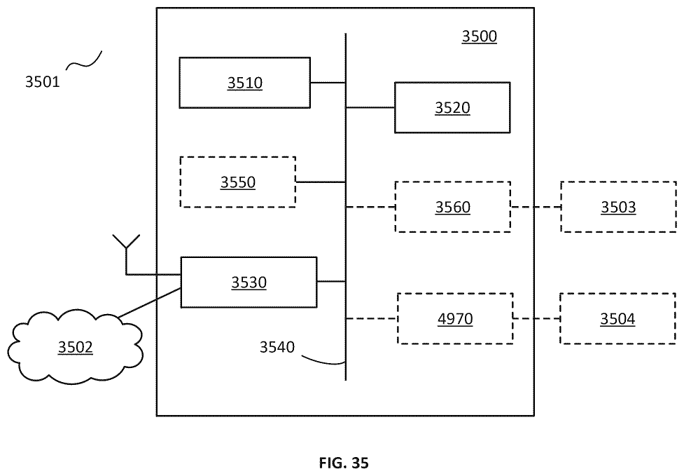

FIG. 35 is a simplified block diagram of a computing device 3500 illustrated within a computing and communications environment 3501, according to an example, that may be used for implementing the devices and methods disclosed herein.

In some non-limiting examples, the device 3500 may comprise a processor 3510, a memory 3520, a network interface 3530, and a bus 3540. In some non-limiting examples, the device 3500 may comprise a storage unit 3550, a video adapter 3560 and a peripheral interface 3570.

In some non-limiting examples, the device 3500 may utilize one of: all of the components shown, and only a subset thereof, and levels of integration may vary from device to device.

In some non-limiting examples, the device 3500 may comprise a plurality of instances of a component.

In some non-limiting examples, the processor 3510 may comprise a central processing unit (CPU), which in some non-limiting examples, may be one of: a single core processor, a multiple core processor, and a plurality of processors for parallel processing, and in some non-limiting examples, may comprise at least one of: a general-purpose processor, a dedicated application-specific specialized processor, including without limitation, a multiprocessor, a microcontroller, a reduced instruction set computer (RISC), a digital signal processor (DSP), a graphics processing unit (GPU), and the like, and a shared-purpose processor. In some non-limiting examples, the processor 3510 may comprise at least one of: dedicated hardware, and hardware capable of executing software. In some non-limiting examples, the processor 3510 may be part of a circuit, including without limitation, an integrated circuit. In some non-limiting examples, at least one other component of the device 3500 may be embodied in the circuit. In some non-limiting examples, the circuit may be one of: an application-specific integrated circuit (ASIC), and a floating-point gate array (FPGA).

In some non-limiting examples, the processor 3510 may control the general operation of the device 3500, in some non-limiting examples, by sending at least one of: data, and control signals, to at least one of: the memory 3520, the network interface 3530, the storage unit 3550, the video adapter 3560, and the peripheral interface 3570, and by retrieving at least one of: data, and instructions, from at least one of: the memory 3520, and the storage unit 3550, to execute methods disclosed herein. In some non-limiting examples, such instructions may be executed in at least one of: simultaneous, serial, and distributed fashion, by at least one processor 3510.

In some non-limiting examples, the processor 3510 may execute a sequence of one of: machine-readable, and machine-executable, instructions, which may be embodied in one of: a program, and software. In some non-limiting examples, the program may be stored in one of: the memory 3520, and the storage unit 3550. In some non-limiting examples, the program may be retrieved from one of: the memory 3520, and the storage unit 3550, and stored in the memory 3520 for ready access, and execution, by the processor 3510. In some non-limiting examples, the program may be directed to the processor 3510, which may subsequently configure the processor 3510 to implement methods of the present disclosure. Non-limiting examples of operations performed by the processor 3510 include at least one of: fetch, decode, execute, and writeback.

In some non-limiting examples, the program may be one of: pre-compiled, and configured for use with a machine having a processor adapted to execute the instructions and may be compiled during run-time. In some non-limiting examples, the program may be supplied in a programming language that may be selected to enable the instructions to execute in one of: a pre-compiled, interpreted, and an as-compiled, fashion.

However configured, the hardware of the processor 3510 may be configured so as to be capable of operating with sufficient software, processing power, memory resources, and network throughput capability, to handle any workload placed upon it.

In some non-limiting examples, the memory 3520 may be a storage device configured to store data, programs, in the form of one of: machine-readable, and machine-executable, instructions, and other information accessible within the device 3500, along the bus 3540.

In some non-limiting examples, the memory 3520 may comprise any type of transitory and non-transitory memory, including without limitation, at least one of: persistent, non-persistent, and volatile storage, including without limitation, system memory, readable by the processor 3510, including without limitation, semiconductor memory devices, including without limitation, random access memory (RAM), static RAM (SRAM), dynamic RAM (DRAM), synchronous DRAM (SDRAM), read-only memory (ROM), programmable ROM (PROM), erasable PROM (EPROM), and electrically erasable PROM (EEPROM), and at least one buffer circuit including without limitation, at least one of: latches and flip flops. In some non-limiting examples, the memory 3520 may comprise a plurality of types of memory, including without limitation, ROM for use at boot-up, and DRAM for program and data storage for use while executing programs.

In some non-limiting examples, the network interface 3530 may allow the device 3500 to communicate with remote entities, across at least one of: a telecommunications network, and a data network (network) 3502, including without limitation, at least one of: the Internet, an intranet, including without limitation, one in communication with the Internet, and an extranet, including without limitation, one in communication with the Internet, and may comprise at least one of: a network adapter, a wired network interface, including without limitation, a local area network (LAN) card, including without limitation, an ethernet card, a token ring card, and a fiber distributed data interface (FDDI) card, and a wireless network interface, including without limitation, a WIFI network interface, a modem, a modem bank, and a wireless LAN (WLAN) card, and a radio access network (RAN) interface, including without limitation, a radio transceiver card, to connect to other devices over a radio link.

In some non-limiting examples, the network 3502 may comprise at least one computer server, which may, in some non-limiting examples, comprise a device 3500, and which, in some non-limiting examples, may enable distributed computing, including without limitation, cloud computing. In some non-limiting examples, the network 3502, with the aid of the device 3500, may implement a peer-to-peer network, which may enable devices coupled with the device 3500, to behave as one of: a client, and a server.

In some non-limiting examples, the device 3500 may be a stand-alone device, while in some non-limiting examples, the device 3500 may be resident within a data centre. In some non-limiting examples, a data centre, as will be apparent to those having ordinary skill in the relevant art, may be a collection of computing resources (in some non-limiting examples, in the form of services) that may be used as a collective computing and storage resource. In some non-limiting examples, within a data centre, a plurality of services may be coupled together to provide a computing resource pool upon which virtualized entities may be instantiated. In some non-limiting examples, data centres may be coupled with each other to form networks comprising pooled computing and storage resources coupled with each other by connectivity resources. In some non-limiting examples, the connectivity resources may take the form of physical connections, including without limitation,

Ethernet and optical communication links, and in some non-limiting examples, may comprise wireless communication channels as well. In some non-limiting examples, if a plurality of different data centres are coupled by a plurality of different communication channels, the links may be combined using any number of techniques, including without limitation, the formation of link aggregation groups (LAGs).

In some non-limiting examples, at least some of the computing, storage, and connectivity resources (along with other resources within the network 3502) may be divided between different sub-networks, in some cases in the form of a resource slice. In some non-limiting examples, if the resources across a number of connected at least one of: data centres, and collections of nodes, are sliced, different network slices may be created.

The device 3500 may, in some non-limiting examples, be schematically thought of, and described, in terms of a number of functional units, each of which has been described in the present disclosure.

In some non-limiting examples, the device 3500 may communicate with at least one remote device 3500, through the network 3502. In some non-limiting examples, the remote device 3500 may access the device 3500, via the network 3502.

In some non-limiting examples, the bus 3540 may couple the components of the device 3500 to facilitate the exchange of data, programs, and other information, within the device 3500 between components thereof. The bus 3540 may comprise at least one type of bus architecture, including without limitation, a memory bus, a memory controller, a peripheral bus, a video bus, and a motherboard.

In some non-limiting examples, the storage unit 3550 may be one of: a storage device that may, in some non-limiting examples, comprise at least one of: a solid-state memory device, a FLASH memory device, a solid-state drive, a hard disk drive, a magnetic disk drive, a magneto-optical disk, an optical memory, and an optical disk drive, and a data repository, for storing at least one of: data, including without limitation, user data, including without limitation, at least one of: user preferences, and user programs, and files, including without limitation, at least one of: drivers, libraries, and saved programs.

In some non-limiting examples, the storage unit 3550 may be distinguished from the memory 3520 in that it may perform storage tasks compatible with at least one of: higher latency, and lower volatility. In some no-limiting examples, the storage unit 3550 may be integrated with a heterogeneous memory 3520. In some non-limiting examples, the storage unit 3550 may be external to, and remote from, the device 3500, and accessible through use of the network interface 3530.

In some non-limiting examples, the video adapter 3560, including without limitation, an electronic display adapter, may provide interfaces to couple the device 3500 to external input and output (I/O) devices, including without limitation, one of: a display 3503, a monitor, a liquid crystal display (LCD), and a light-emitting diode (LED), coupled therewith.

In some non-limiting examples, the display 3503 may comprise a user interface (UI) 3504, including without limitation, a graphical user interface (GUI), and a web-based UI, for managing and organizing at least one of: inputs provided to, and outputs generated by the display 3503, including without limitation, at least one of: results, and solutions to the problems described herein.

In some non-limiting examples, the peripheral interface 3570, including without limitation, at least one of: a parallel interface, and a serial interface, including without limitation, a universal serial bus (USB) interface, may be coupled with other I/O devices 3504, including without limitation, an input part of the display 3503, a touch screen, a printer, a keyboard, a keypad, a switch, a dial, a mouse, a trackball, a track pad, a biometric recognition (and input) device, a card reader, a paper tape reader, a camera, a sensor, a peripheral device, and a memory 3520, coupled therewith.

In some non-limiting examples, the device 3500 may be embodied as at least (part of) one of: a personal computer (PC), a desktop computer, a computer workstation, a mini computer, a mainframe computer, a laptop, and a mobile electronic device, including without limitation, a tablet (slate) PC (including without limitation, at least one of: Apple® iPad and Samsung® Galaxy Tab), a mobile telephone (including without limitation, a smartphone (including without limitation, at least one of: Apple® iPhone, Android-enabled device, and Blackberry® device), an e-reader, and a personal digital assistant).

Other components, as well as related functionality, of the device 3500, may have been omitted in order not to obscure the concepts presented herein.

In general terms each functional unit of the present disclosure may be implemented in at least one of: hardware, software, and firmware, as the context dictates. In some non-limiting examples, the processor 3510 may thus be arranged to fetch instructions from at least one of: the memory 3520, and the storage unit 3550, as provided by a functional unit of the present disclosure, to execute these instructions, thereby performing any of at least one of: an action, and an operation, as were described herein.

Aspects of the systems and methods provided herein, including without limitation, the device 3500, may be embodied in programming. Various aspects of the technology may be thought of as one of: “products”, and “articles of manufacture”, in some non-limiting examples, in the form of at least one of: machine-executable instructions, including without limitation, processor-executable instructions, and associated data, that is one of: carried on, and embodied in, a type of machine-readable medium.

In some non-limiting examples, “storage”-type media may include at least one of: the tangible memory of the device 3500, including without limitation, the processor 3510, and associated modules thereof, including without limitation, at least one of: various semiconductor memories, tape drives, and disk drives, of at least one of the memory 3520, and the storage unit 3550, which may provide non-transitory storage at any time for the software programming. In some non-limiting examples, one of: all, and parts, of the software may at times be communicated through the network 3502. In some non-limiting examples, such communications may enable loading of the software from one computer, including without limitation, the device 3500, including without limitation, a processor 3510 thereof, into another computer, including without limitation, a processor 3510 thereof, including without limitation, from one of: a management server, and a host computer, into the computer platform of an application server.

In some non-limiting examples, “storage”-type media that may bear the software elements of at least one functional unit of the present disclosure, may include at least one of: optical, electrical, and electromagnetic (EM) signals, including without limitation, such signals, including without limitation, waves, used across physical interfaces between local devices, through at least one of: wired, including without limitation a baseband signal, and optical, landline networks, and over various air-links, including without limitation, a signal embodied in a carrier wave. The physical elements that carry such signals, including without limitation, at least one of: the wired links, including without limitation, electrical conductors, including without limitation, coaxial cables, and waveguides, wireless links, including without limitation, those propagating through at least one of: the air, and free space, and optical links, including without limitation, optical media, including without limitation, optical fibre, also may be considered as “storage”-type media bearing the software.

As used herein, unless expressly restricted to non-transitory, tangible “storage” media, terms, including without limitation, one of: “computer-readable medium”, and “machine-readable medium” may refer to any medium that participates in providing instructions to a processor 3510 for execution. Such signals, including without limitation, other types of signals, including without limitation, those currently used and hereafter developed, referred to herein as the transmission medium, may be generated according to several well-known methods.

In some non-limiting examples, the information contained in such signals may be ordered according to different sequences, with applicability for at least one of: processing, and generating the information, and receiving the information.

In some non-limiting examples, a machine-readable medium, including without limitation, computer-executable code, may take many forms, including without limitation, at least one of: a tangible storage medium, a carrier wave medium, and a physical transmission medium.

In some non-limiting examples, non-volatile storage media may comprise one of:
optical, and magnetic, disks, including without limitation, any of the storage devices 3520, 3550 in any device(s) 3500, including without limitation, one that may be used to implement the databases and at least some other associated components shown in the drawings.

In some non-limiting examples, volatile storage media may comprise dynamic

memory, including without limitation, main memory 3520 of such a computer system 3500.

In some non-limiting examples, tangible transmission media may comprise at least one of: coaxial cables, copper wire, and fiber optics, including without limitation, the wires that comprise a bus 3540 within a computer system 3500.

In some non-limiting examples, carrier-wave transmission media may take the form of one of: electric signals, electromagnetic signals, acoustic waves, and light waves, including without limitation, those generated during radio frequency (RF) and infrared (IR) data communication.

Non-limiting example forms of computer-readable media include at least one of: a floppy disk, a flexible disk, a hard disk, a magnetic tape, any other magnetic medium, a CD-ROM, a DVD, a DVD-ROM, any other optical medium, punch cards, paper tape, any other physical storage medium with patterns of holes, a RAM, a ROM, a PROM, an EPROM, an EEPROM, a FLASH-EPROM, any other one of: a memory chip, and cartridge, a carrier wave transporting one of: data, and instructions, one of: cables, and links, transporting such a carrier wave, and any other medium from which a computer system 3500 may read one of: programming code, and data. In some non-limiting examples, many of these forms of computer-readable media may be involved in carrying at least one sequence of at least one instruction to a processor 3510 for execution.

### Definitions

In some non-limiting examples, the opto-electronic device may be an electro-luminescent device. In some non-limiting examples, the electro-luminescent device may be an organic light-emitting diode (OLED) device. In some non-limiting examples, the electro-luminescent device may be part of an electronic device. In some non-limiting examples, the electro-luminescent device may be an OLED lighting panel, including without limitation, a module thereof, including without limitation, an OLED display, including without limitation, a module thereof, of the electronic device, including without limitation, a computing device, such as a smartphone, a tablet, a laptop, an e-reader, a monitor, and a television set.

In some non-limiting examples, the opto-electronic device may be an organic photo-voltaic (OPV) device that converts photons into electricity. In some non-limiting examples, the opto-electronic device may be an electro-luminescent QD device.

In the present disclosure, unless specifically indicated to the contrary, reference will be made to OLED devices, with the understanding that such disclosure could, in some examples, equally be made applicable to other opto-electronic devices, including without limitation, at least one of: an OPV, and QD device, in a manner apparent to those having ordinary skill in the relevant art.

The structure of such devices may be described from each of two aspects, namely from at least one of: a longitudinal aspect, and from a lateral (plan view) aspect.

In the present disclosure, a directional convention may be followed, extending substantially normally to the lateral aspect described above, in which the substrate may be the “bottom” of the device, and the layers may be disposed on “top” of the substrate. Following such convention, the second electrode may be at the top of the device shown, even if (as may be the case in some examples, including without limitation, during a manufacturing process, in which at least one layers may be introduced by means of a vapor deposition process), the substrate may be physically inverted, such that the top surface, in which one of the layers, such as, without limitation, the first electrode, may be disposed, may be physically below the substrate, to allow the deposition material (not shown) to move upward and be deposited upon the top surface thereof as a thin film.

In the context of introducing the longitudinal aspect herein, the components of such devices may be shown in substantially planar lateral strata. Those having ordinary skill in the relevant art will appreciate that such substantially planar representation may be for purposes of illustration only, and that across a lateral extent of such a device, there may be localized substantially planar strata of different thicknesses and dimension, including, in some non-limiting examples, the substantially complete absence of a layer(s) separated by non-planar transition regions (including lateral gaps and even discontinuities). Thus, while for illustrative purposes, the device may be shown below in its longitudinal aspect as a substantially stratified structure, in the plan view aspect discussed below, such device may illustrate a diverse topography to define features, each of which may substantially exhibit the stratified profile discussed in the longitudinal aspect.

In the present disclosure, the terms “layer” and “strata” may be used interchangeably to refer to similar concepts.

The thickness of each layer shown in the figures may be illustrative only and not necessarily representative of a thickness relative to another layer.

In the present disclosure, at least during a manufacturing process, a second layer may be said to be deposited on an exposed layer surface of a first layer to form a layer interface therebetween. Those having ordinary skill in the relevant art will appreciate that at the time of deposition of the second layer, the material, from which the second layer will be comprised, is deposited on a surface of the first layer that is one of: “presented”, and “exposed”, in that there is substantially no material deposited thereon, such that it is available to accept deposition thereon of the material from which the second layer will be composed.

Accordingly, as used herein, the surface of the first layer presented, at the time of deposition, for deposition thereon of the material from which the second layer will be composed, may be said to be an “exposed layer surface” of the first layer, even if, in a device in which deposition has proceeded further, including without limitation, to completion, such surface may no longer be “exposed”, because of the deposition thereon of the material from which the first layer may be composed.

Those having ordinary skill in the relevant art will appreciate that a third layer may be said to be deposited on an exposed layer surface of the second layer to form a layer interface therein. Thus, after deposition of the second layer onto the exposed layer surface of the first layer, and after deposition of the third layer onto the exposed layer surface of the second layer, the second layer may be said to extend between the first layer and the third layer, and concomitantly, the second layer may be said to extend between the layer interface between the first layer and the second layer, and the layer interface between the second layer and the third layer.

As used herein, the terms “distal” and “proximal” may be used to identify relative positions, including without limitation, layer interfaces, from a reference, including without limitation, a substrate of a device. Thus, in a device in which: a first layer has been deposited on an exposed layer surface of the substrate; a second layer has been deposited on an exposed layer surface of the first layer; and a third layer has been deposited on an exposed layer surface of the second layer, the layer interface between the first layer and the second layer may be considered a proximal layer interface of the second layer, while the layer interface between the second layer and third layer may be considered a distal layer interface thereof.

For purposes of simplicity of description, in the present disclosure, a combination of a plurality of elements in a single layer may be denoted by a colon “:”, while a plurality of (combination(s) of) elements comprising a plurality of layers in a multi-layer coating may be denoted by separating two such layers by a slash “/”. In some non-limiting examples, the layer after the slash may be deposited at least one of: after, and on, the layer preceding the slash.

For purposes of illustration, an exposed layer surface of an underlying layer, onto which at least one of: a coating, layer, and material, may be deposited, may be understood to be a surface of such underlying layer that may be presented for deposition of at least one of: the coating, layer, and material, thereon, at the time of deposition.

Those having ordinary skill in the relevant art will appreciate that when one of: a component, a layer, a region, and a portion thereof, is referred to as being at least one of: “formed”, “disposed”, and “deposited” on, and “deposited” over another underlying at least one of: a material, component, layer, region, and/portion, such at least one of: formation, disposition, and deposition, may be one of: directly, and indirectly, on an exposed layer surface (at the time of such at least one of: formation, disposition, and deposition) of such underlying at least one of: material, component, layer, region, and portion, with the potential of intervening at least one of: material(s), component(s), layer(s), region(s), and portion(s) therebetween.

In the present disclosure, the terms “overlap”, and “overlapping” may refer generally to a plurality of at least one of: layers, and structures, arranged to intersect a cross-sectional axis extending substantially normally away from a surface onto which such at least one of: layers, and structures, may be disposed.

While the present disclosure discusses thin film formation, in reference to at least one layer (coating), in terms of vapor deposition, those having ordinary skill in the relevant art will appreciate that, in some non-limiting examples, various components of the device may be selectively deposited using a wide variety of techniques, including without limitation, evaporation (including without limitation, at least one of: thermal, and electron beam, evaporation), photolithography, printing (including without limitation, ink jet, and vapor jet, printing, reel-to-reel printing, and micro-contact transfer printing), PVD (including without limitation, sputtering), chemical vapor deposition (CVD) (including without limitation, at least one of: plasma-enhanced CVD (PECVD), and organic vapor phase deposition (OVPD)), laser annealing, laser-induced thermal imaging (LITI) patterning, atomic-layer deposition (ALD), coating (including without limitation, spin-coating, di coating, line coating, and spray coating) (collectively “deposition process”).

Some processes may be used in combination with a shadow mask, which may, in some non-limiting examples, may be one of: an open mask, and fine metal mask (FMM), during deposition of any of various at least one of: layers, and coatings, to achieve various patterns by at least one of: masking, and precluding deposition of, a deposited material on certain parts of a surface of an underlying layer exposed thereto.

In the present disclosure, the terms “evaporation”, and “sublimation” may be used interchangeably to refer generally to deposition processes in which a source material is converted into a vapor, including without limitation, by heating, to be deposited onto a target surface in, without limitation, a solid state. As will be understood, an evaporation deposition process may be a type of PVD process where at least one source material is sublimed under a low pressure (including without limitation, a vacuum) environment to form vapor monomers, and deposited on a target surface through de-sublimation of the at least one evaporated source material. A variety of different evaporation sources may be used for heating a source material, and, as such, it will be appreciated by those having ordinary skill in the relevant art, that the source material may be heated in various ways. In some non-limiting examples, the source material may be heated by at least one of: an electric filament, electron beam, inductive heating, and by resistive heating. In some non-limiting examples, the source material may be loaded into at least one of: a heated crucible, a heated boat, a Knudsen cell (which may be an effusion evaporator source), and any other type of evaporation source.

In some non-limiting examples, a deposition source material may be a mixture. In some non-limiting examples, at least one component of a mixture of a deposition source material may not be deposited during the deposition process (in some non-limiting examples, be deposited in a substantially small amount compared to other components of such mixture).

In the present disclosure, a reference to at least one of: a layer thickness, a film thickness, and an average one of: layer, and film, thickness, of a material, irrespective of the mechanism of deposition thereof, may refer to an amount of the material deposited on a target exposed layer surface, which corresponds to an amount of the material to cover the target surface with a uniformly thick layer of the material having the referenced layer thickness. In some non-limiting examples, depositing a layer thickness of 10 nm of material may indicate that an amount of the material deposited on the surface may correspond to an amount of the material to form a uniformly thick layer of the material that may be 10 nm thick. It will be appreciated that, having regard to the mechanism by which thin films are formed discussed above, in some non-limiting examples, due to possible at least one of: stacking, and clustering, of monomers, an actual thickness of the deposited material may be non-uniform. In some non-limiting examples, depositing a layer thickness of 10 nm may yield one of: some parts of the deposited material having an actual thickness greater than 10 nm, and other parts of the deposited material having an actual thickness of no more than 10 nm. A certain layer thickness of a material deposited on a surface may thus correspond, in some non-limiting examples, to an average thickness of the deposited material across the target surface.

In the present disclosure, a reference to a reference layer thickness may refer to a layer thickness of the deposited material (such as Mg), that may be deposited on a reference surface exhibiting one of: a high initial sticking probability, and initial sticking coefficient, (that is, a surface having an initial sticking probability that is about 1.0). The reference layer thickness may not indicate an actual thickness of the deposited material deposited on a target surface (such as, without limitation, a surface of a patterning coating). Rather, the reference layer thickness may refer to a layer thickness of the deposited material that would be deposited on a reference surface, in some non-limiting examples, a surface of a quartz crystal, positioned inside a deposition chamber for monitoring a deposition rate and the reference layer thickness, upon subjecting the target surface and the reference surface to identical vapor flux of the deposited material for the same deposition period. Those having ordinary skill in the relevant art will appreciate that in the event that the target surface and the reference surface are not subjected to identical vapor flux simultaneously during deposition, an appropriate tooling factor may be used to determine (monitor) the reference layer thickness.

In the present disclosure, a reference deposition rate may refer to a rate at which a layer of the deposited material would grow on the reference surface, if it were identically positioned and configured within a deposition chamber as the sample surface.

In the present disclosure, a reference to depositing a number X of monolayers of material may refer to depositing an amount of the material to cover a given area of an exposed layer surface with X single layer(s) of constituent monomers of the material, such as, without limitation, in a closed coating.

In the present disclosure, a reference to depositing a fraction of a monolayer of a material may refer to depositing an amount of the material to cover such fraction of a given area of an exposed layer surface with a single layer of constituent monomers of the material. Those having ordinary skill in the relevant art will appreciate that due to, in some non-limiting examples, possible at least one of: stacking, and clustering, of monomers, an actual local thickness of a deposited material across a given area of a surface may be non-uniform. In some non-limiting examples, depositing 1 monolayer of a material may result in some local regions of the given area of the surface being uncovered by the material, while other local regions of the given area of the surface may have multiple at least one of: atomic, and molecular, layers deposited thereon.

In the present disclosure, a target surface (including without limitation, target region(s) thereof) may be considered to be at least one of: “substantially devoid of”, “substantially free of”, and “substantially uncovered by”, a material if there may be a substantial absence of the material on the target surface as determined by any applicable determination mechanism.

In the present disclosure, the terms “sticking probability” and “sticking coefficient” may be used interchangeably.

In the present disclosure, the term “nucleation” may reference a nucleation stage of a thin film formation process, in which monomers in a vapor phase condense onto a surface to form nuclei.

In the present disclosure, in some non-limiting examples, as the context dictates, the terms “patterning coating” and “patterning material” may be used interchangeably to refer to similar concepts, and references to a patterning coating herein, in the context of being selectively deposited to pattern a deposited layer may, in some non-limiting examples, be applicable to a patterning material in the context of selective deposition thereof to pattern at least one of: a deposited material, and an electrode coating material.

Similarly, in some non-limiting examples, as the context dictates, the term “patterning coating” and “patterning material” may be used interchangeably to refer to similar concepts, and reference to an NPC herein, in the context of being selectively deposited to pattern a deposited layer may, in some non-limiting examples, be applicable to an NPC in the context of selective deposition thereof to pattern at least one of: a deposited material, and an electrode coating.

While a patterning material may be one of: nucleation-inhibiting, and nucleation-promoting, in the present disclosure, unless the context dictates otherwise, a reference herein to a patterning material is intended to be a reference to an NIC.

In some non-limiting examples, reference to a patterning coating may signify a coating having a specific composition as described herein.

In the present disclosure, the terms “deposited layer”, “conductive coating”, and “electrode coating” may be used interchangeably to refer to similar concepts and references to a deposited layer herein, in the context of being patterned by selective deposition of at least one of: a patterning coating, and an NPC, may, in some non-limiting examples, be applicable to a deposited layer in the context of being patterned by selective deposition of a patterning material. In some non-limiting examples, reference to an electrode coating may signify a coating having a specific composition as described herein. Similarly, in the present disclosure, the terms “deposited layer material”, “deposited material”, “conductive coating material”, and “electrode coating material” may be used interchangeably to refer to similar concepts and references to a deposited material herein.

In the present disclosure, as used herein, molecular formulae showing fragment(s) of a compound may comprise at least one bond connected to symbols, including without limitation, an asterisk symbol (denoted “*”), and those denoted

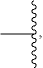

which symbols may be used to indicate the bonds to another atom (not shown) of the compound to which such fragment(s) may be attached.

In the present disclosure, it will be appreciated by those having ordinary skill in the relevant art that an organic material may comprise, without limitation, a wide variety of organic at least one of: molecules, and polymers. Further, it will be appreciated by those having ordinary skill in the relevant art that organic materials that are doped with various inorganic substances, including without limitation, elements, and inorganic compounds, may still be considered organic materials. Still further, it will be appreciated by those having ordinary skill in the relevant art that various organic materials may be used, and that the processes described herein are generally applicable to an entire range of such organic materials. Still further, it will be appreciated by those having ordinary skill in the relevant art that organic materials that comprise at least one of: metals, and other organic elements, may still be considered as organic materials. Still further, it will be appreciated by those having ordinary skill in the relevant art that various organic materials may be at least one of: molecules, oligomers, and polymers.

An organic opto-electronic device may encompass any opto-electronic device where at least one active layers (strata) thereof are formed primarily of an organic (carbon-containing) material, and more specifically, an organic semiconductor material.

In the present disclosure, the term “organic-inorganic hybrid material”, as used herein, may generally refer to a material that comprises both an organic component and an inorganic component. In some non-limiting examples, such organic-inorganic hybrid material may comprise an organic-inorganic hybrid compound that comprises an organic moiety and an inorganic moiety. In some non-limiting examples, such organic-inorganic hybrid compounds may include those in which an inorganic scaffold may be functionalized with at least one organic functional group.

Non-limiting examples of such organic-inorganic hybrid materials include those comprising at least one of: a siloxane group, a silsesquioxane group, a polyhedral oligomeric silsesquioxane (POSS) group, a phosphazene group, and a metal complex.

In the present disclosure, a semiconductor material may be described as a material that generally exhibits a band gap. In some non-limiting examples, the band gap may be formed between a highest occupied molecular orbital (HOMO) and a lowest unoccupied molecular orbital (LUMO) of the semiconductor material. Semiconductor materials thus generally exhibit electrical conductivity that is no more than that of a conductive material (including without limitation, a metal), but that is greater than that of an insulating material (including without limitation, a glass). In some non-limiting examples, the semiconductor material may comprise an organic semiconductor material. In some non-limiting examples, the semiconductor material may comprise an inorganic semiconductor material.

As used herein, an oligomer may generally refer to a material which includes at least two monomer (units). As would be appreciated by a person skilled in the art, an oligomer may differ from a polymer in at least one aspect, including, without limitation: (1) the number of monomer units contained therein; (2) the molecular weight; and (3) other material properties (characteristics). In some non-limiting examples, further description of polymers and oligomers may be found in Naka K. (2014) Monomers, Oligomers, Polymers, and Macromolecules (Overview), and in Kobayashi S., Müllen K. (eds.) Encyclopedia of Polymeric Nanomaterials, Springer, Berlin, Heidelberg.

One of: an oligomer, and a polymer, may generally include monomer units that may be chemically bonded together to form a molecule. Such monomer units may be substantially identical to one another such that one of: the molecule is primarily formed by repeating monomer units, and the molecule may include a plurality of different monomer units. Additionally, the molecule may include at least one terminal unit, which may be different from the monomer units of the molecule. One of: an oligomer, and a polymer, may be at least one of: linear, branched, cyclic, cyclo-linear, and cross-linked. One of: an oligomer, and a polymer, may include a plurality of different monomer units which are arranged in a repeating pattern, including without limitation, in alternating blocks, of different monomer units.

In the present disclosure, the term “semiconducting layer(s)” may be used interchangeably with “organic layer(s)” since the layers in an OLED device may in some non-limiting examples, may comprise organic semiconducting materials.

In the present disclosure, an inorganic substance may refer to a substance that primarily includes an inorganic material. In the present disclosure, an inorganic material may comprise any material that is not considered to be an organic material, including without limitation, metals, glasses, and minerals.

In the present disclosure, the terms “EM radiation”, “photon”, and “light” may be used interchangeably to refer to similar concepts. In the present disclosure, light may have a wavelength that lies in at least one of: the visible spectrum, infrared (IR) region (IR spectrum), near IR region (NIR spectrum), ultraviolet (UV) region (UV spectrum), UVA region (UVA spectrum) (which may correspond to a wavelength range between about 315-400 nm) thereof, and UVB region (UVB spectrum) (which may correspond to a wavelength between about 280-315 nm) thereof.

In the present disclosure, the term “visible spectrum” as used herein, generally refers to at least one wavelength in the visible part of the EM spectrum.

As would be appreciated by those having ordinary skill in the relevant art, such visible part may correspond to any wavelength between about 380-740 nm. In general, electro-luminescent devices may be configured to at least one of: emit, and transmit, light having wavelengths in a range of between about 425-725 nm, and more specifically, in some non-limiting examples, light having peak emission wavelengths of 456 nm, 528 nm, and 624 nm, corresponding to B(lue), G(reen), and R(ed) sub-pixels, respectively. Accordingly, in the context of such electro-luminescent devices, the visible part may refer to any wavelength that is one of: between about 425-725 nm, and between about 456-624 nm. light having a wavelength in the visible spectrum may, in some non-limiting examples, also be referred to as “visible light” herein.

In the present disclosure, the terms “0^{th} order” and “zero-order” may be used herein interchangeably to generally refer to a part of the energy from an incident beam passing through a diffractive optical element that corresponds substantially solely to geometrical ray optics principles, including without limitation, those corresponding to reflection and refraction, that is, substantially without diffraction.

In the present disclosure, the terms “n^{th} order” and “n^{th}-order”, where n is a positive integer, may be used herein interchangeably to generally refer to a part of the energy from an incident beam passing through a diffractive optical element that corresponds substantially to optics principles relating to diffraction.

In the present disclosure, the term “emission spectrum” as used herein, generally refers to an electroluminescence spectrum of light emitted by an opto-electronic device. In some non-limiting examples, an emission spectrum may be detected using an optical instrument, such as, in some non-limiting examples, a spectrophotometer, which may measure an intensity of light across a wavelength range.

In the present disclosure, the term “onset wavelength”, as used herein, may generally refer to a lowest wavelength at which an emission is detected within an emission spectrum.

In the present disclosure, the term “peak wavelength”, as used herein, may generally refer to a wavelength at which a maximum luminous intensity is detected within an emission spectrum.

In some non-limiting examples, the onset wavelength may be less than the peak wavelength. In some non-limiting examples, the onset wavelength λₒₙₛₑₜ may correspond to a wavelength at which a luminous intensity is one of no more than about: 10%, 5%, 3%, 1%, 0.5%, 0.1%, and 0.01%, of the luminous intensity at the peak wavelength.

In some non-limiting examples, an emission spectrum that lies in the R(ed) part of the visible spectrum may be characterized by a peak wavelength that may lie in a wavelength range of about 600-640 nm and in some non-limiting examples, may be substantially about 620 nm.

In some non-limiting examples, an emission spectrum that lies in the G(reen) part of the visible spectrum may be characterized by a peak wavelength that may lie in a wavelength range of about 510-540 nm and in some non-limiting examples, may be substantially about 530 nm.

In some non-limiting examples, an emission spectrum that lies in the B(lue) part of the visible spectrum may be characterized by a peak wavelength Amax that may lie in a wavelength range of about 450-460 nm and in some non-limiting examples, may be substantially about 455 nm.

In the present disclosure, the term “IR signal” as used herein, may generally refer to light having a wavelength in an IR subset (IR spectrum) of the EM spectrum. In some non-limiting examples, an IR signal may have a wavelength of one of between about: 700-1,000 nm, 750-5,000 nm, 750-3,000 nm, 750-1,400 nm, and 850-1,200 nm. An IR signal may, in some non-limiting examples, have a wavelength corresponding to a near-infrared (NIR) subset (NIR spectrum) thereof. In some non-limiting examples, an NIR signal may have a wavelength of one of between about: 750-1,400 nm, 750-1,300 nm, 800-1,300 nm, 800-1,200 nm, 850-1,300 nm, and 900-1,300 nm.

In the present disclosure, the term “absorption spectrum”, as used herein, may generally refer to a wavelength (sub-) range of the EM spectrum over which absorption may be concentrated.

In the present disclosure, the terms “absorption edge”, “absorption discontinuity”, and “absorption limit” as used herein, may generally refer to a sharp discontinuity in the absorption spectrum of a substance. In some non-limiting examples, an absorption edge may tend to occur at wavelengths where the energy of absorbed light may correspond to at least one of: an electronic transition, and ionization potential.

In the present disclosure, the term “extinction coefficient” as used herein, may generally refer to a degree to which an EM coefficient may be attenuated when propagating through a material. In some non-limiting examples, the extinction coefficient may be understood to correspond to the imaginary component k of a complex refractive index. In some non-limiting examples, the extinction coefficient of a material may be measured by a variety of methods, including without limitation, by ellipsometry.

In the present disclosure, the terms “refractive index”, and “index”, as used herein to describe a medium, may refer to a value calculated from a ratio of the speed of light in such medium relative to the speed of light in a vacuum. In the present disclosure, particularly when used to describe the properties of substantially transparent materials, including without limitation, thin film layers (coatings), the terms may correspond to the real part, n, in the expression N=n+ik, in which N may represent the complex refractive index and k may represent the extinction coefficient.

As would be appreciated by those having ordinary skill in the relevant art, substantially transparent materials, including without limitation, thin film layers (coatings), may generally exhibit a substantially low extinction coefficient value in the visible spectrum, and therefore the imaginary component of the expression may have a negligible contribution to the complex refractive index. On the other hand, light-transmissive electrodes formed, for example, by a metallic thin film, may exhibit a substantially low refractive index value and a substantially high extinction coefficient value in the visible spectrum. Accordingly, the complex refractive index, N, of such thin films may be dictated primarily by its imaginary component k.

In the present disclosure, unless the context dictates otherwise, reference without specificity to a refractive index may be intended to be a reference to the real part n of the complex refractive index N.

In some non-limiting examples, there may be a generally positive correlation between refractive index and transmittance, in other words, a generally negative correlation between refractive index and absorption. In some non-limiting examples, the absorption edge of a substance may correspond to a wavelength at which the extinction coefficient approaches 0.

In the present disclosure, the concept of a pixel may be discussed on conjunction with the concept of at least one sub-pixel thereof. For simplicity of description only, such composite concept may be referenced herein as a “(sub-) pixel” and such term may be understood to suggest at least one of: a pixel, and at least one sub-pixel thereof, unless the context dictates otherwise.

In the present disclosure, the term “aperture ratio”, as used herein, generally refers to a ratio, in plan, within a (part of a) display panel, including without limitation, a signal-exchanging part thereof, in plan, occupied by, including without limitation, attributed to, at least one feature, including without limitation, of at least one transmissive region, present in such (part of a) display panel.

In the present disclosure, the term “pixel density”, as used herein, generally refers to a number of (sub-) pixels in a region in which (sub-) pixels appear.

In the present disclosure, the term “configuration”, in respect of a pixel, as used herein, generally refers to at least one of: a number of sub-pixels contained therein, a pattern in which such sub-pixels are disposed therein, and a colour of each such sub-pixel disposed therein.

In the present disclosure, the term “pitch”, as used herein, generally refers to a spacing between adjacent ones of a repeating structure, including without limitation, one of: a (sub-) pixel, and a transmissive region, including without limitation, taken along an axis of a region in which such repeating structure appears, including without limitation, one of: a signal-exchanging part, and a display part.

In some nonlimiting examples, one measure of an amount of a material on a surface may be a percentage coverage of the surface by such material. In some non-limiting examples, surface coverage may be assessed using a variety of imaging techniques, including without limitation, at least one of: TEM, AFM, and SEM.

In the present disclosure, the terms “particle”, “island”, and “cluster” may be used interchangeably to refer to similar concepts.

In the present disclosure, for purposes of simplicity of description, the terms “coating film”, “closed coating”, and “closed film”, as used herein, may refer to a thin film structure (coating) of a deposited material used for a deposited layer, in which a relevant part of a surface may be substantially coated thereby, such that such surface may be not substantially exposed by (through) the coating film deposited thereon.

In the present disclosure, unless the context dictates otherwise, reference without specificity to a thin film may be intended to be a reference to a substantially closed coating.

In some non-limiting examples, a closed coating, in some non-limiting examples, of at least one of: a deposited layer, and a deposited material, may be disposed to cover a part of an underlying layer, such that, within such part, one of no more than about: 40%, 30%, 25%, 20%, 15%, 10%, 5%, 3%, and 1% of the underlying layer therewithin may be exposed by (through), the closed coating.

Those having ordinary skill in the relevant art will appreciate that a closed coating may be patterned using various techniques and processes, including without limitation, those described herein, to deliberately leave a part of the exposed layer surface of the underlying layer to be exposed after deposition of the closed coating. In the present disclosure, such patterned films may nevertheless be considered to constitute a closed coating, if, in some non-limiting examples, the thin film (coating) that is deposited, within the context of such patterning, and between such deliberately exposed parts of the exposed layer surface of the underlying layer, itself substantially comprises a closed coating.

Those having ordinary skill in the relevant art will appreciate that, due to inherent variability in the deposition process, and in some non-limiting examples, to the existence of impurities in at least one of the deposited materials, in some non-limiting examples, the deposited material, and the exposed layer surface of the underlying layer, deposition of a thin film, using various techniques and processes, including without limitation, those described herein, may nevertheless result in the formation of small apertures, including without limitation, at least one of: pin-holes, tears, and cracks, therein. In the present disclosure, such thin films may nevertheless be considered to constitute a closed coating, if, in some non-limiting examples, the thin film (coating) that is deposited substantially comprises a closed coating and meets any specified percentage coverage criterion set out, despite the presence of such apertures.

In the present disclosure, for purposes of simplicity of description, the term “discontinuous layer” as used herein, may refer to a thin film structure (coating) of a material used for a deposited layer, in which a relevant part of a surface coated thereby, may be neither substantially devoid of such material, nor forms a closed coating thereof. In some non-limiting examples, a discontinuous layer of a deposited material may manifest as a plurality of discrete islands disposed on such surface.

In the present disclosure, for purposes of simplicity of description, the result of deposition of vapor monomers onto an exposed layer surface of an underlying layer, that has not (yet) reached a stage where a closed coating has been formed, may be referred to as a “intermediate stage layer”. In some non-limiting examples, such an intermediate stage layer may reflect that the deposition process has not been completed, in which such an intermediate stage layer may be considered as an interim stage of formation of a closed coating. In some non-limiting examples, an intermediate stage layer may be the result of a completed deposition process, and thus constitute a final stage of formation in and of itself.

In some non-limiting examples, an intermediate stage layer may more closely resemble a thin film than a discontinuous layer but may have apertures (gaps) in the surface coverage, including without limitation, at least one of: a dendritic projection, and a dendritic recess. In some non-limiting examples, such an intermediate stage layer may comprise a fraction of a single monolayer of the deposited material such that it does not form a closed coating.

In the present disclosure, for purposes of simplicity of description, the term “dendritic”, with respect to a coating, including without limitation, the deposited layer, may refer to feature(s) that resemble a branched structure when viewed in a lateral aspect. In some non-limiting examples, the deposited layer may comprise at least one of: a dendritic projection, and a dendritic recess. In some non-limiting examples, a dendritic projection may correspond to a part of the deposited layer that exhibits a branched structure comprising a plurality of short projections that are physically connected and extend substantially outwardly. In some non-limiting examples, a dendritic recess may correspond to a branched structure of at least one of: gaps, openings, and uncovered parts, of the deposited layer that are physically connected and extend substantially outwardly. In some non-limiting examples, a dendritic recess may correspond to, including without limitation, a mirror image (inverse pattern) to the pattern of a dendritic projection. In some non-limiting examples, at least one of: a dendritic projection, and a dendritic recess may have a configuration that exhibits, (mimics) at least one of: a fractal pattern, a mesh, a web, and an interdigitated structure.

In some non-limiting examples, sheet resistance may be a property of at least one of: a component, layer, and part, that may alter a characteristic of an electric current passing through at least one of: such component, layer, and part. In some non-limiting examples, a sheet resistance of a coating may generally correspond to a characteristic sheet resistance of the coating, measured (determined) in isolation from other at least one of: components, layers, and parts, of the device.

In the present disclosure, a deposited density may refer to a distribution, within a region, which in some non-limiting examples may comprise at least one of: an area, and a volume, of a deposited material therein. Those having ordinary skill in the relevant art will appreciate that such deposited density may be unrelated to a density of mass (material) within a particle structure itself that may comprise such deposited material. In the present disclosure, unless the context dictates otherwise, reference to a (deposited) density, may be intended to be a reference to a distribution of such deposited material, including without limitation, as at least one particle, within an area.

In some non-limiting examples, a bond dissociation energy of a metal may correspond to a standard-state enthalpy change measured at 298 K from the breaking of a bond of a diatomic molecule formed by two identical atoms of the metal. Bond dissociation energies may, in some non-limiting examples, be determined based on known literature including without limitation, Luo, Yu-Ran, “Bond Dissociation Energies” (2010).

Without wishing to be bound by a particular theory, it is postulated that providing an NPC may facilitate deposition of the deposited layer onto certain surfaces.

Non-limiting examples of materials having applicability for forming an NPC may comprise without limitation, at least one metal, including without limitation, alkali metals, alkaline earth metals, transition metals, post-transition metals, metal fluorides, metal oxides, and fullerene.

Non-limiting examples of such materials include Ca, Ag, Mg, Yb, ITO, IZO, ZnO, ytterbium fluoride (YbF₃), magnesium fluoride (MgF₂), and cesium fluoride (CsF).

In the present disclosure, the term “fullerene” may refer generally to a material including carbon molecules. Non-limiting examples of fullerene molecules include carbon cage molecules, including without limitation, a three-dimensional skeleton that includes multiple carbon atoms that form a closed shell, and which may be, without limitation, (semi-) spherical in shape. In some non-limiting examples, a fullerene molecule may be designated as Cn, where n may be an integer corresponding to several carbon atoms included in a carbon skeleton of the fullerene molecule. Non-limiting examples of fullerene molecules include Cn, where n may be in the range of 50 to 250, such as, without limitation, C₆₀, C₇₀, C₇₂, C₇₄, C₇₆, C₇₈, C₈₀, C₈₂, and C₈₄. Additional non-limiting examples of fullerene molecules include carbon molecules in at least one of: a tube, and a cylindrical shape, including without limitation, single-walled carbon nanotubes, and multi-walled carbon nanotubes.

Based on findings and experimental observations, it may be postulated that nucleation promoting materials, including without limitation, fullerenes, metals, including without limitation, at least one of: Ag, and Yb, and metal oxides, including without limitation, ITO, and IZO, as discussed further herein, may act as nucleation sites for the deposition of a deposited layer, including without limitation Mg.

In some non-limiting examples, applicable materials for use to form an NPC, may include those exhibiting (characterized) as having an initial sticking probability for a material of a deposited layer of one of at least about: 0.4, 0.5, 0.6, 0.7, 0.75, 0.8, 0.9, 0.93, 0.95, 0.98, and 0.99.

In some non-limiting examples, in scenarios where Mg is deposited using without limitation, an evaporation process on a fullerene-treated surface, in some non-limiting examples, the fullerene molecules may act as nucleation sites that may promote formation of stable nuclei for Mg deposition.

In some non-limiting examples, no more than a monolayer of an NPC, including without limitation, fullerene, may be provided on the treated surface to act as nucleation sites for deposition of Mg.

In some non-limiting examples, treating a surface by depositing several monolayers of an NPC thereon may result in a higher number of nucleation sites and accordingly, a higher initial sticking probability.

Those having ordinary skill in the relevant art will appreciate than an amount of material, including without limitation, fullerene, deposited on a surface, may be one of: more, and less than, one monolayer. In some non-limiting examples, such surface may be treated by depositing one of about: 0.1, 1, 10, and more monolayers of at least one of: a nucleation promoting, and a nucleation inhibiting, material.

In some non-limiting examples, an average layer thickness of the NPC deposited on an exposed layer surface of underlying layer(s) may be one of between about: 1-5 nm, and 1-3 nm.

In the present disclosure, the term “point spread function” (PSF), as used herein, generally refers to the response of a focused optical system, including without limitation, an image system, to a point source of light, including without limitation a focused light source.

Where features and aspects of the present disclosure may be described in terms of Markush groups, it will be appreciated by those having ordinary skill in the relevant art that the present disclosure may also be thereby described in terms of any individual member of sub-group of members of such Markush group.

### Terminology

References in the singular form may include the plural and vice versa, unless otherwise noted.

As used herein, relational terms, such as “first” and “second”, and numbering devices such as “a”, “b” and the like, may be used solely to distinguish one entity/element from another entity/element, without necessarily requiring/implying any physical/logical relationship/order between such entities/elements.

The terms “including” and “comprising” may be used expansively and in an open-ended fashion, and thus should be interpreted to mean “including, but not limited to”. The terms “example” and “exemplary” may be used simply to identify instances for illustrative purposes and should not be interpreted as limiting the scope of the invention to the stated instances. In some non-limiting examples, the term “exemplary” should not be interpreted to denote/confer any laudatory, beneficial, and other quality to the expression with which it is used, whether in terms of design, performance and otherwise.

Further, the term “critical”, especially when used in the expressions “critical nuclei”, “critical nucleation rate”, “critical concentration”, “critical cluster”, “critical monomer”, “critical particle structure size”, and “critical surface tension” may be a term familiar to those having ordinary skill in the relevant art, including as relating to/being in a state in which a measurement/point at which some at least one of: quality, property and phenomenon undergoes a definite change. As such, the term “critical” should not be interpreted to denote/confer any significance/importance to the expression with which it is used, whether in terms of design, performance, and otherwise.

The term “common”, especially when used in the expressions “common electrode”, “common conductive coating”, and “common layer” may be intended to mean an electrode, conductive coating, and layer, as the case may be, that is one of: deposited as, and acts as it was deposited as, a single continuous single structure.

The terms “couple” and “communicate” in any form may be intended to mean either one of: a direct, and indirect, connection through some one of: an interface, device, intermediate component, connection, whether optically, electrically, mechanically, chemically, and otherwise.

The terms “on” and “over”, when used in reference to a first component relative to another component, and at least one of: “covering” and which “covers” another component, may encompass situations where the first component is directly on (including without limitation, in physical contact with) the other component, as well as cases where at least one intervening component is positioned between the first component and the other component.

Directional terms such as “upward”, “downward”, “left” and “right” may be used to refer to directions in the drawings to which reference is made unless otherwise stated. Similarly, words such as “inward” and “outward” may be used to refer to directions toward and away from, respectively, the geometric center of the device, area, volume and designated parts thereof. Moreover, all dimensions described herein may be intended solely to be by way of example of purposes of illustrating certain examples and may not be intended to limit the scope of the disclosure to any examples that may depart from such dimensions as may be specified.

As used herein, the terms “substantially”, “substantial”, “approximately”, and “about” may be used to denote and account for small variations. When used in conjunction with an event/circumstance, such terms may refer to instances in which the event/circumstance occurs precisely, as well as instances in which the event/circumstance occurs to a close approximation. In some non-limiting examples, when used in conjunction with a numerical value, such terms may refer to a range of variation of no more than about ±10% of such numerical value, such as at least one of no more than about: ±5%, ±4%, ±3%, ±2%, ±1%, ±0.5%, ±0.1%, and ±0.05%.

As used herein, the phrase “consisting substantially of” may be understood to include those elements specifically recited and any additional elements that do not materially affect the basic and novel characteristics of the described technology, while the phrase “consisting of” without the use of any modifier, may exclude any element not specifically recited.

Whenever the term “at least” precedes the first numerical value in a series of a plurality numerical values, the term “at least” may apply to each of the numerical values in that series of numerical values. In some non-limiting examples, at least one of: 1, 2, and 3 may be equivalent to at least one of: at least 1, at least 2, and at least 3.

Whenever the term “no more than” precedes the first numerical value in a series of a plurality of numerical values, the term “no more than” may apply to each of the numerical values in that series of numerical values. In some non-limiting examples, no more than: 3, 2, and 1 may be equivalent to no more than 3, no more than 2, and no more than 1.

Certain examples herein contemplate numerical ranges. When ranges are present, the ranges may include the range endpoints. Additionally, every sub-range and value within the range may be present as if explicitly written out. The terms “about” and “approximately” may mean within an acceptable error range for the particular value, which will depend in part on how the value is measured (determined), including without limitation, the limitations of the measurement system. In some non-limiting examples, “about” may mean within one of: 1, and more than 1, standard deviation, per the practice in the relevant art. In some non-limiting examples, “about” may mean a range of one of no more than about: 20%, 10%, 5%, and 1% of a given value. Where particular values are described in the application and claims, unless otherwise stated the term “about” meaning within an acceptable error range for the particular value may be assumed.

As will be understood by those having ordinary skill in the relevant art, for any and all purposes, particularly in terms of providing a written description, all ranges disclosed herein may also encompass any and all possible sub-ranges, and combinations of sub-ranges thereof. Any listed range may be easily recognized as substantially describing,/enabling the same range being broken down at least into equal fractions thereof, including without limitation, halves, thirds, quarters, fifths, tenths etc. As a non-limiting example, each range discussed herein may be readily be broken down into a lower third, middle third, and upper third, etc.

As will be understood by those having ordinary skill in the relevant art, for any and all purposes, particularly in terms of providing a written description, all values/ranges disclosed herein that are described in terms of at least one decimal value, should be interpreted as encompassing a value/range that includes rounding error as would be understood by those having ordinary skill in the art, as determined based on the number of significant digits expressed by such decimal value. For greater certainty, the presence/absence of any additional decimal value, in the present disclosure, the same paragraph, and even the same sentence, as the first decimal value, which may have a greater/lesser number of significant digits than the first decimal value, should not be used to limit the value/range encompassed by such first decimal value, in any fashion that limits the value/range so encompassed, to a value/range that is no more than one that includes rounding error based on the number of significant digits expressed thereby.

As will also be understood by those having ordinary skill in the relevant art, all language,/terminology such as “up to”, “at least”, “at least”, “no more than”, “no more than”, and the like, may include,/refer the recited range(s) and may also refer to ranges that may be subsequently broken down into sub-ranges as discussed herein.

As will be understood by those having ordinary skill in the relevant art, a range may include each individual member of the recited range.

### General

The purpose of the Abstract is to enable the relevant patent office and the public generally, and specifically, persons of ordinary skill in the art who are not familiar with patent/legal terms/phraseology, to quickly determine from a cursory inspection, the nature of the technical disclosure. The Abstract is neither intended to define the scope of this disclosure, nor is it intended to be limiting as to the scope of this disclosure in any way.

All publications, patents, and patent applications mentioned in this specification are herein incorporated by reference to the same extent as if each individual one of: a publication, patent, and patent application, was specifically and individually indicated to be incorporated by reference. To the extent publications, patents, and patent applications incorporated by reference contradict the disclosure contained in the specification, the specification is intended to one of: supersede, and take precedence over, any such contradictory material.

Incorporation by reference is expressly limited to the technical aspects of the materials, systems, and methods described in the mentioned publications, patents, and patent applications and may not extend to any lexicographical definitions from the publications, patents, and patent applications. Any lexicographical definition appearing in the publications, patents, and patent applications that is not also expressly repeated in the instant disclosure should not be treated as such and should not be read as defining any terms appearing in the accompanying claims.

The structure, manufacture and use of the presently disclosed examples have been discussed above. The specific examples discussed are merely illustrative of specific ways to make and use the concepts disclosed herein, and do not limit the scope of the present disclosure. Rather, the general principles set forth herein are merely illustrative of the scope of the present disclosure.

It should be appreciated that the present disclosure, which is described by the claims and not by the implementation details provided, and which can be modified by varying, omitting, adding, replacing, and in the absence of, any element(s), at least one of: limitation(s) with alternatives, and equivalent functional elements, whether specifically disclosed herein, will be apparent to those having ordinary skill in the relevant art, and may be made to the examples disclosed herein, and may provide many applicable inventive concepts that may be embodied in a wide variety of specific contexts, without straying from the present disclosure.

In some non-limiting examples, features, techniques, systems, sub-systems and methods described and illustrated in at least one of the above-described examples, whether described and illustrated as discrete/separate, may be combined/integrated in another system without departing from the scope of the present disclosure, to create alternative examples comprised of a (sub-) combination of features that may not be explicitly described above, including without limitation, where certain features may be omitted/not implemented. Features having applicability for such combinations and sub-combinations would be readily apparent to persons skilled in the art upon review of the present application as a whole. Other examples of changes, substitutions, and alterations are easily ascertainable and could be made without departing from the spirit and scope disclosed herein.

All statements herein reciting principles, aspects, and examples of the disclosure, as well as specific examples thereof, are intended to encompass both structural and functional equivalents thereof and to cover and embrace all applicable changes in technology. Additionally, it is intended that such equivalents include both currently known equivalents as well as equivalents developed in the future, i.e., any elements developed that perform the same function, regardless of structure.

### Clauses

The present disclosure includes, without limitation, the following clauses:

The device according to at least one clause herein wherein the patterning coating comprises a patterning material.

The device according to at least one clause herein, wherein an initial sticking probability against deposition of the deposited material of the patterning coating is no more than an initial sticking probability against deposition of the deposited material of the exposed layer surface.

The device according to at least one clause herein, wherein the patterning coating is substantially devoid of a closed coating of the deposited material.

The device according to at least one clause herein, wherein at least one of the patterning coating and the patterning material has an initial sticking probability against deposition of the deposited material that is one of no more than about: 0.3, 0.2, 0.15, 0.1, 0.08, 0.05, 0.03, 0.02, 0.01, 0.008, 0.005, 0.003, 0.001, 0.0008, 0.0005, 0.0003, and 0.0001.

The device according to at least one clause herein, wherein at least one of the patterning coating and the patterning material has an initial sticking probability against deposition of at least one of silver (Ag) and magnesium (Mg) that is one of no more than about: 0.3, 0.2, 0.15, 0.1, 0.08, 0.05, 0.03, 0.02, 0.01, 0.008, 0.005, 0.003, 0.001, 0.0008, 0.0005, 0.0003, and 0.0001.

The device according to at least one clause herein, wherein at least one of the patterning coating and the patterning material has an initial sticking probability against deposition of the deposited material of one of between about: 0.15-0.0001, 0.1-0.0003, 0.08-0.0005, 0.08-0.0008, 0.05-0.001, 0.03-0.0001, 0.03-0.0003, 0.03-0.0005, 0.03-0.0008, 0.03-0.001, 0.03-0.005, 0.03-0.008, 0.03-0.01, 0.02-0.0001, 0.02-0.0003, 0.02-0.0005, 0.02-0.0008, 0.02-0.001, 0.02-0.005, 0.02-0.008, 0.02-0.01, 0.01-0.0001, 0.01-0.0003, 0.01-0.0005, 0.01-0.0008, 0.01-0.001, 0.01-0.005, 0.01-0.008, 0.008-0.0001, 0.008-0.0003, 0.008-0.0005, 0.008-0.0008, 0.008-0.001, 0.008-0.005, 0.005-0.0001, 0.005-0.0003, 0.005-0.0005, 0.005-0.0008, and 0.005-0.001.

The device according to at least one clause herein, wherein at least one of the patterning coating and the patterning material has an initial sticking probability against deposition of the deposited material that is no more than a threshold value that is one of about: 0.3, 0.2, 0.18, 0.15, 0.13, 0.1, 0.08, 0.05, 0.03, 0.02, 0.01, 0.008, 0.005, 0.003, and 0.001.

The device according to at least one clause herein, wherein at least one of the patterning coating and the patterning material has an initial sticking probability against the deposition of one of: Ag, Mg, ytterbium (Yb), cadmium (Cd), and zinc (Zn), that is no more than the threshold value.

The device according to at least one clause herein, wherein the threshold value has a first threshold value against the deposition of a first deposited material and a second threshold value against the deposition of a second deposited material.

The device according to at least one clause herein, wherein the first deposited material is Ag and the second deposited material is Mg.

The device according to at least one clause herein, wherein the first deposited material is Ag and the second deposited material is Yb.

The device according to at least one clause herein, wherein the first deposited material is Yb and the second deposited material is Mg.

The device according to at least one clause herein, wherein the first threshold value exceeds the second threshold value.

The device according to at least one clause herein, wherein at least one of the patterning coating and the patterning material has a transmittance for light of at least a threshold transmittance value after being subjected to a vapor flux of the deposited material.

The device according to at least one clause herein, wherein the threshold transmittance value is measured at a wavelength in the visible spectrum.

The device according to at least one clause herein, wherein the threshold transmittance value is one of at least about 60%, 65%, 70%, 75%, 80%, 85%, and 90% of incident EM power transmitted therethrough.

The device according to at least one clause herein, wherein at least one of the patterning coating and the patterning material has a surface energy of one of no more than about: 24 dynes/cm, 22 dynes/cm, 20 dynes/cm, 18 dynes/cm, 16 dynes/cm, 15 dynes/cm, 13 dynes/cm, 12 dynes/cm, and 11 dynes/cm.

The device according to at least one clause herein, wherein at least one of the patterning coating and the patterning material has a surface energy that is one of at least about: 6 dynes/cm, 7 dynes/cm, and 8 dynes/cm.

The device according to at least one clause herein, wherein at least one of the patterning coating and the patterning material has a surface energy that is one of between about: 10-20 dynes/cm, and 13-19 dynes/cm.

The device according to at least one clause herein, wherein at least one of the patterning coating and the patterning material has a refractive index for light at a wavelength of 550 nm that is one of no more than about: 1.55, 1.5, 1.45, 1.43, 1.4, 1.39, 1.37, 1.35, 1.32, and 1.3

The device according to at least one clause herein, wherein at least one of the patterning coating and the patterning material has an extinction coefficient that is no more than about 0.01 for photons at a wavelength that exceeds one of about: 600 nm, 500 nm, 460 nm, 420 nm, and 410 nm.

The device according to at least one clause herein, wherein at least one of the patterning coating and the patterning material has an extinction coefficient that is one of at least about: 0.05, 0.1, 0.2, 0.5 for light at a wavelength shorter than one of at least about: 400 nm, 390 nm, 380 nm, and 370 nm.

The device according to at least one clause herein, wherein at least one of the patterning coating and the patterning material has a glass transition temperature that is that is one of: one of at least about: 300° C., 150° C., 130° C., 120° C., and 100° C., and one of no more than about: 30° C., 0° C., −30° C., and −50° C.

The device according to at least one clause herein, wherein the patterning material has a sublimation temperature of one of between about: 100-320° C., 120-300° C., 140-280° C., and 150-250° C.

The device according to at least one clause herein, wherein at least one of the patterning coating and the patterning material comprises at least one of a fluorine atom and a silicon atom.

The device according to at least one clause herein, wherein the patterning coating comprises fluorine and carbon.

The device according to at least one clause herein, wherein an atomic ratio of a quotient of fluorine by carbon is one of about: 1, 1.5, and 2.

The device according to at least one clause herein, wherein the patterning coating comprises an oligomer.

The device according to at least one clause herein, wherein the patterning coating comprises a compound having a molecular structure comprising a backbone and at least one functional group bonded thereto.

The device according to at least one clause herein, wherein the compound comprises at least one of: a siloxane group, a silsesquioxane group, an aryl group, a heteroaryl group, a fluoroalkyl group, a hydrocarbon group, a phosphazene group, a fluoropolymer, and a metal complex.

The device according to at least one clause herein, wherein a molecular weight of the compound is one of no more than about: 5,000 g/mol, 4,500 g/mol, 4,000 g/mol, 3,800 g/mol, and 3,500 g/mol.

The device according to at least one clause herein, wherein the molecular weight is about: 1,500 g/mol, 1,700 g/mol, 2,000 g/mol, 2,200 g/mol, and 2,500 g/mol.

The device according to at least one clause herein, wherein the molecular weight is one of between about: 1,500-5,000 g/mol, 1,500-4,500 g/mol, 1,700-4,500 g/mol, 2,000-4,000 g/mol, 2,200-4,000 g/mol, and 2,500-3,800 g/mol.

The device according to at least one clause herein, wherein a percentage of a molar weight of the compound that is attributable to a presence of fluorine atoms, is one of between about: 40-90%, 45-85%, 50-80%, 55-75%, and 60-75%.

The device according to at least one clause herein, wherein fluorine atoms comprise a majority of the molar weight of the compound.

The device according to at least one clause herein, wherein the patterning material comprises an organic-inorganic hybrid material.

The device according to at least one clause herein, wherein the patterning coating has at least one nucleation site for the deposited material.

The device according to at least one clause herein, wherein the patterning coating is supplemented with a seed material that acts as a nucleation site for the deposited material.

The device according to at least one clause herein, wherein the seed material comprises at least one of: a nucleation promoting coating (NPC) material, an organic material, a polycyclic aromatic compound, and a material comprising a non-metallic element selected from one of oxygen (O), sulfur(S), nitrogen (N), I carbon (C).

The device according to at least one clause herein, wherein the patterning coating acts as an optical coating.

The device according to at least one clause herein, wherein the patterning coating modifies at least one of a property and a characteristic of light emitted by the device.

The device according to at least one clause herein, wherein the patterning coating comprises a crystalline material.

The device according to at least one clause herein, wherein the patterning coating is deposited as a non-crystalline material and becomes crystallized after deposition.

The device according to at least one clause herein, wherein the deposited layer comprises a deposited material.

The device according to at least one clause herein, wherein the deposited material comprises an element selected from at least one of: potassium (K), sodium (Na), lithium (Li), barium (Ba), cesium (Cs), ytterbium (Yb), silver (Ag), gold (Au), copper (Cu), aluminum (Al), magnesium (Mg), zinc (Zn), cadmium (Cd), tin (Sn), nickel (Ni), and yttrium (Y).

The device according to at least one clause herein, wherein the deposited material comprises a pure metal.

The device according to at least one clause herein, wherein the deposited material is selected from one of pure Ag and substantially pure Ag.

The device according to at least one clause herein, wherein the substantially pure Ag has a purity of one of at least about: 95%, 99%, 99.9%, 99.99%, 99.999%, and 99.9995%.

The device according to at least one clause herein, wherein the deposited material is selected from one of pure Mg and substantially pure Mg.

The device according to at least one clause herein, wherein the substantially pure Mg has a purity of one of at least about: 95%, 99%, 99.9%, 99.99%, 99.999%, and 99.9995%.

The device according to at least one clause herein, wherein the deposited material comprises an alloy.

The device according to at least one clause herein, wherein the deposited material comprises at least one of: an Ag-containing alloy, an Mg-containing alloy, and an AgMg-containing alloy.

The device according to at least one clause herein, wherein the AgMg-containing alloy has an alloy composition that ranges from 1:10 (Ag:Mg) to about 10:1 by volume.

The device according to at least one clause herein, wherein the deposited material comprises at least one metal other than Ag.

The device according to at least one clause herein, wherein the deposited material comprises an alloy of Ag with at least one metal.

The device according to at least one clause herein, wherein the at least one metal is selected from at least one of Mg and Yb.

The device according to at least one clause herein, wherein the alloy is a binary alloy having a composition between about 5-95 vol. % Ag.

The device according to at least one clause herein, wherein the alloy comprises a Yb:Ag alloy having a composition between about 1:20-10:1 by volume.

The device according to at least one clause herein, wherein the deposited material comprises an Mg:Yb alloy.

The device according to at least one clause herein, wherein the deposited material comprises an Ag:Mg:Yb alloy.

The device according to at least one clause herein, wherein the deposited layer comprises at least one additional element.

The device according to at least one clause herein, wherein the at least one additional element is a non-metallic element.

The device according to at least one clause herein, wherein the non-metallic element is selected from at least one of O, S, N, and C.

The device according to at least one clause herein, wherein a concentration of the non-metallic element is one of no more than about: 1%, 0.1%, 0.01%, 0.001%, 0.0001%, 0.00001%, 0.000001%, and 0.0000001%.

The device according to at least one clause herein, wherein the deposited layer has a composition in which a combined amount of O and C is one of no more than about: 10%, 5%, 1%, 0.1%, 0.01%, 0.001%, 0.0001%, 0.00001%, 0.000001%, and 0.0000001%.

The device according to at least one clause herein, wherein the non-metallic element acts as a nucleation site for the deposited material on the NIC.

The device according to at least one clause herein, wherein the deposited material and the underlying layer comprise a metal in common.

The device according to at least one clause herein, the deposited layer comprises a plurality of layers of the deposited material.

The device according to at least one clause herein, a deposited material of a first one of the plurality of layers is different from a deposited material of a second one of the plurality of layers.

The device according to at least one clause herein, wherein the deposited layer comprises a multilayer coating.

The device according to at least one clause herein, wherein the multilayer coating is one of: Yb/Ag, Yb/Mg, Yb/Mg:Ag, Yb/Yb:Ag, Yb/Ag/Mg, and Yb/Mg/Ag.

The device according to at least one clause herein, wherein the deposited material comprises a metal having a bond dissociation energy of one of no more than about: 300 kJ/mol, 200 kJ/mol, 165 kJ/mol, 150 kJ/mol, 100 kJ/mol, 50 kJ/mol, and 20 kJ/mol.

The device according to at least one clause herein, wherein the deposited material comprises a metal having an electronegativity of one of no more than about: 1.4, 1.3, and 1.2.

The device according to at least one clause herein, wherein a sheet resistance of the deposited layer is one of no more than about: 10 Ω/□, 5Ω/□, 1Ω/□, 0.5Ω/□, 0.2Ω/□, and 0.1Ω/□.

The device according to at least one clause herein, wherein the deposited layer is disposed in a pattern defined by at least one region therein that is substantially devoid of a closed coating thereof.

The device according to at least one clause herein, wherein the at least one region separates the deposited layer into a plurality of discrete fragments thereof.

The device according to at least one clause herein, wherein at least two discrete fragments are electrically coupled.

The device according to at least one clause herein, wherein the patterning coating has a boundary defined by a patterning coating edge.

The device according to at least one clause herein, wherein the patterning coating comprises at least one patterning coating transition region and a patterning coating non-transition part.

The device according to at least one clause herein, wherein the at least one patterning coating transition region transitions from a maximum thickness to a reduced thickness.

The device according to at least one clause herein, wherein the at least one patterning coating transition region extends between the patterning coating non-transition part and the patterning coating edge.

The device according to at least one clause herein, wherein the patterning coating has an average film thickness in the patterning coating non-transition part that is in a range of one of between about: 1-100 nm, 2-50 nm, 3-30 nm, 4-20 nm, 5-15 nm, 5-10 nm, and 1-10 nm.

The device according to at least one clause herein, wherein a thickness of the patterning coating in the patterning coating non-transition part is within one of about: 95%, and 90% of the average film thickness of the NIC.

The device according to at least one clause herein, wherein the average film thickness is one of no more than about: 80 nm, 60 nm, 50 nm, 40 nm, 30 nm, 20 nm, 15 nm, and 10 nm.

The device according to at least one clause herein, wherein the average film thickness exceeds one of about: 3 nm, 5 nm, and 8 nm.

The device according to at least one clause herein, wherein the average film thickness is no more than about 10 nm.

The device according to at least one clause herein, wherein the patterning coating has a patterning coating thickness that decreases from a maximum to a minimum within the patterning coating transition region.

The device according to at least one clause herein, wherein the maximum is proximate to a boundary between the patterning coating transition region and the patterning coating non-transition part.

The device according to at least one clause herein, wherein the maximum is a percentage of the average film thickness that is one of about: 100%, 95%, and 90%.

The device according to at least one clause herein, wherein the minimum is proximate to the patterning coating edge.

The device according to at least one clause herein, wherein the minimum is in a range of between about: 0-0.1 nm.

The device according to at least one clause herein, wherein a profile of the patterning coating thickness is one of sloped, tapered, and defined by a gradient.

The device according to at least one clause herein, wherein the tapered profile follows one of a linear, non-linear, parabolic, and exponential decaying profile.

The device according to at least one clause herein, wherein a non-transition width along a lateral axis of the patterning coating non-transition region exceeds a transition width along the axis of the patterning coating transition region.

The device according to at least one clause herein, wherein a quotient of the non-transition width by the transition width is one of at least about: 5, 10, 20, 50, 100, 500, 1,000, 1,500, 5,000, 10,000, 50,000, and 100,000.

The device according to at least one clause herein, wherein at least one of the non-transition width and the transition width exceeds an average film thickness of the underlying layer.

The device according to at least one clause herein, wherein at least one of the non-transition width and the transition width exceeds the average film thickness of the patterning coating.

The device according to at least one clause herein, wherein the average film thickness of the underlying layer exceeds the average film thickness of the patterning coating.

The device according to at least one clause herein, wherein the deposited layer has a boundary defined by a deposited layer edge.

The device according to at least one clause herein, wherein the deposited layer comprises at least one deposited layer transition region and a deposited layer non-transition part.

The device according to at least one clause herein, wherein the at least one deposited layer transition region transitions from a maximum thickness to a reduced thickness.

The device according to at least one clause herein, wherein the at least one deposited layer transition region extends between the deposited layer non-transition part and the deposited layer edge.

The device according to at least one clause herein, wherein the deposited layer has an average film thickness in the deposited layer non-transition part that is in a range of one of between about: 1-500 nm, 5-200 nm, 5-40 nm, 10-30 nm, and 10-100 nm.

The device according to at least one clause herein, wherein the average film thickness exceeds one of about: 10 nm, 50 nm, and 100 nm.

The device according to at least one clause herein, wherein the average film thickness of is substantially constant thereacross.

The device according to at least one clause herein, wherein the average film thickness exceeds an average film thickness of the underlying layer.

The device according to at least one clause herein, wherein a quotient of the average film thickness of the deposited layer by the average film thickness of the underlying layer is one of at least about: 1.5, 2, 5, 10, 20, 50, and 100.

The device according to at least one clause herein, wherein the quotient is in a range of one of between about: 0.1-10, and 0.2-40.

The device according to at least one clause herein, wherein the average film thickness of the deposited layer exceeds an average film thickness of the patterning coating.

The device according to at least one clause herein, wherein a quotient of the average film thickness of the deposited layer by the average film thickness of the patterning coating is one of at least about: 1.5, 2, 5, 10, 20, 50, and 100.

The device according to at least one clause herein, wherein the quotient is in a range of one of between about: 0.2-10, and 0.5-40.

The device according to at least one clause herein, wherein a deposited layer non-transition width along a lateral axis of the deposited layer non-transition part exceeds a patterning coating non-transition width along the axis of the patterning coating non-transition part.

The device according to at least one clause herein, wherein a quotient of the patterning coating non-transition width by the deposited layer non-transition width is one of between about: 0.1-10, 0.2-5, 0.3-3, and 0.4-2.

The device according to at least one clause herein, wherein a quotient of the deposited layer non-transition width by the patterning coating non-transition width is one of at least: 1, 2, 3, and 4.

The device according to at least one clause herein, wherein the deposited layer non-transition width exceeds the average film thickness of the deposited layer.

The device according to at least one clause herein, wherein a quotient of the deposited layer non-transition width by the average film thickness is at least one of about: 10, 50, 100, and 500.

The device according to at least one clause herein, wherein the quotient is no more than about 100,000.

The device according to at least one clause herein, wherein the deposited layer has a deposited layer thickness that decreases from a maximum to a minimum within the deposited layer transition region.

The device according to at least one clause herein, wherein the maximum is proximate to a boundary between the deposited layer transition region and the deposited layer non-transition part.

The device according to at least one clause herein, wherein the maximum is the average film thickness.

The device according to at least one clause herein, wherein the minimum is proximate to the deposited layer edge.

The device according to at least one clause herein, wherein the minimum is in a range of between about: 0-0.1 nm.

The device according to at least one clause herein, wherein the minimum is the average film thickness.

The device according to at least one clause herein, wherein a profile of the deposited layer thickness is one of sloped, tapered, and defined by a gradient.

The device according to at least one clause herein, wherein the tapered profile follows one of a linear, non-linear, parabolic, and exponential decaying profile.

The device according to at least one clause herein, wherein the deposited layer comprises a discontinuous layer in at least a part of the deposited layer transition region.

The device according to at least one clause herein, wherein the deposited layer overlaps the patterning coating in an overlap portion.

The device according to at least one clause herein, wherein the patterning coating overlaps the deposited layer in an overlap portion.

The device according to at least one clause herein, further comprising at least one particle structure disposed on an exposed layer surface of an underlying layer.

The device according to at least one clause herein, wherein the underlying layer is the patterning coating.

The device according to at least one clause herein, wherein the at least one particle structure comprises a particle material.

The device according to at least one clause herein, wherein the particle material is the same as the deposited material.

The device according to at least one clause herein, wherein at least two of the particle material, the deposited material, and a material of which the underlying layer is comprised, comprises a metal in common.

The device according to at least one clause herein, wherein the particle material comprises an element selected from at least one of: potassium (K), sodium (Na), lithium (Li), barium (Ba), cesium (Cs), ytterbium (Yb), silver (Ag), gold (Au), copper (Cu), aluminum (Al), magnesium (Mg), zinc (Zn), cadmium (Cd), tin (Sn), nickel (Ni), and yttrium (Y).

The device according to at least one clause herein, wherein the particle material comprises a pure metal.

The device according to at least one clause herein, wherein the particle material is selected from one of pure Ag and substantially pure Ag.

The device according to at least one clause herein, wherein the substantially pure Ag has a purity of one of at least about: 95%, 99%, 99.9%, 99.99%, 99.999%, and 99.9995%.

The device according to at least one clause herein, wherein the particle material is selected from one of pure Mg and substantially pure Mg.

The device according to at least one clause herein, wherein the substantially pure Mg has a purity of one of at least about: 95%, 99%, 99.9%, 99.99%, 99.999%, and 99.9995%.

The device according to at least one clause herein, wherein the particle material comprises an alloy.

The device according to at least one clause herein, wherein the particle material comprises at least one of: an Ag-containing alloy, an Mg-containing alloy, and an AgMg-containing alloy.

The device according to at least one clause herein, wherein the AgMg-containing alloy has an alloy composition that ranges from 1:10 (Ag:Mg) to about 10:1 by volume.

The device according to at least one clause herein, wherein the particle material comprises at least one metal other than Ag.

The device according to at least one clause herein, wherein the particle material comprises an alloy of Ag with at least one metal.

The device according to at least one clause herein, wherein the at least one metal is selected from at least one of Mg and Yb.

The device according to at least one clause herein, wherein the alloy is a binary alloy having a composition between about 5-95 vol. % Ag.

The device according to at least one clause herein, wherein the alloy comprises a Yb:Ag alloy having a composition between about 1:20-10:1 by volume.

The device according to at least one clause herein, wherein the particle material comprises an Mg:Yb alloy.

The device according to at least one clause herein, wherein the particle material comprises an Ag:Mg:Yb alloy.

The device according to at least one clause herein, wherein the at least one particle structure comprises at least one additional element.

The device according to at least one clause herein, wherein the at least one additional element is a non-metallic element.

The device according to at least one clause herein, wherein the non-metallic element is selected from at least one of O, S, N, and C.

The device according to at least one clause herein, wherein a concentration of the non-metallic element is one of no more than about: 1%, 0.1%, 0.01%, 0.001%, 0.0001%, 0.00001%, 0.000001%, and 0.0000001%.

The device according to at least one clause herein, wherein the at least one particle structure has a composition in which a combined amount of O and C is one of no more than about: 10%, 5%, 1%, 0.1%, 0.01%, 0.001%, 0.0001%, 0.00001%, 0.000001%, and 0.0000001%.

The device according to at least one clause herein, wherein the at least one particle is disposed at an interface between the patterning coating and at least one overlying layer in the device.

The device according to at least one clause herein, wherein the at least one particle is in physical contact with an exposed layer surface of the patterning coating.

The device according to at least one clause herein, wherein the at least one particle structure affects at least one optical property of the device.

The device according to at least one clause herein, wherein the at least one optical property is controlled by selection of at least one property of the at least one particle structure selected from at least one of: a characteristic size, a length, a width, a diameter, a height, a size distribution, a shape, a surface coverage, a configuration, a deposited density, a dispersity, and a composition.

The device according to at least one clause herein, wherein the at least one property of the at least one particle structure is controlled by selection of at least one of: at least one characteristic of the patterning material, an average film thickness of the patterning coating, at least one heterogeneity in the patterning coating, and a deposition environment for the patterning coating, selected from at least one of a temperature, pressure, duration, deposition rate, and deposition process.

The device according to at least one clause herein, wherein the at least one property of the at least one particle structure is controlled by selection of at least one of: at least one characteristic of the particle material, an extent to which the patterning coating is exposed to deposition of the particle material, a thickness of the discontinuous layer, and a deposition environment for the particle material, selected from at least one of a temperature, pressure, duration, deposition rate, and deposition process.

The device according to at least one clause herein, wherein the at least one particle structures are disconnected from one another.

The device according to at least one clause herein, wherein the at least one particle structure forms a discontinuous layer.

The device according to at least one clause herein, wherein the discontinuous layer is disposed in a pattern defined by at least one region therein that is substantially devoid of the at least one particle structure.

The device according to at least one clause herein, wherein a characteristic of the discontinuous layer is determined by an assessment according to at least one criterion selected from one of: a characteristic size, length, width, diameter, height, size distribution, shape, configuration, surface coverage, deposited distribution, dispersity, presence of aggregation instances, and extent of such aggregation instances.

The device according to at least one clause herein, wherein the assessment is performed by determining at least one attribute of the discontinuous layer by an applied imaging technique selected from one of: electron microscopy, atomic force microscopy, and scanning electron microscopy.

The device according to at least one clause herein, wherein the assessment is performed across an extent defined by at least one observation window.

The device according to at least one clause herein, wherein the at least one observation window is located at one of: a perimeter, interior location, and grid coordinate of the lateral aspect.

The device according to at least one clause herein, wherein the observation window corresponds to a field of view of the applied imaging technique.

The device according to at least one clause herein, wherein the observation window corresponds to a magnification level selected from one of: 2.00 μm, 1.00 μm, 500 nm, and 200 nm.

The device according to at least one clause herein, wherein the assessment incorporates at least one of: manual counting, curve fitting, polygon fitting, shape fitting, and an estimation technique.

The device according to at least one clause herein, wherein the assessment incorporates a manipulation selected from one of: an average, median, mode, maximum, minimum, probabilistic, statistical, and data calculation.

The device according to at least one clause herein, wherein the characteristic size is determined from at least one of: a mass, volume, diameter, perimeter, major axis, and minor axis of the at least one particle structure.

The device according to at least one clause herein, wherein the dispersity is determined from:

$$D = \frac{\overline{{S}_{s}}}{\overline{{S}_{n}}}$$

$$where :$$

$$\overline{{S}_{s}} = \frac{{\sum }_{i = 1}^{n} {s}_{i}^{2}}{{\sum }_{i = 1}^{n} {s}_{i}} , \overline{{S}_{n}} = \frac{{\sum }_{i = 1}^{n} {s}_{i}}{n} ,$$

n is the number of particles in a sample area,
Sᵢ is the (area) size of the i^{th} particle,
S̅ₙ is the number average of the particle (area) sizes; and
S̅ₛ is the (area) size average of the particle (area) sizes.

Accordingly, the specification and the examples disclosed therein are to be considered illustrative only, with a true scope of the disclosure being disclosed by the following numbered claims:

What is claimed is:

1. An electronic device comprising:
a display panel extending in a lateral aspect defined by a lateral axis and comprising at least one signal-exchanging part comprising:
a plurality of emissive regions, each corresponding to a (sub-) pixel; and
a plurality of transmissive regions, each transmissive region being disposed between adjacent emissive regions in the lateral aspect,
a first opto-electronic component and a second opto-electronic component, each adapted to at least one of: emit, and receive, light in a wavelength spectrum that lies within at least one of a: visible, infrared (IR), and near-infrared (NIR), spectrum, and each having, associated therewith, a point spread function (PSF) comprising a main lobe and at least one side lobe;
wherein:
the first opto-electronic component is arranged behind a first one of the at least one signal-exchanging part(s) of the display panel, such that light that is the at least one of: emitted, and received, by the first opto-electronic component, passes through at least one of the transmissive region(s) of the first signal-exchanging part; and
a first PSF associated with the first opto-electronic component comprises a component associated with a layout of the at least one transmissive region(s) of the first signal-exchanging part, and differs from a second PSF associated with the second opto-electronic component, in at least one of a(n): distribution, and intensity, of at least one of the: main, and at least one side, lobe.

2. The electronic device of claim 1, wherein a side-lobe pattern of the first PSF is substantially devoid of a side lobe that overlaps with a side-lobe pattern of the second PSF.

3. The electronic device of claim 1, wherein a side-lobe pattern of the first PSF at least partially overlaps with a side-lobe pattern of the second PSF.

4. The electronic device of claim 1, wherein a first subset of the at least one side lobe of the first PSF at least partially overlaps with one of: all, and a subset of, the side lobes of the second PSF.

5. The electronic device of claim 4, wherein a second subset of the at least one side lobe of the first PSF is substantially devoid of a side lobe that overlaps with any side lobe of the second PSF.

6. The electronic device of claim 1, wherein each side lobe of one of the: first, and second, PSF, corresponds to, and at least partially overlaps with, a side lobe of the other of the: first, and second, PSF.

7. The electronic device of claim 1, wherein the overlap between the side-lobe pattern of the first PSF and the side-lobe pattern of the second PSF is one of no more than about: 60%, 50%, 40%, 30%, 20%, 25%, 20%, 10%, and 5%.

8. The electronic device of claim 1, wherein an intensity of the at least one side lobe of the first PSF differs from an intensity of the at least one side lobe of the second PSF, in at least one of: a profile, and an intensity level.

9. The electronic device of claim 1, wherein the main lobe of the first PSF at least partially overlaps with a side lobe of the second PSF.

10. The electronic device of claim 1, wherein a distribution of the main lobe of the first PSF differs from a distribution of the main lobe of the second PSF.

11. The electronic device of claim 1, wherein the main lobe of the first PSF differs from the main lobe of the second PSF, in at least one of: a profile, and an intensity level.

12. The electronic device of claim 1, wherein the layout of the at least one transmissive region of the at least one signal-exchanging part is characterized by at least one of a: size, shape, orientation, and pitch, thereof.

13. The electronic device of claim 1, wherein the first opto-electronic component and the second opto-electronic component are spaced apart in the lateral aspect of the display panel.

14. The electronic device of claim 1, wherein the first opto-electronic component and the second opto-electronic component are positioned substantially at at least one of: an extremity of the display panel, a centre thereof, and a centre of one of: a side, and an end, of the display panel.

15. The electronic device of claim 1, wherein the second opto-electronic component is arranged in a part of the device that is substantially devoid of the (sub-) pixels of the display panel.

16. The electronic device of claim 1, wherein at least one of the: first opto-electronic component, and second opto-electronic component, comprises at least one of:
a transmitter adapted to emit light, and
a receiver adapted to receive light.

17. The electronic device of claim 1, wherein the first opto-electronic component is an under-display camera.

18. The electronic device of claim 17, wherein the second opto-electronic component is the transmitter.

19. The electronic device of claim 16, wherein the second opto-electronic component is a non under-display component.

20. The electronic device of claim 1, wherein:
the second opto-electronic component is arranged behind a second one of the at least one signal-exchanging part, such that light that is at least one of: emitted, and received, by the second opto-electronic component passes through at least one of the transmissive regions of the second signal-exchanging part, and
the second PSF comprises a component associated with a layout of the at least one transmissive region(s) of the second signal-exchanging part that is different from the layout of the at least one transmissive region(s) of the first signal-exchanging part, in at least one of the: size, shape, orientation, and pitch, thereof.

21. The electronic device of claim 20, wherein at least a part of at least one transmissive region of at least one of: the first signal-exchanging part, and the second signal-exchanging part, has deposited thereon, a patterning coating adapted to impact a propensity of an evaporated flux of a deposited material to be deposited thereon.

22. The electronic device of claim 21, wherein the at least one transmissive region comprises: a first portion that has a first transmittance, and a second portion that has a second transmittance, the first transmittance being at least that of the second transmittance.

23. The electronic device of claim 22, wherein the patterning coating is deposited at least in the first portion.

24. The electronic device of claim 1, wherein:
the first opto-electronic component is adapted to generate a first output that contains diffracted information correlated with the first PSF,
the second opto-electronic component is adapted to generate a second output that contains diffracted information correlated with the second PSF, and
the device comprises a processor adapted to process the first output and the second output to produce a processed output.

25. The electronic device of claim 24, wherein the processor is adapted to apply a correction to the: first, and second, output, to generate a first corrected output and a second corrected output.

26. The electronic device of claim 24, wherein the correction comprises diffraction correction.

27. The electronic device of claim 26, wherein the diffraction correction corrects diffraction contained in the output of one of the: first, and second, opto-electronic component, using the PSF of the other of the: first, and second, opto-electronic component.

28. The electronic device of claim 25, wherein the processor is adapted to produce the processed output by combining the first corrected output and the second corrected output.

29. The electronic device of claim 25, wherein the processed output is displayed by the display panel.

30. The electronic device of claim 25, wherein the processed output comprises at least one of: an image file, a video file, a 3D image, and a 3D video.
